(19) United States
(12) Patent Application Publication
(10) Pub. No.: US 2004/0118348 A1
(43) Pub. Date: Jun. 24, 2004

(54) Microwave power cell, chemical reactor, and power converter

(76) Inventor: Randell L.. Mills, Cranbury, NJ (US)

Correspondence Address: MANELLI DENISON & SELTER, 2000 M STREET NW SUITE 700, WASHINGTON, DC, 20036-3307, US

(21) Appl. No.: 10/469,913

(22) PCT Filed: Mar. 7, 2002
(86) PCT No.: PCT/US02/06945

(51) Int. Cl. C23C 16/00

(52) U.S. Cl. 118/723 MW

(57) ABSTRACT

Provided is a power source and/or power converter. The power source includes a cell 910 for the catalysis of atomic hydrogen to form novel hydrogen species and/or compositions of matter comprising new forms of hydrogen. The reaction can be initiated and/or maintained by a microwave or glow discharge plasma of hydrogen and a source of catalyst The plasma power may be converted to electricity by a magnetohydrodynamic power converter 913 or a plasmadynamic power converter.

### I. INTRODUCTION

1. Field of the Invention

This invention relates to a power source and/or power converter. The power source comprises a cell for the catalysis of atomic hydrogen to form novel hydrogen species and/or compositions of matter comprising new forms of hydrogen. The reaction may be initiated and/or maintained by a microwave or glow discharge plasma of hydrogen and a source of catalyst. The power from the catalysis of hydrogen may be directly converted into electricity since it forms or contributes energy to the plasma. The plasma power may be converted to electricity by a magnetohydrodynamic power converter from a directional flow of ions formed using a magnetic mirror based on the adiabatic invariant

$$\frac{{v}_{⊥}^{2}}{B} = constant .$$

Alternatively, the power converter comprises a magnetic field which permits positive ions to be separated from electrons using at least one electrode to produce a voltage with respect to at least one counter electrode connected through a load.

2. Background of the Invention

2.1 Hydrinos

A hydrogen atom having a binding energy given by

$$Binding Energy = \frac{13.6 eV}{{( \frac{1}{p} )}^{2}} \qquad ( 1 )$$

where p is an integer greater than 1, preferably from 2 to 200, is disclosed in R. Mills, The Grand Unified Theory of Classical Quantum Mechanics, January 2000 Edition, BlackLight Power, Inc., Cranbury, N.J., Distributed by Amazon.com (“'00 Mills GUT”), provided by BlackLight Power, Inc., 493 Old Trenton Road, Cranbury, N.J., 08512; R. Mills, The Grand Unified Theory of Classical Quantum Mechanics, September 2001 Edition, BlackLight Power, Inc., Cranbury, N.J., Distributed by Amazon.com (“'01 Mills GUT”), provided by BlackLight Power, Inc., 493 Old Trenton Road, Cranbury, N.J., 08512 (posted at www.blacklightpower.com); R. Mills, P. Ray, R. Mayo, “CW HI Laser Based on a Stationary Inverted Lyman Population Formed from Incandescently Heated Hydrogen Gas with Certain Group 1 Catalysts”, IEEE Transactions on Plasma Science, submitted; R. L. Mills, P. Ray, J. Dong, M. Nansteel, B. Dhandapani, J. He, “Spectral Emission of Fractional-Principal-Quantum-Energy-Level Molecular Hydrogen”, Int. J. Hydrogen Energy, submitted; R. L. Mills, P. Ray, E. Dayalan, B. Dhandapani, J. He, “Comparison of Excessive Balmer α Line Broadening of Inductively and Capacitively Coupled RF, Microwave, and Glow Discharge Hydrogen Plasmas with Certain Catalysts”, Spectrochimica Acta, Part A, submitted; R. Mayo, R. Mills, M. Nansteel, “Direct Plasmadynamic Conversion of Plasma Thermal Power to Electricity”, IEEE Transactions on Plasma Science, submitted; H. Conrads, R. Mills, Th. Wrubel, “Emission in the Deep Vacuum Ultraviolet from an Incandescently Driven Plasma in a Potassium Carbonate Cell”, Plasma Sources Science and Technology, submitted; R. L. Mills, P. Ray, “Stationary Inverted Lyman Population Formed from Incandescently Heated Hydrogen Gas with Certain Catalysts”, Chem. Phys. Letts., submitted; R. L. Mills, B. Dhandapani, J. He, “Synthesis and Characterization of a Highly Stable Amorphous Silicon Hydride”, Int. J. Hydrogen Energy, submitted; R. L. Mills, A. Voigt, B. Dhandapani, J. He, “Synthesis and Characterization of Lithium Chloro Hydride”, Int. J. Hydrogen Energy, submitted; R. L. Mills, P. Ray, “Substantial Changes in the Characteristics of a Microwave Plasma Due to Combining Argon and Hydrogen”, New Journal of Physics, submitted; R. L. Mills, P. Ray, “High Resolution Spectroscopic Observation of the Bound-Free Hyperfine Levels of a Novel Hydride Ion Corresponding to a Fractional Rydberg State of Atomic Hydrogen”, Int. J. Hydrogen Energy, in press; R. L. Mills, E. Dayalan, “Novel Alkali and Alkaline Earth Hydrides for High Voltage and High Energy Density Batteries”, Proceedings of the 17^{th} Annual Battery Conference on Applications and Advances, California State University, Long Beach, Calif., (Jan. 15-18, 2002), pp. 1-6; R. Mayo, R. Mills, M. Nansteel, “On the Potential of Direct and MHD Conversion of Power from a Novel Plasma Source to Electricity for Microdistributed Power Applications”, IEEE Transactions on Plasma Science, submitted; R. Mills, P. Ray, J. Dong, M. Nansteel, W. Good, P. Jansson, B. Dhandapani, J. He, “Excessive Balmer α Line Broadening, Power Balance, and Novel Hydride Ion Product of Plasma Formed from Incandescently Heated Hydrogen Gas with Certain Catalysts”, Int. J. Hydrogen Energy, submitted; R. Mills, E. Dayalan, P. Ray, B. Dhandapani, J. He, “Highly Stable Novel Inorganic Hydrides from Aqueous Electrolysis and Plasma Electrolysis”, Japanese Journal of Applied Physics, submitted; R. L. Mills, P. Ray, B. Dhandapani, J. He, “Comparison of Excessive Balmer α Line Broadening of Glow Discharge and Microwave Hydrogen Plasmas with Certain Catalysts”, Chem. Phys., submitted; R. L. Mills, P. Ray, B. Dhandapani, J. He, “Spectroscopic Identification of Fractional Rydberg States of Atomic Hydrogen”, J. of Phys. Chem. (letter), submitted; R. L. Mills, P. Ray, B. Dhandapani, M. Nansteel, X. Chen, J. He, “New Power Source from Fractional Rydberg States of Atomic Hydrogen”, Chem. Phys. Letts., in press; R. L. Mills, P. Ray, B. Dhandapani, M. Nansteel, X. Chen, J. He, “Spectroscopic Identification of Transitions of Fractional Rydberg States of Atomic Hydrogen”, Quantitative Spectroscopy and Energy Transfer, submitted; R. L. Mills, P. Ray, B. Dhandapani, M. Nansteel, X. Chen, J. He, “New Power Source from Fractional Quantum Energy Levels of Atomic Hydrogen that Surpasses Internal Combustion”, Spectrochimica Acta, Part A, submitted; R. L. Mills, P. Ray, “Spectroscopic Identification of a Novel Catalytic Reaction of Rubidium Ion with Atomic Hydrogen and the Hydride Ion Product”, Int. J. Hydrogen Energy, in press; R. Mills, J. Dong, W. Good, P. Ray, J. He, B. Dhandapani, “Measurement of Energy Balances of Noble Gas-Hydrogen Discharge Plasmas Using Calvet Calorimetry”, Int. J. Hydrogen Energy, in press; R. L. Mills, A. Voigt, P. Ray, M. Nansteel, B. Dhandapani, “Measurement of Hydrogen Balmer Line Broadening and Thermal Power Balances of Noble Gas-Hydrogen Discharge Plasmas”, Int. J. Hydrogen Energy, Vol.27, No. 6, (2002), pp. 671-685; R. Mills, P. Ray, “Vibrational Spectral Emission of Fractional-Principal-Quantum-Energy-Level Hydrogen Molecular Ion”, Int. J. Hydrogen Energy, Vol.27, No. 5, (2002), pp. 533-564; R. Mills, P. Ray, “Spectral Emission of Fractional Quantum Energy Levels of Atomic Hydrogen from a Helium-Hydrogen Plasma and the Implications for Dark Matter”, Int. J. Hydrogen Energy, Vol. 27, No. 3, pp. 301-322; R. Mills, P. Ray, “Spectroscopic Identification of a Novel Catalytic Reaction of Potassium and Atomic Hydrogen and the Hydride Ion Product”, Int. J. Hydrogen Energy, Vol. 27, No. 2, (2002), pp. 183-192; R. Mills, “BlackLight Power Technology—A New Clean Hydrogen Energy Source with the Potential for Direct Conversion to Electricity”, Proceedings of the National Hydrogen Association, 12 th Annual U.S. Hydrogen Meeting and Exposition, Hydrogen: The Common Thread, The Washington Hilton and Towers, Washington D.C., (Mar. 6-8, 2001), pp. 671-697; R. Mills, W. Good, A. Voigt, Jinquan Dong, “Minimum Heat of Formation of Potassium Iodo Hydride”, Int. J. Hydrogen Energy, Vol. 26, No. 11, (2001), pp. 1199-1208; R. Mills, “Spectroscopic Identification of a Novel Catalytic Reaction of Atomic Hydrogen and the Hydride Ion Product”, Int. J. Hydrogen Energy, Vol.26, No. 10, (2001), pp.1041-1058; R. Mills, N. Greenig, S. Hicks, “Optically Measured Power Balances of Glow Discharges of Mixtures of Argon, Hydrogen, and Potassium, Rubidium, Cesium, or Strontium Vapor”, Int. J. Hydrogen Energy, Vol. 27, No. 6, (2002), pp. 651-670; R. Mills, “The Grand Unified Theory of Classical Quantum Mechanics”, Global Foundation, Inc. Orbis Scientiae entitled The Role of Attractive and Repulsive Gravitational Forces in Cosmic Acceleration of Particles The Origin of the Cosmic Gamma Ray Bursts, (29 th Conference on High Energy Physics and Cosmology Since 1964) Dr. Behram N. Kursunoglu, Chairman, Dec. 14-17, 2000, Lago Mar Resort, Fort Lauderdale, Fla., Kluwer Academic/Plenum Publishers, New York, pp. 243-258; R. Mills, “The Grand Unified Theory of Classical Quantum Mechanics”, Int. J. Hydrogen Energy, Vol. 27, No. 5, (2002), pp. 565-590; R. Mills and M. Nansteel, P. Ray, “Argon-Hydrogen-Strontium Discharge Light Source”, IEEE Transactions on Plasma Science, in press;. R. Mills, B. Dhandapani, M. Nansteel, J. He, A. “Voigt, Identification of Compounds Containing Novel Hydride Ions by Nuclear Magnetic Resonance Spectroscopy”, Int. J. Hydrogen Energy, Vol. 26, No. 9, (2001), pp. 965-979; R. Mills, “BlackLight Power Technology—A New Clean Energy Source with the Potential for Direct Conversion to Electricity”, Global Foundation International Conference on “Global Warming and Energy Policy”, Dr. Behram N. Kursunoglu, Chairman, Fort Lauderdale, Fla., Nov. 26-28, 2000, Kluwer Academic/Plenum Publishers, New York, pp. 1059-1096; R. Mills, “The Nature of Free Electrons in Superfluid Helium—a Test of Quantum Mechanics and a Basis to Review its Foundations and Make a Comparison to Classical Theory”, Int. J. Hydrogen Energy, Vol. 26, No. 10, (2001), pp. 1059-1096; R. Mills, M. Nansteel, and Y. Lu, “Excessively Bright Hydrogen-Strontium Plasma Light Source Due to Energy Resonance of Strontium with Hydrogen”, Plasma Chemistry and Plasma Processing, submitted; R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943; R. Mills, “Observation of Extreme Ultraviolet Emission from Hydrogen-KI Plasmas Produced by a Hollow Cathode Discharge”, Int. J. Hydrogen Energy, Vol. 26, No. 6, (2001), pp.579-592; R. Mills, “Temporal Behavior of Light-Emission in the Visible Spectral Range from a Ti—K2CO3—H-Cell”, Int. J. Hydrogen Energy, Vol. 26, No. 4, (2001), pp.327-332; R. Mills, T. Onuma, and Y. Lu, “Formation of a Hydrogen Plasma from an Incandescently Heated Hydrogen-Catalyst Gas Mixture with an Anomalous Afterglow Duration”, Int. J. Hydrogen Energy, Vol. 26, No. 7, July, (2001), pp. 749-762; R. Mills, M. Nansteel, and Y. Lu, “Observation of Extreme Ultraviolet Hydrogen Emission from Incandescently Heated Hydrogen Gas with Strontium that Produced an Anomalous Optically Measured Power Balance”, Int. J. Hydrogen Energy, Vol. 26, No. 4, (2001), pp.309-326; R. Mills, The Grand Unified Theory of Classical Quantum Mechanics, September 2001 Edition, BlackLight Power, Inc., Cranbury, N.J., Distributed by Amazon.com; R. Mills, B. Dhandapani, N. Greenig, J. He, “Synthesis and Characterization of Potassium Iodo Hydride”, Int. J. of Hydrogen Energy, Vol. 25, Issue 12, Dec., (2000), pp. 1185-1203; R. Mills, “Novel Inorganic Hydride”, Int. J. of Hydrogen Energy, Vol. 25, (2000), pp. 669-683; R. Mills, B. Dhandapani, M. Nansteel, J. He, T. Shannon, A. Echezuria, “Synthesis and Characterization of Novel Hydride Compounds”, Int. J. of Hydrogen Energy, Vol. 26, No. 4, (2001), pp. 339-367;. R. Mills, “Highly Stable Novel Inorganic Hydrides”, Journal of New Materials for Electrochemical Systems, in press; R. Mills, “Novel Hydrogen Compounds from a Potassium Carbonate Electrolytic Cell”, Fusion Technology, Vol. 37, No. 2, March, (2000), pp.157-182; R. Mills, “The Hydrogen Atom Revisited”, Int. J. of Hydrogen Energy, Vol. 25, Issue 12, December, (2000), pp. 1171-1183.; Mills, R., Good, W., “Fractional Quantum Energy Levels of Hydrogen”, Fusion Technology, Vol. 28, No. 4, November, (1995), pp. 1697-1719; Mills, R., Good, W., Shaubach, R., “Dihydrino Molecule Identification”, Fusion Technology, Vol. 25, 103 (1994); R. Mills and S. Kneizys, Fusion Technol. Vol. 20, 65 (1991); V. Noninski, Fusion Technol., Vol. 21, 163 (1992); Niedra, J., Meyers, I., Fralick, G. C., and Baldwin, R., “Replication of the Apparent Excess Heat Effect in a Light Water-Potassium Carbonate-Nickel Electrolytic Cell, NASA Technical Memorandum 107167, February, (1996). pp. 1-20.; Niedra, J., Baldwin, R., Meyers, I., NASA Presentation of Light Water Electrolytic Tests, May 15, 1994.; and in prior PCT applications PCT/US00/20820; PCT/US00/20819; PCT/US99/17171; PCT/US99/17129; PCT/US 98/22822; PCT/US98/14029; PCT/US96/07949; PCT/US94/02219; PCT/US91/08496; PCT/US90/01998; and prior U.S. patent applications Ser. No. 09/225,687, filed on Jan. 6, 1999; Ser. No. 60/095,149, filed Aug. 3, 1998; Ser. No. 60/101,651, filed Sep. 24, 1998; Ser. No. 60/105,752, filed Oct. 26, 1998; Ser. No.60/113,713, filed Dec. 24, 1998; Ser. No. 60/123,835, filed Mar. 11, 1999; Ser. No. 60/130,491, filed Apr. 22, 1999; Ser. No. 60/141,036, filed Jun. 29, 1999; Ser. No. 09/009,294 filed Jan. 20, 1998; Ser. No. 09/111,160 filed Jul. 7, 1998; Ser. No. 09/111,170 filed Jul. 7, 1998; Ser. No. 09/111,016 filed Jul. 7, 1998; Ser. No. 09/111,003 filed Jul. 7, 1998; Ser. No. 09/110,694 filed Jul. 7, 1998; Ser. No. 09/110,717 filed Jul. 7, 1998; Ser. No. 60/053,378 filed Jul. 22, 1997; Ser. No. 60/068,913 filed Dec. 29, 1997; Ser. No. 60/090,239 filed Jun. 22, 1998; Ser. No. 09/009,455 filed Jan. 20, 1998; Ser. No. 09/110,678 filed Jul. 7, 1998; Ser. No.60/053,307 filed Jul. 22, 1997; Ser. No. 60/068918 filed Dec. 29, 1997; Ser. No. 60/080,725 filed Apr. 3, 1998; Ser. No. 09/181,180 filed Oct. 28, 1998; Ser. No. 60/063,451 filed Oct. 29, 1997; Ser. No.09/008,947 filed Jan. 20, 1998; Ser. No. 60/074,006 filed Feb. 9, 1998; Ser. No.60/080,647 filed Apr. 3, 1998; Ser. No. 09/009,837 filed Jan. 20, 1998; Ser. No. 08/822,170 filed Mar. 27, 1997; Ser. No. 08/592,712 filed Jan. 26, 1996; Ser. No.08/467,051 filed on Jun. 6, 1995; Ser. No. 08/416,040 filed on Apr. 3, 1995; Ser. No. 08/467,911 filed on Jun. 6, 1995; Ser. No. 08/107,357 filed on Aug. 16, 1993; Ser. No.08/075,102 filed on Jun. 11, 1993; Ser. No. 07/626,496 filed on Dec. 12, 1990; Ser. No. 07/345,628 filed Apr. 28, 1989; Ser. No.07/341,733 filed Apr. 21, 1989 the entire disclosures of which are all incorporated herein by reference (hereinafter “Mills Prior Publications”).

The binding energy of an atom, ion, or molecule, also known as the ionization energy, is the energy required to remove one electron from the atom, ion, or molecule. A hydrogen atom having the binding energy given in Eq. (1) is hereafter referred to as a hydrino atom or hydrino. The designation for a hydrino of radius

$$\frac{{a}_{H}}{p} ,$$

where a_{H} is the radius of an ordinary hydrogen atom and p is an integer, is

$$H [ \frac{{a}_{H}}{p} ] .$$

A hydrogen atom with a radius a_{H} is hereinafter referred to as “ordinary hydrogen atom” or “normal hydrogen atom.” Ordinary atomic hydrogen is characterized by its binding energy of 13.6 eV.

Hydrinos are formed by reacting an ordinary hydrogen atom with a catalyst having a net enthalpy of reaction of about

m·27.2 eV (2a)

where m is an integer. This catalyst has also been referred to as an “energy hole” or “source of energy hole” in Mills earlier filed Patent Applications. It is believed that the rate of catalysis is increased as the net enthalpy of reaction is more closely matched to m·27.2 eV. It has been found that catalysts having a net enthalpy of reaction within ±10%, preferably ±5%, of m·27.2 eV are suitable for most applications.

In another embodiment, the catalyst to form hydrinos has a net enthalpy of reaction of about

m/2·27.2 eV (2b)

where m is an integer greater that one. It is believed that the rate of catalysis is increased as the net enthalpy of reaction is more closely matched to m/2·27.2 eV. It has been found that catalysts having a net enthalpy of reaction within ±10% preferably ±5%, of m/2·27.2 eV are suitable for most applications.

A catalyst of the present invention may provide a net enthalpy of m·27.2 eV where m is an integer or m/2·27.2 e V where m is an integer greater than one by undergoing a transition to a resonant excited state energy level with the energy transfer from hydrogen. For example, He⁺ absorbs 40.8 eV during the transition from the n=1 energy level to the n=2 energy level which corresponds to 3/2·27.2 eV (m=3 in Eq. (2b)). This energy is resonant with the difference in energy between the p=2 and the p=1 states of atomic hydrogen given by Eq. (1). Thus He⁺ may serve as a catalyst to cause the transition between these hydrogen states.

A catalyst of the present invention may provide a net enthalpy of m·27.2 eV where m is an integer or m/2·27.2 eV where m is an integer greater than one by becoming ionized during resonant energy transfer. For example, the third ionization energy of argon is 40.74 eV; thus, Ar²⁺ absorbs 40.8 eV during the ionization to Ar³⁺ which corresponds to 3/2·27.2 eV (m=3 in Eq. (2b)). This energy is resonant with the difference in energy between the p=2 and the p=1 states of atomic hydrogen given by Eq. (1). Thus Ar²⁺ may serve as a catalyst to cause the transition between these hydrogen states.

This catalysis releases energy from the hydrogen atom with a commensurate decrease in size of the hydrogen atom, rₙ=na_{H}. For example, the catalysis of H(n=1) to H(n=1/2) releases 40.8 eV, and the hydrogen radius decreases from a_{H} to

$$\frac{1}{2} {a}_{H} .$$

A catalytic system is provided by the ionization of t electrons from an atom each to a continuum energy level such that the sum of the ionization energies of the t electrons is approximately m×27.2 eV where m is an integer. One such catalytic system involves potassium metal. The first, second, and third ionization energies of potassium are 4.34066 eV, 31.63 eV, 45.806 eV, respectively [D. R. Linde, CRC Handbook of Chemistry and Physics, 78 th Edition, CRC Press, Boca Raton, Fla., (1997), p. 10-214 to 10-216]. The triple ionization (t=3) reaction of K to K³⁺, then, has a net enthalpy of reaction of 81.7426 eV, which is equivalent to m=3 in Eq. (2a).

$$\begin{matrix}81.7426 eV + K ( m ) + H [ \frac{{a}_{H}}{p} ] \to {K}^{3 +} + 3 {e}^{-} + H [ \frac{{a}_{H}}{( p + 3 )} ] + [ {( p + 3 )}^{2} - {p}^{2} ] X 13.6 eV & ( 3 ) \\ {K}^{3 +} + 3 {e}^{-} \to K ( m ) + 81.7426 eV & ( 4 )\end{matrix}$$

And, the overall reaction is

$$H [ \frac{{a}_{H}}{p} ] \to H [ \frac{{a}_{H}}{( p + 3 )} ] + [ {( p + 3 )}^{2} - {p}^{2} ] X 13.6 eV \qquad ( 5 )$$

Rubidium ion (Rb⁺) is also a catalyst because the second ionization energy of rubidium is 27.28 eV. In this case, the catalysis reaction is

$$27.28 eV + {Rb}^{+} + H [ \frac{{a}_{H}}{p} ] \to {Rb}^{2 +} + {e}^{-} + H [ \frac{{a}_{H}}{( p + 1 )} ] + [ {( p + 1 )}^{2} - {p}^{2} ] X 13.6 eV \qquad ( 6 )$$

Rb²⁺+e⁻→Rb⁺+27.28 eV (7)

And, the overall reaction is

$$H [ \frac{{a}_{H}}{p} ] \to H [ \frac{{a}_{H}}{( p + 1 )} ] + [ {( p + 1 )}^{2} - {p}^{2} ] X 13.6 eV \qquad ( 8 )$$

Helium ion (He⁺) is also a catalyst because the second ionization energy of helium is 54.417 eV. In this case, the catalysis reaction is

$$54.417 eV + {He}^{+} + H [ \frac{{a}_{H}}{p} ] \to {He}^{2 +} + {ⅇ}^{-} + H [ \frac{{a}_{H}}{( p + 2 )} ] + [ {( p + 2 )}^{2} - {p}^{2} ] X 13.6 eV \qquad ( 9 )$$

He²⁺+e⁻→He⁺+54.417 eV (10)

And, the overall reaction is

$$H [ \frac{{a}_{H}}{p} ] \to H [ \frac{{a}_{H}}{( p + 2 )} ] + [ {( p + 2 )}^{2} - {p}^{2} ] X 13.6 eV \qquad ( 11 )$$

Argon ion is a catalyst. The second ionization energy is 27.63 eV.

$$27.63 eV + {Ar}^{+} + H [ \frac{{a}_{H}}{p} ] \to {Ar}^{2 +} + {ⅇ}^{-} + H [ \frac{{a}_{H}}{( p + 1 )} ] + [ {( p + 1 )}^{2} - {p}^{2} ] X 13.6 eV \qquad ( 12 )$$

Ar²⁺+e⁻→Ar⁺+27.63 eV (13)

And, the overall reaction is

$$H [ \frac{{a}_{H}}{p} ] \to H [ \frac{{a}_{H}}{( p + 1 )} ] + [ {( p + 1 )}^{2} - {p}^{2} ] X 13.6 eV \qquad ( 14 )$$

A neon ion and a proton can also provide a net enthalpy of a multiple of that of the potential energy of the hydrogen atom. The second ionization energy of neon is 40.96 eV, and H⁺ releases 13.6 eV when it is reduced to H. The combination of reactions of Ne⁺ to Ne²⁺ and H⁺ to H, then, has a net enthalpy of reaction of 27.36 eV, which is equivalent to m=1 in Eq. (2a).

$$27.36 eV + {Ne}^{+} + {H}^{+} + H [ \frac{{a}_{H}}{p} ] \to H + {Ne}^{2 +} + H [ \frac{{a}_{H}}{( p + 1 )} ] + [ {( p + 1 )}^{2} - {p}^{2} ] X 13.6 eV \qquad ( 15 )$$

H+Ne²⁺→H⁺+Ne⁺+27.36 eV (16)

And, the overall reaction is

$$H [ \frac{{a}_{H}}{p} ] \to H [ \frac{{a}_{H}}{( p + 1 )} ] + [ {( p + 1 )}^{2} - {p}^{2} ] X 13.6 eV \qquad ( 17 )$$

A neon ion can also provide a net enthalpy of a multiple of that of the potential energy of the hydrogen atom. Ne⁺ has an excited state Ne^{+*} of 27.2 e V (46.5 nm) which provides a net enthalpy of reaction of 27.2 eV, which is equivalent to m=1 in Eq. (2a).

$$27.2 eV + {Ne}^{+} + H [ \frac{{a}_{H}}{p} ] \to {Ne}^{{+}^{*}} + H [ \frac{{a}_{H}}{( p + 1 )} ] + [ {( p + 1 )}^{2} - {p}^{2} ] X 13.6 eV \qquad ( 15 a )$$

Ne^{+*}→Ne⁺+27.2 eV (16a)

And, the overall reaction is

$$H [ \frac{{a}_{H}}{p} ] \to H [ \frac{{a}_{H}}{( p + 1 )} ] + [ {( p + 1 )}^{2} - {p}^{2} ] X 13.6 eV \qquad ( 17 a )$$

The first neon excimer continuum Ne₂ * may also provide a net enthalpy of a multiple of that of the potential energy of the hydrogen atom. The first ionization energy of neon is 21.56454 eV, and the first neon excimer continuum Ne₂ * has an excited state energy of 15.92 eV. The combination of reactions of Ne₂ * to 2Ne⁺, then, has a net enthalpy of reaction of 27.21 eV, which is equivalent to m=1 in Eq. (2a).

$$27.21 eV + {Ne}_{2}^{*} + H [ \frac{{a}_{H}}{p} ] \to 2 {Ne}^{+} + H [ \frac{{a}_{H}}{( p + 1 )} ] + [ {( p + 1 )}^{2} - {p}^{2} ] X 13.6 eV \qquad ( 18 )$$

2Ne⁺→Ne₂ *+27.21 eV (19)

And, the overall reaction is

$$H [ \frac{{a}_{H}}{p} ] \to H [ \frac{{a}_{H}}{( p + 1 )} ] + [ {( p + 1 )}^{2} - {p}^{2} ] X 13.6 eV \qquad ( 20 )$$

Similarly for helium, the helium excimer continuum to shorter wavelengths He₂ * may also provide a net enthalpy of a multiple of that of the potential energy of the hydrogen atom. The first ionization energy of helium is 24.58741 eV, and the helium excimer continuum He₂ * has an excited state energy of 21.97 eV. The combination of reactions of He₂ * to 2He⁺, then, has a net enthalpy of reaction of 27.21 eV, which is equivalent to m=1 in Eq.(2a).

$$27.21 eV + {He}_{2}^{*} + H [ \frac{{a}_{H}}{p} ] \to 2 {He}^{+} + H [ \frac{{a}_{H}}{( p + 1 )} ] + [ {( p + 1 )}^{2} - {p}^{2} ] X 13.6 eV \qquad ( 21 )$$

2 He⁺→He₂ *+27.21 eV (22)

And, the overall reaction is

$$H [ \frac{{a}_{H}}{p} ] \to H [ \frac{{a}_{H}}{( p + 1 )} ] + [ {( p + 1 )}^{2} - {p}^{2} ] X 13.6 eV \qquad ( 23 )$$

The ionization energy of hydrogen is 13.6 eV. Two atoms can provide a net enthalpy of a multiple of that of the potential energy of the hydrogen atom for the third hydrogen atom. The ionization energy of two hydrogen atoms is 27.21 eV, which is equivalent to m=1 in Eq. (2a). Thus, the transition cascade for the pth cycle of the hydrogen-type atom,

$$H [ \frac{{a}_{H}}{p} ] ,$$

with two hydrogen atoms,

$$H [ \frac{{a}_{H}}{1} ] ,$$

as the catalyst that causes the transition reaction is represented by

$$\begin{matrix}27.21 eV + 2 H [ \frac{{a}_{H}}{1} ] + H [ \frac{{a}_{H}}{p} ] \to 2 {H}^{+} + 2 {e}^{-} + H [ \frac{{a}_{H}}{( p + 1 )} ] + [ {( p + 1 )}^{2} - {p}^{2} ] X 13.6 eV & ( 24 ) \\ 2 {H}^{+} + 2 {e}^{-} \to 2 H [ \frac{{a}_{H}}{1} ] + 27.21 eV & ( 25 )\end{matrix}$$

And, the overall reaction is

$$H [ \frac{{a}_{H}}{p} ] \to H [ \frac{{a}_{H}}{( p + 1 )} ] + [ {( p + 1 )}^{2} - p ] X 13.6 eV \qquad ( 26 )$$

A nitrogen molecule can also provide a net enthalpy of a multiple of that of the potential energy of the hydrogen atom. The bond energy of the nitrogen molecule is 9.75 eV, and the first and second ionization energies of the nitrogen atom are 14.53414 eV and 29.6013 eV, respectively. The combination of reactions of N₂ to 2N and N to N²⁺, then, has a net enthalpy of reaction of 53.9 eV, which is equivalent to m=2 in Eq. (2a).

$$53.9 eV + {N}_{2} + H [ \frac{{a}_{H}}{p} ] \to N + {N}^{2 +} + H [ \frac{{a}_{H}}{( p + 2 )} ] + [ {( p + 2 )}^{2} - {p}^{2} ] X 13.6 eV \qquad ( 27 )$$

N+N²⁺→N₂+53.9 eV (28)

And, the overall reaction is

$$H [ \frac{{a}_{H}}{p} ] \to H [ \frac{{a}_{H}}{( p + 2 )} ] + [ {( p + 2 )}^{2} - {p}^{2} ] X 13.6 eV \qquad ( 29 )$$

A carbon molecule can also provide a net enthalpy of a multiple of that of the potential energy of the hydrogen atom. The bond energy of the carbon molecule is 6.29 eV, and the first through the sixth ionization energies of a carbon atom are 11.2603 eV, 24.38332 eV, 47.8878 eV, 64.4939 eV, and 392.087 eV, respectively [32]. The combination of reactions of C₂ to 2C and C to C⁵⁺, then, has a net enthalpy of reaction of 546.40232 eV, which is equivalent to m=20 in Eq. (2a).

$$546.4 eV + {C}_{2} + H [ \frac{{a}_{H}}{p} ] \to C + {C}^{5 +} + H [ \frac{{a}_{H}}{( p + 20 )} ] + [ {( p + 20 )}^{2} - {p}^{2} ] X 13.6 eV \qquad ( 30 )$$

C+C⁵⁺→C₂+546.4 eV (31)

And, the overall reaction is

$$H [ \frac{{a}_{H}}{p} ] \to H [ \frac{{a}_{H}}{( p + 20 )} ] + [ {( p + 20 )}^{2} - {p}^{2} ] X 13.6 eV \qquad ( 32 )$$

An oxygen molecule can also provide a net enthalpy of a multiple of that of the potential energy of the hydrogen atom. The bond energy of the oxygen molecule is 5.165 eV, and the first and second ionization energies of an oxygen atom are 13.61806 eV and 35.11730 eV, respectively [32]. The combination of reactions of O₂ to 2O and O to O²⁺, then, has a net enthalpy of reaction of 53.9 eV, which is equivalent to m=2 in Eq. (2a).

$$53.9 eV + {O}_{2} + H [ \frac{{a}_{H}}{p} ] \to O + {O}^{2 +} + H [ \frac{{a}_{H}}{( p + 2 )} ] + [ {( p + 2 )}^{2} - {p}^{2} ] X 13.6 eV \qquad ( 33 )$$

O+O²⁺→O₂+53.9 eV (34)

And, the overall reaction is

$$H [ \frac{{a}_{H}}{p} ] \to H [ \frac{{a}_{H}}{( p + 2 )} ] + [ {( p + 2 )}^{2} - {p}^{2} ] X 13.6 eV \qquad ( 35 )$$

An oxygen molecule can also provide a net enthalpy of a multiple of that of the potential energy of the hydrogen atom by an alternative reaction. The bond energy of the oxygen molecule is 5.165 eV, and the first through the third ionization energies of an oxygen atom are 13.61806 eV, 35.11730 eV, and 54.9355 eV, respectively [32]. The combination of reactions of O₂ to 2O and O to O³⁺, then, has a net enthalpy of reaction of 108.83 eV, which is equivalent to m=4 in Eq. (2a).

$$108.83 eV + {O}_{2} + H [ \frac{{a}_{H}}{p} ] \to O + {O}^{3 +} + H [ \frac{{a}_{H}}{( p + 4 )} ] + [ {( p + 4 )}^{2} - {p}^{2} ] X 13.6 eV \qquad ( 36 )$$

O+O³⁺→O₂+108.83 eV (37)

And, the overall reaction is

$$H [ \frac{{a}_{H}}{p} ] \to H [ \frac{{a}_{H}}{( p + 4 )} ] + [ {( p + 4 )}^{2} - {p}^{2} ] X 13.6 eV \qquad ( 38 )$$

An oxygen molecule can also provide a net enthalpy of a multiple of that of the potential energy of the hydrogen atom by an alternative reaction. The bond energy of the oxygen molecule is 5.165 eV, and the first through the fifth ionization energies of an oxygen atom are 13.61806 eV, 35.11730 eV, 54.9355 eV, 77.41353 eV, and 113.899 eV, respectively [32]. The combination of reactions of O₂ to 2O and O to O⁵⁺, then, has a net enthalpy of reaction of 300.15 eV, which is equivalent to m=11 in Eq. (2a).

$$300.15 eV + {O}_{2} + H [ \frac{{a}_{H}}{p} ] \to O + {O}^{5 +} + H [ \frac{{a}_{H}}{( p + 11 )} ] + [ {( p + 11 )}^{2} - {p}^{2} ] X 13.6 eV \qquad ( 39 )$$

O+O⁵⁺→O₂+300.15 eV (40)

And, the overall reaction is

$$H [ \frac{{a}_{H}}{p} ] \to H [ \frac{{a}_{H}}{( p + 11 )} ] + [ {( p + 11 )}^{2} - {p}^{2} ] X 13.6 eV \qquad ( 41 )$$

In addition to nitrogen, carbon, and oxygen molecules which are exemplary catalysts, other molecules may be catalysts according to the present invention wherein the energy to break the molecular bond and the ionization of t electrons from an atom from the dissociated molecule to a continuum energy level is such that the sum of the ionization energies of the t electrons is approximately m·27.2 eV where t and m are each an integer. The bond energies and the ionization energies may be found in standard sources such as D. R. Linde, CRC Handbook of Chemistry and Physics, 79 th Edition, CRC Press, Boca Raton, Fla., (1999), p. 9-51 to 9-69 and David R. Linde, CRC Handbook of Chemistry and Physics, 79 th Edition, CRC Press, Boca Raton, Fla., (1 998-9), p. 10-175 to p. 10-177, respectively. Thus, further molecular catalysts which provide a positive enthalpy of m·27.2 eV to cause release of energy from atomic hydrogen may be determined by one skilled in the art.

Molecular hydrogen catalysts capable of providing a net enthalpy of reaction of approximately m×27.2 eV where m is an integer to produce hydrino whereby the molecular bond is broken and t electrons are ionized from a corresponding free atom of the molecule are given infra. The bonds of the molecules given in the first column are broken and the atom also given in the first column is ionized to provide the net enthalpy of reaction of m×27.2 eV given in the eleventh column where m is given in the twelfth column. The energy of the bond which is broken given by Linde [R. Linde, CRC Handbook of Chemistry and Physics, 79 th Edition, CRC Press, Boca Raton, Fla., (1999), p. 9-51 to 9-69] which is herein incorporated by reference is given in the 2 nd column, and the electrons which are ionized are given with the ionization potential (also called ionization energy or binding energy). The ionization potential of the nth electron of the atom or ion is designated by IPₙ and is given by Linde [R. Linde, CRC Handbook of Chemistry and Physics, 79 th Edition, CRC Press, Boca Raton, Fla., (1998-9), p. 10-175 to p. 10-177] which is herein incorporated by reference. For example, the bond energy of the oxygen molecule, BE=5.165 eV, is given in the 2 nd column, and the first ionization potential, IP₁=13.61806 eV, and the second ionization potential, IP₂=35.11730 eV, are given in the third and fourth columns, respectively. The combination of reactions of O₂ to 2O and O to O²⁺, then, has a net enthalpy of reaction of 54.26 eV, as given in the Enthalpy column, and m=2 in Eq. (2a) as given in the twelfth column.

TABLE 1
Molecular Hydrogen Catalysts

| Catalyst | BE | IP1 | IP2 | IP3 | IP4 | IP5 | IP6 | Enthalp | m |
|---|---|---|---|---|---|---|---|---|---|
| C₂/C | 6.26 | 11.2603 | 24.38332 | 47.8878 | 64.4939 | 392.087 | | 546.4 | 20 |
| N₂/N | 9.75 | 14.53414 | 29.6013 | | | | | 53.9 | 2 |
| O₂/O | 5.165 | 13.61806 | 35.11730 | | | | | 54.26 | 2 |
| O₂/O | 5.165 | 13.61806 | 35.11730 | 54.9355 | | | | 108.83 | 4 |
| O₂/O | 5.165 | 13.61806 | 35.11730 | 54.9355 | 77.41353 | 113.899 | | 300.15 | 11 |
| CO₂/O | 5.52 | 13.61806 | 35.11730 | | | | | 54.26 | 2 |
| CO₂/O | 5.52 | 13.61806 | 35.11730 | 54.9355 | | | | 109.19 | 4 |
| CO₂/O | 5.52 | 13.61806 | 35.11730 | 54.9355 | 77.41353 | 113.8990 | | 300.5 | 11 |
| NO₂/O | 3.16 | 13.61806 | 35.11730 | 54.9355 | 77.41353 | 113.8990 | | 298.14 | 11 |
| NO₃/O | 2.16 | 13.61806 | 35.11730 | 54.9355 | 77.41353 | 113.8990 | 138.1197 | 435.26 | 16 |

In an embodiment, a molecular catalyst such as nitrogen is combined with another catalyst such as Ar⁺ (Eqs. (12-14)) or He⁺ (Eqs. (9-11)). In an embodiment of a catalyst combination of argon and nitrogen, the percentage of nitrogen is within the range 1-10%. In an embodiment of a catalyst combination of argon and nitrogen, the source of hydrogen atoms is a hydrogen halide such as HF.

The energy given off during catalysis is much greater than the energy lost to the catalyst. The energy released is large as compared to conventional chemical reactions. For example, when hydrogen and oxygen gases undergo combustion to form water

$${H}_{2} ( g ) + \frac{1}{2} {O}_{2} ( g ) \to {H}_{2} O ( l ) \qquad ( 42 )$$

the known enthalpy of formation of water is ΔH_{f}=−286 kJ/mole or 1.48 eV per hydrogen atom. By contrast, each (n=1) ordinary hydrogen atom undergoing catalysis releases a net of 40.8 e V. Moreover, further catalytic transitions may occur:

$$n = \frac{1}{2} \to \frac{1}{3} , \frac{1}{3} \to \frac{1}{4} , \frac{1}{4} \to \frac{1}{5} ,$$

and so on. Once catalysis begins, hydrinos autocatalyze further in a process called disproportionation. This mechanism is similar to that of an inorganic ion catalysis. But, hydrino catalysis should have a higher reaction rate than that of the inorganic ion catalyst due to the better match of the enthalpy to m·27.2 eV.

2.2 Hydride Ions

A hydride ion comprises two indistinguishable electrons bound to a proton. Alkali and alkaline earth hydrides react violently with water to release hydrogen gas which burns in air ignited by the heat of the reaction with water. Typically metal hydrides decompose upon heating at a temperature well below the melting point of the parent metal.

2.3 Hydrogen Plasma

A historical motivation to cause emission from a hydrogen gas was that the spectrum of hydrogen was first recorded from the only known source, the Sun. Suitable sources and spectrometers were developed which permitted observations in the extreme ultraviolet (EUV) range. Developed sources that provide a suitable intensity are high voltage discharges, synchrotron devices, inductively coupled plasma generators, and magnetically confined plasmas. One important variant of the latter type of source is a tokamak wherein a plasma is created and heated to extreme temperatures (e.g. >10⁶ K) by ohmic heating, RF coupling, or neutral beam injection with confinement provided by a toroidal magnetic field.

2.4 Magnetohydrodynamics

Charge separation based on the formation of a mass flow of ions in a crossed magnetic field is well known in the art as magnetohydrodynamic (MHD) power conversion. The positive and negative ions undergo Lorentzian direction in opposite directions and are received at corresponding electrode to affect a voltage between them. The typical MHD method to form a mass flow of ions is to expand a high pressure gas seeded with ions through a nozzle to create a high speed flow through the crossed magnetic field with a set of electrodes crossed with respect to the deflecting field to receive the deflected ions. In the present hydride reactor, the pressure is typically less than atmospheric, but not necessarily so, and the directional mass flow may be achieved by a magnetic mirror or thermodynamically or other suitable means.

2.5 Magnetic Mirror

The power converter may comprise a magnetic mirror which is a source of a magnetic field gradient in a desired direction of ion flow where the initial parallel velocity of plasma electrons v_{∥} increases as the orbital velocity v_{⊥} decreases with conservation of energy according to the adiabatic invariant

$$\frac{{v}_{⊥}^{2}}{B} = constant ,$$

the linear energy being drawn from that of orbital motion. As the magnetic flux B decreases, the radius a will increase such that the flux πa²B remains constant. The invariance of the flux linking an orbit is the basis of the mechanism of a “magnetic mirror”. The principle of a magnetic mirror is that charged particles are reflected by regions of strong magnetic fields if the initial velocity is towards the mirror and are ejected from the mirror otherwise. The adiabatic invariance of flux through the orbit of an ion is a means of the present invention to form a flow of ions along the z-axis with the conversion of v_{⊥} to v_{∥} such that v_{∥}>v_{⊥}.

Two magnetic mirrors or more may form a magnetic bottle to confine plasma formed by hydrogen catalysis. Ions created in the bottle in the center region will spiral along the axis, but will be reflected by the magnetic mirrors at each end. The more energetic ions with high components of velocity parallel to a desired axis will escape at the ends of the bottle. Thus, the bottle may produce an essentially linear flow of ions from the ends of the magnetic bottle to a magnetohydrodynamic converter. Since electrons may be preferentially confined due to their lower mass relative to positive ions, a voltage is developed in a plasmadynamic embodiment of the present invention. Power flows between an anode in contact with the confined electrons and a cathode such as the reactor vessel wall which collects the positive ions. The power is dissipated in a load.

2.6 Plasmadynamics

The mass of a positively charged ion of a plasma is at least 1800 times that of the electron; thus, the cyclotron orbit is 1800 times larger. This result allows electrons to be magnetically trapped on magnetic field lines while ions may drift. Charge separation may occur to provide a voltage.

### II. SUMMARY OF THE INVENTION

An object of the present invention is to generate power and novel hydrogen species and compositions of matter comprising new forms of hydrogen via the catalysis of atomic hydrogen.

Another objective is to convert power from a plasma generated as a product of energy released by the catalysis of hydrogen. The converted power may be used as a source of electricity.

Another objective of the present invention is to generate a plasma and a source of light such as high energy light, extreme ultraviolet light and ultraviolet light, via the catalysis of atomic hydrogen.

1. Catalysis of Hydrogen to Form Novel Hydrogen Species and Compositions of Matter Comprising New Forms of Hydrogen

The above objectives and other objectives are achieved by the present invention comprising a power source, hydride reactor, and/or power converter. The power source comprises a cell for the catalysis of atomic hydrogen to form novel hydrogen species and compositions of matter comprising new forms of hydrogen. The power from the catalysis of hydrogen may be directly converted into electricity. In separate embodiments, the power converter comprises a magnetohydrodymanic or plasmadynamic power converter that receives power from a plasma formed or increased by the catalysis of hydrogen to form novel hydrogen species and compositions of matter comprising new forms of hydrogen. The novel hydrogen compositions of matter comprise:

(a) at least one neutral, positive, or negative hydrogen species (hereinafter “increased binding energy hydrogen species”) having a binding energy

(i) greater than the binding energy of the corresponding ordinary hydrogen species, or

(ii) greater than the binding energy of any hydrogen species for which the corresponding ordinary hydrogen species is unstable or is not observed because the ordinary hydrogen species' binding energy is less than thermal energies at ambient conditions (standard temperature and pressure, STP), or is negative; and

(b) at least one other element. The compounds of the invention are hereinafter referred to as “increased binding energy hydrogen compounds”.

By “other element” in this context is meant an element other than an increased binding energy hydrogen species. Thus, the other element can be an ordinary hydrogen species, or any element other than hydrogen. In one group of compounds, the other element and the increased binding energy hydrogen species are neutral. In another group of compounds, the other element and increased binding energy hydrogen species are charged such that the other element provides the balancing charge to form a neutral compound. The former group of compounds is characterized by molecular and coordinate bonding; the latter group is characterized by ionic bonding.

Also provided are novel compounds and molecular ions comprising

(a) at least one neutral, positive, or negative hydrogen species (hereinafter “increased binding energy hydrogen species”) having a total energy

(i) greater than the total energy of the corresponding ordinary hydrogen species, or

(ii) greater than the total energy of any hydrogen species for which the corresponding ordinary hydrogen species is unstable or is not observed because the ordinary hydrogen species' total energy is less than thermal energies at ambient conditions, or is negative; and

(b) at least one other element.

The total energy of the hydrogen species is the sum of the energies to remove all of the electrons from the hydrogen species. The hydrogen species according to the present invention has a total energy greater than the total energy of the corresponding ordinary hydrogen species. The hydrogen species having an increased total energy according to the present invention is also referred to as an “increased binding energy hydrogen species” even though some embodiments of the hydrogen species having an increased total energy may have a first electron binding energy less that the first electron binding energy of the corresponding ordinary hydrogen species. For example, the hydride ion of Eq. (43) for p=24 has a first binding energy that is less than the first binding energy of ordinary hydride ion, while the total energy of the hydride ion of Eq. (43) for p=24 is much greater than the total energy of the corresponding ordinary hydride ion. /

Also provided are novel compounds and molecular ions comprising

(a) a plurality of neutral, positive, or negative hydrogen species (hereinafter “increased binding energy hydrogen species”) having a binding energy

(i) greater than the binding energy of the corresponding ordinary hydrogen species, or

(ii) greater than the binding energy of any hydrogen species for which the corresponding ordinary hydrogen species is unstable or is not observed because the ordinary hydrogen species' binding energy is less than thermal energies at ambient conditions or is negative; and

(b) optionally one other element. The compounds of the invention are hereinafter referred to as “increased binding energy hydrogen compounds”.

The increased binding energy hydrogen species can be formed by reacting one or more hydrino atoms with one or more of an electron, hydrino atom, a compound containing at least one of said increased binding energy hydrogen species, and at least one other atom, molecule, or ion other than an increased binding energy hydrogen species.

Also provided are novel compounds and molecular ions comprising

(a) a plurality of neutral, positive, or negative hydrogen species (hereinafter “increased binding energy hydrogen species”) having a total energy

(i) greater than the total energy of ordinary molecular hydrogen, or

(ii) greater than the total energy of any hydrogen species for which the corresponding ordinary hydrogen species is unstable or is not observed because the ordinary hydrogen species' total energy is less than thermal energies at ambient conditions or is negative; and

(b) optionally one other element. The compounds of the invention are hereinafter referred to as “increased binding energy hydrogen compounds”.

The total energy of the increased total energy hydrogen species is the sum of the energies to remove all of the electrons from the increased total energy hydrogen species. The total energy of the ordinary hydrogen species is the sum of the energies to remove all of the electrons from the ordinary hydrogen species. The increased total energy hydrogen species is referred to as an increased binding energy hydrogen species, even though some of the increased binding energy hydrogen species may have a first electron binding energy less than the first electron binding energy of ordinary molecular hydrogen. However, the total energy of the increased binding energy hydrogen species is much greater than the total energy of ordinary molecular hydrogen.

In one embodiment of the invention, the increased binding energy hydrogen species can be Hₙ, and Hₙ⁻ where n is a positive integer, or Hₙ⁺ where n is a positive integer greater than one. Preferably, the increased binding energy hydrogen species is Hₙ and Hₙ⁻ where n is an integer from one to about 1×10⁶, more preferably one to about 1×10⁴, even more preferably one to about 1×10², and most preferably one to about 10, and Hₙ⁺ where n is an integer from two to about 1×10⁶, more preferably two to about 1×10⁴, even more preferably two to about 1×10², and most preferably two to about 10. A specific example of Hₙ⁻ is H₁₆⁻.

In an embodiment of the invention, the increased binding energy hydrogen species can be Hₙ^{m-} where n and m are positive integers and Hₙ^{m+} where n and m are positive integers with m<n. Preferably, the increased binding energy hydrogen species is Hₙ^{m-} where n is an integer from one to about 1×10⁶, more preferably one to about 1×10⁴, even more preferably one to about 1×10², and most preferably one to about 10 and m is an integer from one to 100, one to ten, and Hₙ^{m+} where n is an integer from two to about 1×10⁶, more preferably two to about 1×10⁴, even more preferably two to about 1×10², and most preferably two to about 10, and m is preferably one to about 100, and more preferably one to ten.

According to a preferred embodiment of the invention, a compound is provided, comprising at least one increased binding energy hydrogen species selected from the group consisting of (a) hydride ion having a binding energy according to Eq. (43) that is greater than the binding of ordinary hydride ion (about 0.8 eV) for p=2 up to 23, and less for p=24 (“increased binding energy hydride ion” or “hydrino hydride ion”); (b) hydrogen atom having a binding energy greater than the binding energy of ordinary hydrogen atom (about 13.6 eV) (“increased binding energy hydrogen atom” or “hydrino”); (c) hydrogen molecule having a first binding energy greater than about 15.5 eV (“increased binding energy hydrogen molecule” or “dihydrino”); and (d) molecular hydrogen ion having a binding energy greater than about 16.4 eV (“increased binding energy molecular hydrogen ion” or “dihydrino molecular ion”).

The compounds of the present invention are capable of exhibiting one or more unique properties which distinguishes them from the corresponding compound comprising ordinary hydrogen, if such ordinary hydrogen compound exists. The unique properties include, for example, (a) a unique stoichiometry; (b) unique chemical structure; (c) one or more extraordinary chemical properties such as conductivity, melting point, boiling point, density, and refractive index; (d) unique reactivity to other elements and compounds; (e) enhanced stability at room temperature and above; and/or (f) enhanced stability in air and/or water. Methods for distinguishing the increased binding energy hydrogen-containing compounds from compounds of ordinary hydrogen include: 1.) elemental analysis, 2.) solubility, 3.) reactivity, 4.) melting point, 5.) boiling point, 6.) vapor pressure as a function of temperature, 7.) refractive index, 8.) X-ray photoelectron spectroscopy (XPS), 9.) gas chromatography, 10.) X-ray diffraction (XRD), 11.) calorimetry, 12.) infrared spectroscopy (IR), 13.) Raman spectroscopy, 14.) Mossbauer spectroscopy, 15.) extreme ultraviolet (EUV) emission and absorption spectroscopy, 16.) ultraviolet (UV) emission and absorption spectroscopy, 17.) visible emission and absorption spectroscopy, 18.) nuclear magnetic resonance spectroscopy, 19.) gas phase mass spectroscopy of a heated sample (solids probe and direct exposure probe quadrapole and magnetic sector mass spectroscopy), 20.) time-of-flight-secondary-ion-mass-spectroscopy (TOFSIMS), 21.) electrospray-ionization-time-of-flight-mass-spectroscopy (ESITOFMS), 22.) thermogravimetric analysis (TGA), 23.) differential thermal analysis (DTA), 24.) differential scanning calorimetry (DSC), 25.) liquid chromatography/mass spectroscopy (LCMS), and/or 26.) gas chromatography/mass spectroscopy (GCMS).

According to the present invention, a hydrino hydride ion (H) having a binding energy according to Eq. (43) that is greater than the binding of ordinary hydride ion (about 0.8 eV) for p=2 up to 23, and less for p=24 (H⁻) is provided. For p=2 to p=24 of Eq. (43), the hydride ion binding energies are respectively 3, 6.6, 11.2, 16.7, 22.8, 29.3, 36.1, 42.8, 49.4, 55.5, 61.0, 65.6, 69.2, 71.5, 72.4, 71.5, 68.8, 64.0, 56.8,47.1, 34.6, 19.2, and 0.65 eV. Compositions comprising the novel hydride ion are also provided.

The binding energy of the novel hydrino hydride ion can be represented by the following formula:

$$Binding Energy = \frac{{ℏ}^{2} \sqrt{s ( s + 1 )}}{8 {μ}_{c} {{a}_{0}^{2} [ \frac{1 + \sqrt{s ( s + 1 )}}{p} ]}^{2}} - \frac{π {μ}_{0} {e}^{2} {ℏ}^{2}}{{m}_{e}^{2} {a}_{0}^{3}} ( 1 + \frac{{2}^{2}}{{[ \frac{1 + \sqrt{s ( s + 1 )}}{p} ]}^{3}} ) \qquad ( 43 )$$

where p is an integer greater than one, s=1/2, π is pi, \overline{h} is Planck's constant bar, μₒ is the permeability of vacuum, mₑ is the mass of the electron, μₑ is the reduced electron mass, aₒ is the Bohr radius, and e is the elementary charge. The radii are given by

$${r}_{2} = {r}_{1} = {a}_{0} ( 1 + \sqrt{s ( s + 1 )} ) ; s = \frac{1}{2} \qquad ( 44 )$$

The hydrino hydride ion of the present invention can be formed by the reaction of an electron source with a hydrino, that is, a hydrogen atom having a binding energy of about

$$\frac{13.6 eV}{{n}^{2}} ,$$

where

$$n = \frac{1}{p}$$

and p is an integer greater than 1. The hydrino hydride ion is represented by H⁻(n=1/p) or H⁻(1/p):

$$\begin{matrix}H [ \frac{{a}_{H}}{p} ] + {e}^{-} \to {H}^{-} ( n = 1 / p ) & ( 45 a ) \\ H [ \frac{{a}_{H}}{p} ] + {e}^{-} \to {H}^{-} ( 1 / p ) & ( 45 b )\end{matrix}$$

The hydrino hydride ion is distinguished from an ordinary hydride ion comprising an ordinary hydrogen nucleus and two electrons having a binding energy of about 0.8 eV. The latter is hereafter referred to as “ordinary hydride ion” or “normal hydride ion” The hydrino hydride ion comprises a hydrogen nucleus including proteum, deuterium, or tritium, and two indistinguishable electrons at a binding energy according to Eq. (43).

The binding energies of the hydrino hydride ion, H⁻(n=1/p) as a function of p, where p is an integer, are shown in TABLE 2.

TABLE 2
The representative binding energy of the hydrino hydride
ion H⁻(n = 1/p) as a function of p, Eq. (43).

| | r₁ | Binding | Wavelength |
|---|---|---|---|
| Hydride Ion | (a₀)^{a} | Energy (eV)^{b} | (nm) |
| H⁻(n = 1/2) | 0.9330 | 3.047 | 407 |
| H⁻(n = 1/3) | 0.6220 | 6.610 | 188 |
| H⁻(n = 1/4) | 0.4665 | 11.23 | 110 |
| H⁻(n = 1/5) | 0.3732 | 16.70 | 74.2 |
| H⁻(n = 1/6) | 0.3110 | 22.81 | 54.4 |
| H⁻(n = 1/7) | 0.2666 | 29.34 | 42.3 |
| H⁻(n = 1/8) | 0.2333 | 36.08 | 34.4 |
| H⁻(n = 1/9) | 0.2073 | 42.83 | 28.9 |
| H⁻(n = 1/10) | 0.1866 | 49.37 | 25.1 |
| H⁻(n = 1/11) | 0.1696 | 55.49 | 22.3 |
| H⁻(n = 1/12) | 0.1555 | 60.97 | 20.3 |
| H⁻(n = 1/13) | 0.1435 | 65.62 | 18.9 |
| H⁻(n = 1/14) | 0.1333 | 69.21 | 17.9 |
| H⁻(n = 1/15) | 0.1244 | 71.53 | 17.3 |
| H⁻(n = 1/16) | 0.1166 | 72.38 | 17.1 |
| H⁻(n = 1/17) | 0.1098 | 71.54 | 17.33 |
| H⁻(n = 1/18) | 0.1037 | 68.80 | 18.02 |
| H⁻(n = 1/19) | 0.0982 | 63.95 | 19.39 |
| H⁻(n = 1/20) | 0.0933 | 56.78 | 21.83 |
| H⁻(n = 1/21) | 0.0889 | 47.08 | 26.33 |
| H⁻(n = 1/22) | 0.0848 | 34.63 | 35.80 |
| H⁻(n = 1/23) | 0.0811 | 19.22 | 64.49 |
| H⁻(n = 1/24) | 0.0778 | 0.6535 | 1897 |

^{a}Equation (44)
^{b}Equation (43)

Novel compounds are provided comprising one or more hydrino hydride ions and one or more other elements. Such a compound is referred to as a hydrino hydride compound.

Ordinary hydrogen species are characterized by the following binding energies (a) hydride ion, 0.754 eV (“ordinary hydride ion”); (b) hydrogen atom (“ordinary hydrogen atom”), 13.6 eV; (c) diatomic hydrogen molecule, 15.46 eV (“ordinary hydrogen molecule”); (d) hydrogen molecular ion, 16.4 eV (“ordinary hydrogen molecular ion”); and (e) H₃⁺, 22.6 eV (“ordinary trihydrogen molecular ion”). Herein, with reference to forms of hydrogen, “normal” and “ordinary” are synonymous.

According to a further preferred embodiment of the invention, a compound is provided comprising at least one increased binding energy hydrogen species such as (a) a hydrogen atom having a binding energy of about

$$\frac{13.6 eV}{{( \frac{1}{p} )}^{2}} ,$$

preferably within ±10%, more preferably ±5%, where p is an integer, preferably an integer from 2 to 200; (b) a hydride ion (H⁻) having a binding energy of about

$$\frac{{ℏ}^{2} \sqrt{s ( s + 1 )}}{8 {μ}_{c} {{a}_{0}^{2} [ \frac{1 + \sqrt{s ( s + 1 )}}{p} ]}^{2}} - \frac{π {μ}_{0} {e}^{2} {ℏ}^{2}}{{m}_{e}^{2} {a}_{0}^{3}} ( 1 + \frac{{2}^{2}}{{[ \frac{1 + \sqrt{s ( s + 1 )}}{p} ]}^{3}} ) ,$$

preferably within ±10%, more preferably ±5%, where p is an integer, preferably an integer from 2 to 200, s=1/2, π is pi, \overline{h} is Planck's constant bar, μₒ is the permeability of vacuum, mₑ is the mass of the electron, μₑ is the reduced electron mass, aₒ is the Bohr radius, and e is the elementary charge; (c) H₄⁺ (1/p); (d) a trihydrino molecular ion, H₃⁺(1/p), having a binding energy of about

$$\frac{22.6}{{( \frac{1}{p} )}^{2}} eV$$

preferably within ±10%, more preferably ±5%, where p is an integer, preferably an integer from 2 to 200; (e) a dihydrino having a binding energy of about

$$\frac{15.5}{{( \frac{1}{p} )}^{2}} eV$$

preferably within ±10%, more preferably ±5%, where p is an integer, preferably and integer from 2 to 200; or (f) a dihydrino molecular ion with a binding energy of about

$$\frac{16.4}{{( \frac{1}{p} )}^{2}} eV$$

preferably within ±10%, more preferably ±5%, where p is an integer, preferably an integer from 2 to 200.

According to one embodiment of the invention wherein the compound comprises a negatively charged increased binding energy hydrogen species, the compound further comprises one or more cations, such as a proton, ordinary H₂⁺, or ordinary H₃⁺.

A method is provided for preparing compounds comprising at least one increased binding energy hydride ion. Such compounds are hereinafter referred to as “hydrino hydride compounds”. The method comprises reacting atomic hydrogen with a catalyst having a net enthalpy of reaction of about

$$\frac{m}{2} \cdot 27 eV ;$$

where m is an integer greater than 1, preferably an integer less than 400, to produce an increased binding energy hydrogen atom having a binding energy of about

$$\frac{13.6 eV}{{( \frac{1}{p} )}^{2}}$$

where p is an integer, preferably an integer from 2 to 200. A further product of the catalysis is energy. The increased binding energy hydrogen atom can be reacted with an electron source, to produce an increased binding energy hydride ion. The increased binding energy hydride ion can be reacted with one or more cations to produce a compound comprising at least one increased binding energy hydride ion.

2. Hydride Reactor

The invention is also directed to a reactor for producing increased binding energy hydrogen compounds of the invention, such as hydrino hydride compounds. A further product of the catalysis is energy. Such a reactor is hereinafter referred to as a “hydrino hydride reactor”. The hydrino hydride reactor comprises a cell for making hydrinos and an electron source. The reactor produces hydride ions having the binding energy of Eq. (43). The cell for making hydrinos may, for example, take the form of a gas cell, a gas discharge cell, a plasma torch cell, or microwave power cell. The gas cell, gas discharge cell, and plasma torch cell are disclosed in Mills Prior Publications. Each of these cells comprises: a source of atomic hydrogen; at least one of a solid, molten, liquid, or gaseous catalyst for making hydrinos; and a vessel for reacting hydrogen and the catalyst for making hydrinos. As used herein and as contemplated by the subject invention, the term “hydrogen”, unless specified otherwise, includes not only proteum (¹H), but also deuterium (²H) and tritium (³H). Electrons from the electron source contact the hydrinos and react to form hydrino hydride ions.

The reactors described herein as “hydrino hydride reactors” are capable of producing not only hydrino hydride ions and compounds, but also the other increased binding energy hydrogen compounds of the present invention. Hence, the designation “hydrino hydride reactors” should not be understood as being limiting with respect to the nature of the increased binding energy hydrogen compound produced.

According to one aspect of the present invention, novel compounds are formed from hydrino hydride ions and cations. In the gas cell, the cation can be an oxidized species of the material of the cell, a cation comprising the molecular hydrogen dissociation material which produces atomic hydrogen, a cation comprising an added reductant, or a cation present in the cell (such as a cation comprising the catalyst). In the discharge cell, the cation can be an oxidized species of the material of the cathode or anode, a cation of an added reductant, or a cation present in the cell (such as a cation comprising the catalyst). In the plasma torch cell, the cation can be either an oxidized species of the material of the cell, a cation of an added reductant, or a cation present in the cell (such as a cation comprising the catalyst).

In an embodiment, a plasma forms in the hydrino hydride cell as a result of the energy released from the catalysis of hydrogen. Water vapor may be added to the plasma to increase the hydrogen concentration as shown by Kikuchi et al. [J. Kikuchi, M. Suzuki, H. Yano, and S. Fujimura, Proceedings SPIE—The International Society for Optical Engineering, (1993), 1803 (Advanced Techniques for Integrated Circuit Processing II), pp. 70-76] which is herein incorporated by reference.

3. Catalysts

3.1 Atom and Ion Catalysts

In an embodiment, a catalytic system is provided by the ionization of t electrons from a participating species such as an atom, an ion, a molecule, and an ionic or molecular compound to a continuum energy level such that the sum of the ionization energies of the t electrons is approximately m×27.2 e V where m is an integer. One such catalytic system involves cesium. The first and second ionization energies of cesium are 3.89390 eV and 23.15745 eV, respectively [David R. Linde, CRC Handbook of Chemistry and Physics, 74 th Edition, CRC Press, Boca Raton, Fla., (1993), p. 10-207]. The double ionization (t=2 ) reaction of Cs to Cs²⁺, then, has a net enthalpy of reaction of 27.05135 eV, which is equivalent to m=1 in Eq. (2a).

$$27.05135 eV + Cs ( m ) + H [ \frac{{a}_{H}}{p} ] -> {Cs}^{2 +} + 2 {e}^{-} + H [ \frac{{a}_{H}}{( p + 1 )} ] + [ {( p + 1 )}^{2} - {p}^{2} ] \times 13.6 eV \qquad ( 46 )$$

Cs²⁺+2e⁻→Cs(m)+27.05135 eV (47)

And, the overall reaction is

$$H [ \frac{{a}_{H}}{p} ] \to H [ \frac{{a}_{H}}{( p + 1 )} ] + [ {( p + 1 )}^{2} - {p}^{2} ] \times 13.6 eV \qquad ( 48 )$$

Thermal energies may broaden the enthalpy of reaction. The relationship between kinetic energy and temperature is given by

$${E}_{kinetic} = \frac{3}{2} kT \qquad ( 49 )$$

For a temperature of 1200 K, the thermal energy is 0.16 eV, and the net enthalpy of reaction provided by cesium metal is 27.21 eV which is an exact match to the desired energy.

Hydrogen catalysts capable of providing a net enthalpy of reaction of approximately m×27.2 eV where m is an integer to produce hydrino whereby t electrons are ionized from an atom or ion are given infra. A further product of the catalysis is energy. The atoms or ions given in the first column are ionized to provide the net enthalpy of reaction of m×27.2 eV given in the tenth column where m is given in the eleventh column. The electrons which are ionized are given with the ionization potential (also called ionization energy or binding energy). The ionization potential of the nth electron of the atom or ion is designated by IPₙ and is given by Linde [David R. Linde, CRC Handbook of Chemistry and Physics, 78 th Edition, CRC Press, Boca Raton, Fla., (1997), p. 10-214 to 10-216] which is herein incorporated by reference. That is for example, Cs+3.89390 eV→Cs⁺+e⁻ and Cs⁺23.15745 eV→Cs²⁺+e⁻. The first ionization potential, IP₁=3.89390 eV, and the second ionization potential, IP₂=23.15745 eV, are given in the second and third columns, respectively. The net enthalpy of reaction for the double ionization of Cs is 27.05135 eV as given in the tenth column, and m=1 in Eq. (2a) as given in the eleventh column of Table 3.

TABLE 3
Hydrogen Ion or Atom Catalysts

| Catalyst | IP1 | IP2 | IP3 | IP4 | IP5 | IP6 | IP7 | IP8 | Enthalpy | m |
|---|---|---|---|---|---|---|---|---|---|---|
| Li | 5.39172 | 75.6402 | | | | | | | 81.032 | 3 |
| Be | 9.32263 | 18.2112 | | | | | | | 27.534 | 1 |
| Ar | 15.75962 | 27.62967 | 40.74 | | | | | | 84.12929 | 3 |
| Ar | 15.75962 | 27.62967 | 40.74 | 59.81 | 75.02 | | | | 218.95929 | 8 |
| Ar | 15.75962 | 27.62967 | 40.74 | 59.81 | 75.02 | 91.009 | 124.323 | | 434.29129 | 16 |
| K | 4.34066 | 31.63 | 45.806 | | | | | | 81.777 | 3 |
| Ca | 6.11316 | 11.8717 | 50.9131 | 67.27 | | | | | 136.17 | 5 |
| Ti | 6.8282 | 13.5755 | 27.4917 | 43.267 | 99.3 | | | | 190.46 | 7 |
| V | 6.7463 | 14.66 | 29.311 | 46.709 | 65.2817 | | | | 162.71 | 6 |
| Cr | 6.76664 | 16.4857 | 30.96 | | | | | | 54.212 | 2 |
| Mn | 7.43402 | 15.64 | 33.668 | 51.2 | | | | | 107.94 | 4 |
| Fe | 7.9024 | 16.1878 | 30.652 | | | | | | 54.742 | 2 |
| Fe | 7.9024 | 16.1878 | 30.652 | 54.8 | | | | | 109.54 | 4 |
| Co | 7.881 | 17.083 | 33.5 | 51.3 | | | | | 109.76 | 4 |
| Co | 7.881 | 17.083 | 33.5 | 51.3 | 79.5 | | | | 189.26 | 7 |
| Ni | 7.6398 | 18.1688 | 35.19 | 54.9 | 76.06 | | | | 191.96 | 7 |
| Ni | 7.6398 | 18.1688 | 35.19 | 54.9 | 76.06 | 108 | | | 299.96 | 11 |
| Cu | 7.72638 | 20.2924 | | | | | | | 28.019 | 1 |
| Zn | 9.39405 | 17.9644 | | | | | | | 27.358 | 1 |
| Zn | 9.39405 | 17.9644 | 39.723 | 59.4 | 82.6 | 108 | 134 | 174 | 625.08 | 23 |
| As | 9.8152 | 18.633 | 28.351 | 50.13 | 62.63 | 127.6 | | | 297.16 | 11 |
| Se | 9.75238 | 21.19 | 30.8204 | 42.945 | 68.3 | 81.7 | 155.4 | | 410.11 | 15 |
| Kr | 13.9996 | 24.3599 | 36.95 | 52.5 | 64.7 | 78.5 | | | 271.01 | 10 |
| Kr | 13.9996 | 24.3599 | 36.95 | 52.5 | 64.7 | 78.5 | 111 | | 382.01 | 14 |
| Rb | 4.17713 | 27.285 | 40 | 52.6 | 71 | 84.4 | 99.2 | | 378.66 | 14 |
| Rb | 4.17713 | 27.285 | 40 | 52.6 | 71 | 84.4 | 99.2 | 136 | 514.66 | 19 |
| Sr | 5.69484 | 11.0301 | 42.89 | 57 | 71.6 | | | | 188.21 | 7 |
| Nb | 6.75885 | 14.32 | 25.04 | 38.3 | 50.55 | | | | 134.97 | 5 |
| Mo | 7.09243 | 16.16 | 27.13 | 46.4 | 54.49 | 68.8276 | | | 151.27 | 8 |
| Mo | 7.09243 | 16.16 | 27.13 | 46.4 | 54.49 | 68.8276 | 125.664 | 143.6 | 489.36 | 18 |
| Pd | 8.3369 | 19.43 | | | | | | | 27.767 | 1 |
| Sn | 7.34381 | 14.6323 | 30.5026 | 40.735 | 72.28 | | | | 165.49 | 6 |
| Te | 9.0096 | 18.6 | | | | | | | 27.61 | 1 |
| Te | 9.0096 | 18.6 | 27.96 | | | | | | 55.57 | 2 |
| Cs | 3.8939 | 23.1575 | | | | | | | 27.051 | 1 |
| Ce | 5.5387 | 10.85 | 20.198 | 36.758 | 65.55 | | | | 138.89 | 5 |
| Ce | 5.5387 | 10.85 | 20.198 | 36.758 | 65.55 | 77.6 | | | 216.49 | 8 |
| Pr | 5.464 | 10.55 | 21.624 | 38.98 | 57.53 | | | | 134.15 | 5 |
| Sm | 5.6437 | 11.07 | 23.4 | 41.4 | | | | | 81.514 | 3 |
| Gd | 6.15 | 12.09 | 20.63 | 44 | | | | | 82.87 | 3 |
| Dy | 5.9389 | 11.67 | 22.8 | 41.47 | | | | | 81.879 | 3 |
| Pb | 7.41666 | 15.0322 | 31.9373 | | | | | | 54.386 | 2 |
| Pt | 8.9587 | 18.563 | | | | | | | 27.522 | 1 |
| He+ | | 54.4178 | | | | | | | 54.418 | 2 |
| Na+ | | 47.2864 | 71.6200 | 98.91 | | | | | 217.816 | 8 |
| Rb+ | | 27.285 | | | | | | | 27.285 | 1 |
| Fe3+ | | | | 54.8 | | | | | 54.8 | 2 |
| Mo2+ | | | 27.13 | | | | | | 27.13 | 1 |
| Mo4+ | | | | | 54.49 | | | | 54.49 | 2 |
| In3+ | | | | 54 | | | | | 54 | 2 |
| Ar+ | | 27.62967 | | | | | | | 27.62967 | 1 |

In an embodiment, the catalyst Rb⁺ according to Eqs. (6-8) may be formed from rubidium metal by ionization. The source of ionization may be UV light or a plasma. At least one of a source of UV light and a plasma may be provided by the catalysis of hydrogen with a one or more hydrogen catalysts such as potassium metal or K⁺ ions. In the latter case, potassium ions can also provide a net enthalpy of a multiple of that of the potential energy of the hydrogen atom. The second ionization energy of potassium is 31.63 eV; and K⁺ releases 4.34 eV when it is reduced to K. The combination of reactions K⁺ to K²⁺ and K⁺ to K, then, has a net enthalpy of reaction of 27.28 eV, which is equivalent to m=1 in Eq. (2a).

In an embodiment, the catalyst K⁺/K⁺ may be formed from potassium metal by ionization. The source of ionization may be UV light or a plasma. At least one of a source of UV light and a plasma may be provided by the catalysis of hydrogen with a one or more hydrogen catalysts such as potassium metal or K⁺ ions.

In an embodiment, the catalyst Rb⁺ according to Eqs. (6-8) or the catalyst K⁺/K⁺ may be formed by reaction of rubidium metal or potassium metal, respectively, with hydrogen to form the corresponding alkali hydride or by ionization at a hot filament which may also serve to dissociate molecular hydrogen to atomic hydrogen. The hot filament may be a refractory metal such as tungsten or molybdenum operated within a high temperature range such as 1000 to 2800° C.

A catalyst of the present invention can be an increased binding energy hydrogen compound having a net enthalpy of reaction of about

$$\frac{m}{2} \cdot 27 eV ,$$

where m is an integer greater than 1, preferably an integer less than 400, to produce an increased binding energy hydrogen atom having a binding energy of about

$$\frac{13.6 eV}{{( \frac{1}{p} )}^{2}}$$

where p is an integer, preferably an integer from 2 to 200.

In another embodiment of the catalyst of the present invention, hydrinos are formed by reacting an ordinary hydrogen atom with a catalyst having a net enthalpy of reaction of about

$$\frac{m}{2} \cdot 27.2 eV \qquad ( 50 )$$

where m is an integer. It is believed that the rate of catalysis is increased as the net enthalpy of reaction is more closely matched to

$$\frac{m}{2} \cdot 27.2 eV .$$

It has been found that catalysts having a net enthalpy of reaction within ±10%, preferably ±5% of

$$\frac{m}{2} \cdot 27.2 eV$$

are suitable for most applications.

In an embodiment, catalysts are identified by the formation of a plasma at low voltage as described in Mills publication R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943 which is incorporated by reference. In another embodiment, a means of identifying catalysts and monitoring the catalytic rate comprises a high resolution visible spectrometer with resolution preferable in the range 1 to 0.01 Å. The identity of a catalysts and the rate of catalysis may be determined by the degree of Doppler broadening of the hydrogen Balmer lines or other atomic lines.

3.2 Hydrino Catalysts

In a process called disproportionation, lower-energy hydrogen atoms, hydrinos, can act as catalysts because each of the metastable excitation, resonance excitation, and ionization energy of a hydrino atom is m×27.2 eV. The transition reaction mechanism of a first hydrino atom affected by a second hydrino atom involves the resonant coupling between the atoms of m degenerate multipoles each having 27.21 eV of potential energy [R. Mills, The Grand Unified Theory of Classical Quantum Mechanics, January 2000 Edition, BlackLight Power, Inc., Cranbury, N.J., Distributed by Amazon.com]. The energy transfer of m×27.2 eV from the first hydrino atom to the second hydrino atom causes the central field of the first atom to increase by m and its electron to drop m levels lower from a radius of

$$\frac{{a}_{H}}{p}$$

to a radius of

$$\frac{{a}_{H}}{p + m}$$

The second interacting lower-energy hydrogen is either excited to a metastable state, excited to a resonance state, or ionized by the resonant energy transfer. The resonant transfer may occur in multiple stages. For example, a nonradiative transfer by multipole coupling may occur wherein the central field of the first increases by m, then the electron of the first drops m levels lower from a radius of

$$\frac{{a}_{H}}{p}$$

to a radius of

$$\frac{{a}_{H}}{p + m}$$

with further resonant energy transfer. The energy transferred by multipole coupling may occur by a mechanism that is analogous to photon absorption involving an excitation to a virtual level. Or, the energy transferred by multipole coupling during the electron transition of the first hydrino atom may occur by a mechanism that is analogous to two photon absorption involving a first excitation to a virtual level and a second excitation to a resonant or continuum level [B. J. Thompson, Handbook of Nonlinear Optics, Marcel Dekker, Inc., New York, (1996), pp.497-548; Y. R. Shen, The Principles of Nonlinear Optics, John Wiley & Sons, New York, (1984), pp. 203-210; B. de Beauvoir, F. Nez, L. Julien, B. Cagnac, F. Biraben, D. Touahri, L. Hilico, O. Acef, A. Clairon, and J. J. Zondy, Physical Review Letters, Vol. 78, No. 3, (1997), pp. 440-443]. The transition energy greater than the energy transferred to the second hydrino atom may appear as a photon in a vacuum medium.

The transition of

$$H [ \frac{{a}_{H}}{p} ] to H [ \frac{{a}_{H}}{p + m} ]$$

induced by a multipole resonance transfer of m·27.21 eV and a transfer of [(p′)²−(p′−m′)²]×13.6 eV−m·27.2 eV with a resonance state of

$$H [ \frac{{a}_{H}}{{p}^{′} - {m}^{′}} ]$$

excited in

$$H [ \frac{{a}_{H}}{{p}^{′}} ]$$

is represented by

$$H ⌊ \frac{{a}_{H}}{{p}^{′}} ⌋ + H ⌊ \frac{{a}_{H}}{p} ⌋ \to H [ \frac{{a}_{H}}{{p}^{′} - {m}^{′}} ] + H [ \frac{{a}_{H}}{p + m} ] + [ ( {( p + m )}^{2} - {p}^{2} ) - ( {p}^{′2} - {( {p}^{′} - {m}^{′} )}^{2} ) ] X 13.6 eV \qquad ( 51 )$$

where p, p′, m, and m′ are integers.

Hydrinos may be ionized during a disproportionation reaction by the resonant energy transfer. A hydrino atom with the initial lower-energy state quantum number p and radius

$$\frac{{a}_{H}}{p}$$

may undergo a transition to the state with lower-energy state quantum number (p+m) and radius

$$\frac{{a}_{H}}{( p + m )}$$

by reaction with a hydrino atom with the initial lower-energy state quantum number m′, initial radius

$$\frac{{a}_{H}}{{m}^{′}} ,$$

and final radius a_{H} that provides a net enthalpy of m×27.2 e V. Thus, reaction of hydrogen-type atom,

$$H [ \frac{{a}_{H}}{p} ] ,$$

with the hydrogen-type atom,

$$H [ \frac{{a}_{H}}{{m}^{′}} ] ,$$

that is ionized by the resonant energy transfer to cause a transition reaction is represented by

$$\begin{matrix}\begin{matrix}m X 27.21 eV + H [ \frac{{a}_{H}}{{m}^{′}} ] + H [ \frac{{a}_{H}}{p} ] \to \\ {H}^{+} + {e}^{-} + H [ \frac{{a}_{H}}{( p + m )} ] + [ {( p + m )}^{2} - {p}^{2} - ( {m}^{′2} - 2 m ) ] X 13.6 eV\end{matrix} & ( 52 ) \\ {H}^{+} + {e}^{-} \to H [ \frac{{a}_{H}}{1} ] + 13.6 eV & ( 53 )\end{matrix}$$

And, the overall reaction is

$$H [ \frac{{a}_{H}}{{m}^{′}} ] + H ⌊ \frac{{a}_{H}}{p} ⌋ \to H [ \frac{{a}_{H}}{1} ] + H [ \frac{{a}_{H}}{( p + m )} ] + [ 2 pm + {m}^{2} - {m}^{′2} ] X 13.6 eV + 13.6 eV \qquad ( 54 )$$

4. Adjustment of Catalysis Rate

It is believed that the rate of catalysis is increased as the net enthalpy of reaction is more closely matched to m·27.2 eV where m is an integer. An embodiment of the hydrino hydride reactor for producing increased binding energy hydrogen compounds of the invention further comprises an electric or magnetic field source. The electric or magnetic field source may be adjustable to control the rate of catalysis. Adjustment of the electric or magnetic field provided by the electric or magnetic field source may alter the continuum energy level of a catalyst whereby one or more electrons are ionized to a continuum energy level to provide a net enthalpy of reaction of approximately m×27.2 eV. The alteration of the continuum energy may cause the net enthalpy of reaction of the catalyst to more closely match m·27.2 eV. Preferably, the electric field is within the range of about 0.01-10⁶ V/m, more preferably 0.1-10⁴ V/m, and most preferably 1-10³ V/m. Preferably, the magnetic flux is within the range of about 0.01-50 T. A magnetic field may have a strong gradient. Preferably, the magnetic flux gradient is within the range of about 10⁻⁴-10² Tcm⁻¹ and more preferably 10⁻³-1 Tcm⁻¹.

In an embodiment, the electric field E and magnetic field B are orthogonal to cause an EXB electron drift. The EXB drift may be in a direction such that energetic electrons produced by hydrogen catalysis dissipate a minimum amount of power due to current flow in the direction of the applied electric field which may be adjustable to control the rate of hydrogen catalysis.

In an embodiment of the energy cell, a magnetic field confines the electrons to a region of the cell such that interactions with the wall are reduced, and the electron energy is increased. The field may be a solenoidal field or a magnetic mirror field. The field may be adjustable to control the rate of hydrogen catalysis.

In an embodiment, the electric field such as a radio frequency field produces minimal current. In another embodiment, a gas which may be inert such as a noble gas is added to the reaction mixture to decrease the conductivity of the plasma produced by the energy released from the catalysis of hydrogen. The conductivity is adjusted by controlling the pressure of the gas to achieve an optimal voltage that controls the rate of catalysis of hydrogen. In another embodiment, a gas such as an inert gas may be added to the reaction mixture which increases the percentage of atomic hydrogen versus molecular hydrogen.

For example, the cell may comprise a hot filament that dissociates molecular hydrogen to atomic hydrogen and may further heat a hydrogen dissociator such as transition elements and inner transition elements, iron, platinum, palladium, zirconium, vanadium, nickel, titanium, Sc, Cr, Mn, Co, Cu, Zn, Y, Nb, Mo, Tc, Ru, Rh, Ag, Cd, La, Hf, Ta, W, Re, Os, Ir, Au, Hg, Ce, Pr, Nd, Pm, Sm, Eu, Gd, Tb, Dy, Ho, Er, Tm, Vb, Lu, Th, Pa, U, activated charcoal (carbon), and intercalated Cs carbon (graphite). The filament may further supply an electric field in the cell of the reactor. The electric field may alter the continuum energy level of a catalyst whereby one or more electrons are ionized to a continuum energy level to provide a net enthalpy of reaction of approximately m×27.2 eV. In another embodiment, an electric field is provided by electrodes charged by a variable voltage source. The rate of catalysis may be controlled by controlling the applied voltage which determines the applied field which controls the catalysis rate by altering the continuum energy level.

In another embodiment of the hydrino hydride reactor, the electric or magnetic field source ionizes an atom or ion to provide a catalyst having a net enthalpy of reaction of approximately m×27.2 eV. For examples, potassium metal is ionized to K⁺, or rubidium metal is ionized to Rb⁺ to provide the catalysts. The electric field source may be a hot filament whereby the hot filament may also dissociate molecular hydrogen to atomic hydrogen.

The high power levels observed previously in the microwave cells [R. L. Mills, P. Ray, B. Dhandapani, M. Nansteel, X. Chen, J. He, “New Power Source from Fractional Rydberg States of Atomic Hydrogen”, Chem. Phys. Letts., submitted.] may be due to the accumulation of an energetic material such as HeH(1/p) or ArH(1/p) on the quartz tube wall that undergoes reaction with a plasma containing helium to produce very high power as seen with the Beenakker cavity and the red-yellow coating which appears to be ArH(1/p). In an embodiment of the microwave power cell and hydride reactor, the microwave is run for an extended duration to build up these materials which may decompose to produce power and provide hydrino as a catalyst and a reactant for disproportionation reactions.

Alternatively, the helium-hydrogen microwave plasma showed very strong hydrino lines down to 8 nm with KI present in the reaction chamber. A titanium screen was also present in some experiments. Both KI and Ti act as a source of electrons to form hydrino hydride compounds. When these have accumulated to a sufficient extent, the disproportionation reaction may occur sufficiently to sustain a very high catalysis reaction rate which exceeds the rate at which hydrinos are lost by reaction or transport. In an embodiment of the microwave power cell and hydride reactor, the cell is run with a source of electrons such as KI, Sr, and/or Ti to form hydrino hydride compounds to generate a high power condition. In one case, the reactant may be placed directly into the cell. In another, the reactant may be volatilized from a reservoir by heating.

In an embodiment of the compound hollow cathode and microhollow discharge power cell and hydride reactor, the cell wall may comprise an electrically conductive material such as stainless steel. Preferably, the glow discharge power is operated at the level which gives the highest power output gain or a desirable output power gain for a given input power. In the case that the output to input power ratio increase with input power and is limited by arching of the discharge to the conductive cell wall. The plasma is preferably maintained inside of the hollow cathode or cathodes by insulating the electrically conductive wall with a material such as quartz or Alumina. In an embodiment, a stainless steel cell is lined with a quartz or alumna sleeve.

A preferable hollow cathode is comprised of refractory materials such as molybdenum or tungsten. A preferably hollow cathode comprises a compound hollow cathode. A preferable source of catalyst of a compound hollow cathode discharge cell is neon as described in R. L. Mills, P. Ray, J. Dong, M. Nansteel, B. Dhandapani, J. He, “Spectral Emission of Fractional-Principal-Quantum-Energy-Level Molecular Hydrogen”, INT. J. HYDROGEN ENERGY, submitted which is herein incorporated by reference in its entirety. In an embodiment of the cell comprising a compound hollow cathode and neon as the source of catalyst with hydrogen, the partial pressure of neon is, for example, in the range of about 90% to about 99.99 atom% and hydrogen is in the range of about 0.01 to about 10%. Preferably the partial pressure of neon is in the range of about 99 to about 99.9% and hydrogen is in the range of about 0.1 to about 1 atom %.

In an embodiment of the power cell and hydride reactor such as the compound hollow cathode, microwave, and inductively coupled RF cell, the cell temperature is greater than room temperature. The cell is preferably operated at an elevated temperature between about 25° C. and about 1500° C. More preferably the cell is operated in the temperature range of about 200 to about 1000° C. Most preferably, the cell is operated in the temperature range of about 200 to about 650° C.

In an embodiment of the cell, the requirement of a high wall temperature is provided with a gas-gap wall wherein the cell such as the microwave cell is surrounded by a gas gap and a surrounding water wall. A steep temperature exists in the gas gap. The thermal conductivity of the gap may be adjustable by varying the pressure or thermal conductivity of the gas in the gap.

5. Noble Gas Catalysts and Products

In an embodiment of the power source, hydride reactor and power converter comprising an energy cell for the catalysis of atomic hydrogen to form novel hydrogen species and compositions of matter comprising new forms of hydrogen of the present invention, the catalyst comprises a mixture of a first catalyst and a source of a second catalyst. In an embodiment, the first catalyst produces the second catalyst from the source of the second catalyst. In an embodiment, the energy released by the catalysis of hydrogen by the first catalyst produces a plasma in the energy cell. The energy ionizes the source of the second catalyst to produce the second catalyst. The second catalyst may be one or more ions produced in the absence of a strong electric field as typically required in the case of a glow discharge. The weak electric field may increase the rate of catalysis of the second catalyst such that the enthalpy of reaction of the catalyst matches m×27.2 e V to cause hydrogen catalysis. In embodiments of the energy cell, the first catalyst is selected from the group of catalyst given in TABLE 3 such as potassium and strontium, the source of the second catalyst is selected from the group of helium and argon and the second catalyst is selected from the group of He⁺ and Ar⁺ wherein the catalyst ion is generated from the corresponding atom by a plasma created by catalysis of hydrogen by the first catalyst. For examples, 1.) the energy cell contains strontium and argon wherein hydrogen catalysis by strontium produces a plasma containing Ar⁺ which serves as a second catalyst (Eqs. (12-14)) and 2.) the energy cell contains potassium and helium wherein hydrogen catalysis by potassium produces a plasma containing He⁺ which serves as a second catalyst (Eqs. (9-11)). In an embodiment, the pressure of the source of the second catalyst is in the range of about 1 millitorr to about one atmosphere. The hydrogen pressure is in the range of about 1 millitorr to about one atmosphere. In a preferred embodiment, the total pressure is in the range of about 0.5 torr to about 2 torr. In an embodiment, the ratio of the pressure of the source of the second catalyst to the hydrogen pressure is greater than one. In a preferred embodiment, hydrogen is about 0.1% to about 99%, and the source of the second catalyst comprises the balance of the gas present in the cell. More preferably, the hydrogen is in the range of about I% to about 5% and the source of the second catalyst is in the range of about 95% to about 99%. Most preferably, the hydrogen is about 5% and the source of the second catalyst is about 95%. These pressure ranges are representative examples and a skilled person will be able to practice this invention using a desired pressure to provide a desired result.

In an embodiment of the power cell and power converter the catalyst comprises at least one selected from the group of He⁺ and Ar⁺ wherein the ionized catalyst ion is generated from the corresponding atom by a plasma created by methods such as a glow discharge or inductively couple microwave discharge. Preferably, the corresponding reactor such as a discharge cell or plasma torch hydrino hydride reactor has a region of low electric field strength such that the enthalpy of reaction of the catalyst matches m×27.2 eV to cause hydrogen catalysis. In one embodiment, the reactor is a discharge cell having a hollow anode as described by Kuraica and Konjevic [Kuraica, M., Konjevic, N., Physical Review A, Volume 46, No. 7, October (1992), pp. 4429-4432]. In another embodiment, the reactor is a discharge cell having a hollow cathode such as a central wire or rod anode and a concentric hollow cathode such as a stainless or nickel mesh. In a preferred embodiment, the cell is a microwave cell wherein the catalyst is formed by a microwave plasma. In an embodiment atomic hydrogen is formed by a microwave plasma of molecular hydrogen gas and serves as the catalyst according the catalytic reaction given by Eqs. (24-26). Preferably the hydrogen pressure of the hydrogen microwave plasma is in the range of about 1 mTorr to about 10,000 Torr, more preferably the hydrogen pressure of the hydrogen microwave plasma is in the range of about 10 mTorr to about 100 Torr; most preferably, the hydrogen pressure of the hydrogen microwave plasma is in the range of about 10 mTorr to about 10 Torr.

In an embodiment of the cell wherein an electric field controls the rate of reaction of a catalyst comprising a cation such He⁺ or Ar⁺, the catalysis of hydrogen occurs primarily at a cathode. The cathode is selected to provide a desired field. In an embodiment of the cell, a first catalyst such as strontium is run with hydrogen gas and a source of a second catalyst such as argon or helium. In an embodiment, the catalysis of hydrogen produces a second catalyst from the source of a second catalyst such as Ar⁺ from argon or He⁺ from helium which serves as a second catalyst. The plasma produced by hydrogen catalysis may be magnetized to add confinement. In an embodiment, of the cell, the reaction is run in a magnet which provides a solenoidal or minimum magnetic (minimum B) field such that the second catalyst such as Ar⁺ is trapped and acquires a longer half-life. By confining the plasma, the ions such as the electrons become more energetic which increases the amount of second catalyst such as Ar⁺. The confinement also increases the energy of the plasma to create more atomic hydrogen. By increasing the concentration of second catalyst and atomic hydrogen, the hydrogen catalysis rate is increased. Strontium metal may react with Ar⁺ to decrease the amount available to act as a catalyst. The temperature of the cell may be controlled in at least a part of the cell to control the strontium vapor pressure to achieve a desired rate of catalysis. Preferably, the vapor pressure of strontium is controlled at the region of the cathode wherein a high concentration of Ar⁺ exists.

The compound may have the formula MHₙ wherein n is an integer from 1 to 100, more preferably 1 to 10, most preferably 1 to 6, M is a noble gas atom such as helium, neon, argon, xenon, and krypton, and the hydrogen content Hₙ of the compound comprises at least one increased binding energy hydrogen species.

A method of synthesis of increased binding energy ArHₙ wherein n is an integer from 1 to 100, more preferably 1 to 10, most preferably 1 to 6 comprises a discharge of a mixture of argon and hydrogen wherein the catalyst comprises Ar⁺. The ArHₙ product may be collected in a cooled reservoir such as a liquid nitrogen cooled reservoir.

A method of synthesis of increased binding energy HeHₙ wherein n is an integer from 1 to 100, more preferably 1 to 10, most preferably 1 to 6 comprises a discharge of a mixture of helium and hydrogen wherein He⁺ is the catalyst. The HeHₙ product may be collected in a cooled reservoir such as a liquid nitrogen cooled reservoir.

An embodiment to synthesize increased binding energy hydrogen compounds comprising at least one noble gas atom comprises adding the noble gas as a reactant in the hydrino hydride reactor with a source of atomic hydrogen and hydrogen catalyst.

An embodiment to enrich a noble gas from a source containing noble gas comprises reacting a source of noble atoms with increased binding energy hydrogen to form and increased binding energy hydrogen compound which may be isolated and decomposed to give the noble gas. In one embodiment, a gas stream containing the noble gas to be enriched is flowed through the hydrino hydride reactor such as a gas cell, gas discharge cell, or microwave cell hydrino hydride reactor such that increased binding energy hydrogen species produced in the reactor reacts with the noble gas of the gas stream to form an increased binding energy hydrogen compound containing at least one atom of the noble gas. The compound may be isolated and decomposed to give the enriched noble gas.

In an embodiment of the plasma cell wherein the catalyst is a cation such as at least one selected from the group of He⁺ and Ar⁺ an increased binding energy hydrogen compound, iron hydrino hydride, is formed as hydrino atoms react with iron present in the cell. The source of iron may be from a stainless steel cell. In another embodiment, an additional catalyst such as strontium, cesium, or potassium is present.

6. Plasma and Light Source from Hydrogen Catalysis

Typically the emission of vacuum ultraviolet light from hydrogen gas is achieved using discharges at high voltage, synchrotron devices, high power inductively coupled plasma generators, or a plasma is created and heated to extreme temperatures by RF coupling (e.g. >10⁶ K) with confinement provided by a toroidal magnetic field. Observation of intense extreme ultraviolet (EUV) emission at low temperatures (e.g. ≈10³ K) from atomic hydrogen generated at a tungsten filament that heated a titanium dissociator and certain gaseous atom or ion catalysts of the present invention vaporized by filament heating has been reported previously [R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943]. Potassium, cesium, and strontium atoms and Rb⁺ ionize at integer multiples of the potential energy of atomic hydrogen formed the low temperature, extremely low voltage plasma called a resonance transfer or rt-plasma having strong EUV emission. Similarly, the ionization energy of Ar⁺ is 27.63 eV, and the emission intensity of the plasma generated by atomic strontium increased significantly with the introduction of argon gas only when Ar⁺ emission was observed [R. Mills, P. Ray, “Spectroscopic Identification of a Novel Catalytic Reaction of Potassium and Atomic Hydrogen and the Hydride Ion Product”, Int. J. Hydrogen Energy, in press]. In contrast, the chemically similar atoms, sodium, magnesium and barium, do not ionize at integer multiples of the potential energy of atomic hydrogen did not form a plasma and caused no emission.

For further characterization, the width of the 656.2 nm Balmer α line emitted from microwave and glow discharge plasmas of hydrogen alone, strontium or magnesium with hydrogen, or helium, neon, argon, or xenon with 10% hydrogen was recorded with a high resolution visible spectrometer [R. L. Mills, A. Voigt, P. Ray, M. Nansteel, B. Dhandapani, “Measurement of Hydrogen Balmer Line Broadening and Thermal Power Balances of Noble Gas-Hydrogen Discharge Plasmas”, Int. J. Hydrogen Energy, submitted; R. L. Mills, P. Ray, B. Dhandapani, J. He, Comparison of Excessive Balmer α Line Broadening of Glow Discharge and Microwave Hydrogen Plasmas with Certain Catalysts, See Experimental section]. It was found that the strontium-hydrogen microwave plasma showed a broadening similar to that observed in the glow discharge cell of 27-33 eV; whereas, in both sources, no broadening was observed for magnesium-hydrogen. With noble-gas hydrogen mixtures, the trend of broadening with the particular noble gas was the same for both sources, but the magnitude of broadening was dramatically different. The microwave helium-hydrogen and argon-hydrogen plasmas showed extraordinary broadening corresponding to an average hydrogen atom temperature of 110-130 eV and 180-210 eV, respectively. The corresponding results from the glow discharge plasmas were 30-35 eV and 33-38 eV, respectively. Whereas, plasmas of pure hydrogen, neon-hydrogen, krypton-hydrogen, and xenon-hydrogen maintained in either source showed no excessive broadening corresponding to an average hydrogen atom temperature of ≈3 eV. In the case of the helium-hydrogen mixture and argon-hydrogen mixture microwave plasmas, the electron temperature Tₑ was measured from the ratio of the intensity of the He 501.6 nm line to that of the He 492.2 line and the ratio of the intensity of the Ar 104.8 nm line to that of the Ar 420.06 nm line, respectively. Similarly, the average electron temperature for helium-hydrogen and argon-hydrogen plasmas were high, 28,000 K and 11,600 K, respectively; whereas, the corresponding temperatures of helium and argon alone were only 6800 K and 4800 K, respectively. Stark broadening or acceleration of charged species due to high fields (e.g. over 10 kV/cm) can not be invoked to explain the microwave results since no high field was observationally present. Rather, the results may be explained by a resonant energy transfer between atomic hydrogen and atomic strontium, Ar⁺, or He²⁺ which ionize at an integer multiple of the potential energy of atomic hydrogen.

A preferred embodiment of the power cell produces a plasma which may be converted to electricity by at least one of the converters disclosed herein such as the magnetic mirror magnetohydrodynamic power converter and the plasmadynamic power. The power cell may also comprise a light source of at least one of extreme ultraviolet, ultraviolet, visible, infrared, microwave, or radio wave radiation.

A light source of the present invention comprises a cell of the present invention that comprises a light propagation structure or window for a desired radiation of a desired wavelength or desired wavelength range. For example, a quartz window may be used to transmit ultraviolet, visible, infrared, microwave, and/or radio wave light from the cell since it is transparent to the corresponding wavelength range. Similarly, a glass window may be used to transmit visible, infrared, microwave, and/or radio wave light from the cell, and a ceramic window may be used to transmit infrared, microwave, and/or radio wave light from the cell. The cell wall may comprise the light propagation structure or window. The cell wall or window may be coated with a phosphor that converts one or more short wavelengths to desired longer wavelengths. For example, ultraviolet or extreme ultraviolet may be converted to visible light. The light source may provide short wavelength light directly, and the short wavelength line emission may be used for applications known in the art such as photolithography.

A light source of the present invention such as a visible light source may comprise a transparent cell wall that may be insulated such that an elevated temperature may be maintained in the cell. In an embodiment, the wall may be a double wall with a separating vacuum space. The dissociator may be a filament such as a tungsten filament. The filament may also heat the catalyst to form a gaseous catalyst. A first catalyst may be at least one selected from the group of potassium, rubidium, cesium, and strontium metal. A second catalyst may be generated by a first. In an embodiment, at least one of helium and argon is ionized to He⁺ and Ar⁺, respectively, by the plasma formed by the catalysis of hydrogen by a first catalysts such as strontium. He⁺ and/or Ar⁺ serve as second hydrogen catalysts. The hydrogen may be supplied by a hydride that decomposes over time to maintain a desired pressure which may be determined by the temperature of the cell. The cell temperature may be controlled with a heater and a heater controller. In an embodiment, the temperature may be determined by the power supplied to the filament by a power controller.

A further embodiment of the present invention of a light source comprises a tunable light source that may provide coherent or laser light. Extreme ultraviolet (EUV) spectroscopy was recorded on microwave discharges of argon or helium with 10% hydrogen. Novel emission lines that matched those predicted for vibrational transitions of H₂^{*}[n=1/4n*=2]⁺ were observed with energies of ν·1.185 eV, ν=17 to 38 that terminated at the predicted dissociation limit, E_{D}, of H₂[n=1/4]⁺, E_{D}=42.88 eV (28.92 nm) [R. Mills, P. Ray, “Vibrational Spectral Emission of Fractional-Principal-Quantum-Energy-Level Hydrogen Molecular Ion”, Int. J. Hydrogen Energy, in press which is incorporated herein by reference.]. The vibrational lines of a dihydrino molecular ion such as H₂^{*}[n=1/4;n*=2]⁺ having energies of ν·1.185 eV, ν=integer may be a source of tunable laser light. The tunable light source of the present invention comprises at least one of the gas, gas discharge, plasma torch, or microwave plasma cell wherein the cell may comprise a laser cavity. A source of tunable laser light may be provided by the light emitted from a dihydrino molecular ion using systems and means which are known in the art as described in Laser Handbook, Edited by M. L. Stitch, North-Holland Publishing Company, (1979).

The light source of the present invention may comprise at least one of the gas, gas discharge, plasma torch, or microwave plasma cell wherein ions or excimers are effectively formed that serve as catalysts from a source of catalyst such as He⁺, He₂*, Ne₂*, Ne⁺/H⁺ or Ar⁺ catalysts from helium, helium, neon, neon-hydrogen mixture, and argon gases, respectively. The light may be largely monochromatic light such as line emission of the Lyman series such as Lyman α or Lyman β.

A mixture of helium and neon is the basis of a He—Ne laser. Both of these atoms are also a source of catalyst. In an embodiment of the plasma power cell such as the microwave cell, the source of catalyst comprises a mixture of helium and neon with hydrogen. Population of helium-neon lasing state (20.66 eV metastable state to an excited 18.70 eV state with the laser emission at 632. 8 nm) is pumped by the catalysis of atomic hydrogen. Examples of microwave and discharge cell which use at least one of neon or helium as a source of catalyst are given in Mills Publications [R. L. Mills, P. Ray, J. Dong, M. Nansteel, B. Dhandapani, J. He, “Spectral Emission of Fractional-Principal-Quantum-Energy-Level Molecular Hydrogen”, INT. J. HYDROGEN ENERGY, submitted; R. L. Mills, P. Ray, B. Dhandapani, M. Nansteel, X. Chen, J. He, “New Power Source from Fractional Rydberg States of Atomic Hydrogen”, Chem. Phys. Letts., in press; R. Mills, P. Ray, “Spectral Emission of Fractional Quantum Energy Levels of Atomic Hydrogen from a Helium-Hydrogen Plasma and the Implications for Dark Matter”, Int. J. Hydrogen Energy, Vol. 27, No. 3, pp. 301-322] which are incorporated herein by reference in their entirety.

Rb⁺ to Rb²⁺ and 2K⁺ to K+K²⁺ each provide a reaction with a net enthalpy equal to the potential energy of atomic hydrogen. The presence of these gaseous ions with thermally dissociated hydrogen formed a plasma having strong VUV emission with a stationary inverted Lyman population. We propose an energetic catalytic reaction involving a resonance energy transfer between hydrogen atoms and Rb⁺ or 2K⁺ to form a very stable novel hydride ion. Its predicted binding energy of 3.0468 eV was observed at 4070.0 Å with its predicted bound-free hyperfine structure lines E_{HF}=j²3.0056×10⁻⁵+3.0575 eV (j is an integer) that matched for j=1 to j=37 to within a 1 part per 10. This catalytic reaction may pump a cw HI laser. The enabling description is given in Mills articles [R. Mills, P. Ray, R. Mayo, “C W HI Laser Based on a Stationary Inverted Lyman Population Formed from Incandescently Heated Hydrogen Gas with Certain Group I Catalysts”, IEEE Transactions on Plasma Science, submitted; R. L. Mills, P. Ray, “Stationary Inverted Lyman Population Formed from Incandescently Heated Hydrogen Gas with Certain Catalysts”, Chem. Phys. Letts., submitted] which are herein incorporated by reference in their entirety.

As given in R. L. Mills, P. Ray, “Stationary Inverted Lyman Population Formed from Incandescently Heated Hydrogen Gas with Certain Catalysts”, Chem. Phys. Letts., submitted: Then the inverted population is explained by a resonance nonradiative energy transfer from the short-lived highly energetic intermediates, atoms undergoing catalyzed transitions to states given by Eqs. (1) and (3), to yield H(n>2) atoms directly by multipole coupling [R. L. Mills, P. Ray, B. Dhandapani, J. He, “Spectroscopic Identification of Fractional Rydberg States of Atomic Hydrogen”, J. of Phys. Chem., submitted] and fast H(n=1) atoms. The emission of H(n=3) from fast H(n=1) atoms excited by collisions with the background H₂ has been discussed by Radovanov et al. [S. B. Radovanov, K. Dzierzega, J. R. Roberts, J. K. Olthoff, “Time-resolved Balmer-alpha emission from fast hydrogen atoms in low pressure, radio-frequency discharges in hydrogen”, Appl. Phys. Lett., Vol. 66, No. 20, (1995), pp. 2637-2639]. Formation of H⁺ is also predicted which is far from thermal equilibrium in terms of the ion temperature as discussed in Section 3B. Akatsuka et al. [H. Akatsuka, M. Suzuki, “Stationary population inversion of hydrogen in arc-heated magnetically trapped expanding hydrogen-helium plasma jet”, Phys. Rev. E, Vol. 49, (1994), pp. 1534-1544] show that it is characteristic of cold recombining plasmas to have the high lying levels in local thermodynamic equilibrium (LTE); whereas, for the low lying levels, population inversion is obtained when T_{c} becomes low with an appropriate electron density as shown by the Saha-Boltzmann equation.

As a consequence of the nonradiative energy transfer of m·27.2 eV to the catalyst, the hydrogen atom becomes unstable and emits further energy until it achieves a lower-energy nonradiative state having a principal energy level given by Eqs. (1) and (3). Thus, these intermediate states also correspond to an inverted population, and the emission from these states with energies of q·13.6 eV where q=1,2,3,4,6,7,8,9,11,12 shown in Refs. 14 and 19 may be the basis of a laser in the EUV and soft X-ray, since the excitation of the corresponding relaxed Rydberg state atoms H(1/(p+m)) requires the participation of a nonradiative process [H. Conrads, R. Mills, Th. Wrubel, “Emission in the Deep Vacuum Ultraviolet from an Incandescently Driven Plasma in a Potassium Carbonate Cell”, Plasma Sources Science and Technology, submitted].

7. Energy Reactor

An energy reactor 50, in accordance with the invention, is shown in FIG. 1 and comprises a vessel 52 which contains an energy reaction mixture 54, a heat exchanger 60, and a power converter such as a steam generator 62 and turbine 70. The heat exchanger 60 absorbs heat released by the catalysis reaction, when the reaction mixture, comprised of hydrogen and a catalyst reacts to form lower-energy hydrogen. The heat exchanger exchanges heat with the steam generator 62 which absorbs heat from the exchanger 60 and produces steam. The energy reactor 50 further comprises a turbine 70 which receives steam from the steam generator 62 and supplies mechanical power to a power generator 80 which converts the steam energy into electrical energy, which can be received by a load 90 to produce work or for dissipation.

The energy reaction mixture 54 comprises an energy releasing material 56 including a source of hydrogen isotope atoms or a source of molecular hydrogen isotope, and a source of catalyst 58 which resonantly remove approximately m×27.21 eV to form lower-energy atomic hydrogen and approximately m×48.6 eV to form lower-energy molecular hydrogen where m is an integer wherein the reaction to lower energy states of hydrogen occurs by contact of the hydrogen with the catalyst. The catalysis releases energy in a form such as heat and lower-energy hydrogen isotope atoms and/or molecules.

The source of hydrogen can be hydrogen gas, dissociation of water including thermal dissociation, electrolysis of water, hydrogen from hydrides, or hydrogen from metal-hydrogen solutions. In all embodiments, the source of catalysts can be one or more of an electrochemical, chemical, photochemical, thermal, free radical, sonic, or nuclear reaction(s) or inelastic photon or particle scattering reaction(s). In the latter two cases, the present invention of an energy reactor comprises a particle source 75b and/or photon source 75a to supply the catalyst. In these cases, the net enthalpy of reaction supplied corresponds to a resonant collision by the photon or particle. In a preferred embodiment of the energy reactor shown in FIG. 9, atomic hydrogen is formed from molecular hydrogen by a photon source 75a such as a microwave source or a UV source.

The photon source may also produce photons of at least one energy of approximately

$$mX 27.21 eV , \frac{m}{2} X 27.21 eV ,$$

or 40.8 eV causes the hydrogen atoms undergo a transition to a lower energy state. In another preferred embodiment, a photon source 75a producing photons of at least one energy of approximately m×48.6 eV, 95.7 eV, or m×31.94 eV causes the hydrogen molecules to undergo a transition to a lower energy state. In all reaction mixtures, a selected external energy device 75, such as an electrode may be used to supply an electrostatic potential or a current (magnetic field) to decrease the activation energy of the reaction. In another embodiment, the mixture 54, further comprises a surface or material to dissociate and/or absorb atoms and/or molecules of the energy releasing material 56. Such surfaces or materials to dissociate and/or absorb hydrogen, deuterium, or tritium comprise an element, compound, alloy, or mixture of transition elements and inner transition elements, iron, platinum, palladium, zirconium, vanadium, nickel, titanium, Sc, Cr, Mn, Co, Cu, Zn, Y, Nb, Mo, Tc, Ru, Rh, Ag, Cd, La, Hf, Ta, W, Re, Os, Ir, Au, Hg, Ce, Pr, Nd, Pm, Sm, Eu, Gd, Tb, Dy, Ho, Er, Tm, Vb, Lu, Th, Pa, U, activated charcoal (carbon), and intercalated Cs carbon (graphite).

A catalyst is provided by the ionization of t electrons from an atom or ion to a continuum energy level such that the sum of the ionization energies of the t electrons is approximately m×27.2 eV where t and m are each an integer. A catalyst may also be provided by the transfer of t electrons between participating ions. The transfer of t electrons from one ion to another ion provides a net enthalpy of reaction whereby the sum of the ionization energy of the electron donating ion minus the ionization energy of the electron accepting ion equals approximately m·27.2 eV where t and m are each an integer.

In a preferred embodiment, a source of hydrogen atom catalyst comprises a catalytic material 58, that typically provide a net enthalpy of approximately m×27.21 eV plus or minus 1 eV. In a preferred embodiment, a source of hydrogen molecule catalysts comprises a catalytic material 58, that typically provide a net enthalpy of reaction of approximately m×48.6 eV plus or minus 5 eV. The catalysts include those given in TABLES 1 and 3 and the atoms, ions, molecules, and hydrinos described in Mills Prior Publications which are incorporated herein by reference.

A further embodiment is the vessel 52 containing a catalysts in the molten, liquid, gaseous, or solid state and a source of hydrogen including hydrides and gaseous hydrogen. In the case of a reactor for catalysis of hydrogen atoms, the embodiment further comprises a means to dissociate the molecular hydrogen into atomic hydrogen including an element, compound, alloy, or mixture of transition elements, inner transition elements, iron, platinum, palladium, zirconium, vanadium, nickel, titanium, Sc, Cr, Mn, Co, Cu, Zn, Y, Nb, Mo, Tc, Ru, Rh, Ag, Cd, La, Hf, Ta, W, Re, Os, Ir, Au, Hg, Ce, Pr, Nd, Pm, Sm, Eu, Gd, Tb, Dy, Ho, Er, Tm, Vb, Lu, Th, Pa, U, activated charcoal (carbon), and intercalated Cs carbon (graphite) or electromagnetic radiation including UV light provided by photon source 75a.

The present invention of an electrolytic cell energy reactor, pressurized gas energy reactor, a gas discharge energy reactor, and a microwave cell energy reactor comprises: a source of hydrogen; one of a solid, molten, liquid, and gaseous source of catalyst; a vessel containing hydrogen and the catalyst wherein the reaction to form lower-energy hydrogen occurs by contact of the hydrogen with the catalyst; and a means for removing the lower-energy hydrogen product. The present energy invention is further described in Mills Prior Publications which are incorporated herein by reference.

In a preferred embodiment, the catalysis of hydrogen produces a plasma. The plasma may also be at least partially maintained by a microwave generator wherein the microwaves are tuned by a tunable microwave cavity, carried by a waveguide, and are delivered to the reaction chamber though an RF transparent window or antenna. The microwave frequency may be selected to efficiently form atomic hydrogen from molecular hydrogen. It may also effectively form ions or excimers that serve as catalysts from a source of catalyst such as He⁺, He₂ *, Ne₂ *, Ne⁺/H⁺ or Ar⁺ catalysts from helium, helium, neon, neon-hydrogen mixture, and argon gases, respectively.

8. Microwave Gas Cell Hydride and Power Reactor

A microwave gas cell hydride and power reactor of the present invention for the catalysis of atomic hydrogen to form increased-binding-energy-hydrogen species and increased-binding-energy-hydrogen compounds comprises a vessel having a chamber capable of containing a vacuum or pressures greater than atmospheric, a source of atomic hydrogen, a source of microwave power to form a plasma, and a catalyst capable of providing a net enthalpy of reaction of m/2·27.2±0.5 eV where m is an integer, preferably m is an integer less than 400. The source of microwave power may comprise a microwave generator, a tunable microwave cavity, waveguide, and an antenna. Alternatively, the cell may further comprise a means to at least partially convert the power for the catalysis of atomic hydrogen to microwaves to maintain the plasma.

9. Capacitively and Inductively Coupled RF Plasma Cell Hydride and Power Reactor

A capacitively and/or inductively coupled radio frequency (RF) plasma cell hydride and power reactor of the present invention for the catalysis of atomic hydrogen to form increased-binding-energy-hydrogen species and increased-binding-energy-hydrogen compounds comprises a vessel having a chamber capable of containing a vacuum or pressures greater than atmospheric, a source of atomic hydrogen, a source of RF power to form a plasma, and a catalyst capable of providing a net enthalpy of reaction of m/2·27.2±0.5 eV where m is an integer, preferably m is an integer less than 400. The cell may further comprise at least two electrodes and an RF generator wherein the source of RF power may comprise the electrodes driven by the RF generator. Alternatively, the cell may further comprise a source coil which may be external to a cell wall which permits RF power to couple to the plasma formed in the cell, a conducting cell wall which may be grounded and a RF generator which drives the coil which may inductively and/or capacitively couple RF power to the cell plasma.

10. Magnetic Mirror Magnetohydrodynamic Power Converter

The plasma formed by the catalysis of atomic hydrogen comprises energetic electrons and ions which may be generated selectively in a desired region. A magnetic mirror 913 of a magnetic mirror magnetohydrodynamic power converter shown in FIG. 10 may be located in the desired region such that electrons and ions are forced from a homogeneous distribution of velocities in x, y, and z to a preferential velocity along the axis of magnetic field gradient of the magnetic mirror, the z-axis. The component of electron motion perpendicular to the direction of the z-axis v_{⊥} is at least partially converted into to parallel motion v_{∥} due to the adiabatic invariant:

$$\frac{{v}_{⊥}^{2}}{B} = constant .$$

The magnetic mirror magnetohydrodynamic power converter further comprises a magnetohydrodynamic power converter 911 and 915 of FIG. 10 comprising a source of magnetic flux transverse to the z-axis. Thus, the ions have a preferential velocity along the z-axis and propagate into the region of the transverse magnetic flux from the source of transverse flux. The Lorentzian force on the propagating ions is transverse to the velocity and the magnetic field and in opposite directions for positive and negative ions. Thus, a transverse current is produced. The magnetohydrodynamic power converter further comprises at least two electrodes which may be transverse to the magnetic field to receive the transversely Lorentzian deflected ions which creates a voltage across the electrodes. The voltage may drive a current through an electrical load.

11. Plasmadynamic Power Converter

The mass of a positively charged ion of a plasma is at least 1800 times that of the electron; thus, the cyclotron orbit is 1800 times larger. This result allows electrons to be magnetically trapped on field lines while ions may drift. Charge separation may occur to provide a voltage between two electrons which is the basis of plasmadynamic power conversion of the present invention.

12. Hydrino Hydride Battery

A battery 400′ shown in FIG. 2 is provided comprising a cathode 405′ and a cathode compartment 401′ containing an oxidant; an anode 410′ and an anode compartment 402′ containing a reductant, a salt bridge 420′ completing a circuit between the cathode and anode compartments, and an electrical load 425′. Increased binding energy hydrogen compounds may serve as oxidants of the battery cathode half reaction. The oxidant may be an increased binding energy hydrogen compound. A cation Mⁿ⁺ (where n is an integer) bound to a hydrino hydride ion such that the binding energy of the cation or atom M⁽ⁿ⁻¹⁾⁺ is less than the binding energy of the hydrino hydride ion

$${H}^{-} ( \frac{1}{p} )$$

may serve as the oxidant. Alternatively, a hydrino hydride ion may be selected for a given cation such that the hydrino hydride ion is not oxidized by the cation. Thus, the oxidant

$${M}^{n +} {{H}^{-} ( \frac{1}{p} )}_{n}$$

comprises a cation Mⁿ⁺, where n is an integer and the hydrino hydride ion

$${H}^{-} ( \frac{1}{p} ) ,$$

where p is an integer greater than 1, that is selected such that its binding energy is greater than that of M⁽ⁿ⁻¹⁾⁺. By selecting a stable cation-hydrino hydride anion compound, a battery oxidant is provided wherein the reduction potential is determined by the binding energies of the cation and anion of the oxidant.

Hydride ions having extraordinary binding energies may stabilize a cation M^{X+} in an extraordinarily high oxidation state such as +2 in the case of lithium. Thus, these hydride ions may be used as the basis of a high voltage battery of a rocking chair design wherein the hydride ion moves back and forth between the cathode and anode half cells during discharge and charge cycles. Alternatively, a cation such as lithium ion, Li⁺, may move back and forth between the cathode and anode half cells during discharge and charge cycles. Exemplary reactions for a cation M^{X+} such as Li²⁺ are:

Cathode Reaction:

MHₓ+e⁻+M⁺MHₓ₋₁+MH (55)

Anode Reaction:

M→M⁺+e⁻ (56)

Overall Reaction:

M+MHₓ→2MHₓ₋₁ (57)

A suitable solid electrolyte for lithium ions comprises polyphosphazenes and ceramic powder.

In an embodiment of the battery, the oxidant and/or reductant are molten with heat supplied by the internal resistance of the battery or by external heater 450′. Lithium ions of the molten battery reactants complete the circuit by migrating through the salt bridge 420′.

### III. BRIEF DESCRIPTION OF THE DRAWINGS

FIG. 1 is a schematic drawing of a power system comprising a hydride reactor in accordance with the present invention;

FIG. 2 is a schematic drawing of a battery in accordance with the present invention;

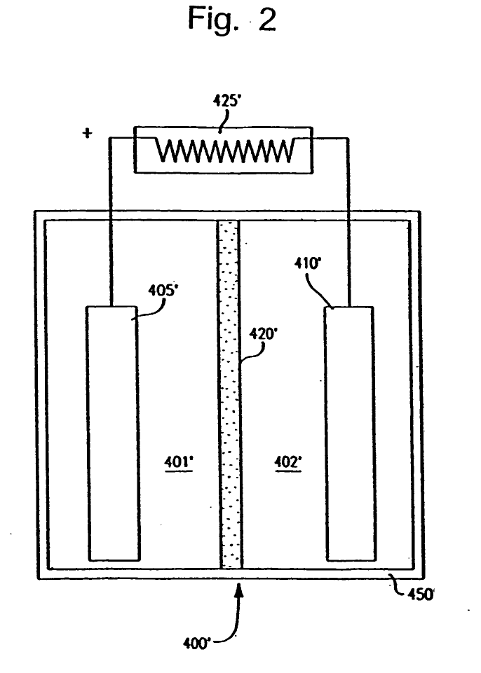

FIG. 3 is a schematic drawing of a plasma electrolytic cell hydride reactor in accordance with the present invention;

FIG. 4 is a schematic drawing of a gas cell hydride reactor in accordance with the present invention;

FIG. 5 is a schematic drawing of a gas discharge cell hydride reactor in accordance with the present invention;

FIG. 6 is a schematic drawing of a RF barrier electrode gas discharge cell hydride reactor in accordance with the present invention;

FIG. 7 is a schematic drawing of a plasma torch cell hydride reactor in accordance with the present invention;

FIG. 8 is a schematic drawing of another plasma torch cell hydride reactor in accordance with the present invention;

FIG. 9 is a schematic drawing of a microwave gas cell reactor or a RF gas cell reactor in accordance with the present invention;

FIG. 10 is a schematic drawing of a magnetic mirror magnetohydrodynamic power converter in accordance with the present invention;

FIG. 11 is another schematic drawing of a magnetic mirror magnetohydrodynamic power converter in accordance with the present invention;

FIG. 12 is a schematic drawing of field lines of a magnetic mirror centered at z=0 for positions z<0 in accordance with the present invention;

FIG. 13 is a schematic drawing of a magnetic bottle power converter which may serve as source of energetic ions for a magnetohydrodymanic power converter and may further serve as a means to preferentially confine electrons in an embodiment of a plasmadynamic power converter in accordance with the present invention;

FIG. 14 is a schematic drawing of a plasmadynamic power converter in accordance with the present invention;

FIG. 15 is a schematic drawing of a plurality of magnetized electrodes which serves as cathodes of the plasmadynamic power converter of FIG. 14 in accordance with the present invention; and

FIG. 16 is a schematic drawing of a radio frequency power converter with RF bunching of protons in accordance with the present invention.

FIG. 17. The experimental set up comprising a microwave discharge gas cell light source and an EUV spectrometer which was differentially pumped.

FIG. 18. The EUV spectra (15-50 nm) of the microwave cell emission of the helium-hydrogen mixture (98/2%) recorded at 1, 24, and 72 hours with a normal incidence EUV spectrometer and a CEM, and control helium (dotted curve) recorded with a 4° grazing incidence EUV spectrometer and a CEM. The pressure was maintained at 20 torr. Only known He I and He II peaks were observed with the helium control. Reproducible novel emission lines that increased with time were observed at 45.6 nm and 30.4 nm with energies of q·13.6 eV where q=2 or 3 and at 37.4 nm and 20.5 nm with energies of q·13.6 eV where q=4 or 6 that were inelastically scattered by helium atoms wherein 21.2 eV (58.4 nm) was absorbed in the excitation of He (1s²). These lines were identified in Table 1 as hydrogen transitions to electronic energy levels below the “ground” state corresponding to fractional quantum numbers.

FIG. 19. The short wavelength EUV spectra (5-50 nm) of the microwave cell emission of the helium-hydrogen mixture (98/2%) (top curve) and control hydrogen (bottom curve) recorded with a normal incidence EUV spectrometer and a CEM. No hydrogen emission was observed in this region, and no instrument artifacts were observed. Reproducible novel emission lines were observed at 45.6 nm, 30.4 nm, 13.03 nm, 10.13 nm, and 8.29 nm with energies of q·13.6 eV where q=2,3,7,9, or 11 and at 37.4 nm, 20.5 nm, and 14.15 nm with energies of q·13.6 eV where q=4,6, or 8 that were inelastically scattered by helium atoms wherein 21.2 eV (58.4 nm) was absorbed in the excitation of He (1s²). These lines were identified in Table 1 as hydrogen transitions to electronic energy levels below the “ground” state corresponding to fractional quantum numbers.

FIG. 20. The EUV spectrum (50-65 nm) of the helium-hydrogen mixture (98/2%) discharge cell emission recorded with a 4° grazing incidence EUV spectrometer and a CEM. The pressure was maintained at 400 mtorr. A novel line was observed at 63.3 nm corresponding to the 30.4 nm lower-energy hydrogen transition line shown in FIGS. 2 and 3 and Table 1 that was inelastically scattered by helium atoms wherein 21.2 eV (58.4 nm) was absorbed in the excitation of He (1s²).

FIG. 21. The EUV spectrum (88-125 nm ) of the helium-hydrogen mixture (98/2%) microwave cell emission recorded with a normal incidence EUV spectrometer and a CEM. The pressure was maintained at 20 torr. An emission line was observed at 91.2 nm with an energy of q·13.6 eV where q=1 which was identified in Table 1 as hydrogen transitions to electronic energy levels below the “ground” state corresponding to fractional quantum numbers based on the 91.2 nm line intensity relative to Lβ compared to that of the control hydrogen plasma.

FIG. 22. The EUV spectrum (80-105 nm ) of the control hydrogen microwave discharge cell emission recorded with a normal incidence EUV spectrometer and a CEM.

FIG. 23. The 656.2 nm Balmer α line width recorded with a high resolution (±0.025 nm) visible spectrometer on a helium-hydrogen mixture (90/10%) discharge plasma. Significant broadening was observed corresponding to an average hydrogen atom temperature of 33-38 eV.

FIG. 24. The temperature rise above the ambient as a function of time for helium alone and the helium-hydrogen mixture (90/10%) with microwave input power set at 60 W and 30 W, respectively. In both cases, the constant microwave input was maintained for 90 seconds and then terminated. The cooling curves were then recorded. The maximum ΔT for helium-hydrogen mixture and helium alone was 873° C. and 178° C., respectively. The thermal output power of the helium-hydrogen plasma was determined to be at least 300 W.

FIG. 25. Cross sectional view of the discharge cell.

FIG. 26. The experimental set up comprising a discharge gas cell light source and an EUV spectrometer which was differentially pumped.

FIG. 27. The experimental set up comprising a microwave discharge gas cell light source and an EUV-UV-VIS spectrometer which was differentially pumped.

FIG. 28. Cylindrical stainless steel gas cell for studies of the broadening of the Balmer α line emitted from glow discharge plasmas of 1.) pure hydrogen alone, 2.) hydrogen with strontium or magnesium, 3.) a mixture of 10% hydrogen and helium, argon, krypton, or xenon, and 4.)strontium with a mixture of 10% hydrogen and helium or argon.

FIG. 29. The EUV spectra (100-170 nm) of emission from the discharge and microwave plasmas of argon-hydrogen mixture (97/3%). The microwave plasma showed significant broadening of the width of the Lyman α line of 10 nm; whereas, the width of the Lyman α line emitted from the glow discharge plasma was 2.6 nm. In addition, the intensity of the Lyman α emission compared to the molecular hydrogen emission was significantly higher in the case of the microwave plasma. The results indicate a much greater ion temperature in the microwave plasma.

FIG. 30. The 656 nm Balmer α line width recorded with a high resolution (±0.025 nm) visible spectrometer on a xenon-hydrogen (90/10%) and a hydrogen glow discharge plasma. No line excessive broadening was observed corresponding to an average hydrogen atom temperature of 3-4 eV.

FIG. 31. The 656 nm Balmer α line width recorded with a high resolution (±0.025 nm) visible spectrometer on a strontium-hydrogen and a hydrogen glow discharge plasma. Significant broadening was observed corresponding to an average hydrogen atom temperature of 23-25 eV.

FIG. 32. The 656 nm Balmer α line width recorded with a high resolution (±0.025 nm) visible spectrometer on an argon-hydrogen (90/10%) and a hydrogen glow discharge plasma. Significant broadening was observed corresponding to an average hydrogen atom temperature of 30-35 eV.

FIG. 33. The 656 nm Balmer α line width recorded with a high resolution (±0.006 nm ) visible spectrometer on a xenon-hydrogen (90/10%) and a hydrogen microwave discharge plasma. No line excessive broadening was observed corresponding to an average hydrogen atom temperature of 3-4 eV.

FIG. 34. The 656 nm Balmer α line width recorded with a high resolution (±0.006 nm ) visible spectrometer on an magnesium-hydrogen and a hydrogen microwave discharge plasma. No line excessive broadening was observed corresponding to an average hydrogen atom temperature of 4-5 eV.

FIG. 35. The 656 nm Balmer α line width recorded with a high resolution (±0.006 nm ) visible spectrometer on a helium-hydrogen (90/10%) and a hydrogen microwave discharge plasma. Significant broadening was observed corresponding to an average hydrogen atom temperature of 180-210 eV.

### IV. DETAILED DESCRIPTION OF THE INVENTION

The following preferred embodiments of the invention disclose numerous property ranges, including but not limited to, voltage, current, pressure, temperature, and the like, which are merely intended as illustrative examples. Based on the detailed written description, one skilled in the art would easily be able to practice this invention within other property ranges to produce the desired result without undue experimentation.

1. Power Cell, Hydride Reactor, and Power Converter

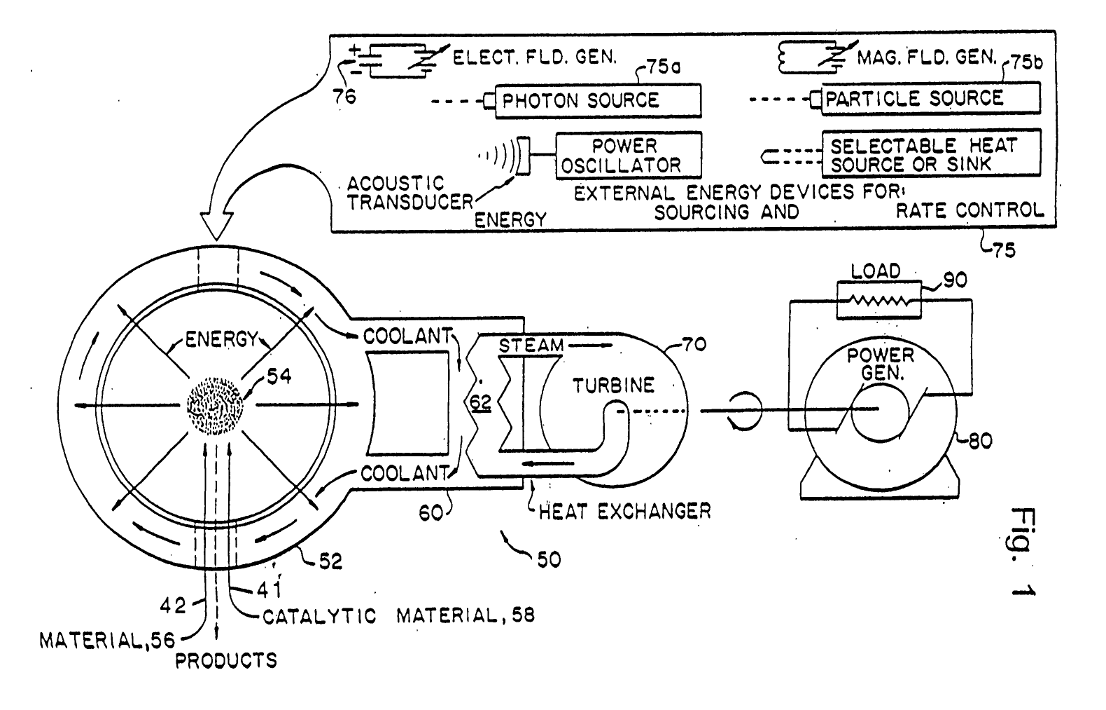

One embodiment of the present invention involves a power system comprising a hydride reactor shown in FIG. 1. The hydrino hydride reactor comprises a vessel 52 containing a catalysis mixture 54. The catalysis mixture 54 comprises a source of atomic hydrogen 56 supplied through hydrogen supply passage 42 and a catalyst 58 supplied through catalyst supply passage 41. Catalyst 58 has a net enthalpy of reaction of about

$$\frac{m}{2} \cdot 27.21 \pm 0.5 eV ,$$

where m is an integer, preferably an integer less than 400. The catalysis involves reacting atomic hydrogen from the source 56 with the catalyst 58 to form lower-energy hydrogen “hydrinos” and produce power. The hydride reactor further includes an electron source for contacting hydrinos with electrons, to reduce the hydrinos to hydrino hydride ions.

The source of hydrogen can be hydrogen gas, water, ordinary hydride, or metal-hydrogen solutions. The water may be dissociated to form hydrogen atoms by, for example, thermal dissociation or electrolysis. According to one embodiment of the invention, molecular hydrogen is dissociated into atomic hydrogen by a molecular hydrogen dissociating catalyst. Such dissociating catalysts include, for example, noble metals such as palladium and platinum, refractory metals such as molybdenum and tungsten, transition metals such as nickel and titanium, inner transition metals such as niobium and zirconium, and other such materials listed in the Prior Mills Publications.

According to another embodiment of the invention, a photon source such as a microwave or UV photon source dissociates hydrogen molecules to hydrogen atoms.

In the hydrino hydride reactor embodiments of the present invention, the means to form hydrinos can be one or more of an electrochemical, chemical, photochemical, thermal, free radical, sonic, or nuclear reaction(s), or inelastic photon or particle scattering reaction(s). In the latter two cases, the hydride reactor comprises a particle source 75b and/or photon source 75a as shown in FIG. 1, to supply the reaction as an inelastic scattering reaction. In one embodiment of the hydrino hydride reactor, the catalyst in the molten, liquid, gaseous, or solid state includes those given in TABLES 1 and 3 and those given in the Tables of the Prior Mills Publications (e.g. TABLE 4 of PCT/US90/01998 and pages 25-46, 80-108 of PCT/US94/02219).

When the catalysis occurs in the gas phase, the catalyst may be maintained at a pressure less than atmospheric, preferably in the range about 10 millitorr to about 100 torr. The atomic and/or molecular hydrogen reactant is also maintained at a pressure less than atmospheric, preferably in the range about 10 millitorr to about 100 torr. However, if desired, higher pressures even greater than atmospheric can be used.

The hydrino hydride reactor comprises the following: a source of atomic hydrogen; at least one of a solid, molten, liquid, or gaseous catalyst for generating hydrinos; and a vessel for containing the atomic hydrogen and the catalyst. Methods and apparatus for producing hydrinos, including a listing of effective catalysts and sources of hydrogen atoms, are described in the Prior Mills Publications. Methodologies for identifying hydrinos are also described. The hydrinos so produced react with the electrons to form hydrino hydride ions. Methods to reduce hydrinos to hydrino hydride ions include, for example, the following: in the gas cell hydride reactor, chemical reduction by a reactant; in the gas discharge cell hydride reactor, reduction by the plasma electrons or by the cathode of the gas discharge cell; in the plasma torch hydride reactor, reduction by plasma electrons.

The power system may further comprise a source of electric field 76 which can be used to adjust the rate of hydrogen catalysis. It may further focus ions in the cell. It may further impart a drift velocity to ions in the cell. The cell may comprise a source of microwave power, which is generally known in the art, such as traveling wave tubes, klystrons, magnetrons, cyclotron resonance masers, gyrotrons, and free electron lasers. The present power cell may be an internal source of microwaves wherein the plasma generated from the hydrogen catalysis reaction may be magnetized to produce microwaves.

1.1 Plasma Electrolysis Cell Hydride Reactor

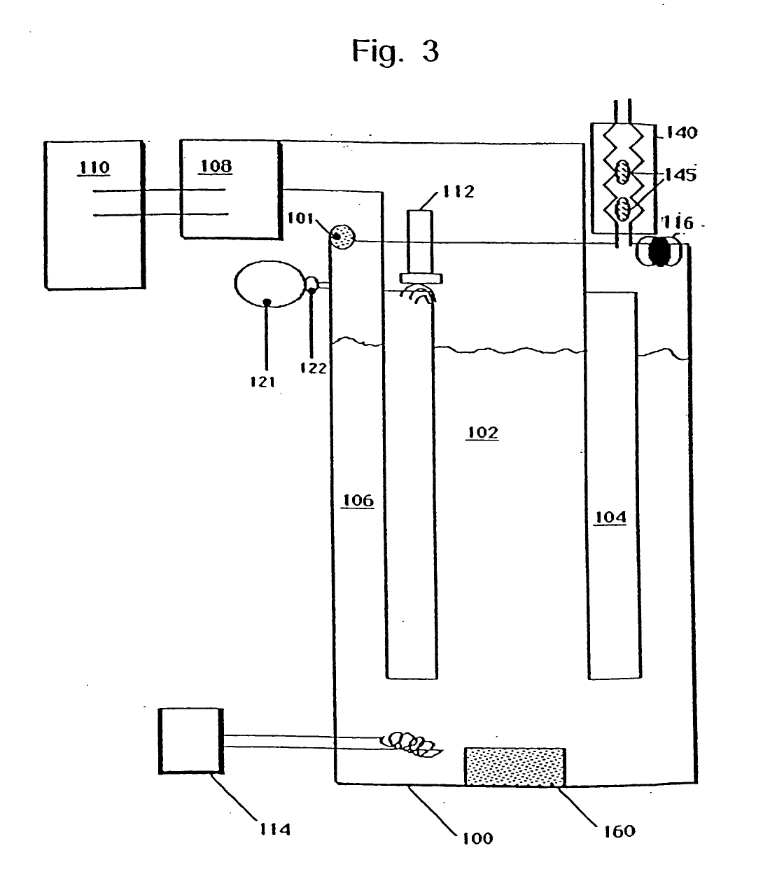

A plasma electrolytic power and hydride reactor of the present invention to make lower-energy hydrogen compounds comprises an electrolytic cell forming the reaction vessel 52 of FIG. 1, including a molten electrolytic cell. The electrolytic cell 100 is shown generally in FIG. 3. An electric current is passed through the electrolytic solution 102 having a catalyst by the application of a voltage to an anode 104 and cathode 106 by the power controller 108 powered by the power supply 110. Ultrasonic or mechanical energy may also be imparted to the cathode 106 and electrolytic solution 102 by vibrating means 112. Heat can be supplied to the electrolytic solution 102 by heater 114. The pressure of the electrolytic cell 100 can be controlled by pressure regulator means 116 where the cell can be closed. The reactor further comprises a means 101 that removes the (molecular) lower-energy hydrogen such as a selective venting valve to prevent the exothermic shrinkage reaction from coming to equilibrium.

In an embodiment, the electrolytic cell is further supplied with hydrogen from hydrogen source 121 where the over pressure can be controlled by pressure control means 122 and 116. An embodiment of the electrolytic cell energy reactor, comprises a reverse fuel cell geometry which removes the lower-energy hydrogen under vacuum. The reaction vessel may be closed except for a connection to a condensor 140 on the top of the vessel 100. The cell may be operated at a boil such that the steam evolving from the boiling electrolyte 102 can be condensed in the condensor 140, and the condensed water can be returned to the vessel 100. The lower-energy state hydrogen can be vented through the top of the condensor 140. In one embodiment, the condenser contains a hydrogen/oxygen recombiner 145 that contacts the evolving electrolytic gases. The hydrogen and oxygen are recombined, and the resulting water can be returned to the vessel 100. The heat released from the catalysis of hydrogen and the heat released due to the recombination of the electrolytically generated normal hydrogen and oxygen can be removed by a heat exchanger 60 of FIG. 1 which can be connected to the condensor 140.

Hydrino atoms form at the cathode 106 via contact of the catalyst of electrolyte 102 with the hydrogen atoms generated at the cathode 106. The electrolytic cell hydride reactor apparatus further comprises a source of electrons in contact with the hydrinos generated in the cell, to form hydrino hydride ions. The hydrinos are reduced (i.e. gain the electron) in the electrolytic cell to hydrino hydride ions. Reduction occurs by contacting the hydrinos with any of the following: 1.) the cathode 106, 2.) a reductant which comprises the cell vessel 100, or 3.) any of the reactor's components such as features designated as anode 104 or electrolyte 102, or 4.) a reductant or other element 160 extraneous to the operation of the cell (i.e. a consumable reductant added to the cell from an outside source). Any of these reductants may comprise an electron source for reducing hydrinos to hydrino hydride ions.

A compound may form in the electrolytic cell between the hydrino hydride ions and cations. The cations may comprise, for example, an oxidized species of the material of the cathode or anode, a cation of an added reductant, or a cation of the electrolyte (such as a cation comprising the catalyst).

A plasma forming electrolytic power cell and hydride reactor of the present invention for the catalysis of atomic hydrogen to form increased-binding-energy-hydrogen species and increased-binding-energy-hydrogen compounds comprises a vessel, a cathode, an anode, an electrolyte, a high voltage electrolysis power supply, and a catalyst capable of providing a net enthalpy of reaction of m/2·27.2±0.5 eV where m is an integer. Preferably m is an integer less than 400. In an embodiment, the voltage is in the range of about 10 V to 50 kV and the current density may be high such as in the range of about 1 to 100 A/cm² or higher. In an embodiment, K⁺ is reduced to potassium atom which serves as the catalyst. The cathode of the cell may be tungsten such as a tungsten rod, and the anode of cell of may be platinum. The catalysts of the cell may comprise at least one selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt He⁺, Na⁺, Rb⁺, Fe³⁺, Mo²⁺, Mo⁴⁺, and In³⁺. The catalyst of the cell of may be formed from a source of catalyst. The source of catalyst that forms the catalyst may comprise at least one selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Fe³⁺, Mo²⁺, Mo⁴⁺, In³⁺ and K⁺/K⁺ alone or comprising compounds. The source of catalyst may comprise a compound that provides K⁺ that is reduced to the catalyst potassium atom during electrolysis.

The compound formed comprises

(a) at least one neutral, positive, or negative increased binding energy hydrogen species having a binding energy

(i) greater than the binding energy of the corresponding ordinary hydrogen species, or

(ii) greater than the binding energy of any hydrogen species for which the corresponding ordinary hydrogen species is unstable or is not observed because the ordinary hydrogen species' binding energy is less than thermal energies at ambient conditions, or is negative; and

(b) at least one other element.

The increased binding energy hydrogen species may be selected from the group consisting of Hₙ, Hₙ⁻, and Hₙ⁺ where n is a positive integer, with the proviso that n is greater than 1 when H has a positive charge. The compound formed may be characterized in that the increased binding energy hydrogen species is selected from the group consisting of (a) hydride ion having a binding energy that is greater than the binding of ordinary hydride ion (about 0.8 eV) for p=2 up to 23 in which the binding energy is represented

$$Binding Energy = \frac{ℏ \sqrt{s ( s + 1 )}}{8 {μ}_{c} {{a}_{0}^{2} [ \frac{1 + \sqrt{s ( s + 1 )}}{p} ]}^{2}} - \frac{π {μ}_{0} {ⅇ}^{2} {ℏ}^{2}}{{m}_{c}^{2} {a}_{0}^{3}} ( 1 + \frac{{2}^{2}}{{[ \frac{1 + \sqrt{s ( s + 1 )}}{p} ]}^{3}} )$$

where p is an integer greater than one, s=1/2, π is pi, \overline{h} is Planck's constant bar, μₒ is the permeability of vacuum, m_{c} is the mass of the electron, μ_{c} is the reduced electron mass, aₒ is the Bohr radius, and e is the elementary charge; (b) hydrogen atom having a binding energy greater than about 13.6 eV; (c) hydrogen molecule having a first binding energy greater than about 15.5 eV; and (d) molecular hydrogen ion having a binding energy greater than about 16.4 eV. The compound may be characterized in that the increased binding energy hydrogen species is a hydride ion having a binding energy of about 3.0, 6.6, 11.2, 16.7, 22.8, 29.3, 36.1, 42.8, 49.4, 55.5, 61.0, 65.6, 69.2, 71.5, 72.4, 71.5, 68.8, 64.0, 56.8, 47.1, 34.6, 19.2, or 0.65 eV. The compound may characterized in that the increased binding energy hydrogen species is a hydride ion having the binding energy:

$$Binding Energy = \frac{ℏ \sqrt{s ( s + 1 )}}{8 {μ}_{c} {{a}_{0}^{2} [ \frac{1 + \sqrt{s ( s + 1 )}}{p} ]}^{2}} - \frac{π {μ}_{0} {ⅇ}^{2} {ℏ}^{2}}{{m}_{c}^{2} {a}_{0}^{3}} ( 1 + \frac{{2}^{2}}{{[ \frac{1 + \sqrt{s ( s + 1 )}}{p} ]}^{3}} )$$

where p is an integer greater than one, s=1/2, π is pi, \overline{h} is Planck's constant bar, μₒ is the permeability of vacuum, m_{c} is the mass of the electron, μₑ is the reduced electron mass, aₒ is the Bohr radius, and e is the elementary charge. The compound may characterized in that the increased binding energy hydrogen species is selected from the group consisting of

(a) a hydrogen atom having a binding energy of about

$$\frac{13.6 eV}{{( \frac{1}{p} )}^{2}}$$

where p is an integer,

(b) an increased binding energy hydride ion (H⁻) having a binding energy of about

$$\frac{ℏ \sqrt{s ( s + 1 )}}{8 {μ}_{c} {{a}_{0}^{2} [ \frac{1 + \sqrt{s ( s + 1 )}}{p} ]}^{2}} - \frac{π {μ}_{0} {ⅇ}^{2} {ℏ}^{2}}{{m}_{c}^{2} {a}_{0}^{3}} ( 1 + \frac{{2}^{2}}{{[ \frac{1 + \sqrt{s ( s + 1 )}}{p} ]}^{3}} )$$

where s=1/2, π or is pi, \overline{h} is Planck's constant bar, μₒ is the permeability of vacuum, mₑ is the mass of the electron, μₑ is the reduced electron mass, aₒ is the Bohr radius, and e is the elementary charge;

(c) an increased binding energy hydrogen species H₄⁺(1/p);

(d) an increased binding energy hydrogen species trihydrino molecular ion, H₃⁺(1/p), having a binding energy of about

$$\frac{22.6 }{{( \frac{1}{p} )}^{2}} eV$$

where p is an integer,

(e) an increased binding energy hydrogen molecule having a binding energy of about

$$\frac{15.5 }{{( \frac{1}{p} )}^{2}} eV ;$$

and

(f) an increased binding energy hydrogen molecular ion with a binding energy of about

$$\frac{16.4 }{{( \frac{1}{p} )}^{2}} eV .$$

1.2 Gas Cell Hydride Reactor and Power Converter

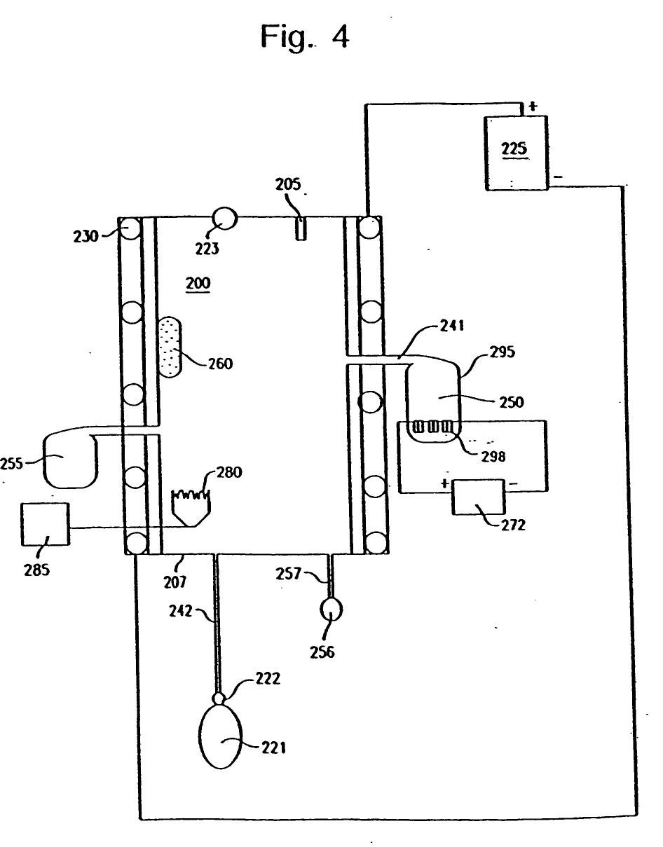

According to an embodiment of the invention, a reactor for producing hydrino hydride ions and power may take the form of a hydrogen gas cell hydride reactor. A gas cell hydride reactor of the present invention is shown in FIG. 4. Reactant hydrinos are provided by a catalytic reaction with a catalyst such as at least one of those given in TABLES 1 and 3 and/or a by a disproportionation reaction. Catalysis may occur in the gas phase.

The reactor of FIG. 4 comprises a reaction vessel 207 having a chamber 200 capable of containing a vacuum or pressures greater than atmospheric. A source of hydrogen 221 communicating with chamber 200 delivers hydrogen to the chamber through hydrogen supply passage 242. A controller 222 is positioned to control the pressure and flow of hydrogen into the vessel through hydrogen supply passage 242. A pressure sensor 223 monitors pressure in the vessel. A vacuum pump 256 is used to evacuate the chamber through a vacuum line 257. The apparatus further comprises a source of electrons in contact with the hydrinos to form hydrino hydride ions.

In an embodiment, the source of hydrogen 221 communicating with chamber 200 that delivers hydrogen to the chamber through hydrogen supply passage 242 is a hydrogen permeable hollow cathode of an electrolysis cell. Electrolysis of water produces hydrogen that permeates through the hollow cathode. The cathode may be a transition metal such as nickel, iron, or titanium, or a noble metal such as palladium, or platinum, or tantalum or palladium coated tantalum, or palladium coated niobium. The electrolyte may be basic and the anode may be nickel. The electrolyte may be aqueous K₂CO₃. The flow of hydrogen into the cell may be controlled by controlling the electrolysis current with an electrolysis power controller.

A catalyst 250 for generating hydrino atoms can be placed in a catalyst reservoir 295. The catalyst in the gas phase may comprise the catalysts given in TABLES 1 and 3 and those in the Mills Prior Publications. The reaction vessel 207 has a catalyst supply passage 241 for the passage of gaseous catalyst from the catalyst reservoir 295 to the reaction chamber 200. Alternatively, the catalyst may be placed in a chemically resistant open container, such as a boat, inside the reaction vessel.

The molecular and atomic hydrogen partial pressures in the reactor vessel 207, as well as the catalyst partial pressure, is preferably maintained in the range of about 10 millitorr to about 100 torr. Most preferably, the hydrogen partial pressure in the reaction vessel 207 is maintained at about 200 millitorr.

Molecular hydrogen may be dissociated in the vessel into atomic hydrogen by a dissociating material. The dissociating material may comprise, for example, a noble metal such as platinum or palladium, a transition metal such as nickel and titanium, an inner transition metal such as niobium and zirconium, or a refractory metal such as tungsten or molybdenum. The dissociating material may be maintained at an elevated temperature by the heat liberated by the hydrogen catalysis (hydrino generation) and hydrino reduction taking place in the reactor. The dissociating material may also be maintained at elevated temperature by temperature control means 230, which may take the form of a heating coil as shown in cross section in FIG. 4. The heating coil is powered by a power supply 225.

Molecular hydrogen may be dissociated into atomic hydrogen by application of electromagnetic radiation, such as UV light provided by a photon source 205.

Molecular hydrogen may be dissociated into atomic hydrogen by a hot filament or grid 280 powered by power supply 285.

The hydrogen dissociation occurs such that the dissociated hydrogen atoms contact a catalyst which is in a molten, liquid, gaseous, or solid form to produce hydrino atoms. The catalyst vapor pressure is maintained at the desired pressure by controlling the temperature of the catalyst reservoir 295 with a catalyst reservoir heater 298 powered by a power supply 272. When the catalyst is contained in a boat inside the reactor, the catalyst vapor pressure is maintained at the desired value by controlling the temperature of the catalyst boat, by adjusting the boat's power supply.

The rate of production of hydrinos and power by the gas cell hydride reactor can be controlled by controlling the amount of catalyst in the gas phase and/or by controlling the concentration of atomic hydrogen. The rate of production of hydrino hydride ions can be controlled by controlling the concentration of hydrinos, such as by controlling the rate of production of hydrinos. The concentration of gaseous catalyst in vessel chamber 200 may be controlled by controlling the initial amount of the volatile catalyst present in the chamber 200. The concentration of gaseous catalyst in chamber 200 may also be controlled by controlling the catalyst temperature, by adjusting the catalyst reservoir heater 298, or by adjusting a catalyst boat heater when the catalyst is contained in a boat inside the reactor. The vapor pressure of the volatile catalyst 250 in the chamber 200 is determined by the temperature of the catalyst reservoir 295, or the temperature of the catalyst boat, because each is colder than the reactor vessel 207. The reactor vessel 207 temperature is maintained at a higher operating temperature than catalyst reservoir 295 with heat liberated by the hydrogen catalysis (hydrino generation) and hydrino reduction.

The reactor vessel temperature may also be maintained by a temperature control means, such as heating coil 230 shown in cross section in FIG. 4. Heating coil 230 is powered by power supply 225. The reactor temperature further controls the reaction rates such as hydrogen dissociation and catalysis.

In an embodiment, the catalyst comprises a mixture of a first catalyst supplied from the catalyst reservoir 295 and a source of a second catalyst supplied from gas supply 221 regulated by flow controller 222. Hydrogen may also be supplied to the cell from gas supply 221 regulated by flow controller 222. The flow controller 222 may achieve a desired mixture of the source of a second catalyst and hydrogen, or the gases may be premixed in a desired ratio. In an embodiment, the first catalyst produces the second catalyst from the source of the second catalyst. In an embodiment, the energy released by the catalysis of hydrogen by the first catalyst produces a plasma in the energy cell. The energy ionizes the source of the second catalyst to produce the second catalyst. The first catalyst may be selected from the group of catalyst given in TABLE 3 such as potassium and strontium, the source of the second catalyst may be selected from the group of helium and argon and the second catalyst may be selected from the group of He⁺ and Ar⁺ wherein the catalyst ion is generated from the corresponding atom by a plasma created by catalysis of hydrogen by the first catalyst. For example, 1.) the energy cell contains strontium and argon wherein hydrogen catalysis by strontium produces a plasma containing Ar⁺ which serves as a second catalyst (Eqs. (12-14)) and 2.) the energy cell contains potassium and helium wherein hydrogen catalysis by potassium produces a plasma containing He⁺ which serves as a second catalyst (Eqs. (9-11)). In an embodiment, the pressure of the source of the second catalyst is in the range of about 1 millitorr to about one atmosphere. The hydrogen pressure is in the range of about 1 millitorr to about one atmosphere. In a preferred embodiment, the total pressure is in the range of about 0.5 torr to about 2 torr. In an embodiment, the ratio of the pressure of the source of the second catalyst to the hydrogen pressure is greater than one. In a preferred embodiment, hydrogen is about 0.1% to about 99%, and the source of the second catalyst comprises the balance of the gas present in the cell. More preferably, the hydrogen is in the range of about 1% to about 5% and the source of the second catalyst is in the range of about 95% to about 99%. Most preferably, the hydrogen is about 5% and the source of the second catalyst is about 95%. These pressure ranges are representative examples and a skilled person will be able to practice this invention using a desired pressure to provide a desired result.

The preferred operating temperature depends, in part, on the nature of the material comprising the reactor vessel 207. The temperature of a stainless steel alloy reactor vessel 207 is preferably maintained at about 200-1200° C. The temperature of a molybdenum reactor vessel 207 is preferably maintained at about 200-1800° C. The temperature of a tungsten reactor vessel 207 is preferably maintained at about 200-3000° C. The temperature of a quartz or ceramic reactor vessel 207 is preferably maintained at about 200-1800° C.

The concentration of atomic hydrogen in vessel chamber 200 can be controlled by the amount of atomic hydrogen generated by the hydrogen dissociation material. The rate of molecular hydrogen dissociation can be controlled by controlling the surface area, the temperature, and/or the selection of the dissociation material. The concentration of atomic hydrogen may also be controlled by the amount of atomic hydrogen provided by the atomic hydrogen source 221. The concentration of atomic hydrogen can be further controlled by the amount of molecular hydrogen supplied from the hydrogen source 221 controlled by a flow controller 222 and a pressure sensor 223. The reaction rate may be monitored by windowless ultraviolet (UV) emission spectroscopy to detect the intensity of the UV emission due to the catalysis and the hydrino hydride ion and compound emissions.

The gas cell hydride reactor further comprises an electron source 260 in contact with the generated hydrinos to form hydrino hydride ions. In the gas cell hydride reactor of FIG. 4, hydrinos are reduced to hydrino hydride ions by contacting a reductant comprising the reactor vessel 207. Alternatively, hydrinos are reduced to hydrino hydride ions by contact with any of the reactor's components, such as, photon source 205, catalyst 250, catalyst reservoir 295, catalyst reservoir heater 298, hot filament grid 280, pressure sensor 223, hydrogen source 221, flow controller 222, vacuum pump 256, vacuum line 257, catalyst supply passage 241, or hydrogen supply passage 242. Hydrinos may also be reduced by contact with a reductant extraneous to the operation of the cell (i.e. a consumable reductant added to the cell from an outside source). Electron source 260 is such a reductant. The cell may further comprise a getter or cryotrap 255 to selectively collect the lower-energy-hydrogen species and/or the increased-binding-energy hydrogen compounds.

Compounds comprising a hydrino hydride anion and a cation may be formed in the gas cell. The cation which forms the hydrino hydride compound may comprise a cation of the material of the cell, a cation comprising the molecular hydrogen dissociation material which produces atomic hydrogen, a cation comprising an added reductant, or a cation present in the cell (such as the cation of the catalyst).

In another embodiment of the gas cell hydride reactor, the vessel of the reactor is the combustion chamber of an internal combustion engine, rocket engine, or gas turbine. A gaseous catalyst forms hydrinos from hydrogen atoms produced by pyrolysis of a hydrocarbon during hydrocarbon combustion. A hydrocarbon- or hydrogen-containing fuel contains the catalyst. The catalyst is vaporized (becomes gaseous) during the combustion. In another embodiment, the catalyst at least one of those given in TABLES 1 and 3, hydrinos, and a thermally stable salt of rubidium or potassium such as RbF, RbCl, RbBr, RbI, Rb₂S₂, RbOH, Rb₂SO₄, Rb₂CO₃, Rb₃PO₄, and KF, KCl, KBr, KI, K₂S₂, KOH, K₂SO₄, K₂CO₃, K₃PO₄, K₂GeF₄. Additional counter or couple include organic anions, such as wetting or emulsifying agents.

In another embodiment of the gas cell hydride reactor, the source of atomic hydrogen is an explosive which detonates to provide atomic hydrogen and vaporizes a source of catalyst such that catalyst reacts with atomic hydrogen in the gas phase to liberate energy in addition to that of the explosive reaction. One such catalyst is potassium metal. In one embodiment, the gas cell ruptures with the explosive release of energy with a contribution from the catalysis of atomic hydrogen. One example of such a gas cell is a bomb containing a source of atomic hydrogen and a source of catalyst such as helium gas.

In another embodiment of the invention utilizing a combustion engine to generate hydrogen atoms, the hydrocarbon- or hydrogen-containing fuel further comprises water and a solvated source of catalyst, such as emulsified catalysts. During pyrolysis, water serves as a further source of hydrogen atoms which undergo catalysis. The water can be dissociated into hydrogen atoms thermally or catalytically on a surface, such as the cylinder or piston head. The surface may comprise material for dissociating water to hydrogen and oxygen. The water dissociating material may comprise an element, compound, alloy, or mixture of transition elements or inner transition elements, iron, platinum, palladium, zirconium, vanadium, nickel, titanium, Sc, Cr, Mn, Co, Cu, Zn, Y, Nb, Mo, Tc, Ru, Rh, Ag, Cd, La, Hf, Ta, W, Re, Os, Ir, Au, Hg, Ce, Pr, Nd, Pm, Sm, Eu, Gd, Tb, Dy, Ho, Er, Tm, Vb, Lu, Th, Pa, U, activated charcoal (carbon), or Cs intercalated carbon (graphite).

In another embodiment of the invention utilizing an engine to generate hydrogen atoms through pyrolysis, vaporized catalyst is drawn from the catalyst reservoir 295 through the catalyst supply passage 241 into vessel chamber 200. The chamber corresponds to the engine cylinder. This occurs during each engine cycle. The amount of catalyst 250 used per engine cycle may be determined by the vapor pressure of the catalyst and the gaseous displacement volume of the catalyst reservoir 295. The vapor pressure of the catalyst may be controlled by controlling the temperature of the catalyst reservoir 295 with the reservoir heater 298. A source of electrons, such as a hydrino reducing reagent in contact with hydrinos, results in the formation of hydrino hydride ions.

1.3 Gas Discharge Cell Hydride Reactor

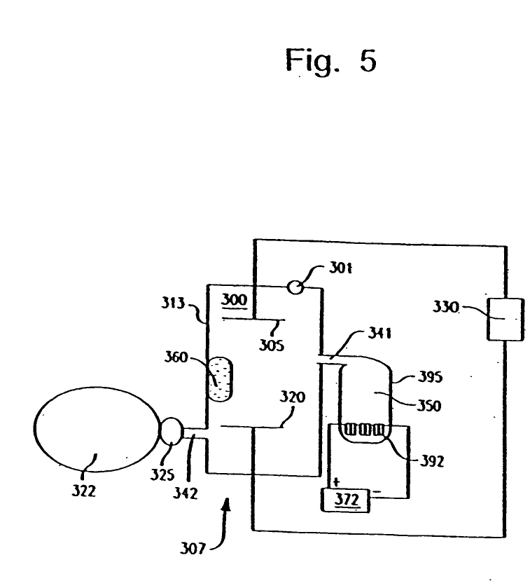

A gas discharge cell hydride reactor of the present invention is shown in FIG. 5. The gas discharge cell hydride reactor of FIG. 5, includes a gas discharge cell 307 comprising a hydrogen isotope gas-filled glow discharge vacuum vessel 313 having a chamber 300. A hydrogen source 322 supplies hydrogen to the chamber 300 through control valve 325 via a hydrogen supply passage 342. A catalyst is contained in catalyst reservoir 395. A voltage and current source 330 causes current to pass between a cathode 305 and an anode 320. The current may be reversible. In another embodiment, the plasma is generated with a microwave source such as a microwave generator.

In one embodiment of the gas discharge cell hydride reactor, the wall of vessel 313 is conducting and serves as the anode. In another embodiment, the cathode 305 is hollow such as a hollow, nickel, aluminum, copper, or stainless steel hollow cathode. In an embodiment, the cathode material may be a source of catalyst such as iron or samarium.

The cathode 305 may be coated with the catalyst for generating hydrinos and energy. The catalysis to form hydrinos and energy occurs on the cathode surface. To form hydrogen atoms for generation of hydrinos and energy, molecular hydrogen is dissociated on the cathode. To this end, the cathode is formed of a hydrogen dissociative material. Alternatively, the molecular hydrogen is dissociated by the discharge.

According to another embodiment of the invention, the catalyst for generating hydrinos and energy is in gaseous form. For example, the discharge may be utilized to vaporize the catalyst to provide a gaseous catalyst. Alternatively, the gaseous catalyst is produced by the discharge current. For example, the gaseous catalyst may be provided by a discharge in rubidium metal to form Rb⁺, or titanium metal to form Ti²⁺, or potassium or strontium metal to volatilize the metal. The gaseous hydrogen atoms for reaction with the gaseous catalyst are provided by a discharge of molecular hydrogen gas such that the catalysis occurs in the gas phase.

Another embodiment of the gas discharge cell hydride reactor where catalysis occurs in the gas phase utilizes a controllable gaseous catalyst. The gaseous hydrogen atoms for conversion to hydrinos are provided by a discharge of molecular hydrogen gas. The gas discharge cell 307 has a catalyst supply passage 341 for the passage of the gaseous catalyst 350 from catalyst reservoir 395 to the reaction chamber 300. The catalyst reservoir 395 is heated by a catalyst reservoir heater 392 having a power supply 372 to provide the gaseous catalyst to the reaction chamber 300. The catalyst vapor pressure is controlled by controlling the temperature of the catalyst reservoir 395, by adjusting the heater 392 by means of its power supply 372. The reactor further comprises a selective venting valve 301.

In another embodiment of the gas discharge cell hydride reactor where catalysis occurs in the gas phase utilizes a controllable gaseous catalyst. Gaseous hydrogen atoms provided by a discharge of molecular hydrogen gas. A chemically resistant (does not react or degrade during the operation of the reactor) open container, such as a tungsten or ceramic boat, positioned inside the gas discharge cell contains the catalyst. The catalyst in the catalyst boat is heated with a boat heater using by means of an associated power supply to provide the gaseous catalyst to the reaction chamber. Alternatively, the glow gas discharge cell is operated at an elevated temperature such that the catalyst in the boat is sublimed, boiled, or volatilized into the gas phase. The catalyst vapor pressure is controlled by controlling the temperature of the boat or the discharge cell by adjusting the heater with its power supply.

The gas discharge cell may be operated at room temperature by continuously supplying catalyst. Alternatively, to prevent the catalyst from condensing in the cell, the temperature is maintained above the temperature of the catalyst source, catalyst reservoir 395 or catalyst boat. For example, the temperature of a stainless steel alloy cell is about 0-1200° C.; the temperature of a molybdenum cell is about 0-1800° C.; the temperature of a tungsten cell is about 0-3000° C.; and the temperature of a glass, quartz, or ceramic cell is about 0-1800° C. The discharge voltage may be in the range of about 1000 to about 50,000 volts. The current may be in the range of about 1 μA to about 1 A, preferably about 1 mA.

The discharge current may be intermittent or pulsed. Pulsing may be used to reduce the input power, and it may also provide a time period wherein the field is set to a desired strength by an offset voltage which may be below the discharge voltage. One application of controlling the field during the nondischarge period is to optimize the energy match between the catalyst and the atomic hydrogen. In an embodiment, the offset voltage is between, about 0.5 to about 500 V. In another embodiment, the offset voltage is set to provide a field of about 0.1 V/cm to about 50 V/cm. Preferably, the offset voltage is set to provide a field between about 1 V/cm to about 10 V/cm. The peak voltage may be in the range of about 1 V to 10 MV. More preferably, the peak voltage is in the range of about 10 V to 100 kV. Most preferably, the voltage is in the range of about 100 V to 500 V. The pulse frequency and duty cycle may also be adjusted. An application of controlling the pulse frequency and duty cycle is to optimize the power balance. In an embodiment, this is achieved by optimizing the reaction rate versus the input power. The amount of catalyst and atomic hydrogen generated by the discharge decay during the nondischarge period. The reaction rate may be controlled by controlling the amount of catalyst generated by the discharge such as Ar⁺ and the amount of atomic hydrogen wherein the concentration is dependent on the pulse frequency, duty cycle, and the rate of decay. In an embodiment, the pulse frequency is of about 0.1 Hz to about 100 MHz. In another embodiment, the pulse frequency is faster than the time for substantial atomic hydrogen recombination to molecular hydrogen. Based on anomalous plasma afterglow duration studies [R. Mills, T. Onuma, and Y. Lu, “Formation of a Hydrogen Plasma from an Incandescently Heated Hydrogen-Catalyst Gas Mixture with an Anomalous Afterglow Duration”, Int. J. Hydrogen Energy, in press; R. Mills, “Temporal Behavior of Light-Emission in the Visible Spectral Range from a Ti—K2CO3—H-Cell”, Int. J. Hydrogen Energy, Vol. 26, No. 4, (2001), pp. 327-332], preferably the frequency is within the range of about 1 to about 200 Hz. In an embodiment, the duty cycle is about 0.1% to about 95%. Preferably, the duty cycle is about 1% to about 50%.

In another embodiment, the power may be applied as an alternating current (AC). The frequency may be in the range of about 0.001 Hz to 1 GHz. More preferably the frequency is in the range of about 60 Hz to 100 MHz. Most preferably, the frequency is in the range of about 10 to 100 MHz. The system may comprises two electrodes wherein one or more electrodes are in direct contact with the plasma; otherwise, the electrodes may be separated from the plasma by a dielectric barrier. The peak voltage may be in the range of about 1 V to 10 MV. More preferably, the peak voltage is in the range of about 10 V to 100 kV. Most preferably, the voltage is in the range of about 100 V to 500 V.

The gas discharge cell apparatus includes an electron source in contact with the hydrinos, in order to generate hydrino hydride ions. The hydrinos are reduced to hydrino hydride ions by contact with cathode 305, with plasma electrons of the discharge, or with the vessel 313. Also, hydrinos may be reduced by contact with any of the reactor components, such as anode 320, catalyst 350, heater 392, catalyst reservoir 395, selective venting valve 301, control valve 325, hydrogen source 322, hydrogen supply passage 342 or catalyst supply passage 341. According to yet another variation, hydrinos are reduced by a reductant 360 extraneous to the operation of the cell (e.g. a consumable reductant added to the cell from an outside source).

Compounds comprising a hydrino hydride anion and a cation may be formed in the gas discharge cell. The cation which forms the hydrino hydride compound may comprise an oxidized species of the material comprising the cathode or the anode, a cation of an added reductant, or a cation present in the cell (such as a cation of the catalyst).

In one embodiment of the gas discharge cell apparatus, potassium or rubidium hydrino hydride and energy is produced in the gas discharge cell 307. The catalyst reservoir 395 contains potassium metal catalyst or rubidium metal which is ionized to Rb⁺ catalyst. The catalyst vapor pressure in the gas discharge cell is controlled by heater 392. The catalyst reservoir 395 is heated with the heater 392 to maintain the catalyst vapor pressure proximal to the cathode 305 preferably in the pressure range 10 millitorr to 100 torr, more preferably at about 200 mtorr. In another embodiment, the cathode 305 and the anode 320 of the gas discharge cell 307 are coated with potassium or rubidium. The catalyst is vaporized during the operation of the cell. The hydrogen supply from source 322 is adjusted with control 325 to supply hydrogen and maintain the hydrogen pressure in the 10 millitorr to 100 torr range.

In an embodiment, the electrode to provide the electric field is a compound electrode comprising multiple electrodes in series or parallel that may occupy a substantial portion of the volume of the reactor. In one embodiment, the electrode comprises multiple hollow cathodes in parallel so that the desired electric field is produced in a large volume to generate a substantial power level. One design of the multiple hollow cathodes comprises an anode and multiple concentric hollow cathodes each electrically isolated from the common anode. Another compound electrode comprises multiple parallel plate electrodes connected in series.

A preferable hollow cathode is comprised of refractory materials such as molybdenum or tungsten. A preferably hollow cathode comprises a compound hollow cathode. A preferable catalyst of a compound hollow cathode discharge cell is neon as described in R. L. Mills, P. Ray, J. Dong, M. Nansteel, B. Dhandapani, J. He, “Spectral Emission of Fractional-Principal-Quantum-Energy-Level Molecular Hydrogen”, INT. J. HYDROGEN ENERGY, submitted which is herein incorporated by reference in its entirety.

1.4 Radio Frequency (RF) Barrier Electrode Discharge Cell

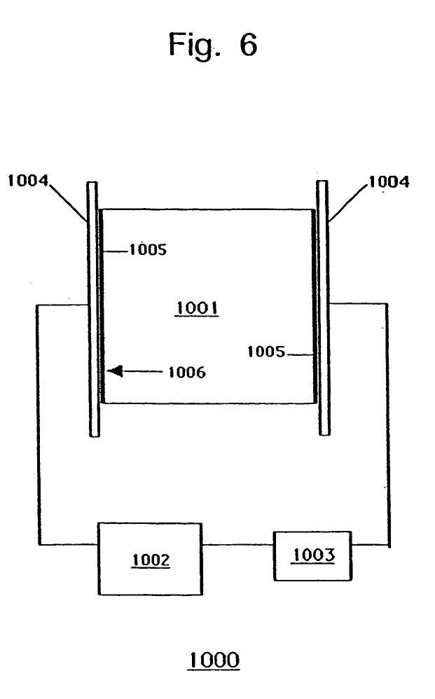

In an embodiment of the discharge cell reactor, at least one of the discharge electrodes is shielded by a dielectric barrier such as glass, quartz, Alumina, or ceramic in order to provide an electric field with minimum power dissipation. A radio frequency (RF) barrier electrode discharge cell system 1000 of the present invention is shown in FIG. 6. The RF power may be capacitively coupled. In an embodiment, the electrodes 1004 may be external to the cell 1001. A dielectric layer 1005 separates the electrodes from the cell wall 1006. The high driving voltage may be AC and may be high frequency. The driving circuit comprises a high voltage power source 1002 which is capable of providing RF and an impedance matching circuit 1003. The frequency is preferably in the range of about 100 Hz to about 10 GHz, more preferably, about 1 kHz to about 1 MHz, most preferably about 5-10 kHz. The voltage is preferably in the range of about 100 V to about 1 MV, more preferably about 1 kV to about 100 kV, and most preferably about 5 to about 10 kV.

1.5 Plasma Torch Cell Hydride Reactor

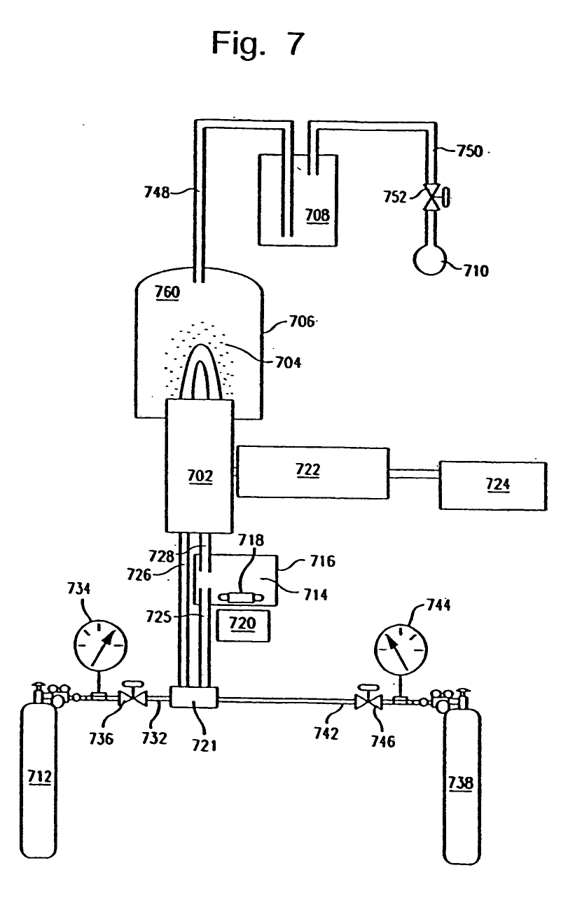

A plasma torch cell hydride reactor of the present invention is shown in FIG. 7. A plasma torch 702 provides a hydrogen isotope plasma 704 enclosed by a manifold 706 and contained in plasma chamber 760. Hydrogen from hydrogen supply 738 and plasma gas from plasma gas supply 712, along with a catalyst 714 for forming hydrinos and energy, is supplied to torch 702. The plasma may comprise argon, for example. The catalyst may comprise at least one of those given in TABLES 1 and 3 or a hydrino atom to provide a disproportionation reaction. The catalyst is contained in a catalyst reservoir 716. The reservoir is equipped with a mechanical agitator, such as a magnetic stirring bar 718 driven by magnetic stirring bar motor 720. The catalyst is supplied to plasma torch 702 through passage 728. The catalyst may be generated by a microwave discharge. Preferred catalysts are He⁺ or Ar⁺ from a source such as helium gas or argon gas.

Hydrogen is supplied to the torch 702 by a hydrogen passage 726. Alternatively, both hydrogen and catalyst may be supplied through passage 728. The plasma gas is supplied to the torch by a plasma gas passage 726. Alternatively, both plasma gas and catalyst may be supplied through passage 728.

Hydrogen flows from hydrogen supply 738 to a catalyst reservoir 716 via passage 742. The flow of hydrogen is controlled by hydrogen flow controller 744 and valve 746. Plasma gas flows from the plasma gas supply 712 via passage 732. The flow of plasma gas is controlled by plasma gas flow controller 734 and valve 736. A mixture of plasma gas and hydrogen is supplied to the torch via passage 726 and to the catalyst reservoir 716 via passage 725. The mixture is controlled by hydrogen-plasma-gas mixer and mixture flow regulator 721. The hydrogen and plasma gas mixture serves as a carrier gas for catalyst particles which are dispersed into the gas stream as fine particles by mechanical agitation. The aerosolized catalyst and hydrogen gas of the mixture flow into the plasma torch 702 and become gaseous hydrogen atoms and vaporized catalyst ions (such as Rb⁺ ions from a salt of rubidium) in the plasma 704. The plasma is powered by a microwave generator 724 wherein the microwaves are tuned by a tunable microwave cavity 722. Catalysis may occur in the gas phase.

The amount of gaseous catalyst in the plasma torch can be controlled by controlling the rate at which the catalyst is aerosolized with a mechanical agitator. The amount of gaseous catalyst can also be controlled by controlling the carrier gas flow rate where the carrier gas includes a hydrogen and plasma gas mixture (e.g., hydrogen and argon). The amount of gaseous hydrogen atoms to the plasma torch can be controlled by controlling the hydrogen flow rate and the ratio of hydrogen to plasma gas in the mixture. The hydrogen flow rate and the plasma gas flow rate to the hydrogen-plasma-gas mixer and mixture flow regulator 721 can be controlled by flow rate controllers 734 and 744, and by valves 736 and 746. Mixer regulator 721 controls the hydrogen-plasma mixture to the torch and the catalyst reservoir. The catalysis rate can also be controlled by controlling the temperature of the plasma with microwave generator 724.

Hydrino atoms and hydrino hydride ions are produced in the plasma 704. Hydrino hydride compounds are cryopumped onto the manifold 706, or they flow into hydrino hydride compound trap 708 through passage 748. Trap 708 communicates with vacuum pump 710 through vacuum line 750 and valve 752. A flow to the trap 708 is effected by a pressure gradient controlled by the vacuum pump 710, vacuum line 750, and vacuum valve 752.

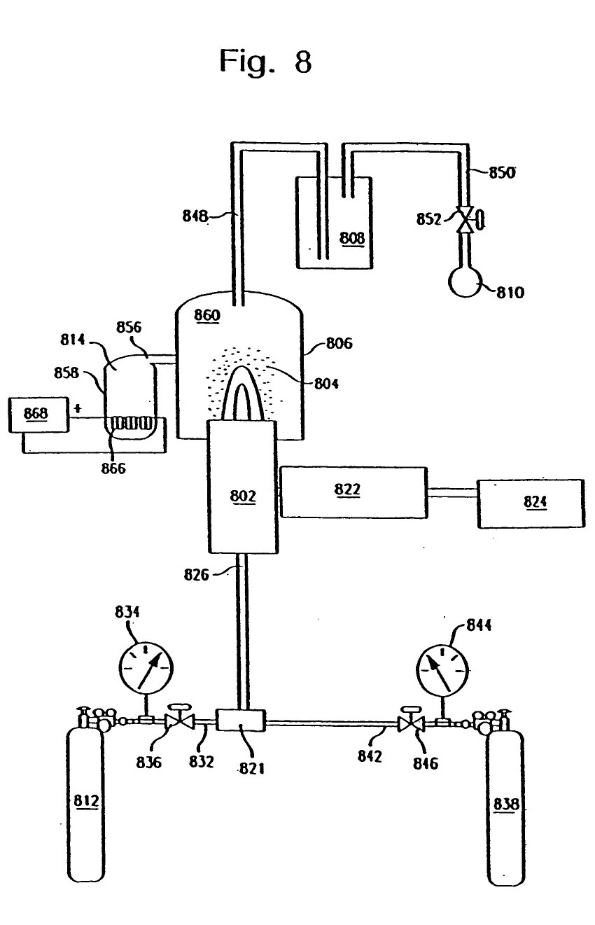

In another embodiment of the plasma torch cell hydride reactor shown in FIG. 8, at least one of plasma torch 802 or manifold 806 has a catalyst supply passage 856 for passage of the gaseous catalyst from a catalyst reservoir 858 to the plasma 804. The catalyst 814 in the catalyst reservoir 858 is heated by a catalyst reservoir heater 866 having a power supply 868 to provide the gaseous catalyst to the plasma 804. The catalyst vapor pressure can be controlled by controlling the temperature of the catalyst reservoir 858 by adjusting the heater 866 with its power supply 868. The remaining elements of FIG. 8 have the same structure and function of the corresponding elements of FIG. 7. In other words, element 812 of FIG. 8 is a plasma gas supply corresponding to the plasma gas supply 712 of FIG. 7, element 838 of FIG. 8 is a hydrogen supply corresponding to hydrogen supply 738 of FIG. 7, and so forth.

In another embodiment of the plasma torch cell hydride reactor, a chemically resistant open container such as a ceramic boat located inside the manifold contains the catalyst. The plasma torch manifold forms a cell which can be operated at an elevated temperature such that the catalyst in the boat is sublimed, boiled, or volatilized into the gas phase. Alternatively, the catalyst in the catalyst boat can be heated with a boat heater having a power supply to provide the gaseous catalyst to the plasma. The catalyst vapor pressure can be controlled by controlling the temperature of the cell with a cell heater, or by controlling the temperature of the boat by adjusting the boat heater with an associated power supply.

The plasma temperature in the plasma torch cell hydride reactor is advantageously maintained in the range of about 5,000-30,000° C. The cell may be operated at room temperature by continuously supplying catalyst. Alternatively, to prevent the catalyst from condensing in the cell, the cell temperature can be maintained above that of the catalyst source, catalyst reservoir 858 or catalyst boat. The operating temperature depends, in part, on the nature of the material comprising the cell. The temperature for a stainless steel alloy cell is preferably about 0-1200° C. The temperature for a molybdenum cell is preferably about 0-1800° C. The temperature for a tungsten cell is preferably about 0-3000° C. The temperature for a glass, quartz, or ceramic cell is preferably about 0-1800° C. Where the manifold 706 is open to the atmosphere, the cell pressure is atmospheric.

An exemplary plasma gas for the plasma torch hydride reactor is argon which may also serve as a source of catalyst. Exemplary aerosol flow rates are about 0.8 standard liters per minute (slm) hydrogen and about 0.15 slm argon. An exemplary argon plasma flow rate is about 5 slm. An exemplary forward input power is about 1000 W, and an exemplary reflected power is about 10-20 W.

In other embodiments of the plasma torch hydride reactor, the mechanical catalyst agitator (magnetic stirring bar 718 and magnetic stirring bar motor 720) is replaced with an aspirator, atomizer, or nebulizer to form an aerosol of the catalyst 714 dissolved or suspended in a liquid medium such as water. The medium is contained in the catalyst reservoir 716. Or, the aspirator, atomizer, ultrasonic dispersion means, or nebulizer injects the catalyst directly into the plasma 704. The nebulized or atomized catalyst can be carried into the plasma 704 by a carrier gas, such as hydrogen.

In an embodiment, the plasma torch cell hydride reactor further comprises a structure that interacts with the microwaves to cause localized regions of high electric and/or magnetic field strength. A high magnetic field may cause electrical breakdown of the gases in the plasma chamber 760. The electric field may form a nonthermal plasma that increases the rate of catalysis by methods such as the formation of the catalyst from a source of catalyst. The source of catalyst may be helium, helium, neon, neon-hydrogen mixture, or argon to form He⁺, He₂*, Ne₂*, Ne⁺/H⁺ or Ar⁺, respectively. The ionization and formation of a nonthermal plasma may occur at low plasma temperatures for a plasma which may be a thermal plasma. The structure to cause high local fields may be conductive, may be a source of a conductive material, may have a high dielectric constant, and/or may have terminations which are preferably sharp, pointed or small compared to the mean free path of the plasma electrons. The dimensions may be in the range of about atomic thickness to about 5 mm. The structure may be at least one of the group of metal screen, metal fiber mat, metal wool, metal sponge, and metal foam. A structure to form point-like sources of increased field strength to cause ionization of gasses which may form a nonthermal plasma and increase the catalysis rate may comprise small particles sintered to a supporting structure. The structure may comprise at least one of the group of metal screen, metal fiber mat, metal wool, and metal foam. A further structure may comprise a material that is etched to form a roughened surface. The material may be at least one of the group of metal screen, metal fiber mat, metal wool, metal sponge, and metal foam. The etching process may be acid etching.

In another embodiment, the high local field which may cause local ionization may comprise conducting particles, a source of conductive particles, and/or particles with a high dielectric constant which are seeded in the plasma 704. The particles may be nano or micro particles. The seeded particles may comprise at least one element or oxide of the group of aluminum, transition elements and inner transition elements, iron, platinum, palladium, zirconium, vanadium, nickel, titanium, Sc, Cr, Mn, Co, Cu, Zn, Y, Nb, Mo, Tc, Ru, Rh, Ag, Cd, La, Hf, Ta, W, Re, Os, Ir, Au, Hg, Ce, Pr, Nd, Pm, Sm, Eu, Gd, Tb, Dy, Ho, Er, Tm, Vb, Lu, Th, Pa, U, activated charcoal (carbon), and intercalated Cs carbon (graphite). The oxide may be at least one of the group of NiO, WₓO_{y} where x and y are integers such as WO₂ and WO₃, TiₓO_{y} where x and y are integers such as TiO₂, AlₓO_{y} where x and y are integers such as Al₂O₃, The source of conductive particles may be reduced by hydrogen and or may decompose in the plasma 704 to give at least a conductive surface. The diameter of the particles may be in the range of about 1 nm to about 10 mm; more preferably in the range of about 0.01 micron to about 1 mm; and most preferably in the range of about 1 micron to about 1 mm. The particle flow rate per liter of reactor volume is preferably in the range of about 1 ng/minute to about 1 kg/minute; more preferably about 1 μg/minute to about 1 g/minute; and most preferably about 50 μg/minute to about 50 mg/minute. In the case that the particles have a high dielectric constant, the dielectric constant may be in the range of about 2 to 1000 times that of vacuum.

The particles may be contained in a reservoir 716 which may also contain the catalyst or the reservoir may be a separate particle reservoir. The reservoir may be equipped with a mechanical agitator, such as a magnetic stirring bar 718 driven by magnetic stirring bar motor 720. The particles may be supplied to plasma torch 702 through passage 728. Hydrogen may flow from hydrogen supply 738 to a reservoir 716 via passage 742. The flow of hydrogen is controlled by hydrogen flow controller 744 and valve 746. Plasma gas flows from the plasma gas supply 712 via passage 732. The flow of plasma gas is controlled by plasma gas flow controller 734 and valve 736. A mixture of plasma gas and hydrogen is supplied to the torch via passage 726 and to the reservoir 716 via passage 725. The mixture is controlled by hydrogen-plasma-gas mixer and mixture flow regulator 721. The hydrogen and plasma gas mixture serves as a carrier gas for particles which are dispersed into the gas stream as fine particles by mechanical agitation. The aerosolized particles flow into the plasma torch 702 and seed the plasma to cause high local fields around the particles in the plasma 704.

The amount of particles in the plasma torch can be controlled by controlling the rate at which they are aerosolized with a mechanical agitator. The amount of particles can also be controlled by controlling the carrier gas flow rate where the carrier gas includes a hydrogen and plasma gas mixture (e.g., hydrogen and argon). The particles may be trapped in the trap 708 and may be recirculated.

In other embodiments of the plasma torch hydride reactor, the mechanical catalyst agitator (magnetic stirring bar 718 and magnetic stirring bar motor 720) is replaced with an aspirator, atomizer, ultrasonic dispersion means, or nebulizer to form an aerosol of the particles dissolved or suspended in a liquid medium such as water. The medium is contained in the reservoir 716. Or, the aspirator, atomizer, or nebulizer injects the particles directly into the plasma 704. The nebulized or atomized particles may be carried into the plasma 704 by a carrier gas, such as hydrogen.

In another embodiment, micro droplets are spayed into the plasma 704 using an electrostatic atomizer such as that described by Kelly [Arnold Kelly, “Pulsing Electrostatic Atomizer”, U.S. Pat. No. 6,227,465 B1, May 8, 2001] and in the references therein which are all incorporated herein by reference in their entirety. The liquid that is atomized may be recirculated. The liquid may be conductive. The liquid may be a metal such as an alkali or alkaline earth metal.

A nonthermal plasma may also be formed from a thermal plasma by supplying a metal which may be vaporized and refluxed in the plasma chamber 760. The volatile metal may also be a catalyst such as potassium metal, cesium metal, and/or strontium metal or may be a source of catalyst such as rubidium metal. The metal may be contained in the catalyst reservoir 658 and heated by heater 666 to become vaporized as described previously for the case of a catalyst 614. The volatilized metal may form micro droplets by condensation in the gas phase corresponding to a metal vapor fog. The droplets may form by vaporizing the metal such that the cell thermal temperature is lower that the boiling point of the metal, the metal may be vaporized by the plasma or by heating the catalyst boat or reservoir 858.

In addition to flow suspension of the particles, they may be suspended by rotation the cell to mechanical disperse them. In another embodiment, the seeded particles may be ferromagnetic. The plasma torch cell may further comprise a means to disperse the particles into the plasma 704 by application of a time varying source of magnetic field.

The plasma torch hydride reactor further includes an electron source in contact with the hydrinos, for generating hydrino hydride ions. In the plasma torch cell, the hydrinos can be reduced to hydrino hydride ions by contacting 1.) the manifold 706, 2.) plasma electrons, or 4.) any of the reactor components such as plasma torch 702, catalyst supply passage 856, or catalyst reservoir 858, or 5) a reductant extraneous to the operation of the cell (e.g. a consumable reductant added to the cell from an outside source).

Compounds comprising a hydrino hydride anion and a cation may be formed in the gas cell. The cation which forms the hydrino hydride compound may comprise a cation of an oxidized species of the material forming the torch or the manifold, a cation of an added reductant, or a cation present in the plasma (such as a cation of the catalyst).

2. Microwave Gas Cell Hydride and Power Reactor

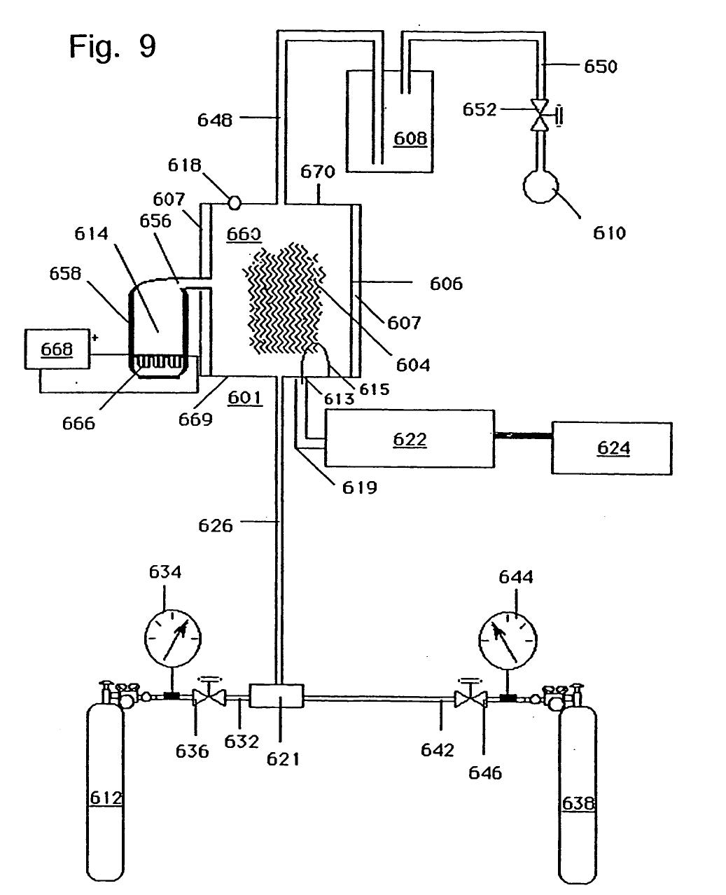

According to an embodiment of the invention, a reactor for producing power and at least one of hydrinos, hydrino hydride ions, dihydrino molecular ions and dihydrino molecules may take the form of a microwave hydrogen gas cell hydride reactor. A microwave gas cell hydride reactor of the present invention is shown in FIG. 9. Hydrinos are provided by a reaction with a catalyst capable of providing a net enthalpy of reaction of m/2·27.2±0.5 eV where m is an integer, preferably an integer less than 400 such as those given in TABLES 1 and 3 and/or by a disproportionation reaction wherein lower-energy hydrogen, hydrinos, serve to cause transitions of hydrogen atoms and hydrinos to lower-energy levels with the release of power. Catalysis may occur in the gas phase. The catalyst may be generated by a microwave discharge. Preferred catalysts are He⁺ or Ar⁺ from a source such as helium gas or argon gas. The catalysis reaction may provide power to form and maintain a plasma that comprises energetic ions. Microwaves that may or may not be phase bunched may be generated by ionized electrons in a magnetic field; thus, the magnetized plasma of the cell comprises an internal microwave generator. The generated microwaves may then be the source of microwaves to at least partially maintain the microwave discharge plasma.

The reactor system of FIG. 9 comprises a reaction vessel 601 having a chamber 660 capable of containing a vacuum or pressures greater than atmospheric. A source of hydrogen 638 delivers hydrogen to supply tube 642, and hydrogen flows to the chamber through hydrogen supply passage 626. The flow of hydrogen can be controlled by hydrogen flow controller 644 and valve 646. In an embodiment, a source of hydrogen communicating with chamber 660 that delivers hydrogen to the chamber through hydrogen supply passage 626 is a hydrogen permeable hollow cathode of an electrolysis cell of the reactor system. Electrolysis of water produces hydrogen that permeates through the hollow cathode. The cathode may be a transition metal such as nickel, iron, or titanium, or a noble metal such as palladium, or platinum, or tantalum or palladium coated tantalum, or palladium coated niobium. The electrolyte may be basic and the anode may be nickel, platinum, or a dimensionally stable anode. The electrolyte may be aqueous K₂CO₃. The flow of hydrogen into the cell may be controlled by controlling the electrolysis current with an electrolysis power controller.

Plasma gas flows from the plasma gas supply 612 via passage 632. The flow of plasma gas can be controlled by plasma gas flow controller 634 and valve 636. A mixture of plasma gas and hydrogen can be supplied to the cell via passage 626. The mixture is controlled by hydrogen-plasma-gas mixer and mixture flow regulator 621. The plasma gas such as helium may be a source of catalyst such as He⁺ or He₂*, argon may be a source of catalyst such as Ar⁺, neon may serve as a source of catalyst such as Ne₂*, and neon-hydrogen mixture may serve as a source of catalyst such as Ne⁺/H⁺. The source of catalyst and hydrogen of the mixture flow into the plasma and become catalyst and atomic hydrogen in the chamber 660.

The plasma may be powered by a microwave generator 624 wherein the microwaves are tuned by a tunable microwave cavity 622, carried by waveguide 619, and can be delivered to the chamber 660 though an RF transparent window 613 or antenna 615. Sources of microwaves known in the art are traveling wave tubes, klystrons, magnetrons, cyclotron resonance masers, gyrotrons, and free electron lasers. The waveguide or antenna may be inside or outside of the cell. In the latter case, the microwaves may penetrate the cell from the source through a window of the cell 613. The microwave window may comprise Alumina or quartz.

In another embodiment, the cell 601 is a microwave resonator cavity. In an embodiment, the source of microwave supplies sufficient microwave power density to the cell to ionize a source of catalyst such as at least one of helium, neon-hydrogen mixture, and argon gases to form a catalyst such as He⁺, Ne⁺/H⁺, and Ar⁺, respectively. In such an embodiment, the microwave power source or applicator such as an antenna, waveguide, or cavity forms a nonthermal plasma wherein the species corresponding to the source of catalyst such as helium or argon atoms and ions have a higher temperature than that at thermal equilibrium. Thus, higher energy states such as ionized states of the source of catalyst are predominant over that of hydrogen compared to a corresponding thermal plasma wherein excited states of hydrogen are predominant. In an embodiment, the source of catalyst is in excess compared to the source of hydrogen atoms such that the formation of a nonthermal plasma is favored. The power supplied by the source of microwave power may be delivered to the cell such that it is dissipated in the formation of energetic electrons within about the electron mean free path. In an embodiment, the total pressure is about 0.5 to about 5 Torr and the mean electron free path is about 0.1 cm to 1 cm. In an embodiment, the dimensions of the cell are greater than the electron mean free path. In an embodiment, the cavity is at least one of the group of Evenson, Beenakker, McCarrol, and cylindrical cavity. In an embodiment, the cavity provides a strong electromagnetic field which may form a nonthermal plasma. The strong electromagnetic field may be due to a TM₀₁₀ mode of a cavity such as a Beenakker cavity. Multiple sources of microwave power may be used simultaneously. For example, the microwave plasma such as a nonthermal plasma may be maintained by multiple Evenson cavities operated in parallel to form the plasma in the microwave cell 601. The cell may be cylindrical and may comprise a quartz cell with Evenson cavities spaced along the longitudinal axis. In another embodiment, a multi slotted antenna such as a planar antenna serves as the equivalent of multiple sources of microwaves such as dipole-antenna-equivalent sources. One such embodiment is given in Y. Yasaka, D. Nozaki, M. Ando, T. Yamamoto, N. Goto, N. Ishii, T. Morimoto, “Production of large-diameter plasma using multi-slotted planar antenna,” Plasma Sources Sci. Technol., Vol. 8, (1999), pp. 530-533 which is incorporated herein by reference in its entirety.

The cell may further comprise a magnet such a solenoidal magnet 607 to provide an axial magnetic field. The ions such as electrons formed by the hydrogen catalysis reaction produce microwaves to at least partially maintain the microwave discharge plasma. The microwave frequency may be selected to efficiently form atomic hydrogen from molecular hydrogen. It may also effectively form ions that serve as catalysts from a source of catalyst such as He⁺, Ne⁺/H⁺, or Ar⁺ catalysts from helium, neon-hydrogen mixture, and argon gases, respectively. The microwave frequency is preferably in the range of about 1 MHz to about 100 GHz, more preferably in the range about 50 MHz to about 10 GHz, most preferably in the range of about 75 MHz±50 MHz or about 2.4 GHz ±1GHz.

A hydrogen dissociator may be located at the wall of the reactor to increase the atomic hydrogen concentrate in the cell. The reactor may further comprise a magnetic field wherein the magnetic field may be used to provide magnetic confinement to increase the electron and ion energy to be converted into power by means such as a magnetohydrodynamic or plasmadynamic power converter.

A vacuum pump 610 may be used to evacuate the chamber 660 through vacuum lines 648 and 650. The cell may be operated under flow conditions with the hydrogen and the catalyst supplied continuously from catalyst source 612 and hydrogen source 638. The amount of gaseous catalyst may be controlled by controlling the plasma gas flow rate where the plasma gas includes a hydrogen and a source of catalyst (e.g., hydrogen and argon or helium). The amount of gaseous hydrogen atoms to the plasma may be controlled by controlling the hydrogen flow rate and the ratio of hydrogen to plasma gas in the mixture. The hydrogen flow rate and the plasma gas flow rate to the hydrogen-plasma-gas mixer and mixture flow regulator 621 are controlled by flow rate controllers 634 and 644, and by valves 636 and 646. Mixer regulator 621 controls the hydrogen-plasma mixture to the chamber 660. The catalysis rate is also controlled by controlling the temperature of the plasma with microwave generator 624.

Catalysis may occur in the gas phase. Hydrino atoms and hydrino hydride ions are produced in the plasma 604. Hydrino hydride compounds cam be cryopumped onto the wall 606, or they can flow into hydrino hydride compound trap 608 through passage 648. Alternatively dihydrino molecules may be collected in trap 608. Trap 608 communicates with vacuum pump 610 through vacuum line 650 and valve 652. A flow to the trap 608 can be effected by a pressure gradient controlled by the vacuum pump 610, vacuum line 650, and vacuum valve 652.

In another embodiment of the microwave cell reactor shown in FIG. 9, the wall 606 has a catalyst supply passage 656 for passage of the gaseous catalyst from a catalyst reservoir 658 to the plasma 604. The catalyst in the catalyst reservoir 658 can be heated by a catalyst reservoir heater 666 having a power supply 668 to provide the gaseous catalyst to the plasma 604. The catalyst vapor pressure can be controlled by controlling the temperature of the catalyst reservoir 658 by adjusting the heater 666 with its power supply 668. The catalyst in the gas phase may comprise those given in TABLES 1 and 3, hydrinos, and those described in the Mills Prior Publication.

In another embodiment of the microwave cell reactor, a chemically resistant open container such as a ceramic boat located inside the chamber 660 contains the catalyst. The reactor further comprises a heater that may maintain an elevated temperature. The cell can be operated at an elevated temperature such that the catalyst in the boat is sublimed, boiled, or volatilized into the gas phase. Alternatively, the catalyst in the catalyst boat can be heated with a boat heater having a power supply to provide the gaseous catalyst to the plasma. The catalyst vapor pressure can be controlled by controlling the temperature of the cell with a cell heater, or by controlling the temperature of the boat by adjusting the boat heater with an associated power supply.

In an embodiment, the microwave cell hydride reactor further comprises a structure interact with the microwaves to cause localized regions of high electric and/or magnetic field strength. A high magnetic field may cause electrical breakdown of the gases in the plasma chamber 660. The electric field may form a nonthermal plasma that increases the rate of catalysis by methods such as the formation of the catalyst from a source of catalyst. The source of catalyst may be argon, neon-hydrogen mixture, helium to form He⁺, Ne⁺/H⁺, and Ar⁺, respectively. The structures and methods are equivalent to those given in the Plasma Torch Cell Hydride Reactor section.

The nonthermal plasma temperature corresponding to the energetic ion and/or electron temperature as opposed to the relatively low energy thermal neutral gas temperature in the microwave cell reactor is advantageously maintained in the range of about 5,000-5,000,000° C. The cell may be operated without heating or insulation. Alternatively, in the case that the catalyst has a low volatility, the cell temperature is maintained above that of the catalyst source, catalyst reservoir 658 or catalyst boat to prevent the catalyst from condensing in the cell. The operating temperature depends, in part, on the nature of the material comprising the cell. The temperature for a stainless steel alloy cell is preferably about 0-1200° C. The temperature for a molybdenum cell is preferably about 0-1800° C. The temperature for a tungsten cell is preferably about 0-3000° C. The temperature for a glass, quartz, or ceramic cell is preferably about 0-1800° C.

The molecular and atomic hydrogen partial pressures in the chamber 660, as well as the catalyst partial pressure, is preferably maintained in the range of about 1 mtorr to about 100 atm. Preferably the pressure is in the range of about 100 mtorr to about 1 atm, more preferably the pressure is about 100 mtorr to about 20 torr.

An exemplary plasma gas for the microwave cell reactor is argon. Exemplary flow rates are about 0.1 standard liters per minute (slm) hydrogen and about 1 slm argon. An exemplary forward microwave input power is about 1000 W. The flow rate of the plasma gas or hydrogen-plasma gas mixture such as at least one gas selected for the group of hydrogen, argon, helium, argon-hydrogen mixture, helium-hydrogen mixture is preferably about 0-1 standard liters per minute per cm³ of vessel volume and more preferably about 0.001-10 sccm per cm³ of vessel volume. In the case of an argon-hydrogen or helium-hydrogen mixture, preferably helium or argon is in the range of about 99 to about 1%, more preferably about 99 to about 95%. The power density of the source of plasma power is preferably in the range of about 0.01 W to about 100 W/cm³ vessel volume.

In other embodiments of the microwave reactor, the catalyst may be agitated and supplied through a flowing gas stream such as the hydrogen gas or plasma gas which may be an additional source of catalyst such as helium or argon gas. The source of catalyst may also be provided by an aspirator, atomizer, or nebulizer to form an aerosol of the source of catalyst. The catalyst which may become an aerosol may be dissolved or suspended in a liquid medium such as water. The medium may be contained in the catalyst reservoir 614. Alternatively, the aspirator, atomizer, or nebulizer may inject the source of catalyst or catalyst directly into the plasma 604. In another embodiment, the nebulized or atomized catalyst may be carried into the plasma 604 by a carrier gas, such as hydrogen, helium, neon, or argon where the helium, neon-hydrogen, or argon may be ionized to He⁺, Ne⁺/H⁺, or Ar⁺, respectively, and serve as hydrogen catalysts.

The microwave cell may be interfaced with any of the converters of plasma or thermal energy to mechanical or electrical power described herein such as the magnetic mirror magnetohydrodynamic power converter, plasmadynamic power converter, or heat engine, such as a steam or gas turbine system, sterling engine, or thermionic or thermoelectric converter. In addition it may be interfaced with the gyrotron, photon bunching microwave power converter, charge drift power, or photoelectric converter as disclosed in Mills Prior Publications.

The microwave reactor further includes an electron source in contact with the hydrinos, for generating hydrino hydride ions. In the cell, the hydrinos are reduced to hydrino hydride ions by contacting 1.) the wall 606, 2.) plasma electrons, or 4.) any of the reactor components such as catalyst supply passage 656, or catalyst reservoir 658, or 5) a reductant extraneous to the operation of the cell (e.g. a consumable reductant added to the cell from an outside source). In an embodiment, the microwave cell reactor further comprise a selective valve 618 for removal of lower-energy hydrogen products such as dihydrino molecules.

Compounds comprising a hydrino hydride anion and a cation may be formed in the gas cell. The cation which forms the hydrino hydride compound may comprise a cation of an oxidized species of the material forming the cell, a cation of an added reductant, or a cation present in the plasma (such as a cation of the catalyst).

3. Capacitively and Inductively Coupled RF Plasma Gas Cell Hydride and Power Reactor

According to an embodiment of the invention, a reactor for producing power and at least one of hydrinos, hydrino hydride ions, dihydrino molecular ions and dihydrino molecules may take the form of a capacitively or inductively coupled RF plasma cell hydride reactor. A RF plasma cell hydride reactor of the present invention is also shown in FIG. 9. The cell structures, systems, catalysts, and methods may be the same as those given for the microwave plasma cell reactor except that the microwave source may be replaced by a RF source 624 with an impedance matching network 622 that may drive at least one electrode and/or a coil. The RF plasma cell may further comprise two electrodes 669 and 670. The coaxial cable 619 may connect to the electrode 669 by coaxial center conductor 615. Alternatively, the coaxial center conductor 615 may connect to an external source coil which is wrapped around the cell 601 which may terminate without a connection to ground or it may connect to ground. The electrode 670 may be connected to ground in the case of the parallel plate or external coil embodiments. The parallel electrode cell may be according to the industry standard, the Gaseous Electronics Conference (GEC) Reference Cell or modification thereof by those skilled in the art as described in G A. Hebner, K. E. Greenberg, “Optical diagnostics in the Gaseous electronics Conference Reference Cell, J. Res. Natl. Inst. Stand. Technol., Vol. 100, (1995), pp. 373-383; V. S. Gathen, J. Ropcke, T. Gans, M. Kaning, C. Lukas, H. F. Dobele, “Diagnostic studies of species concentrations in a capacitively coupled RF plasma containing CH₄—H₂—Ar,” Plasma Sources Sci. Technol., Vol. 10, (2001), pp. 530-539; P. J. Hargis, et al., Rev. Sci. Instrum., Vol. 65, (1994), p. 140; Ph. Belenguer, L. C. Pitchford, J. C. Hubinois, “Electrical characteristics of a RF-GD-OES cell,” J. Anal. At. Spectrom., Vol. 16, (2001), pp. 1-3 which are herein incorporated by reference in their entirety. The cell which comprises an external source coil such as al 3.56 MHz external source coil microwave plasma source is as given in D. Barton, J. W. Bradley, D. A. Steele, and R. D. Short, “investigating radio frequency plasmas used for the modification of polymer surfaces,” J. Phys. Chem. B, Vol. 103, (1999), pp. 4423-4430; D. T. Clark, A. J. Dilks, J. Polym. Sci. Polym. Chem. Ed., Vol. 15, (1977), p. 2321; B. D. Beake, J. S. G. Ling, G. J. Leggett, J. Mater. Chem., Vol. 8, (1998), p. 1735; R. M. France, R. D. Short, Faraday Trans. Vol. 93, No. 3, (1997), p. 3173, and R. M. France, R. D. Short, Langmuir, Vol. 14, No. 17, (1998), p. 4827 which are herein incorporated by reference in their entirety. At least one wall of the cell 601 wrapped with the external coil is at least partially transparent to the RF excitation. The RF frequency is preferably in the range of about 100 Hz to about 100 GHz, more preferably in the range about 1 kHz to about 100 MHz, most preferably in the range of about 13.56 MHz±50 MHz or about 2.4 GHz±1 GHz.

In another embodiment, an inductively coupled plasma source is a toroidal plasma system such as the Astron system of Astex Corporation described in U.S. Pat. No. 6,150,628 which is herein incorporated by reference in its entirety. In an embodiment, the field strength is high to cause a nonthermal plasma. The toroidal plasma system may comprise a primary of a transformer circuit. The primary may be driven by a radio frequency power supply. The plasma may be a closed loop which acts at as a secondary of the transformer circuit. The RF frequency is preferably in the range of about 100 Hz to about 100 GHz, more preferably in the range about 1 kHz to about 100 MHz, most preferably in the range of about 13.56 MH±50 MHz or about 2.4 GHz±1 GHz.

4. Power Converter

4.1 Plasma Confinement by Spatially Controlling Catalysis

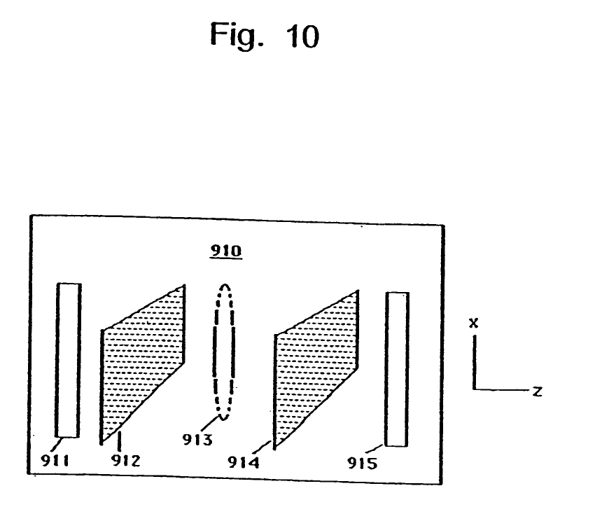

The plasma formed by the catalysis of hydrogen may be confined to a desired region of the reactor by structures and methods such as those that control the source of catalyst, the source of atomic hydrogen, or the source of an electric or magnetic field which alters the catalysis rate as given in the “Adjustment of Catalysis Rate with an Applied Field” section. In an embodiment, the reactor comprises two electrodes, which provide an electric field to control the catalysis rate of atomic hydrogen. The electrodes may produce an electric field parallel to the z-axis. The electrodes may be grids oriented in a plane perpendicular to the z-axis such as grid electrodes 912 and 914 shown in FIG. 10. The space between the electrodes may define the desired region of the reactor.

In another embodiment, a magnetic field may confine a charged catalyst such as Ar⁺ to a desired region to selectively form a plasma as described in the “Noble Gas Catalysts and Products” section. In an embodiment of the cell, the reaction is maintained in a magnetic field such as a solenoidal or minimum magnetic (minimum B) field such that a second catalyst such as Ar⁺ is trapped and acquires a longer half-life. The second catalyst may be generated by a plasma formed by hydrogen catalysis using a first catalyst. By confining the plasma, the ions such as the electrons become more energetic, which increases the amount of second catalyst such as Ar⁺. The confinement also increases the energy of the plasma to create more atomic hydrogen.

In another embodiment, a hot filament which dissociates molecular hydrogen to atomic hydrogen and which may also provide an electric field that controls the rate of catalysis may be used to define the desired region in the cell. The plasma may form substantially in the region surrounding the filament wherein at least one of the atomic hydrogen concentration, the catalyst concentration, and the electric field provides a much faster rate of catalysis there than in any undesired region of the reactor.

In another embodiment, the source of atomic hydrogen such as the source of molecular hydrogen or a hydrogen dissociator may be used to determine the desired region of the reactor by providing atomic hydrogen selectively in the desired region.

In an another embodiment, the source of catalyst may determine the desired region of the reactor by providing catalyst selectively in the desired region.

In an embodiment of a microwave power cell, the plasma may be maintained in a desire region by selectively providing microwave energy to that region with at least one antenna 615 or waveguide 619 and RPF window 613 shown in FIG. 9. The cell may comprise a microwave cavity which causes the plasma to be localized to the desired region.

4.2 Power Converter Based on Magnetic Flux Invariance

Jackson [J. D. Jackson, Classical Electrodynamics, Second Edition, John Wiley & Sons, New York, (1962), pp. 588-593] the complete disclosure of which is incorporated by reference shows that if a particle moves through regions where the magnetic field strength varies slowly in space or time, which corresponds to an adiabatic change of the field, then the flux linked by the particle's orbit remains a constant. If the magnetic flux B decreases, the radius a will increase such that the flux πa²B remains constant. The constancy of flux linked can be expressed in several ways in terms of the particle's orbital radius a and magnetic flux B, its transverse momentum p_{⊥}, and the magnetic moment μ=eω_{c}a²/2 of the current loop of the particle in orbit:

$$\frac{\begin{matrix}{Ba}^{2} \\ {p}_{⊥}\end{matrix}}{\begin{matrix}B \\ γμ\end{matrix}} \} are adiabatic invariants \qquad ( 58 )$$

where γ is the special relativistic factor. For a static magnetic field, the speed of the particle is constant and its total energy does not change. Then the magnetic moment μ is an adiabatic invariant. In time varying magnetic fields or electric fields μ is an adiabatic invariant only in the nonrelativistic limit. In the present, invention the ions may be essentially nonrelativistic.

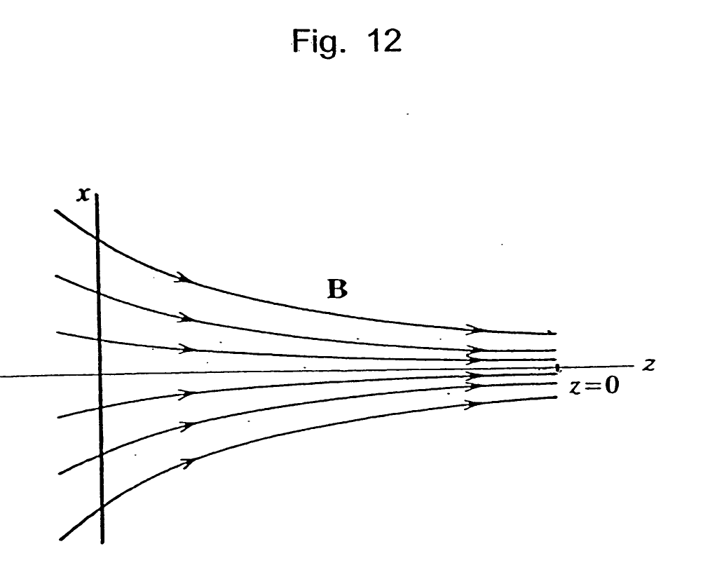

In an embodiment of the magnetic mirror power converter, a static field from a source acts mainly along the z-axis but has a small positive gradient in that direction. FIG. 12 shows the field lines of an exemplary case. In addition to the z component of the field, there is a small radial component due to the curvature of the field lines. Cylindrical symmetry may be a good approximation. Consider a particle spiraling about the z-axis in an orbit of small radius with a transverse velocity v_{⊥0} and a component of velocity v_{∥0} parallel to B at z=0, the center of the desired region where the axial field strength is B₀. The speed v₀ of the particle is constant so that at any position along the z-axis

v_{∥}²+v_{⊥}²=v₀² (59)

Since the flux linked is a constant of motion, then

$$\frac{{v}_{⊥}^{2}}{B} = \frac{{v}_{⊥ 0}^{2}}{{B}_{0}} \qquad ( 60 )$$

where B is the axial magnetic flux density. Then the parallel velocity at any position along the z-axis is given by

$${v}_{‖ 0}^{2} = {v}_{0}^{2} - {v}_{⊥ 0}^{2} \frac{B ( z )}{{B}_{0}} \qquad ( 61 )$$

The invariance of the flux linking an orbit is the basis of the mechanism of a “magnetic mirror” as described by J. D. Jackson, Classical Electrodynamics. A principle of a magnetic mirror is that charged particles are reflected by regions of strong magnetic fields if the initial velocity is towards the mirror and are ejected from the mirror otherwise. In the case of the magnetic mirror power converter of the present invention, the acceleration for an ion in the desired region with a position z>z₀ or z<z₀ with a magnetic mirror at z=0 is given by

$$\approx - \frac{{v}_{⊥ 0}^{2}}{2 {B}_{0}} \frac{δ B ( z )}{δ z} \qquad ( 62 )$$

Two magnetic mirrors at two positions along the z-axis (“tandem mirrors”) with solenoidal windings in between may create a “magnetic bottle” which confines plasma between the mirrors inside the solenoid as described by J. D. Jackson, Classical Electrodynamics. The field lines may be as shown in FIG. 12. Ions created in the bottle in the center region will spiral along the axis, but will be reflected by the magnetic mirrors at each end which provide a much higher field towards the ends. In this configuration, the acceleration for an ion in the desired region with a position −z₀<z<z₀ with the magnetic mirrors at the ends of the bottle at z=±z₀ is given by

$$\approx - \frac{{v}_{⊥ 0}^{2}}{2 {B}_{0}} \frac{δ B ( z - {z}_{0}^{′} )}{δ z} \qquad ( 63 )$$

where z₀=±z₀. The flux maximum Bₘ is at the ends of the bottle at z=±z₀. If the ratio of the maximum magnetic flux Bₘ in the mirror to the field B in the central region is very large, only particles with a very large component of velocity parallel to the axis can penetrate through the ends. The condition for an ion to penetrate is

$$\vert \frac{{v}_{‖ 0}}{{v}_{⊥ 0}} \vert > {( \frac{{B}_{m}}{B} - 1 )}^{1 / 2} \qquad ( 64 )$$

4.2.1 Ion Flow Power Converter

An objective of a power converter based on magnetic flux invariance of the present invention is to form a mass flow of charged ions from the hydrogen catalysis generated plasma to an “ion flow power converter”, which is a means to convert the flow of ions into power such as electrical power. The ion flow power converter may be a magnetohydrodynamic power converter. Preferable, the propagation direction of the ions is along an axis parallel to the magnetic field lines of a source of a magnetic field gradient along that axis such as the z-axis in the case of a magnetic mirror power converter or along the confinement axis, the z-axis, in the case of a magnetic bottle power converter.

The energy released by the catalysis of hydrogen to form increased binding energy hydrogen species and compounds produces a plasma in the cell such as a plasma of the catalyst and hydrogen. The force F on a charged ion in a magnetic field of flux density B perpendicular to the velocity v is given by

F=ma=evB (65)

where a is the acceleration and m is the mass of the ion of charge e. The force is perpendicular to both v and B. The electrons and ions of the plasma orbit in a circular path in a plane transverse to the applied magnetic field for sufficient field strength, and the acceleration a is given by

$$a = \frac{{v}^{2}}{r} \qquad ( 66 )$$

where r is the radius of the ion path. Therefore,

$$ma = \frac{{mv}^{2}}{r} = evB \qquad ( 67 )$$

The angular frequency ω_{c} of the ion in radians per second is

$${ω}_{c} = \frac{v}{r} = \frac{eB}{m} \qquad ( 68 )$$

The ion cyclotron frequency ω_{c} is independent of the velocity of the ion. Thus, for a typical case which involves a large number of ions with a distribution of velocities, all ions of a particular m/e value will be characterized by a unique cyclotron frequency independent of their velocities. The velocity distribution, however, will be reflected by a distribution of orbital radii since

$${ω}_{c} = \frac{v}{r} \qquad ( 69 )$$

From Eq. (68) and Eq. (69), the radius is given by

$$r = \frac{v}{{ω}_{c}} = \frac{v}{\frac{eB}{m}} = \frac{mv}{eB} \qquad ( 70 )$$

The velocity and radius are influenced by electric fields, and applying a potential drop in the cell will increase v and r; whereas, with time, v and r may decrease due to loss of energy and decrease of temperature. The frequency v_{c} may be determined from the angular frequency given by Eq. (68)

$${v}_{c} = \frac{{ω}_{c}}{2 π} = \frac{eB}{2 π m} \qquad ( 71 )$$

In a uniform magnetic field, the motion of a moving charged particle is helical with a cyclotron frequency given by Eq. (68) and a radius given by Eq. (70). The pitch of the helix is determined by the ratio of v_{∥}, the velocity parallel to the magnetic field and v_{⊥}, the velocity of Eq. (70) which is perpendicular to the magnetic field. In a homogeneous plasma, the average v_{∥} is equal to the average v_{⊥}. The adiabatic invariance of flux through the orbit of an ion is a means of the present invention of a magnetic mirror power converter to form a flow of ions along the z-axis with the conversion of v_{⊥} to v_{∥} such that v_{∥}>v_{⊥}. Preferably, v_{∥}>>v_{⊥}. In the case of a magnetic bottle power converter the adiabatic invariant

$$\frac{{v}_{⊥}^{2}}{B} = constant$$

is also a means to form a flow of ions along the z-axis with v_{∥}>>v_{⊥} wherein the selection of ions with large parallel velocities occurs at the magnetic mirrors at the ends.

The converter may further comprise a magnetohydrodynamic power converter comprising a source of magnetic flux transverse to the z-axis, the direction of ion flow. Thus, the ions have preferential velocity along the z-axis and propagate into the region of the transverse magnetic flux. The Lorentzian force on the propagating electrons and ions is given by

F=ev×B (72)

The force is transverse to the ion velocity and the magnetic field and in opposite directions for positive and negative ions. Thus, a transverse current forms. The source of transverse magnetic field may comprise components which provide transverse magnetic fields of different strengths as a function of position along the z-axis in order to optimize the crossed deflection (Eq. (72)) of the flowing ions having a parallel velocity dispersion. The magnetohydrodynamic power converter further comprises at least two electrodes which may be transverse to the magnetic field to receive the transversely Lorentzian deflected ions which creates a voltage across the electrodes. Magnetohydrodynamic generation is described by Walsh [E. M. Walsh, Energy Conversion Electromechanical, Direct, Nuclear, Ronald Press Company, NY, N.Y., (1967), pp. 221-248] the complete disclosure of which is incorporated herein by reference.

In one embodiment, the magnetohydrodymanic power converter is a segmented Faraday generator. In another embodiment, the transverse current formed by the Lorentzian deflection of the ion flow undergoes further Lorentzian deflection in the direction parallel to the input flow of ions (z-axis) to produce a Hall voltage between at least a first electrode and a second electrode relatively displaced along the z-axis. Such a device is known in the art as a Hall generator embodiment of a magnetohydrodymanic power converter. A similar device with electrodes angled with respect to the z-axis in the xy-plane comprises another embodiment of the present invention and is called a diagonal generator with a “window frame” construction. In each case, the voltage may drive a current through an electrical load. Embodiments of a segmented Faraday generator, Hall generator, and diagonal generator are given in Petrick [J. F. Louis, V. 1. Kovbasyuk, Open-cycle Magnetohydrodynamic Electrical Power Generation, M Petrick, and B. Ya Shumyatsky, Editors, Argonne National Laboratory, Argonne, Ill., (1978), pp. 157-163] the complete disclosure of which is incorporated by reference.

In a further embodiment of the magnetohydrodynamic power converter, the flow of ions along the z-axis with v_{∥}>>v_{⊥} may then enter a compression section comprising an increasing axial magnetic field gradient wherein the component of electron motion parallel to the direction of the z-axis v_{∥} is at least partially converted into to perpendicular motion v_{⊥} due to the adiabatic invariant

$$\frac{{v}_{⊥}^{2}}{B} = constant .$$

An azimuthal current due to v_{⊥} is formed around the z-axis. The current is deflected radially in the plane of motion by the axial magnetic field to produce a Hall voltage between an inner ring and an outer ring electrode of a disk generator magnetohydrodynamic power converter. The voltage may drive a current through an electrical load.

In a neutral plasma or ion flow, the ions recombine into neutrals as a function of time. The ions also undergo collisions. The lifetime is proportional to the afterglow duration which may be about 100 μsec. For example, the afterglow with decay to zero emission of cesium lines (e.g. 455.5 nm) of a high voltage pulse discharge is about 100 μsec [A. Surmeian, C. Diplasu, C. B. Collins, G. Musa, I-lovittz Popescu, J. Phys. D: Appl. Phys. Vol. 30, (1997), pp. 1755-1758]. And, the duration of the afterglow of a neon plasma which was switched off from a stationary state was under 250 μsec [T. Bauer, S. Gortchakov, D. Loffhagen, S. Pfau, R. Winkler, J. Phys. D: Appl. Phys. Vol. 30, (1997), pp. 3223-3239]. However, in the case of the magnetic mirror power converter, the ions gain a greater parallel component of velocity with time of propagation from the mirror due to the adiabatic invariance of flux linked by each particle's orbit. In an embodiment of the magnetic mirror power converter, a least one means to convert an essentially linear flow of ions to a voltage such as a magnetohydrodynamic power converter is positioned along the z-axis to maximize the power.

Another objective of the present invention is to decrease the scattering of ions flowing essentially along the z-axis with v_{∥}>v_{⊥}. Background ions and neutrals may scatter the ions propagating along the z-axis to form the mass flow of ions along the z-direction. The pressure of the catalyst or the molecular hydrogen pressure may be controlled to achieve a desired rate of catalysis while achieving a desired rate of ion scattering such that the desired power output is achieved. In an embodiment, the desired rate of catalysis is a maximum, and the desired rate of ion scattering is a minimum.

4.2.2 Magnetic Mirror Power Converter

Another embodiment of the present invention comprises a magnetic mirror power converter shown in FIG. 10 that comprises a hydride reactor of the present invention 910, a magnetic mirror 913 having a magnetic flux gradient along the z-axis that produces an essentially linear flow of ions from the hydrogen catalysis formed plasma (“corkless magnetic bottle with ion flow down the magnetic field gradient”), and a least one means 911 and 915 to convert an essentially linear flow of ions to power such as a magnetohydrodynamic power converter.

The plasma formed by the catalysis of atomic hydrogen comprises energetic electrons and ions which may be generated selectively in a desired region by a means such as grid electrodes or microwave antennas 912 and 914. The magnetic mirror may be centered in the desired region, or in another embodiment, the magnetic mirror may be at the position of the cathode 914. Electrons and ions are forced from a homogeneous distribution of velocities in x, y, and z to a preferential velocity along the axis of magnetic field gradient of the magnetic mirror, the z-axis. The component of electron motion perpendicular to the direction of the z-axis v_{⊥} is at least partially converted into to parallel motion v_{∥} due to the adiabatic invariance of linked flux of a particle's orbit (the kinetic energy is conserved as the linear energy is drawn from that of orbital motion).

In an embodiment of the magnetic mirror power converter, the magnetic mirror is centered at z=0 in the desired region such that ions are accelerated along the positive and negative z-axis. The converter may further comprise two magnetohydrodynamic power converters comprising two sources of magnetic flux transverse to the z-axis as shown in FIG. 10. The sources may be symmetric along the z-axis (i.e. equidistant from the center of the magnetic mirror). Each magnetohydrodynamic power converter may further comprise electrodes which are oriented to receive the ions which undergo Lorentzian deflection. The voltage from the deflected ions may be dissipated by a load in electrical contact with the electrodes. Preferably, the plasma is predominantly in the desired region such that ions may only pass in one direction through each magnetohydrodynamic power converter.

The embodiment of the magnetic mirror power converter wherein the magnetic mirror is positioned at the cathode 914 of FIG. 10 may comprise a single magnetohydrodynamic converter located at a position along the z-axis from the magnetic mirror greater than that of anode 912. In addition to grid electrodes, other electrodes may be used to produce a field to localize the plasma to a desired region and permit the conversion of plasma to a linear flow of ions by methods such as the at least partial conversion of the component of electron motion perpendicular to the direction of the z-axis v_{⊥} into to parallel motion v_{∥} due to the adiabatic invariant

$$\frac{{v}_{⊥}^{2}}{B} = constant .$$

Further exemplary electrodes are concentric cylindrical electrodes aligned with the z-axis, hollow cathodes, hollow anodes, conical electrodes, spiral electrodes, and a cylindrical cathode or anode aligned with the z-axis with the conductive cell wall serving as the counter electrode.

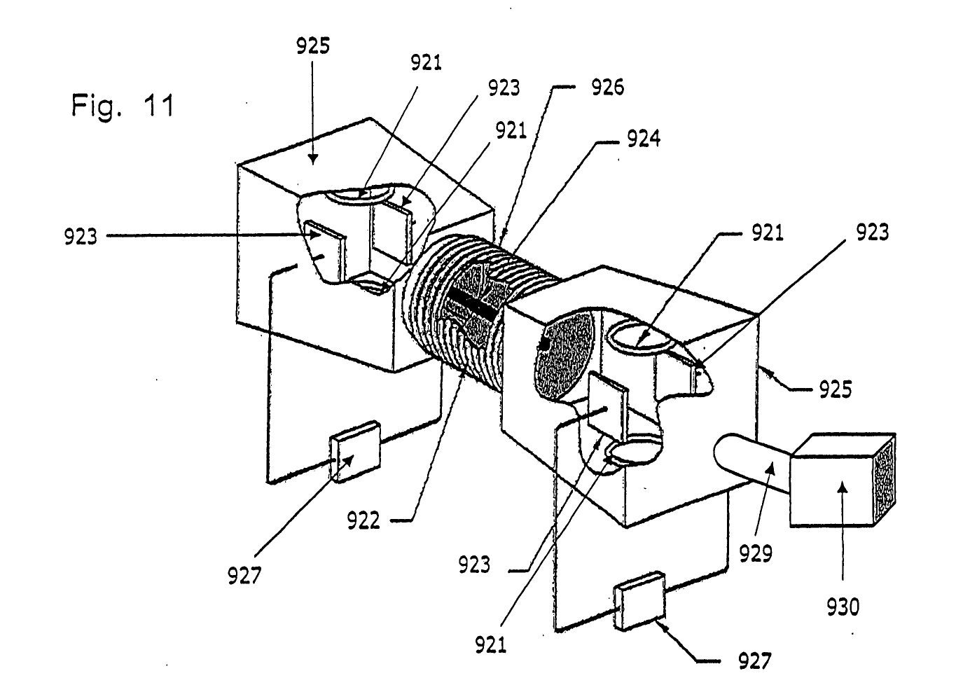

Another embodiment of the present invention comprises a magnetic mirror power converter shown in FIG. 11 that comprises a power and hydride reactor 926 such as the microwave plasma or discharge plasma cell of the present invention located inside of a solenoid magnet 922 having a magnetic flux gradient along the z-axis that produces an essentially linear flow of ions from the hydrogen catalysis formed plasma (“corkless magnetic bottle with ion flow down the magnetic field gradient”), an axial electrode 924 such as an anode which provides a radial field with the wall of the cell 926 as the counter electrode wherein the field confines the plasma to the desired region inside of the solenoid 922, magnetohydrodynamic magnets 921 to cause a Lorentzian deflection of the ion flow, and transverse electrodes 923 to collect the ions to form a voltage between the opposed electrodes whereby the essentially linear flow of ions is converted to electrical power that is delivered to load 927. In an embodiment, the mirror magnetohydrodynamic (“MHD”) power converter is enclosed in a vacuum vessel 925 that connects to the hydrino hydride reactor 926. In an embodiment of the mirror MHD power converter wherein the power and hydride reactor 926 is a microwave plasma cell, the plasma may be maintained in a desire region by selectively providing microwave energy to that region with at least one antenna 615 or waveguide 619 and RF window 613 shown in FIG. 9. The cell 926 may comprise a microwave cavity which causes the plasma to be localized to the desired region. Preferably the plasma is confined to the volume of the solenoid magnet 922. In an embodiment wherein the power and hydride reactor 926 is a discharge plasma cell, the electrode 924 may serve as the discharge anode and the wall of the reactor 926 may serve as the cathode.

In an embodiment of the magnetic mirror power converter, the magnetic mirror comprises an electromagnet or a permanent magnet that produces the field equivalent to a Helmholtz coil or a solenoid. The magnetohydrodynamic power converter may be outside of the solenoid or Helmholtz coil or the permanent magnet equivalent in the region wherein the magnetic field is significantly less than the maximum field at the center of the magnetic mirror. The desired region may be the region wherein the magnetic field is greater than a desired fraction of the maximum magnitude of the magnetic field of the magnetic mirror such as one half the maximum field strength. In the solenoid embodiment, the desired region may be in the solenoid. In the case of an electromagnetic magnetic mirror, the magnetic field strength may be adjustable by controlling the electromagnetic current to control the rate at which ions flow from the desired region to control the catalyst rate and the power conversion. In the case that v_{∥0}²=v_{⊥0}²=0.5v₀² and

$$\frac{B ( z )}{{B}_{0}} = 0.1$$

at the magnetohydrodymanic power converter, the velocity given by Eq. (61) is about 95% parallel to the z-axis. The deflection of the ions may be essentially 100%. Thus, very high efficiency may be achieved.

In a further embodiment of the magnetic mirror converter, the reactor has at least one aperture through which the ions propagate in the direction of the positive or negative z-axis from the center of the magnetic mirror to the ion flow power converter such as a magnetohydrodymanic power converter. The aperture may comprise baffles as a flow separator of neutrals to allow for the passage of ions while retaining neutrals in the reactor. The reactor further comprises at least one differentially pumped section 925. In an embodiment, the ions become neutrals after being received by the ion flow power converter, and the neutrals are removed by differential pumping with pump 930 through vacuum line 929.

In another embodiment, of the magnetohydrodynamic power converter, the plasma is generated in a desired region such as the cell 926. The plasma temperature may be much greater than the temperature of the MHD power converter vacuum vessel 925. In this case, the magnetic mirror 922 may not be needed since very high energy ions and electrons flow from the hot section to the cold section by virtue of the second law of thermodynamics. The thermodynamically produced ion flow is then converted into electricity by a means such as the MHD converter which receives the flow. In an embodiment, the MHD power converter vacuum vessel 925 may be pumped to maintain a lower pressure than that in the cell 924. In a further embodiment, the power conversion comprises a flow of energetic ions into the MHD power converter and a flow of neutral particles in the opposite direction following the conversion process. This latter convective flow may eliminate a need for a pump on the MHD section. In an embodiment, the ions such as protons and electron have a large mean free path. Energetic protons and electrons flow from the cell into the MHD power converter, and hydrogen flows convectively in the opposite direction.

4.2.3 Magnetic Bottle Power Converter

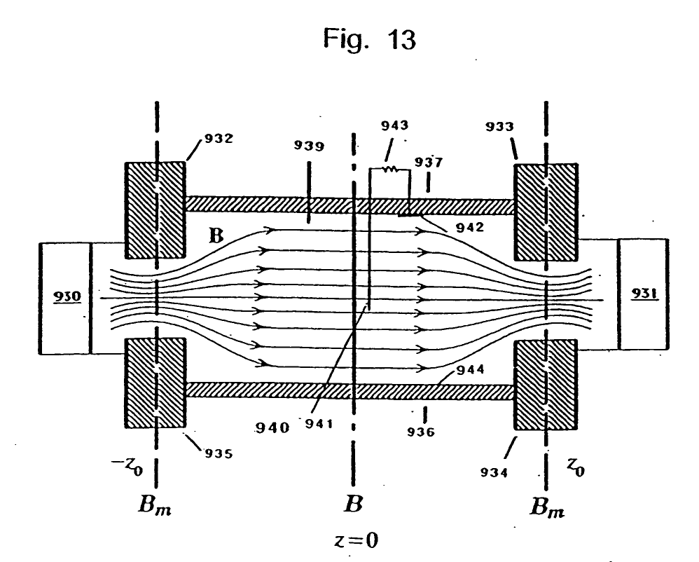

Another embodiment of the present invention comprises a magnetic bottle power converter shown in FIG. 13 that comprises a hydrino hydride reactor 939 of the present invention, and magnetic bottle 940, and a least one means 930 and 931 to convert an essentially linear flow of ions to power. The magnetic bottle 940 may confine most of the hydrogen catalysis generated plasma to a desired region in the hydrino hydride reactor. The magnetic bottle may be constructed with an axial field produced by a magnetic field source such as solenoidal windings 937 and 936 over the desired region and additional magnetic field sources such as additional coils 933, 934, 932, and 935 at each end of the bottle to provide a much higher field towards the ends. The field lines may be as shown in FIG. 12. Ions created in the bottle in the center region will spiral along the axis, but will be reflected by the magnetic mirrors at each end. Only ions with a very large component of velocity parallel to the z-axis may propagate through or penetrate the magnetic mirror without being reversed. Thus, the bottle supplies an essentially linear flow of ions from the hydrogen catalysis formed plasma from at least one end. These ions propagate to an ion flow power converter 930 and 931 such as a magnetohydrodynamic power converter. A magnetohydrodymanic power converter may comprise a source of magnetic flux substantially perpendicular to the z-axis at a position outside of the magnetic bottle and two electrodes crossed with the field which receive the Lorentzian deflected ions to form a voltage across the electrodes.

In an embodiment, the height of the barrier of each of the magic mirrors of the magnetic bottle is low (or the parallel velocity of the ion required to penetrate the mirror is intermediate) so that a high current and a high power may be converted. The barrier height may be adjustable to a desired value to provide a desired power conversion level.

In the case of one or more electromagnetic magnetic mirrors that form the bottle, the magnetic field strength may be adjustable by controlling the electromagnetic current to control the rate at which ions flow from the desired region to control the catalyst rate and the power conversion.

The reactor of the magnetic bottle power converter may have at least one aperture through which the ions propagate in the direction of the positive or negative z-axis away from the center of the corresponding penetrated magnetic mirror to an ion flow power converter such as a magnetohydrodymanic power converter. The reactor may further comprise at least one differentially pumped section such as the section of the magnetohydrodymanic power converter.

In an embodiment of the magnetic bottle power converter, the ions become neutrals after a sufficient time or after being received by the ion flow power converter such as the electrodes of the magnetohydrodynamic power converter. The neutrals may be removed from the power conversion region by differential pumping.

In another embodiment of the magnetic bottle power converter, the plasma may at be at least partially confined in a magnetic bottle that is inside of a second magnetic bottle, and other embodiments may comprise further stages of such magnetic bottles. Thus, the ions must penetrate at least two magnetic mirrors with adjustable heights determined by their maximum magnetic field which serve as energy selectors to provide ions to the ion flow power converter such as a magnetohydrodynamic power converter of a desired energy with a low parallel velocity dispersion.

4.3 Power Converter Based on Magnetic Space Charge Separation

The orbital radius of a charged particle is proportional to its momentum as given by Eq. (70) wherein mv is the particle momentum. Since positive ions such as protons, molecular hydrogen ions, and positive catalyst ions have much greater momentum than electrons, their radii are very large compared to those of the electrons. Thus, the positive ions may be preferentially lost from a plasma confinement structure such as a magnetic bottle or solenoid. The loss of ions from a plasma confined by a minimum B field confinement structure such as a magnetic bottle gives rise to a negatively charged plasma and positively charged cell walls. Such a confinement magnetic field may also increase the electron energy to be converted to electrical power.

A power plasmadynamic power converter based on magnetic space charge separation, as shown in FIG. 13, comprises a hydrino hydride reactor of the present invention, or other power source such as the microwave plasma cell, a plasma confinement structure such as a magnetic bottle or source of solenoidal field which confines most of the hydrogen catalysis generated plasma to a desired region in the hydrino hydride reactor, and a least one means to convert the separated ions into a voltage such as two separated electrodes 941 and 942 in contact with the regions of separated charges. The electrode 941 in contact with the confined plasma collects electrons, and the counter electrode 942 collects positive ions in a region outside of the confined plasma. In an embodiment, the positive ion collector comprises the cell wall 944. The confinement may be in a desired region wherein the hydrogen catalysis generated plasma is selectively formed. In the microwave plasma cell embodiment, the plasma may be localized with one or more spatially selective antennas, waveguides, or cavities. In the discharge plasma cell embodiment, the plasma may be selectively localized by applying an electric field in a desired region with at least two electrodes. Power may be supplied to a load 943 through the electrodes.

4.4 Plasmadynamic Power Converter

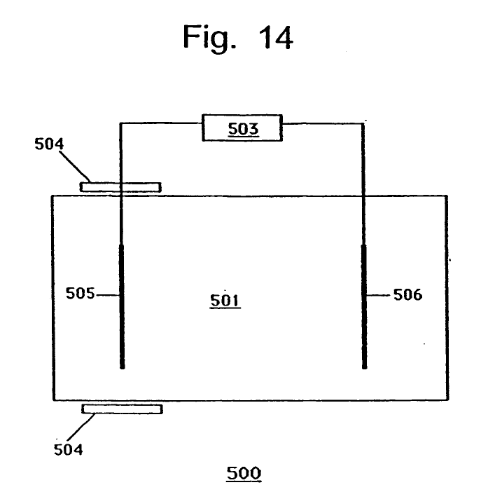

A plasmadynamic power converter 500 of the present invention based on magnetic space charge separation shown in FIG. 14 comprises a hydrino hydride reactor 501 of the present invention, or other power source such as a microwave plasma cell, at least one electrode 505 magnetized with a source of magnetic field, such as solenoidal magnets or permanent magnets 504, which may provide a uniform parallel magnetic field, at least one magnetized electrode, and at least one counter electrode 506. In an embodiment, the converter further comprises a means to localized the plasma in a desired region, such as a magnetic confinement structure or spatially selective generation means as given in the Plasma Confinement by Spatially Controlling Catalysis section. In the microwave plasma cell embodiment, the plasma may be localized with one or more spatially selective antennas, waveguides, or cavities. The mass of a positively charge ion of a plasma is at least about 1800 times that of the electron; thus, the cyclotron orbit may be an order of magnitude larger. This result allows electrons to be magnetically trapped on field lines while ions may drift. Thus, the floating potential is increased at the magnetized electrode 505 relative to the unmagnetized counter electrode 506 to produce a voltage between the electrodes. Power may be supplied to a load 503 through the connected electrodes.

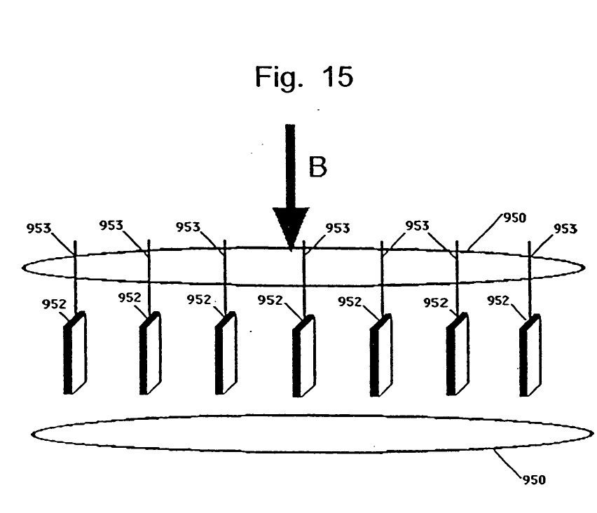

A plurality of magnetized electrodes 952 are shown in FIG. 15 wherein each electrode corresponds to electrode 505 of FIG. 14. Further shown in FIG. 15 is a source of uniform magnetic field B parallel to each electrode such as Helmholtz coils 950. The strength of the magnetic field B is adjusted to produce an optimal positive ion versus electron radius of gyration to maximize the power at the electrodes. The power can be delivered to a load through leads 953 which are connected to at least one counter electrode.

In a different embodiment, the plasma may be confined to the region of at least one magnetized electrode 505, and the counter electrode 506 may be in a region outside of the 35 energetic plasma. In further embodiments, 1.) the energetic plasma may be confined to a region of one unmagnetized electrode and a counter magnetized electrode may be outside of the desired region; 2.) both electrodes 505 and 506 may be magnetized and the field strength at one electrode may be greater than that at the other electrode.

In another embodiment, the plasmadynamic converter further comprises a heater. The magnetized electrode called the anode in this disclosure is heated to boil off electrons which are much more mobile than the ions. The electrons may be trapped by the magnetic field lines or may recombine with ions to give rise to a greater positive voltage at the anode. Preferably energy is extracted from the energetic positive ions as well as the electrons.

In an embodiment of the plasmadynamic power converter, the magnetized electrode, defined as the anode, comprises a magnetized pin wherein the field lines are substantially parallel to the pin. Any flux that would intercept the pin ends on an electrical insulator. An array of such pins may be used to increase the power converted. The at least one counter unmagnetized electrode defined as the cathode is electrically connected to the one or more anode pins through an electrical load.

4.5. Proton RF Power Converter

The energy released by the catalysis of hydrogen to form hydrino hydride compounds (“HHCs”) produces a plasma in the cell. The energetic protons of the plasma produced by the hydrogen catalysis are introduced into an axial magnetic field where they undergo cyclotron motion. The force on a charged ion in a magnetic field is perpendicular to both its velocity and the direction of the applied magnetic field. The protons of the plasma orbit in a circular path in a plane transverse to the applied magnetic field for sufficient field strength at an ion cyclotron frequency ω_{c} that is independent of the proton velocity. Thus, a typical case, which involves a large number of protons with a distribution of velocities, will be characterized by a unique cyclotron frequency that is dependent on the proton charge to mass ratio and the strength of the applied magnetic field. Except for when relativistic effects are nonnegligible, there is no dependence on their velocities. The velocity distribution will, however, be reflected by a distribution of orbital radii. The protons emit electromagnetic radiation with a maximum intensity at the cyclotron frequency. The velocity and radius of each proton may decrease due to loss of energy and a decrease of the temperature.

A proton RF power converter of the present invention comprises a resonator cavity, which has a dominant resonator mode at the cyclotron frequency. The plasma contains protons with a range of energies and trajectories (momenta) and randomly distributed phases initially. Electromagnetic oscillations are generated from the protons to produce induced radiation due to the grouping of protons under the action of the self-consistent field produced by the protons themselves with coherent radiation of the resulting packets. In this case, the device is a feedback oscillator. The theory of induced radiation of excited classical oscillators under the action of an external field and its use in high-frequency electronics is described by A. Gaponov et al. [A. Gaponov, M. I. Petelin, V. K. Yulpatov, Izvestiya VUZ. Radiofizika, Vol. 10, No. 9-10, (1965), pp. 1414-1453] the complete disclosure of which is incorporated herein by reference.

The proton spin resonance is about 42 MHz/T; whereas, the gyroresonance is about 15 MHz/T. Gyro bunching may be achieved by spin bunching with the application of resonant RF at the proton spin resonance frequency. The electromagnetic radiation emitted from the protons excites the mode of the cavity and is received by a resonant receiving antenna. The radiowaves may be rectified into DC electricity by means such as those given in the Art [R. M. Dickinson, Performance of a high-power, 2.388 GHz receiving array in wireless power transmission over 1.5 km, in 1976 IEEE MTT-S International Microwave Symposium, (1976), pp. 139-141; R. M. Dickinson, Bill Brown's Distinguished Career, http://www.mtt.org/awards/WCB's%20distinquished %20 career.htm; J. O. McSpadden, Wireless power transmission demonstration, Texas A&M University, http://www.tsgc.utexas.edu/power/general/wpt.html; History of microwave power transmission before 1980, http://rasc5.kurasc.kyoto-u.acjp/docs/plasma-group/sps/history2-e.html; J. O. McSpadden, R. M. Dickson, L. Fan, K. Chang, A novel oscillating rectenna for wireless microwave power transmission, Texas A&M University, Jet Propulsion Laboratory, Pasadena, Calif., http://www.tamu.edu, Microwave Engineering Department]. The DC electricity may be inverted and transformed into any desired voltage and frequency with conventional power conditioning equipment.

The hydrino hydride reactor cell plasma contains ions such as protons with randomly distributed phases initially. The present invention further comprises a means of amplification and generation of electromagnetic oscillations from the protons that may be connected with perturbations imposed by an external field on the protons. Induced radiation processes are due to the grouping or bunching of protons under the action of the so called “primary” electromagnetic field introduced from the system from outside in an amplifier embodiment, or under the action of the self-consistent field produced by the protons themselves in a feedback oscillator embodiment.

In an embodiment of the proton RF power converter, bunching of protons may be achieved by driving the protons orbiting in a magnetic field with RF input. Fast waves, slow waves, and waves that propagate at essentially the speed of light (k_{z}≈ω/c may be amplified from interactions with gyrating protons in cavities and waveguides as given for electrons in the following references [E. Jerby, A. Shahadi, R. Drori, M. Korol, M. Einat, M. Sheinin, V. Dikhtiar, V. Grinberg, M. Bensal, T. Harhel, Y. Baron, A. Fruchtman, V. L. Granatstein, and G. Bekefi, “Cyclotron resonance Maser experiment in a nondispersive waveguide”, IEEE Transactions on Plasma Science, Vol. 24, No. 3, June, (1996), pp. 816-823; H. Guo, L. Chen, H. Keren, J. L. Hirshfield, S. Y. Park, and K. R. Chu, “Measurements of gain of slow cyclotron waves on an annular electron beam, Phys. Rev. Letts., Vol. 49, No. 10, Sep. 6, (1982), pp. 730-733, and T. H. Kho, and A. T. Lin, “Slow wave electron cyclotron maser”, Phys. Rev. A, Vol. 38, No. 6, Sep. 15, (1988), pp. 2883-2888] the complete disclosure of which are herein incorporated by reference. In the later case, to overcome the effect of the cancellation of azimuthal and axial bunching for

$${k}_{z} ≅ \frac{ω}{c} ,$$

the perpendicular proton velocity may be greater than the parallel velocity as described by Jerby et al. [E. Jerby, A. Shahadi, R. Drori, M. Korol, M. Einat, M. Sheinin, V. Dikhtiar, V. Grinberg, M. Bensal, T. Harhel, Y. Baron, A. Fruchtman, V. L. Granatstein, and G. Bekefi, IEEE Transactions on Plasma Science, Vol. 24, No. 3, June, (1996), pp. 816-823] the complete disclosure of which is herein incorporated by reference.

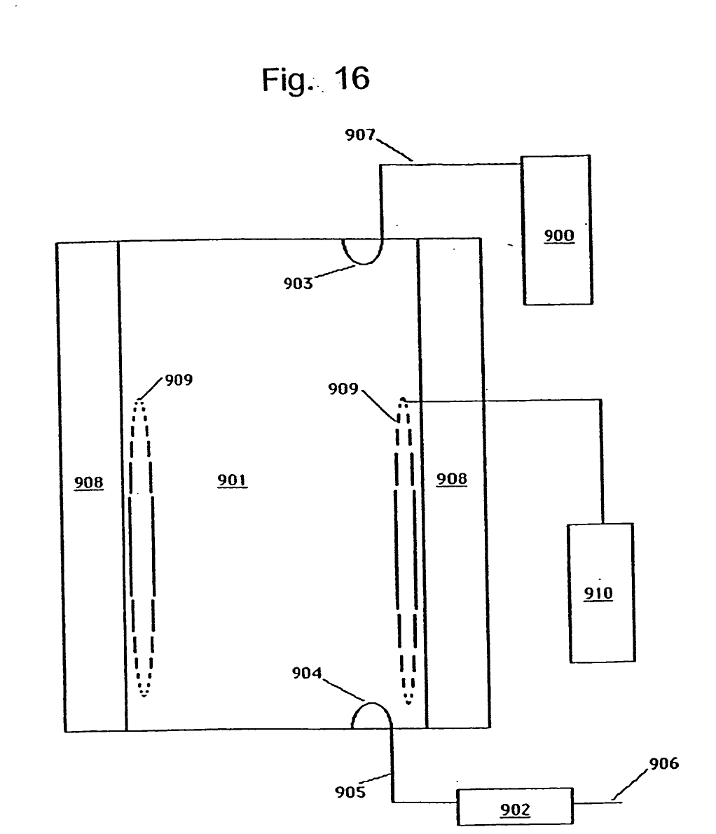

The proton RF power converter may be operated in an RF amplifier mode by an embodiment comprising a cavity 901 shown in FIG. 16 with a source 908 of a solenoidal magnetic field parallel to the axis of the cavity which may also be a hydrino hydride reactor. A current coupled loop 903 of FIG. 16 may receive RF power from the RF generator 900 through the connector 907 and input the RF power to the cavity. The RF power may be input to the cavity or waveguide 901 from a wave guide or antenna. The output amplified radiowaves may be output from the resonator cavity 901 by a current coupled loop 904 of FIG. 16. The current coupled loop may be connected to a rectifier 902 by connector 905 which outputs DC electricity to an inverter or an electrical load through connection 906. In another embodiments, the cavity 901 may be a waveguide, the input RF power may be from an input waveguide or antenna, and the output RF power may be through an RF window and output waveguide.

In an embodiment, RF power is supplied by RF power source 910 to RF coils 909 of FIG. 16. The RF power is applied at the proton nuclear magnetic spin resonance frequency to cause gyrobunching via spin bunching.

Further systems and methods to cause RF emission from protons are given for electrons in Mills Prior Provisional Applications such as that entitled “MAGNETIC MIRROR MAGNETOHYDRODYNAMIC POWER CONVERTER”, filed on Aug. 9, 2001 as U.S. Ser. No. 60/710,848 in the following sections which are incorporated by reference:

2.1 Cyclotron Power Converter

2.2. Coherent Microwave Power Converter

2.2.1 Cyclotron Resonance Maser (CRM) Power Converter

2.2.2 Gyrotron Power Converter

2.2.3 RF Amplifier Electron Bunching

2.2.4 Beam Generation

2.2.5 Fast or Slow Wave Microwave Power Converter

5. Experimental

5.1 Summary

Studies that confirm the novel reaction of atomic hydrogen which produces a chemically generated or assisted plasma and produces novel hydride compounds include extreme ultraviolet (EUV) spectroscopy [7-14, 20-24], characteristic emission from catalysis and the hydride ion products [10-12], lower-energy hydrogen emission [5, 7-9], plasma formation [10-14, 20-21, 23-24], Balmer α line broadening [8, 17-18], elevated electron temperature [8, 17], anomalous plasma afterglow duration [23-24], power generation [13-20, 31-33], and analysis of chemical compounds [25-31]. Exemplary studies include:

1.) the observation of intense extreme ultraviolet (EUV) emission at low temperatures (e.g. ≈10³ K) from atomic hydrogen and only those atomized elements or gaseous ions which provide a net enthalpy of reaction of approximately m·27.2 eV via the ionization of t electrons to a continuum energy level where t and m are each an integer (e.g. K, Cs, and Sr atoms and Rb⁺ ion ionize at integer multiples of the potential energy of atomic hydrogen and caused emission; whereas, the chemically similar atoms, Na, Mg, and Ba, do not ionize at integer multiples of the potential energy of atomic hydrogen and caused no emission) [7-14, 20-24],

2.) the observation of novel EUV emission lines from microwave and glow discharges of helium with 2% hydrogen with energies of q·13.6 eV where q=1,2,3,4,6,7,8,9,11,12 or these lines inelastically scattered by helium atoms in the excitation of He (1s²) to He (1s¹2p¹) that were identified as hydrogen transitions to electronic energy levels below the “ground” state corresponding to fractional quantum numbers [7, 8],

3.) the observation of novel EUV emission lines from microwave and glow discharges of helium with 2% hydrogen at 44.2 nm and 40.5 nm with energies of

$$q \cdot 13.6 + ( \frac{1}{{n}_{f}^{2}} - \frac{1}{{n}_{i}^{2}} ) \times 13.6 eV$$

where q=2 and n_{f}=2,4 n₁=∞ that corresponded to multipole coupling to give two photon emission from a continuum excited state atom and an atom undergoing fractional Rydberg state transition [8],

4.) the identification of transitions of atomic hydrogen to lower energy levels corresponding to lower-energy hydrogen atoms in the extreme ultraviolet emission spectrum from interstellar medium and the sun [1, 5, 7],

5.) the EUV spectroscopic observation of lines by the Institut f\O(u,^{\ddot{}})r Niedertemperatur-Plasmaphysik e.V. that could be assigned to transitions of atomic hydrogen to lower energy levels corresponding to fractional principal quantum numbers and the emission from the excitation of the corresponding hydride ions [22],

6.) the recent analysis of mobility and spectroscopy data of individual electrons in liquid helium which shows direct experimental confirmation that electrons may have fractional principal quantum energy levels [6],

7.) the observation of novel EUV emission lines from microwave discharges of argon or helium with 10% hydrogen that matched those predicted for vibrational transitions of H₂*[n=1/4;n*=2]⁺ with energies of ν=1.185 eV, ν=17 to 38 that terminated at the predicted dissociation limit, E_{ν}, of H₂[n=1/4]⁺, E_{D}=42.88 eV (28.92 nm) [9],

8.) the observation of continuum state emission of Cs²⁺ and Ar²⁺ at 53.3 nm and 45.6 nm, respectively, with the absence of the other corresponding Rydberg series of lines from these species which confirmed the resonant nonradiative energy transfer of 27.2 eV from atomic hydrogen to the catalysts atomic Cs or Ar⁺[12],

9.) the spectroscopic observation of the predicted hydride ion H⁻ (1/2) of hydrogen catalysis by either Cs atom or Ar⁺ catalyst at 407 nm corresponding to its predicted binding energy of 3.05 eV [12],

10.) the observation of characteristic emission from K³⁺ which confirmed the resonant nonradiative energy transfer of 3·27.2 eV from atomic hydrogen to atomic K [11],

11.) the spectroscopic observation of the predicted H⁻ (1/4) ion of hydrogen catalysis by K catalyst at 110 nm corresponding to its predicted binding energy of 11.2 eV [11],

12.) the observation of characteristic emission from Rb²⁺ which confirmed the resonant nonradiative energy transfer of 27.2 eV from atomic hydrogen to Rb⁺[10],

13.) the spectroscopic observation of the predicted H⁻ (1/2) ion of hydrogen catalysis by Rb⁺ catalyst at 407 nm corresponding to its predicted binding energy of 3.05 eV [10],

14.) the observation by the Institut f\O(u,^{\ddot{}})r Niedertemperatur-Plasmaphysik e.V. of an anomalous plasma and plasma afterglow duration formed with hydrogen-potassium mixtures [23],

15.) the observation of anomalous afterglow durations of plasmas formed by catalysts providing a net enthalpy of reaction within thermal energies of m·27.28 eV [23-24],

16.) the observation of Lyman series in the EUV that represents an energy release about 10 times that of hydrogen combustion which is greater than that of any possible known possible chemical reaction [7-14, 20-24],

17.) the observation of line emission by the institut f\O(u,^{\ddot{}})r Niedertemperatur-Plasmaphysik e.V. with a 4° grazing incidence EUV spectrometer that was 100 times more energetic than the combustion of hydrogen [22],

18.) the observation of anomalous plasmas formed with Sr and Ar⁺ catalysts at 1% of the theoretical or prior known voltage requirement with a light output per unit power input up to 8600 times that of the control standard light source [13-14, 19-20],

19.) the observation that the optically measured output power of gas cells for power supplied to the glow discharge increased by over two orders of magnitude depending on the presence of less than 1% partial pressure of certain catalysts in hydrogen gas or argon-hydrogen gas mixtures, and an excess thermal balance of 42 W was measured for the 97% argon and 3% hydrogen mixture versus argon plasma alone [19],

20.) the observation that glow discharge plasmas of the catalyst-hydrogen mixtures of strontium-hydrogen, helium-hydrogen, argon-hydrogen, strontium-helium-hydrogen, and strontium-argon-hydrogen showed significant Balmer α line broadening corresponding to an average hydrogen atom temperature of 25-45 eV; whereas, plasmas of the noncatalyst-hydrogen mixtures of pure hydrogen, krypton-hydrogen, xenon-hydrogen, and magnesium-hydrogen showed no excessive broadening corresponding to an average hydrogen atom temperature of ≈3 eV [17-18],

21.) the observation that microwave helium-hydrogen and argon-hydrogen plasmas having catalyst Ar⁺ or He²⁺ showed extraordinary Balmer α line broadening due to hydrogen catalysis corresponding to an average hydrogen atom temperature of 110-130 eV and 180-210 eV, respectively; whereas, plasmas of pure hydrogen, neon-hydrogen, krypton-hydrogen, and xenon-hydrogen showed no excessive broadening corresponding to an average hydrogen atom temperature of ≈3 eV [8, 17],

22.) the observation that microwave helium-hydrogen and argon-hydrogen plasmas showed average electron temperatures that were high, 28,000 K and 11,600 K, respectively; whereas, the corresponding temperatures of helium and argon alone were only 6800 K and 4800 K, respectively [8, 17],

23.) the observation that the power output exceeded the power supplied to a hydrogen glow discharge plasmas by 35-184 W depending on the presence of catalysts helium or argon and less than 1% partial pressure of strontium metal in noble gas-hydrogen mixtures; whereas, the chemically similar noncatalyst krypton had no effect on the power balance [18],

24.) the Calvet calorimetry measurement of an energy balance of over −151,000 kJ/mole H₂ with the addition of 3% hydrogen to a plasma of argon having the catalyst Ar⁺ compared to the enthalpy of combustion of hydrogen of −241.8 kJ/mole H₂; whereas, under identical conditions no change in the Calvet voltage was observed when hydrogen was added to a plasma of noncatalyst krypton [15],

25.) the observation that upon the addition of 10% hydrogen to a helium microwave plasma maintained with a constant microwave input power of 40 W, the thermal output power was measured to be at least 400 W corresponding to a reactor temperature rise from room temperature to 1200° C. within 150 seconds, a power density of 40 MW/m³, and an energy balance of at least −5×10⁵ kJ/mole H₂ compared to the enthalpy of combustion of hydrogen of −241.8 kJ/mole H₂ [16],

26.) the differential scanning calorimetry (DSC) measurement of minimum heats of formation of KHI by the catalytic reaction of K with atomic hydrogen and KI that were over 31 2000 kJ/mole H₂ compared to the enthalpy of combustion of hydrogen of −241.8 kJ/mole H₂ [31],

27.) the isolation of novel hydrogen compounds as products of the reaction of atomic hydrogen with atoms and ions which formed an anomalous plasma as reported in the EUV studies [25-31],

28.) the identification of novel hydride compounds by a number of analytic methods as shown in Table 1 such as (i) time of flight secondary ion mass spectroscopy which showed a dominant hydride ion in the negative ion spectrum, (ii) X-ray photoelectron spectroscopy which showed novel hydride peaks and significant shifts of the core levels of the primary elements bound to the novel hydride ions, (iii) ¹H nuclear magnetic resonance spectroscopy (NMR) which showed extraordinary upfield chemical shifts compared to the NMR of the corresponding ordinary hydrides, and (iv) thermal decomposition with analysis by gas chromatography, and mass spectroscopy which identified the compounds as hydrides [25-31],

29.) the NMR identification of novel hydride compounds MH*X wherein M is the alkali or alkaline earth metal, X, is a halide, and H* comprises a novel high binding energy hydride ion identified by a large distinct upfield resonance [25-30],

30.) the replication of the NMR results of the identification of novel hydride compounds by large distinct upfield resonances at Spectral Data Services, University of Massachusetts Amherst, University of Delaware, Grace Davison, and National Research Council of Canada [25],

31.) the NMR identification of novel hydride compounds MH* and MH₂* wherein M is the alkali or alkaline earth metal and H* comprises a novel high binding energy hydride ion identified by a large distinct upfield resonance that proves the hydride ion is different from the hydride ion of the corresponding known compound of the same composition [25].

5.1.1 References

1. R. Mills, The Grand Unified Theory of Classical Quantum Mechanics, January 2000 Edition, BlackLight Power, Inc., Cranbury, N.J., Distributed by Amazon.com; posted at www.blacklightpower.com.

2. R. Mills, “The Grand Unified Theory of Classical Quantum Mechanics”, Global Foundation, Inc. Orbis Scientiae entitled The Role of Attractive and Repulsive Gravitational Forces in Cosmic Acceleration of Particles The Origin of the Cosmic Gamma Ray Bursts, (29th Conference on High Energy Physics and Cosmology Since 1964) Dr. Behram N. Kursunoglu, Chairman, Dec. 14-17, 2000, Lago Mar Resort, Fort Lauderdale, Fla.

3. R. Mills, “The Grand Unified Theory of Classical Quantum Mechanics”, Global Foundation, Inc. Orbis Scientiae entitled The Role of Attractive and Repulsive Gravitational Forces in Cosmic Acceleration of Particles The Origin of the Cosmic Gamma Ray Bursts, (29th Conference on High Energy Physics and Cosmology Since 1964) Dr. Behram N. Kursunoglu, Chairman, Dec. 14-17, 2000, Lago Mar Resort, Fort Lauderdale, Fla., Kluwer Academic/Plenum Publishers, New York, pp. 243-258.

4. R. Mills, “The Grand Unified Theory of Classical Quantum Mechanics”, Int. J. of Hydrogen Energy, in press.

5. R. Mills, “The Hydrogen Atom Revisited”, Int. J. of Hydrogen Energy, Vol. 25, Issue 12, December, (2000), pp. 1171-1183.

6. R. Mills, The Nature of Free Electrons in Superfluid Helium—a Test of Quantum Mechanics and a Basis to Review its Foundations and Make a Comparison to Classical Theory, Int. J. Hydrogen Energy, Vol. 26, No. 10, (2001), pp. 1059-1096.

7. R. Mills, P. Ray, “Spectral Emission of Fractional Quantum Energy Levels of Atomic Hydrogen from a Helium-Hydrogen Plasma and the Implications for Dark Matter”, Int. J. Hydrogen Energy, in press.

8. R. L. Mills, P. Ray, B. Dhandapani, J. He, “Spectroscopic Identification of Fractional Rydberg States of Atomic Hydrogen” J. Phys. Chem. Letts., submitted.

9. R. Mills, P. Ray, “Vibrational Spectral Emission of Fractional-Principal-Quantum-Energy-Level Hydrogen Molecular Ion”, Int. J. Hydrogen Energy, in press.

10. R. L. Mills, P. Ray, “Spectroscopic Identification of a Novel Catalytic Reaction of Rubidium Ion with Atomic Hydrogen and the Hydride Ion Product”, Int. J. Hydrogen Energy, submitted.

11. R. Mills, P. Ray, Spectroscopic Identification of a Novel Catalytic Reaction of Potassium and Atomic Hydrogen and the Hydride Ion Product, Int. J. Hydrogen Energy, in press.

12. R. Mills, “Spectroscopic Identification of a Novel Catalytic Reaction of Atomic Hydrogen and the Hydride Ion Product”, Int. J. Hydrogen Energy, Vol. 26, No. 10, (2001), pp. 1041-1058.

13. R. Mills and M. Nansteel, “Argon-Hydrogen-Strontium Plasma Light Source”, IEEE Transactions on Plasma Science, submitted.

14. R. Mills, M. Nansteel, and Y. Lu, “Excessively Bright Hydrogen-Strontium Plasma Light Source Due to Energy Resonance of Strontium with Hydrogen”, European Journal of Physics D, submitted.

15. R. Mills, J. Dong, W. Good, P. Ray, J. He, B. Dhandapani, Measurement of Energy Balances of Noble Gas-Hydrogen Discharge Plasmas Using Calvet Calorimetry, Int. J. Hydrogen Energy, submitted.

16. Randell L. Mills, P. Ray, B. Dhandapani, M. Nansteel, X. Chen, J. He, “New Power Source from Fractional Quantum Energy Levels of Atomic Hydrogen that Surpasses Internal Combustion”, Spectrochimica Acta, in progress.

17. R. L. Mills, P. Ray, B. Dhandapani, J. He, “Comparison of Excessive Balmer α Line Broadening of Glow Discharge and Microwave Hydrogen Plasmas with Certain Catalysts” J. Phys. Chem., submitted.

18. R. L. Mills, A. Voigt, P. Ray, M. Nansteel, B. Dhandapani, “Measurement of Hydrogen Balmer Line Broadening and Thermal Power Balances of Noble Gas-Hydrogen Discharge Plasmas”, Int. J. Hydrogen Energy, submitted.

19. R. Mills, N. Greenig, S. Hicks, “Optically Measured Power Balances of Anomalous Discharges of Mixtures of Argon, Hydrogen, and Potassium, Rubidium, Cesium, or Strontium Vapor”, Int. J. Hydrogen Energy, submitted.

20. R. Mills, M. Nansteel, and Y. Lu, “Observation of Extreme Ultraviolet Hydrogen Emission from Incandescently Heated Hydrogen Gas with Strontium that Produced an Anomalous Optically Measured Power Balance”, Int. J. Hydrogen Energy, Vol. 26, No. 4, (2001), pp. 309-326.

21. R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943.

22. R. Mills, “Observation of Extreme Ultraviolet Emission from Hydrogen-KI Plasmas Produced by a Hollow Cathode Discharge”, Int. J. Hydrogen Energy, Vol. 26, No. 6, (2001), pp. 579-592.

23. R. Mills, “Temporal Behavior of Light-Emission in the Visible Spectral Range from a Ti-K2CO3-H-Cell”, Int. J. Hydrogen Energy, Vol. 26, No. 4, (2001), pp. 327-332.

24. R. Mills, T. Onuma, and Y. Lu, “Formation of a Hydrogen Plasma from an Incandescently Heated Hydrogen-Catalyst Gas Mixture with an Anomalous Afterglow Duration”, Int. J. Hydrogen Energy, Vol. 26, No. 7, July, (2001), pp. 749-762.

25. R. Mills, B. Dhandapani, M. Nansteel, J. He, A. Voigt, “Identification of Compounds Containing Novel Hydride Ions by Nuclear Magnetic Resonance Spectroscopy”, Int. J. Hydrogen Energy, Vol. 26, No. 9, Sep. (2001), pp. 965-979.

26. R. Mills, B. Dhandapani, N. Greenig, J. He, “Synthesis and Characterization of Potassium Iodo Hydride”, Int. J. of Hydrogen Energy, Vol. 25, Issue 12, December, (2000), pp. 1185-1203.

27. R. Mills, “Novel Inorganic Hydride”, Int. J. of Hydrogen Energy, Vol. 25, (2000), pp. 669-683.

28. R. Mills, “Novel Hydrogen Compounds from a Potassium Carbonate Electrolytic Cell”, Fusion Technology, Vol. 37, No. 2, March, (2000), pp. 157-182.

29. R. Mills, B. Dhandapani, M. Nansteel, J. He, T. Shannon, A. Echezuria, “Synthesis and Characterization of Novel Hydride Compounds”, Int. J. of Hydrogen Energy, Vol. 26, No. 4, (2001), pp. 339-367.

30. R. Mills, “Highly Stable Novel Inorganic Hydrides”, Journal of Materials Research, submitted.

31. R. Mills, W. Good, A. Voigt, Jinquan Dong, “Minimum Heat of Formation of Potassium Iodo Hydride”, Int. J. Hydrogen Energy, Vol. 26, No. 11, Oct., (2001), pp. 1199-1208.

32. R. Mills, “BlacIcLight Power Technology—A New Clean Hydrogen Energy Source with the Potential for Direct Conversion to Electricity”, Proceedings of the National Hydrogen Association, 12 th Annual U.S. Hydrogen Meeting and Exposition, Hydrogen: The Common Thread, The Washington Hilton and Towers, Washington D.C., (Mar. 6-8, 2001), pp. 671-697.

33. R. Mills, “BlackLight Power Technology—A New Clean Energy Source with the Potential for Direct Conversion to Electricity”, Global Foundation International Conference on “Global Warming and Energy Policy”, Dr. Behram N. Kursunoglu, Chairman, Fort Lauderdale, Fla., Nov. 26-28, 2000, Kluwer Academic/Plenum Publishers, New York, pp. 1059-1096.

5.2 New Power Source from Fractional Quantum Energy Levels of Atomic Hydrogen that Surpasses Internal Combustion

5.2.1 Introduction

From a solution of a Schrodinger-type wave equation with a nonradiative boundary condition based on Maxwell's equations, Mills predicts that atomic hydrogen may undergo a catalytic reaction with certain atomized elements and ions which singly or multiply ionize at integer multiples of the potential energy of atomic hydrogen, m·27.2 eV wherein m is an integer [1, 6-28]. The reaction involves a nonradiative energy transfer to form a hydrogen atom that is lower in energy than unreacted atomic hydrogen that corresponds to a fractional principal quantum number

$$( n = \frac{1}{p} = \frac{1}{integer}$$

replaces the well known parameter n=integer in the Rydberg equation for hydrogen excited states). One such atomic catalytic system involves helium ions because the second ionization energy of helium is 54.417 eV, which is equivalent to m=2. In this case, the catalysis reaction is

$$54.417 eV + {He}^{+} + H [ {a}_{H} ] -> {He}^{2 +} + {ⅇ}^{-} + H [ \frac{{a}_{H}}{3} ] + 108.8 eV \qquad ( 1 )$$

He²⁺+e⁻→He⁺+54.417 eV (2)

And, the overall reaction is

$$H [ {a}_{H} ] -> H [ \frac{{a}_{H}}{3} ] + 54.4 eV + 54.4 eV \qquad ( 3 )$$

Since the products of the catalysis reaction have binding energies of m·27.2 eV, they may further serve as catalysts. Thus, further catalytic transitions may occur:

$$n = \frac{1}{3} -> \frac{1}{4} , \frac{1}{4} -> \frac{1}{5} ,$$

and so on. In this process called disproportionation, lower-energy hydrogen atoms, hydrinos, can act as catalysts because each of the metastable excitation, resonance excitation, and ionization energy of a hydrino atom is m·27.2 eV. The transition reaction mechanism of a first hydrino atom affected by a second hydrino atom involves the resonant coupling between the atoms of m degenerate multipoles each having 27.21 eV of potential energy [1, 6-28]. The energy transfer of m·27.2 eV from the first hydrino atom to the second hydrino atom causes the central field of the first atom to increase by m and its electron to drop m levels lower from a radius of

$$\frac{{a}_{H}}{p}$$

to a radius of

$$\frac{{a}_{H}}{p + m} .$$

The second interacting lower-energy hydrogen is either excited to a metastable state, excited to a resonance state, or ionized by the resonant energy transfer.

The resonant transfer may occur in multiple stages. For example, a nonradiative transfer by multipole coupling may occur wherein the central field of the first increases by m, then the electron of the first drops m levels lower from a radius of

$$\frac{{a}_{H}}{p}$$

to a radius of

$$\frac{{a}_{H}}{p + m}$$

with further resonant energy transfer. The energy transferred by multipole coupling may occur by a mechanism that is analogous to photon absorption involving an excitation to a virtual level. Or, the energy transferred by multipole coupling during the electron transition of the first hydrino atom may occur by a mechanism that is analogous to two photon absorption involving a first excitation to a virtual level and a second excitation to a resonant or continuum level [29-31]. The transition energy greater than the energy transferred to the second hydrino atom may appear as a photon in a vacuum medium.

The transition of

$$H [ \frac{{a}_{H}}{p} ] to H [ \frac{{a}_{H}}{p + m} ]$$

induced by a multipole resonance transfer of m·27.21 eV and a transfer of [(p′)²−(p′−m′)²]X 13.6 eV−m·27.2 eV with a resonance state of

$$H [ \frac{{a}_{H}}{{p}^{′} - {m}^{′}} ]$$

excited in

$$H [ \frac{{a}_{H}}{{p}^{′}} ]$$

is represented by

$$H [ \frac{{a}_{H}}{{p}^{′}} ] + H [ \frac{{a}_{H}}{p} ] \to H [ \frac{{a}_{H}}{{p}^{′} - {m}^{′}} ] + H [ \frac{{a}_{H}}{p + m} ] + [ ( {( p + m )}^{2} - {p}^{2} ) - ( {p}^{′2} - {( {p}^{′} - {m}^{′} )}^{2} ) ] X 13.6 eV \qquad ( 4 )$$

where p, p′, m, and m′ are integers.

Hydrinos may be ionized during a disproportionation reaction by the resonant energy transfer. A hydrino atom with the initial lower-energy state quantum number p and radius

$$\frac{{a}_{H}}{p}$$

may undergo a transition to the state with lower-energy state quantum number (p+m) and radius

$$\frac{{a}_{H}}{( p + m )}$$

by reaction with a hydrino atom with the initial lower-energy state quantum number m′, initial radius

$$\frac{{a}_{H}}{{m}^{′}} ,$$

and final radius a_{H} that provides a net enthalpy of m·27.2 eV. Thus, reaction of hydrogen-type atom,

$$H [ \frac{{a}_{H}}{p} ] ,$$

with the hydrogen-type atom,

$$H [ \frac{{a}_{H}}{{m}^{′}} ] ,$$

that is ionized by the resonant energy transfer to cause a transition reaction is represented by

$$\begin{matrix}m X 27.21 eV + H [ \frac{{a}_{H}}{{m}^{′}} ] + H [ \frac{{a}_{H}}{p} ] \to {H}^{+} + {e}^{-} + H [ \frac{{a}_{H}}{( p + m )} ] + [ {( p + m )}^{2} - {p}^{2} - ( {m}^{′2} - 2 m ) ] X 13.6 eV & ( 5 ) \\ {H}^{+} + {e}^{-} \to H [ \frac{{a}_{H}}{1} ] + 13.6 eV & ( 6 )\end{matrix}$$

And, the overall reaction is

$$H [ \frac{{a}_{H}}{{m}^{′}} ] + H [ \frac{{a}_{H}}{p} ] \to H [ \frac{{a}_{H}}{1} ] + H [ \frac{{a}_{H}}{( p + m )} ] + [ 2 p m + {m}^{2} - {m}^{′2} ] X 13.6 eV + 13.6 eV \qquad ( 7 )$$

It is further proposed that the photons that arise from hydrogen catalysis may undergo inelastic helium scattering. That is, the catalytic reaction

$$H [ {a}_{H} ] {⟶}^{{He}^{+}} H [ \frac{{a}_{H}}{3} ] + 54.4 eV + 54.4 eV \qquad ( 8 )$$

yields two 54.4 eV photons (22.8 nm). When each of these photons strikes He (1 s²), 21.2 eV is absorbed in the excitation to He (1s¹2p¹). This leaves a 33.19 eV (37.4 nm) photon peak shown in Table 1. Thus, for helium the inelastic scattered peak of 54.4 eV photons from Eq. (3) is given by

E=54.4 eV−21.21 eV=33.19 eV (37.4 nm) (9)

The general reaction is

photon (hv)+He (1s²)→He (1s¹2p¹)+photon (hv−21.21 eV) (10)

A number of independent experimental observations lead to the conclusion that atomic hydrogen can exist in fractional quantum states that are at lower energies than the traditional “ground” (n=1) state. Prior related studies that support the possibility of a novel reaction of atomic hydrogen which produces a chemically generated or assisted plasma and produces novel hydride compounds include extreme ultraviolet (EUV) spectroscopy [7-12, 15-19], characteristic emission from catalysis and the hydride ion products [9-10], lower-energy hydrogen emission [5, 7-8], plasma formation [9-12, 15-16, 18-19], Balmer α line broadening [13], anomalous plasma afterglow duration [18-19], power generation [11-15,26], and analysis of chemical compounds [20-26]. We report that microwave and glow discharges of helium-hydrogen mixtures were studied by extreme ultraviolet (EUV) spectroscopy to search for hydrino lines. Since the corresponding electronic transitions are very energetic, Balmer α line broadening was anticipated and was measured. Since the second ionization energy of He⁺ is an exact multiple of the potential energy of atomic hydrogen and microwave plasmas may have significant concentrations of He⁺ as well as atomic hydrogen, fast kinetics observable as heat may be possible. Thus, power balances of microwave plasmas of helium-hydrogen mixtures were also measured.

5.2.2 Experimental

Summary

Extreme ultraviolet (EUV) spectroscopy was recorded on microwave discharges of helium with 2% hydrogen. Novel emission lines were observed with energies of q·13.6 eV where q=1,2,3,4,6,7,8,9, or 11 or these lines inelastically scattered by helium atoms wherein 21.2 eV was absorbed in the excitation of He (1s²) to He (1s¹2p¹). These lines were identified as hydrogen transitions to electronic energy levels below the “ground” state corresponding to fractional quantum numbers. Significant line broadening corresponding to an average hydrogen atom temperature of 33-38 eV was observed for helium-hydrogen discharge plasmas; whereas, pure hydrogen showed no excessive broadening corresponding to an average hydrogen atom temperature of ≈3 eV. Since a significant increase in ion temperature was observed with helium-hydrogen discharge plasmas, and energetic hydrino lines were observed at short wavelengths in the corresponding microwave plasmas that required a very significant reaction rate due to low photon detection efficiency in this region, the power balance was measured on the helium-hydrogen microwave plasmas. With a microwave input power of 30 W, the thermal output power was measured to be at least 300 W corresponding to a reactor temperature rise from room temperature to 900° C. within 90 seconds, a power density of 30 MW/m³, and an energy balance of about −4×10⁵ kJ/mole H₂ compared to the enthalpy of combustion of hydrogen of −241.8 kJ/mole H₂.

5.2.2.1 EUV Spectroscopy

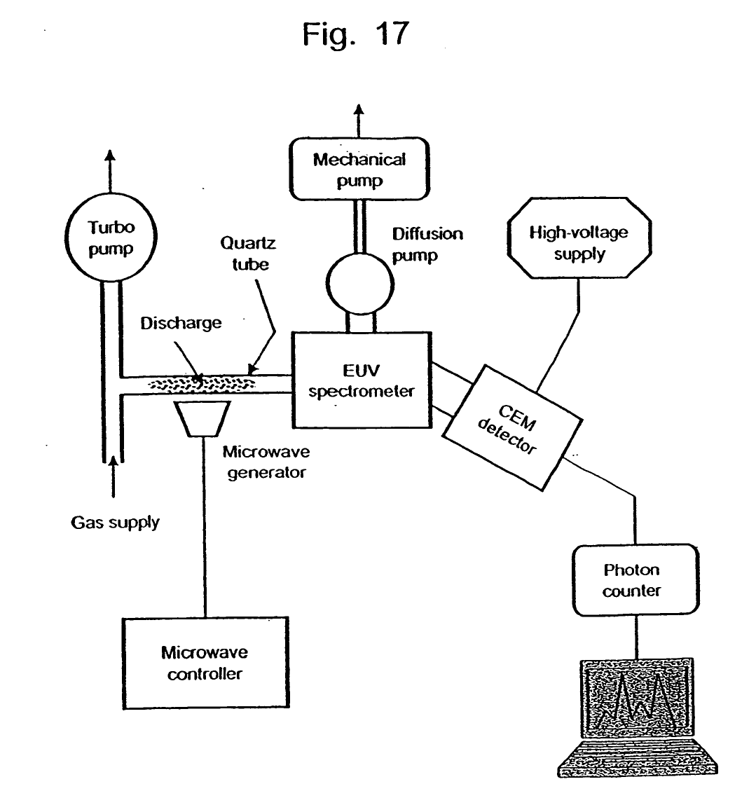

EUV spectroscopy was recorded on hydrogen, helium, and helium-hydrogen (98/2%) microwave and glow discharge plasmas according to the methods given previously [7]. The glow discharge experimental set up was given previously [7]. The microwave experimental set up comprising a microwave discharge gas cell light source and an EUV spectrometer which was differentially pumped is shown in FIG. 17. Helium-hydrogen (98/2%) gas mixture was flowed through a half inch diameter quartz tube at 1 torr, 20 torr, or 760 torr. The gas pressure inside the cell was maintained by flowing the mixture while monitoring the pressure with a 10 torr and 1000 torr MKS Baratron absolute pressure gauge. By the same method, the hydrogen alone and helium alone plasmas were run at 20 torr. The tube was fitted with an Opthos coaxial microwave cavity (Evenson cavity). The microwave generator was a Opthos model MPG-4M generator (Frequency: 2450 MHz). The input power to the plasma was set at 85 watts with air cooling of the cell.

The spectrometer was a normal incidence McPherson 0.2 meter monochromator (Model 302, Seya-Namioka type) equipped with a 1200 lines/mm holographic grating with a platinum coating. The wavelength region covered by the monochromator was 5-560 nm. The EUV spectrum was recorded with a channel electron multiplier (CEM) at 2500-3000 V. The wavelength resolution was about 0.02 nm (FWHM) with an entrance and exit slit width of 50 μm. The increment was 0.2 nm and the dwell time was 500 ms. Novel peak positions were based on a calibration against the known He I and He II lines.

To achieve higher sensitivity at the shorter EUV wavelengths, the light emission from a helium microwave plasma and a glow discharge plasma of a helium-hydrogen mixture (98/2%) maintained according to the methods given previously [7] were recorded with a McPherson 4° grazing incidence EUV spectrometer (Model 248/310G) equipped with a grating having 600 G/mm with a radius of curvature of ≈1 m. The angle of incidence was 87°. The wavelength region covered by the monochromator was 5-65 nm. The wavelength resolution was about 0.04 nm (FWHM) with an entrance and exit slit width of 300 μm. A channel electron multiplier (CEM) at 2400 V was used to detect the EUV light. The increment was 0.1 nm and the dwell time was 1 s.

5.2.2.2 Line Broadening Measurements

The width of the 656.2 nm Balmer α line emitted from gas glow discharge plasmas having atomized hydrogen from pure hydrogen alone or with a mixture of 10% hydrogen and helium at 2 torr total pressure was measured according to the methods given previously [11]. The plasmas were maintained in a cylindrical stainless steel gas cell (9.21 cm in diameter and 14.5 cm in height) with an axial hollow cathode glow discharge electrode assembly comprised a stainless steel plate (4.2 cm diameter, 0.9 mm thick) anode and a circumferential stainless steel cylindrical frame (5.1 cm OD, 7.2 cm long) perforated with evenly spaced 1 cm diameter holes. The emission was viewed normal to the cell axis through a 1.6 mm thick UV-grade sapphire window with a 1.5 cm view diameter. The discharge was carried out under static gas conditions with a DC voltage of about 275 V which produced about 0.2 A of current. The plasma emission from the glow discharges was fiber-optically coupled through a 220 F matching fiber adapter to a high resolution visible spectrometer with a resolution of ±0.025 nm over the spectral range 190-860 nm. The entrance and exit slits were set to 20 μm. The spectrometer was scanned between 656-657 nm using a 0.01 nm step size. The signal was recorded by a PMT with a stand alone high voltage power supply (950 V) and an acquisition controller. The data was obtained in a single accumulation with a 1 second integration time.

5.2.2.3 Power Balance Measurements

The power balances of microwave plasmas of helium, krypton, and xenon alone and each noble gas with 10% hydrogen were determined by heat loss calorimetry [32] in the cell described in section A except that the cell was not air cooled. A K-type thermocouple (±0.1° C.) housed in a stainless steel tube was placed axially inside the center of the 10 cm³ plasma volume of the quartz microwave cell. The thermocouple was read with a multichannel computer data acquisition system. The gas in each case was ultrahigh purity grade or higher. The gas pressure inside the cell was maintained at about 300 mtorr with a noble gas flow rate of 9.3 sccm or an noble gas flow rate of 8.3 sccm and a hydrogen flow rate of 1 sccm. Each gas flow was controlled by a 0-20 sccm range mass flow controller (MKS 1179A21CS1BB) with a readout (MKS type 246). The cell pressure was monitored by a 0-10 torr MKS Baratron absolute pressure gauge.

No increase in temperature was observed when 10% hydrogen was added to krypton or xenon plasmas. In contrast, with the addition of 10% hydrogen to a helium plasma, the quartz wall was observed to melt in about 90 seconds unless the power was 30 W or less. Whereas, the helium alone plasma at 60 W input had a maximum temperature rise above room temperature, ΔT, of 178° C. at 90 seconds. Thus, to achieve a higher control ΔT to give greater analytical accuracy, the temperature rise of the inside of the cell was measured for 90 seconds with helium at 60 W input. The input power was stopped, and a cooling curve was measured. Then the experiment was repeated with the addition of 10% hydrogen to the helium run at only 30 W to prevent the cell from melting. In additional controls, noncatalysts krypton or xenon replaced helium.

5.2.3 Results and Discussion

5.2.3.1 EUV Spectroscopy

The EUV emission was recorded from microwave and glow discharge plasmas of hydrogen, helium, and helium with 2% hydrogen over the wavelength range 5-125 nm. In the case of hydrogen, no peaks were observed below 78 nm, and no spurious peaks or artifacts due to the grating or the spectrometer were observed. Only known He I and He II peaks were observed in the EUV spectra of the control helium microwave or glow discharge cell emission.

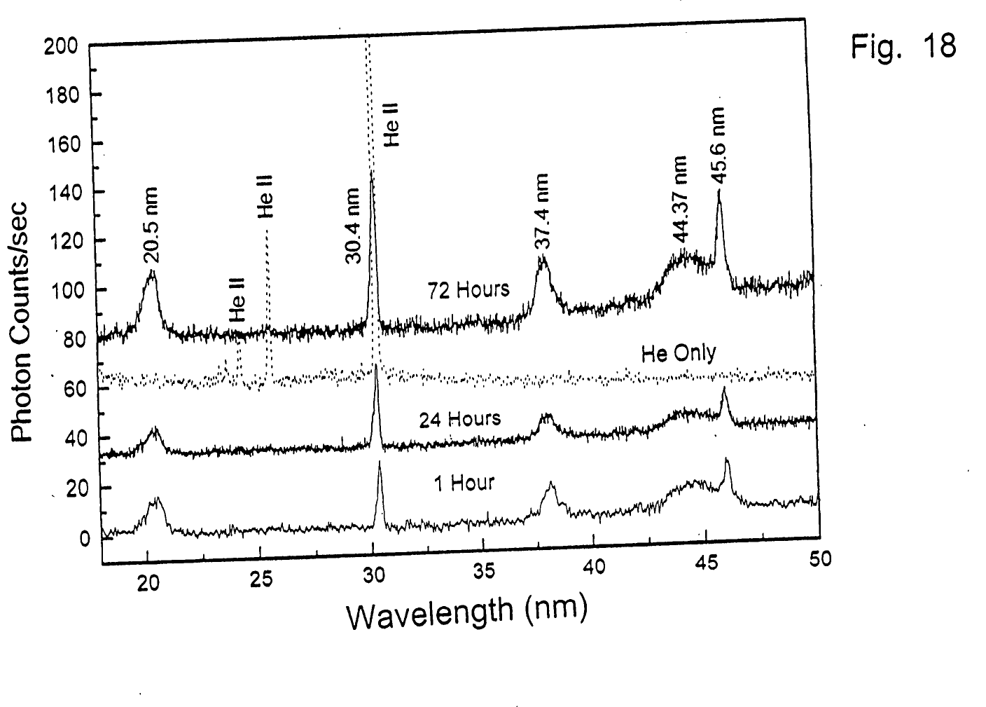

The EUV spectra (15-50 nm) of the microwave cell emission of the helium-hydrogen mixture (98/2%) that was recorded at 1, 24, and 72 hours and the helium control (dotted curve) is shown in FIG. 18. Ordinary hydrogen has no emission in these regions. Peaks observed at 45.6 nm, 37.4 nm, and 20.5 nm which do not correspond to helium and increased with time were assigned to lower-energy hydrogen transitions in Table 1. The lines that corresponded to hydrogen transitions to lower electronic energy levels were not observed in the helium control. The pressure was increased from 20 torr to 760 torr. The peaks appeared slightly more intense at the lower pressure; so, the pressure was decreased to 1 torr and spectra were recorded.

TABLE 1
Observed line emission from helium-hydrogen plasmas assigned to the dominant
disproportionation reactions given by Eqs. (4-7) and helium inelastic scattered peaks of
hydrogen transitions, wherein the photon strikes He (1s²) and 21.2 e V is
absorbed in the excitation to He (1s¹2p¹).

| Observed | Predicted | | |
|---|---|---|---|
| Line | (Mills) | Assignment | Figure |
| (nm) | (nm) | (Mills) | # |
| 8.29 | 8.29 | $H [ \frac{{a}_{H}}{3} ] + H [ \frac{{a}_{H}}{3} ] \to H [ \frac{{a}_{H}}{5} ] + H [ \frac{{a}_{H}}{2} ] + 149.6 eV$ | 19 |
| 10.13 | 10.13 | $H [ \frac{{a}_{H}}{2} ] + H [ \frac{{a}_{H}}{2} ] \to H [ \frac{{a}_{H}}{4} ] + H [ {a}_{H} ] + 122.4 eV$ | 19 |
| 13.03^{a} | 13.03 | $H [ \frac{{a}_{H}}{3} ] + H [ \frac{{a}_{H}}{3} ] \to H [ \frac{{a}_{H}}{5} ] + {H}^{+} + {e}^{-} + 95.2 eV$ | 19 |
| 14.15 | 14.15 | $\begin{matrix}H [ \frac{{a}_{H}}{2} ] + H [ \frac{{a}_{H}}{2} ] \to H [ \frac{{a}_{H}}{4} ] + {H}^{+} + {e}^{-} + 108.8 eV \\ 108.8 eV + He ( 1 {s}^{2} ) \to He ( 1 {s}^{1} 2 {p}^{1} ) \to + 87.59 eV\end{matrix}$ | 19 |
| 20.5 | 20.5 | $\begin{matrix}H [ \frac{{a}_{H}}{4} ] + H [ \frac{{a}_{H}}{2} ] \to H [ \frac{{a}_{H}}{5} ] + H [ {a}_{H} ] + 81.6 eV \\ 81.6 eV + He ( 1 {s}^{2} ) \to He ( 1 {s}^{1} 2 {p}^{1} ) \to + 60.39 eV\end{matrix}$ | 18, 19 |
| 30.4 | 30.4 | $H [ \frac{{a}_{H}}{3} ] + H [ \frac{{a}_{H}}{2} ] \to H [ \frac{{a}_{H}}{4} ] + {H}^{+} + {e}^{-} + 40.8 eV$ | 18, 19 |
| 30.4 | 30.4 | He⁺(n = 2) → He⁺(n = 1) + 40.8 ev^{b} | 18, 19 |
| 37.4 | 37.4 | $\begin{matrix}H [ {a}_{H} ] {\to }^{ {He}^{+} } H [ \frac{{a}_{H}}{3} ] + 54.4 eV + 54.4 eV \\ 54.4 eV + He ( 1 {s}^{2} ) \to He ( 1 {s}^{1} 2 {p}^{1} ) \to + 33.19 eV\end{matrix}$ | 18, 19 |
| 45.6 | 45.6 | $H [ \frac{{a}_{H}}{3} ] + H [ \frac{{a}_{H}}{3} ] \to H [ \frac{{a}_{H}}{4} ] + H [ \frac{{a}_{H}}{2} ] + 27.2 eV$ | 18, 19 |
| 58.4 | 58.4 | He (1s¹2p¹) → He (1s²) + 21.2 eV^{c} | 20 |
| 63.3 | 63.3 | $\begin{matrix}H [ \frac{{a}_{H}}{3} ] + H [ \frac{{a}_{H}}{2} ] \to H [ \frac{{a}_{H}}{4} ] + {H}^{+} + {e}^{-} + 40.8 eV \\ 40.8 eV + He ( 1 {s}^{2} ) \to He ( 1 {s}^{1} 2 {p}^{1} ) \to + 19.59 eV\end{matrix}$ | 20 |
| 63.3 | 63.3 | $\begin{matrix}{He}^{+} ( n = 2 ) \to {He}^{+} ( n = 1 ) + 40.8 {eV}^{b} \\ 40.8 eV + He ( 1 {s}^{2} ) \to He ( 1 {s}^{1} 2 {p}^{1} ) \to + 19.59 eV\end{matrix}$ | 20 |
| 91.2 | 91.2 | $H [ \frac{{a}_{H}}{2} ] + H [ \frac{{a}_{H}}{2} ] \to H [ \frac{{a}_{H}}{3} ] + {H}^{+} + {e}^{-} + 13.6 eV$ | 21 |
| 91.2 | 91.2 | H⁺ + e⁻ → H[a_{H}] + 13.6 eV^{d} | 22 |

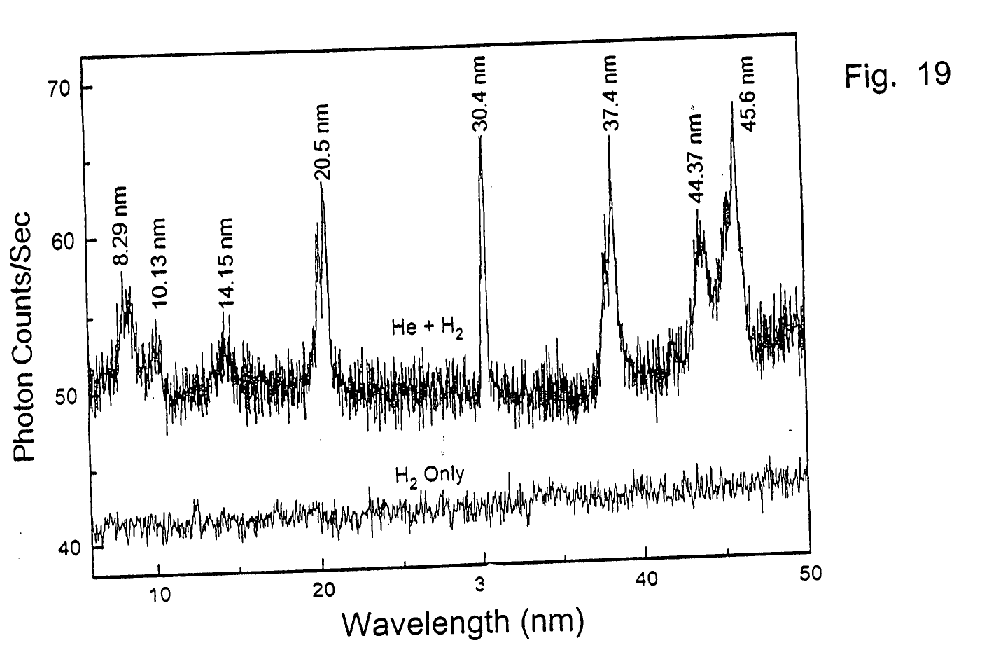

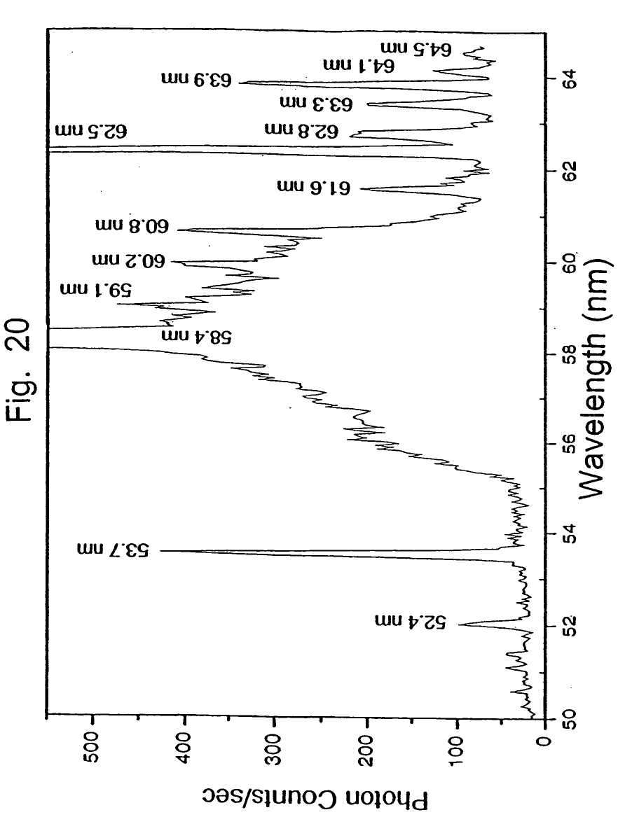

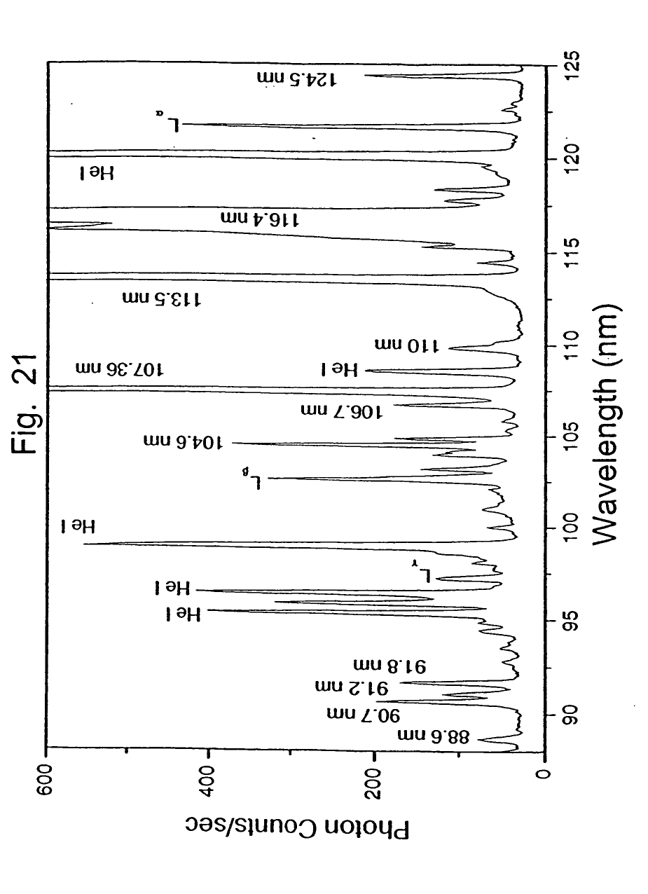

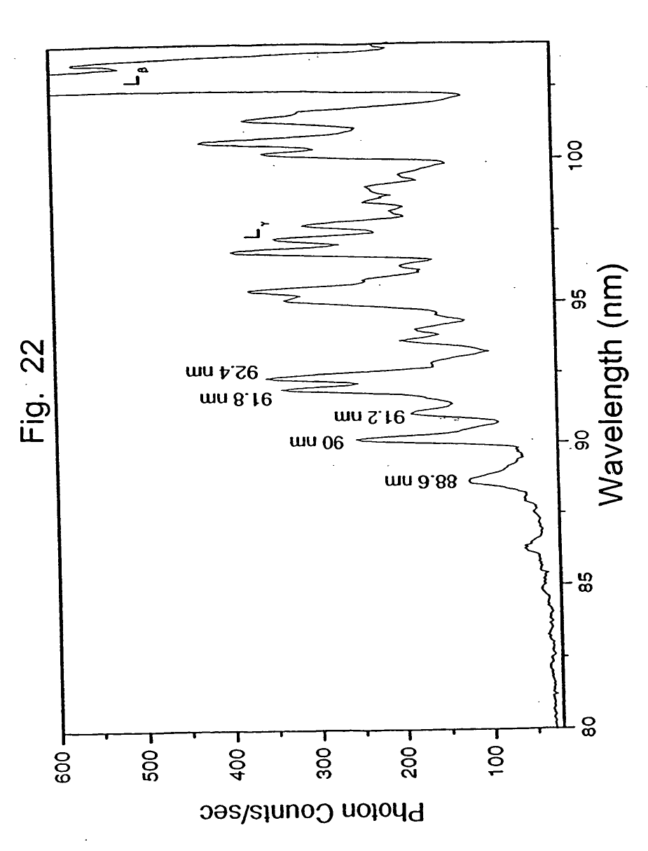

^{a}Weak shoulder on the 14.15 nm peak.
^{b}In FIGS. 18 and 19, the peak corresponding to He⁺(n = 3) = He⁺(n = 1) + 48.35 eV (25.6 nm )was absent which makes this assignment difficult.
^{c}The intensity was 56,771 photons/sec in FIG. 20; thus, the transition He (1s²) → He (1s¹2p¹) dominated the inelastic scattering of EUV peaks.
^{d}The ratio of the Lβ peak to the 91.2 nm peak of the helium-hydrogen plasma shown in FIG. 21 was 2; whereas, the ratio of the Lβ peak to the 91.2 nm peak of the control hydrogen plasma shown in FIG. 22, was 8 which makes this assignment difficult.

At the 1 torr condition, additional novel peaks were observed in the short wavelength region. The short wavelength EUV spectrum (5-50 nm) of the control hydrogen microwave cell emission (bottom curve) is shown in FIG. 19. No spectrometer artifacts were observed at the short wavelengths. The short wavelength EUV spectrum (5-50 nm) of the helium-hydrogen mixture (98/2%) microwave cell emission with a pressure of 1 torr (top curve) is also shown in FIG. 19. Peaks observed at 14.15 nm, 13.03 nm, 10.13 nm, and 8.29 nm which do not correspond to helium were assigned to lower-energy hydrogen transitions in Table 1. It is also proposed that the 30.4 nm peak shown in FIGS. 18 and 19 was not entirely due to the He II transition. In the case of helium-hydrogen mixture, conspicuously absent was the 25.6 nm (48.3 eV) line of He II shown in FIG. 18 which implies only a minor He II transition contribution to the 30.4 nm peak.

A novel 63.3 nm peak was observed in the EUV spectrum (50-65 nm) of the helium-hydrogen mixture (98/2%) glow discharge cell emission shown in FIG. 20. It is proposed that the 63.3 nm peak arises from inelastic helium scattering of the 30.4 nm peak. That is, the

$$\frac{1}{3} \to \frac{1}{4}$$

transition yields a 40.8 eV photon (30.4 nm). When this photon strikes He (1 s²), 21.2 eV is absorbed in the excitation to He (1 s¹2p¹). This leaves a 19.6 eV (63.3 nm) photon and a 21.2 eV (58.4 nm) photon from He (1 s¹2p¹). The intensity of the 58.4 nm shown in FIG. 20 was off-scale with 56,771 photons/sec. Thus, the transition He (1 s²)→He (1 s¹2p¹) dominated the inelastic scattering of EUV peaks. For the first nine peaks assigned as lower-energy hydrogen transitions or such transitions inelastically scattered by helium, the agreement between the predicted values and the experimental values shown in Table 1 is remarkable. It is also remarkable that the hydrino lines are moderately intense based on the low grating efficiency at these short wavelengths.

As shown in FIGS. 21 and 22, the ratio of the Lβ peak to the 91.2 nm peak of the helium-hydrogen microwave plasma was 2; whereas, the ratio of the Lβ peak to the 91.2 nm peak of the control hydrogen microwave plasma was 8 which indicates that the majority of the 91.2 nm peak was due to a transition other than the binding of an electron by a proton. Based on the intensity, it is proposed that the majority of the 91.2 nm peak was due to the

$$\frac{1}{2} \to \frac{1}{4}$$

transition given in Table 1.

The energies for the hydrogen transitions given in Table 1 in order of energy are 13.6 eV, 27.2 eV, 40.8 eV, 54.4 eV, 81.6 eV, 95.2 eV, 108.8 eV, 122.4 eV and 149.6 eV. The corresponding peaks are 91.2 nm, 45.6 nm, 30.4 nm with 63.3 nm, 37.4 nm, 20.5 nm, 13.03 nm, 14.15 nm, 10.13 nm, and 8.29 nm, respectively. Thus, the lines identified as hydrogen transitions to electronic energy levels below the “ground” state corresponding to fractional quantum numbers correspond to energies of q·13.6 eV where q=1,2,3,4,6,7,8,9, or 11 or these lines inelastically scattered by helium atoms wherein 21.2 eV was absorbed in the excitation of He (1 s²) to He (1 s¹2p¹). All other peaks besides those assigned to lower-energy hydrogen transitions could be assigned to He I, He II, second order lines, or atomic or molecular hydrogen emission. No known lines of helium or hydrogen explain the q·13.6 eV related set of peaks. Given that these spectra are readily repeatable, these peaks may have been overlooked in the past without considering the role of the helium scattering.

5.2.3.2 Line Broadening Measurements

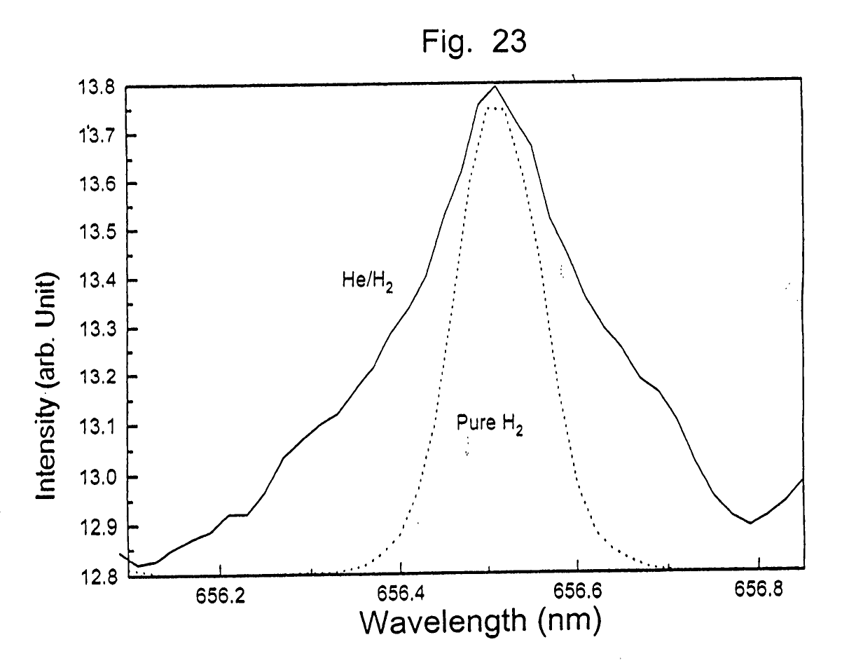

The results of the 656.2 nm Balmer α line width measured with a high resolution (±0.025 nm) visible spectrometer on glow discharge plasmas having atomized hydrogen from pure hydrogen alone and helium-hydrogen (90/10%) is given in FIG. 23. Using the method of Kuraica and Konjevic [33] and Videnocic et al. [34], the energetic hydrogen atom densities and energies were calculated. It was found that helium-hydrogen showed significant broadening corresponding to an average hydrogen atom temperature of 33-38 eV and an atom density of 3×10 atoms 1 cm³; whereas, pure hydrogen showed no excessive broadening corresponding to an average hydrogen atom temperature of ≧3 eV and an atom density of only 5×10³ atoms/cm³ ever though 10 times more hydrogen was present.

5.2.3.3 Power Balance Measurements

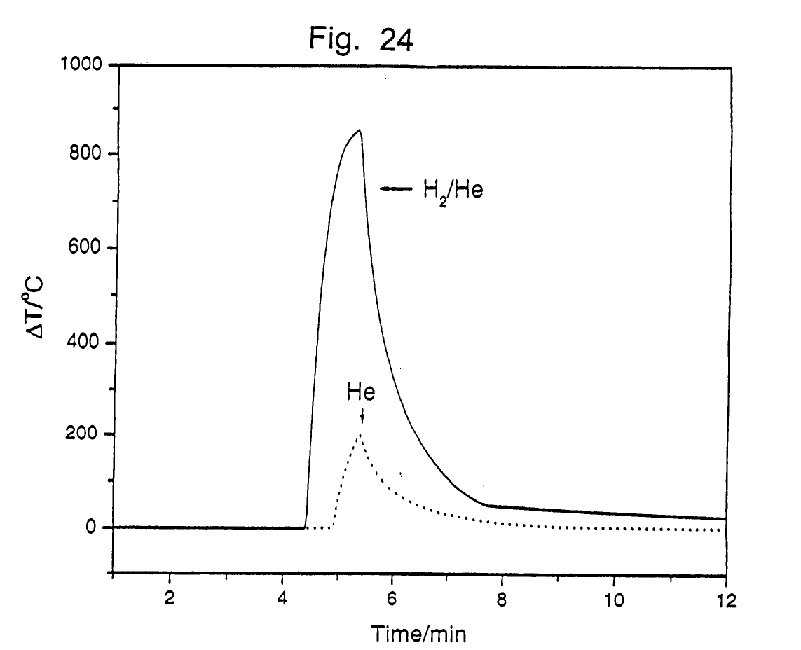

Since a significant increase in ion temperature was observed with helium-hydrogen discharge plasmas, and energetic hydrino lines were observed at short wavelengths in the corresponding microwave plasmas that required a very significant reaction rate due to low photon detection efficiency in this region, the power balance was measured on the helium-hydrogen microwave plasmas by heat loss calorimetry [32]. No increase in temperature with the addition of hydrogen to xenon was observed. In contrast, a remarkable temperature increase was observed when hydrogen was added to the helium microwave plasma. The temperature rise as a function of time for helium alone and the helium-hydrogen mixture (90/10%) is shown in FIG. 24. The microwave input power to the helium alone was set at 60 W, and the input power to the helium-hydrogen mixture was 30 W. In both cases, the constant microwave input was maintained for 90 seconds and then terminated. The cooling curves were then recorded.

A conservative measure of the total output power was determined by taking the ratio of the areas of the helium-hydrogen temperature-rise-above-ambient-versus-time curve compared to that of helium only normalized by the ratio of the input powers. The ratio of the areas was determined to be about a factor of 10. The reactor volume was 10 cm³ and the hydrogen flow rate was 1 sccm. Thus, with a microwave input power of 30 W, the thermal output power was measured to be at least 300 W corresponding to a reactor temperature rise from room temperature to 900° C. within 90 seconds, a power density of over 30 MW/m³, and an energy balance of over −4×10⁵ kJ/mole H₂ compared to the enthalpy of combustion of hydrogen of −241.8 kJ/mole H₂.

A more accurate measure was determined by modeling the heat flow from the quartz reactor wherein the parameters of the model were taken from the Newton cooling curves. Consider a small heat increment.

dQₜ=Pₒᵤₜdt=dQₘ+dQₗ=CdTₕ−CdT_{c} (11)

where Qₜ is the total heat, Qₘ is the measured heat, Qₗ is the lost heat, Pₒᵤₜ is the power output, t is time, C is the system heat capacity, dTₕ is the temperature rise due to heating, and dT_{c} is the temperature drop due to cooling (dT_{c} is negative). The system heat capacity is a function of temperature, and at a given temperature, the power output can be expressed by the following equation,

$${P}_{out} = C ( \frac{ⅆ {T}_{h}}{ⅆ t} - \frac{ⅆ {T}_{c}}{ⅆ t} ) \qquad ( 12 )$$

The slopes dTₕ/dt and dT_{c}/dt can be calculated from the heating and cooling curves, respectively. Assuming that, at a given temperature, the heat capacities of the two systems (system 1: helium alone; system 2: helium-hydrogen) are the same, C₁═C₂, then the power ratio can be calculated by

$$R = \frac{{P}_{out , 2}}{{P}_{out , 1}} = \frac{( \frac{ⅆ {T}_{h , 2}}{ⅆ t} - \frac{ⅆ {T}_{c , 2}}{ⅆ t} )}{( \frac{ⅆ {T}_{h , 1}}{ⅆ t} - \frac{ⅆ {T}_{c , 1}}{ⅆ t} )} \qquad ( 13 )$$

The slopes of the heating and cooling curves were calculated using the experimental data presented in FIG. 24. The power ratios were calculated by Eq. (13) in the temperature range ΔT=50-150° C., where ΔT was the difference between the plasma temperature and the room temperature, 24° C. The calculated results are given in Table 2. The average power ratio is R=5.35 with a standard deviation of 0.23. The following power balance existed in the microwave plasma systems,

Pₒᵤₜ=Pᵢₙ+Pₑₓ (14)

where Pᵢₙ was the input power and Pₑₓ was the excess power. For the helium plasma, there was no excess power, P_{ex,1}=0, P_{in,1}=60 W. Therefore, at microwave input power of 30 W, the thermal output power was measured to be P_{out,2}=321±14 W corresponding to an excess power of 291±14 W and an unoptimized gain of about 11 times the input power.

TABLE 2
Calculation of Power Ratios between Helium-Hydrogen and
Helium Plasmas.

| ΔT | dT_{h,1}/dt | dT_{c,1}/dt | dT_{h,2}/dt | dT_{c,2}/dt | Power Ratio, |
|---|---|---|---|---|---|
| (° C.) | (° C./sec) | (° C./sec) | (° C./sec) | (° C./sec) | R |
| 50 | 10.731 | −0.800 | 55.951 | −0.989 | 4.938 |
| 60 | 9.801 | −1.004 | 54.893 | −1.118 | 5.183 |
| 70 | 9.020 | −1.255 | 53.874 | −1.266 | 5.367 |
| 80 | 8.354 | −1.549 | 52.892 | −1.433 | 5.486 |
| 90 | 7.779 | −1.876 | 51.946 | −1.619 | 5.548 |
| 100 | 7.279 | −2.216 | 51.032 | −1.819 | 5.566 |
| 110 | 6.839 | −2.551 | 50.150 | −2.025 | 5.557 |
| 120 | 6.449 | −2.879 | 49.299 | −2.222 | 5.523 |
| 130 | 6.101 | −3.235 | 48.475 | −2.390 | 5.448 |
| 140 | 5.789 | −3.716 | 47.679 | −2.507 | 5.280 |
| 150 | 5.507 | −4.561 | 46.908 | −2.555 | 4.913 |

5.2.4 Conclusion

We report that extreme ultraviolet (EUV) spectroscopy was recorded on microwave and glow discharges of helium with 2% hydrogen. Novel emission lines were observed with energies of q·13.6 eV where q=1,2,3,4,6,7,8,9, or 11 or these lines inelastically scattered by helium atoms wherein 21.2 eV was absorbed in the excitation of He (1 s²) to He (1 s¹2p¹). These lines were identified as hydrogen transitions to electronic energy levels below the “ground” state corresponding to fractional quantum numbers. In glow discharge plasmas, an average hydrogen atom temperature of 33-38 eV was observed by line broadening with the presence of helium ion catalyst with hydrogen; whereas, pure hydrogen plasmas showed no excessive broadening corresponding to an average hydrogen atom temperature of ≈3 eV.

Excess thermal power of about 300 W and a gain of over an order of magnitude was observed from helium-hydrogen microwave plasmas. The power from the catalytic reaction of helium ions with atomic hydrogen corresponded to a volumetric power density of over 30 MW/m³ which is about 100 times that of many coal fired electric power plants, and rivals some internal combustion engines. In addition, the presently observed and previously reported energy balances [13-14] were over 100 eV/H atom which matched the present and previously reported EUV emission that corresponded to over 100 eV/H atom [7-9, 17]. Since the net enthalpy released is at least 100 times that of combustion, the catalysis of atomic hydrogen represents a new source of energy with H₂O as the source of hydrogen fuel. Moreover, rather that air pollutants or radioactive waste, novel hydride compounds with potential commercial applications are the products [20-26]. Since the power is in the form of a plasma that may form at room temperature, high-efficiency, low cost direct energy conversion may be possible, thus, avoiding heat engines such as turbines and the severe limitations of fuel cells [27-28]. Significantly lower capital costs and lower commercial operating costs than that of any known competing energy source are anticipated.

5.2.5 References

1. R. Mills, The Grand Unified Theory of Classical Quantum Mechanics, January 2000 Edition, BlackLight Power, Inc., Cranbury, N.J., Distributed by Amazon.com; posted at www.blacklightpower.com.

2. R. Mills, “The Grand Unified Theory of Classical Quantum Mechanics”, Global Foundation, Inc. Orbis Scientiae entitled The Role of Attractive and Repulsive Gravitational Forces in Cosmic Acceleration of Particles The Origin of the Cosmic Gamma Ray Bursts, (29th Conference on High Energy Physics and Cosmology Since 1964) Dr. Behram N. Kursunoglu, Chairman, Dec. 14-17, 2000, Lago Mar Resort, Fort Lauderdale, Fla.

3. R. Mills, “The Grand Unified Theory of Classical Quantum Mechanics”, Global Foundation, Inc. Orbis Scientiae entitled The Role of Attractive and Repulsive Gravitational Forces in Cosmic Acceleration of Particles The Origin of the Cosmic Gamma Ray Bursts, (29th Conference on High Energy Physics and Cosmology Since 1964) Dr. Behram N. Kursunoglu, Chairman, Dec. 14-17, 2000, Lago Mar Resort, Fort Lauderdale, Fla., Kluwer Academic/Plenum Publishers, New York, pp. 243-258.

4. R. Mills, “The Grand Unified Theory of Classical Quantum Mechanics”, Int. J. of Hydrogen Energy, in press.

5. R. Mills, “The Hydrogen Atom Revisited”, Int. J. of Hydrogen Energy, Vol. 25, Issue 12, December, (2000), pp. 1171-1183.

6. R. Mills, The Nature of Free Electrons in Superfluid Helium—a Test of Quantum Mechanics and a Basis to Review its Foundations and Make a Comparison to Classical Theory, Int. J. Hydrogen Energy, Vol. 26, No. 10, (2001), pp. 1059-1096.

7. R. Mills, P. Ray, “Spectral Emission of Fractional Quantum Energy Levels of Atomic Hydrogen from a Helium-Hydrogen Plasma and the Implications for Dark Matter”, Int. J. Hydrogen Energy, in press.

8. R. Mills, P. Ray, “Vibrational Spectral Emission of Fractional-Principal-Quantum-Energy-Level Hydrogen Molecular Ion”, Int. J. Hydrogen Energy, in press.

9. R. Mills, P. Ray, Spectroscopic Identification of a Novel Catalytic Reaction of Potassium and Atomic Hydrogen and the Hydride Ion Product, Int. J. Hydrogen Energy, in press.

10. R. Mills, “Spectroscopic Identification of a Novel Catalytic Reaction of Atomic Hydrogen and the Hydride Ion Product”, Int. J. Hydrogen Energy, Vol. 26, No. 10, (2001), pp. 1041-1058.

11. R. Mills and M. Nansteel, “Argon-Hydrogen-Strontium Plasma Light Source”, IEEE Transactions on Plasma Science, submitted.

12. R. Mills, M. Nansteel, and Y. Lu, “Excessively Bright Hydrogen-Strontium Plasma Light Source Due to Energy Resonance of Strontium with Hydrogen”, European Journal of Physics D, submitted.

13. R. Mills, A. Voigt, P. Ray, M. Nanstell, “Measurement of Hydrogen Balmer Line Broadening and Thermal Power Balances of Noble Gas-Hydrogen Discharge Plasmas”, Int. J. Hydrogen Energy, submitted.

14. R. Mills, N. Greenig, S. Hicks, “Optically Measured Power Balances of Anomalous Discharges of Mixtures of Argon, Hydrogen, and Potassium, Rubidium, Cesium, or Strontium Vapor”, Int. J. Hydrogen Energy, submitted.

15. R. Mills, M. Nansteel, and Y. Lu, “Observation of Extreme Ultraviolet Hydrogen Emission from Incandescently Heated Hydrogen Gas with Strontium that Produced an Anomalous Optically Measured Power Balance”, Int. J. Hydrogen Energy, Vol. 26, No. 4, (2001), pp. 309-326.

16. R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943.

17. R. Mills, “Observation of Extreme Ultraviolet Emission from Hydrogen-KI Plasmas Produced by a Hollow Cathode Discharge”, Int. J. Hydrogen Energy, Vol. 26, No. 6, (2001), pp. 579-592.

18. R. Mills, “Temporal Behavior of Light-Emission in the Visible Spectral Range from a Ti-K2CO3-H-Cell”, Int. J. Hydrogen Energy, Vol. 26, No. 4, (2001), pp. 327-332.

19. R. Mills, T. Onuma, and Y. Lu, “Formation of a Hydrogen Plasma from an Incandescently Heated Hydrogen-Catalyst Gas Mixture with an Anomalous Afterglow Duration”, Int. J. Hydrogen Energy, Vol. 26, No. 7, July, (2001), pp. 749-762.

20. R. Mills, B. Dhandapani, M. Nansteel, J. He, A. Voigt, “Identification of Compounds Containing Novel Hydride Ions by Nuclear Magnetic Resonance Spectroscopy”, Int. J. Hydrogen Energy, Vol. 26, No. 9, Sep. (2001), pp. 965-979.

21. R. Mills, B. Dhandapani, N. Greenig, J. He, “Synthesis and Characterization of Potassium lodo Hydride”, Int. J. of Hydrogen Energy, Vol. 25, Issue 12, December, (2000), pp. 1185-1203.

22. R. Mills, “Novel Inorganic Hydride”, Int. J. of Hydrogen Energy, Vol. 25, (2000), pp. 669-683.

23. R. Mills, “Novel Hydrogen Compounds from a Potassium Carbonate Electrolytic Cell”, Fusion Technology, Vol. 37, No. 2, March, (2000), pp. 157-182.

24. R. Mills, B. Dhandapani, M. Nansteel, J. He, T. Shannon, A. Echezuria, “Synthesis and Characterization of Novel Hydride Compounds”, Int. J. of Hydrogen Energy, Vol. 26, No. 4, (2001), pp. 339-367.

25. R. Mills, “Highly Stable Novel Inorganic Hydrides”, Journal of Materials Research, submitted.

26. R. Mills, W. Good, A. Voigt, Jinquan Dong, “Minimum Heat of Formation of Potassium Iodo Hydride”, Int. J. Hydrogen Energy, Vol. 26, No. 11, Oct., (2001), pp. 1199-1208.

27. R. Mills, “BlackLight Power Technology—A New Clean Hydrogen Energy Source with the Potential for Direct Conversion to Electricity”, Proceedings of the National Hydrogen Association, 12 th Annual U.S. Hydrogen Meeting and Exposition, Hydrogen: The Common Thread, The Washington Hilton and Towers, Washington D.C., (Mar. 6-8, 2001), pp. 671-697.

28. R. Mills, “BlackLight Power Technology—A New Clean Energy Source with the Potential for Direct Conversion to Electricity”, Global Foundation International Conference on “Global Warming and Energy Policy”, Dr. Behram N. Kursunoglu, Chairman, Fort Lauderdale, Fla., Nov. 26-28, 2000, Kluwer Academic/Plenum Publishers, New York, pp. 1059-1096.

29. B. J. Thompson, Handbook of Nonlinear Optics, Marcel Dekker, Inc., New York, (1996), pp. 497-548.

30. Y. R. Shen, The Principles of Nonlinear Optics, John Wiley & Sons, New York, (1984), pp. 203-210.

31. B. de Beauvoir, F. Nez, L. Julien, B. Cagnac, F. Biraben, D. Touahri, L. Hilico, O. Acef, A. Clairon, and J. J. Zondy, Physical Review Letters, Vol. 78, No. 3, (1997), pp. 440-443.

32. C. Chen, T. Wei, L. R. Collins, and J. Phillips, “Modeling the discharge region of a microwave generated hydrogen plasma”, J. Phys. D: Appl. Phys., Vol. 32, (1999), pp. 688-698.

33. M. Kuraica, N. Konjevic, “Line shapes of atomic hydrogen in a plane-cathode abnormal glow discharge”, Physical Review A, Volume 46, No. 7, October (1992), pp. 4429-4432.

34. I. R. Videnoc\O(i,′)c, N. Konjev\O(i,′)c, M. M. Kuraica, “Spectroscopic investigations of a cathode fall region of the Grimm-type glow discharge”, Spectrochimica Acta, Part B, Vol. 51, (1996), pp. 1707-1731.

5.3 Comparison of Excessive Balmer α Line Broadening of Glow Discharge and Microwave Hvdrogen Plasmas with Certain Catalysts

Summary

The width of the 656.2 nm Balmer α line emitted from microwave and glow discharge plasmas of hydrogen alone, strontium or magnesium with hydrogen, or helium, neon, argon, or xenon with 10% hydrogen was recorded with a high resolution visible spectrometer. It was found that the strontium-hydrogen microwave plasma showed a broadening similar to that observed in the glow discharge cell of 27-33 eV; whereas, in both sources, no broadening was observed for magnesium-hydrogen. With noble-gas hydrogen mixtures, the trend of broadening with the particular noble gas was the same for both sources, but the magnitude of broadening was dramatically different. The microwave helium-hydrogen and argon-hydrogen plasmas showed extraordinary broadening corresponding to an average hydrogen atom temperature of 110-130 eV and 180-210 eV, respectively. The corresponding results from the glow discharge plasmas were 30-35 eV and 33-38 eV, respectively. Whereas, plasmas of pure hydrogen, neon-hydrogen, krypton-hydrogen, and xenon-hydrogen maintained in either source showed no excessive broadening corresponding to an average hydrogen atom temperature of ≈4 eV. In the case of the helium-hydrogen mixture and argon-hydrogen mixture microwave plasmas, the electron temperature T_{c} was measured from the ratio of the intensity of the He 501.6 nm line to that of the He 492.2 line and the ratio of the intensity of the Ar 104.8 nm line to that of the Ar 420.06 nm line, respectively. Similarly, the average electron temperature for helium-hydrogen and argon-hydrogen plasmas were high, 28,000 K and 11,600 K, respectively; whereas, the corresponding temperatures of helium and argon alone were only 6800 K and 4800 K, respectively. Stark broadening or acceleration of charged species due to high fields (e.g. over 10 kV/cm) can not be invoked to explain the microwave results since no high field was observationally present. Rather, the results may be explained by a resonant energy transfer between atomic hydrogen and atomic strontium, Ar⁺, or He⁺ which ionize at an integer multiple of the potential energy of atomic hydrogen.

5.3.1 Introduction

Glow discharge devices have been developed over decades as light sources, ionization sources for mass spectroscopy, excitation sources for optical spectroscopy, and sources of ions for surface etching and chemistry [1-3]. A Grimm-type glow discharge is a well established excitation source for the analysis of conducting solid samples by optical emission spectroscopy [4-6]. Despite extensive performance characterizations, data was lacking on the plasma parameters of these devices. M. Kuraica and N. Konjevic [7] and Videnovic et al. [8] have characterized these plasmas by determining the excited hydrogen atom concentrations and energies from measurements of the line broadening of the 656.2 nm Balmer α line. The data was analyzed in terms of Stark and Doppler effects wherein acceleration of charges such as H, H₂⁺, and H₃⁺ in the high fields (e. g. over 10 kV/cm) which were present in the cathode fall region was used to explain the Doppler component.

More recently, microhollow glow discharges have been spectroscopically studied as candidates for the development of an intense monochromatic EUV light source (e.g. Lyman α) for short wavelength lithograph for production of the next generation of integrated circuits. A neon-hydrogen microhollow cathode glow discharge has been proposed as a source of predominantly Lyman α radiation. Kurunczi, Shah, and Becker [9] observed intense emission of Lyman α and Lyman β radiation at 121.6 nm and 102.5 nm, respectively, from microhollow cathode discharges in high-pressure Ne (740 Torr) with the addition of a small amount of hydrogen (up to 3 Torr). With essentially no molecular emission observed, Kurunczi et al. attributed the anomalous Lyman α emission to the near-resonant energy transfer between the Ne₂* excimer and H₂ which leads to formation of H(n=2) atoms, and attributed the Lyman β emission to the near-resonant energy transfer between excited Ne* atoms (or vibrationally excited neon excimer molecules) and H₂ which leads to formation of H(n=3) atoms. Despite the emission characterization of this source, data is lacking about plasma parameters.

For analyses of solids, direct current (dc) glow discharge sources have been successfully complemented by radio-frequency (rf) discharges [10]. The use of dc discharges is limited to metals; whereas, rf discharges are applicable to non-conducting materials. Other developed sources that provide a usefully intense plasma are synchrotron devices, inductively coupled plasma generators [11], and magnetically confined plasmas. Plasma characterization data on these sources is also limited.

A new plasma source has been developed that operates by incandescently heating a hydrogen dissociator and a catalyst to provide atomic hydrogen and gaseous catalyst, respectively, such that the catalyst reacts with the atomic hydrogen to produce a plasma. It was extraordinary, that intense EUV emission was observed by Mills et al. [12-19] at low temperatures (e.g. ≈10³ K ) from atomic hydrogen and certain atomized elements or certain gaseous ions which singly or multiply ionize at integer multiples of the potential energy of atomic hydrogen, 27.2 eV [6-10] that comprise catalysts. The only pure elements that were observed to emit EUV were those wherein the ionization of t electrons from an atom to a continuum energy level is such that the sum of the ionization energies of the t electrons is approximately m·27.2 eV where t and m are each an integer.

Since Ar⁺, He⁺, and strontium each ionize at an integer multiple of the potential energy of atomic hydrogen, a discharge with one or more of these species present with hydrogen is anticipated to form a plasma called a resonance transfer (rt) plasma. The plasma forms by a resonance transfer mechanism involving the species providing a net enthalpy of a multiple of 27.2 eV and atomic hydrogen.

Mills and Nansteel [14, 19] have reported that strontium atoms each ionize at an integer multiple of the potential energy of atomic hydrogen and caused emission. (The enthalpy of ionization of Sr to Sr⁵⁺ has a net enthalpy of reaction of 188.2 eV, which is equivalent to m=7.) The emission intensity of the plasma generated by atomic strontium increased significantly with the introduction of argon gas only when Ar⁺ emission was observed. Whereas, no emission was observed when chemically similar atoms that do not ionize at integer multiples of the potential energy of atomic hydrogen (sodium, magnesium, or barium) replaced strontium with hydrogen, hydrogen-argon mixtures, or strontium alone.

Mills and Nanstell [14, 19] measured the power balance of a gas cell having vaporized strontium and atomized hydrogen from pure hydrogen or argon-hydrogen mixture (77/23%) by integrating the total light output corrected for spectrometer system response and energy over the visible range. Hydrogen control cell experiments were identical except that sodium, magnesium, or barium replaced strontium. In the case of hydrogen-sodium, hydrogen-magnesium, and hydrogen-barium mixtures, 4000, 7000, and 6500 times the power of the hydrogen-strontium mixture was required, respectively, in order to achieve that same optically measured light output power. With the addition of argon to the hydrogen-strontium plasma, the power required to achieve that same optically measured light output power was reduced by a factor of about two. The power required to maintain a plasma of equivalent optical brightness with strontium atoms present was 8600 and 6300 times less than that required for argon-hydrogen and argon control, respectively. A plasma formed at a cell voltage of about 250 V for hydrogen alone and sodium-hydrogen mixtures, 140-150 V for hydrogen-magnesium and hydrogen-barium mixtures, 224 V for an argon-hydrogen mixture, and 190 V for argon alone; whereas, a plasma formed for hydrogen-strontium mixtures and argon-hydrogen-strontium mixtures at extremely low voltages of about 2 V and 6.6 V, respectively.

It was reported [13] that characteristic emission was observed from a continuum state of Ar²⁺ which confirmed the resonant nonradiative energy transfer of 27.2 eV from atomic hydrogen Ar⁺. The transfer of 27.2 eV from atomic hydrogen to Ar⁺ in the presence of a electric weak field resulted in its excitation to a continuum state. Then, the energy for the transition from essentially the Ar²⁺state to the lowest state of Ar⁺ was predicted to give a broad continuum radiation in the region of 45.6 nm. This broad continuum emission was observed. This emission was dramatically different from that given by an argon microwave plasma wherein the entire Rydberg series of lines of Ar⁺ was observed with a discontinuity of the series at the limit of the ionization energy of Ar⁺ to Ar²⁺. The observed Ar⁺ continuum in the region of 45.6 nm confirmed the rt-plasma mechanism of the excessively bright, extraordinarily low voltage discharge. With Ar⁺ as the catalyst, the product hydride ion was predicted to have a binding energy of 3.05 eV, and it was observed spectroscopically at 407 nm [13].

He⁺ ionizes at 54.417 eV which is 2·27.2 eV, and novel EUV emission lines were observed from microwave and glow discharges of helium with 2% hydrogen [20]. The observed energies were q=13.6 eV (q=1,2,3,4,6,7,8,9, or 11) or these energies less 21.2 eV due to inelastic scattering of the lines by helium atoms in the excitation of He (1 s²) to He (1 s¹2p¹). These lines can be explained by the resonance transfer of m·27.2 eV [20].

It was anticipated that microwave and glow discharges would also provide atomic hydrogen and vaporized catalyst to form a rt-plasma. To further characterize the plasma parameters observed in rt-plasmas and to study the difference between microwave and discharge sources, 1.) a comparison between the width of the Lyman α line of an argon-hydrogen plasma emitted from a glow discharge cell and a microwave cell was compared, 2.) by measuring the line broadening of the 656.2 nm Balmer α line, the excited hydrogen atom energy and concentration were determined on plasmas of hydrogen and a catalyst or plasmas comprising hydrogen with chemically similar controls that did not provide gaseous ions having electron ionization energies which are a multiple of 27.2 eV, and 3.) the electron temperature Tₑ was measured on microwave plasmas using the ratio of the intensity I of two noble gas or metal lines in two quantum states such as the ratio I(He 501.6 nm line)/I(He 492.2 nm line) and the ratio I(Ar 104.8 nm line)/I(Ar 420.06 nm line) for plasmas having helium and argon, respectively, alone or as a mixture with hydrogen.

5.3.2 Experimental

5.3.2.1 EUV Spectroscopy

Extreme ultraviolet (EUV) spectroscopy was recorded on microwave and discharge cell light sources. Due to the extremely short wavelength of this radiation, “transparent” optics do not exist. Therefore, a windowless arrangement was used wherein the microwave or discharge cell was connected to the same vacuum vessel as the grating and detectors of the extreme ultraviolet (EUV) spectrometer. Differential pumping permitted a high pressure in the cell as compared to that in the spectrometer. This was achieved by pumping on the cell outlet and pumping on the grating side of the collimator that served as a pin-hole inlet to the optics. The spectrometer was continuously evacuated to 10⁻⁴-10⁻⁶ torr by a turbomolecular pump with the pressure read by a cold cathode pressure gauge. The EUV spectrometer was connected to the cell light source with a 1.5 mm×5 mm collimator which provided a light path to the slits of the EUV spectrometer. The collimator also served as a flow constrictor of gas from the cell. The cell was operated under gas flow conditions while maintaining a constant gas pressure in the cell.

Spectra were obtained on glow discharge and microwave plasmas of an argon-hydrogen mixture (97/3%). Each gas was ultrahigh pure. The gas pressure inside the cell was maintained at about 300 mtorr with an argon flow rate of 5.2 sccm and a hydrogen flow rate of 0.3 sccm. Each gas flow was controlled by a 0-20 sccm range mass flow controller (MKS 1179A21CS1BB) with a readout (MKS type 246).

For spectral measurement, the light emission from discharge and microwave plasmas of argon-hydrogen (97/3%) was introduced to a normal incidence McPherson 0.2 meter monochromator (Model 302, Seya-Namioka type) equipped with a 1200 lines/mm holographic grating with a platinum coating. The wavelength region covered by the monochromator was 5-560 nm. The UV spectrum (100-170 nm) of the cell emission was recorded with a photomultiplier tube (PMT) and a sodium salicylate scintillator. The PMT (Model R1527P, Hamamatsu) used has a spectral response in the range of 185-680 nm with a peak efficiency at about 400 nm. The wavelength resolution was about 1 nm (FWHM) with an entrance and exit slit width of 300 μm. The increment was 0.1 nm and the dwell time was 500 ms.

5.3.2.2 Glow Discharge Emission Spectra

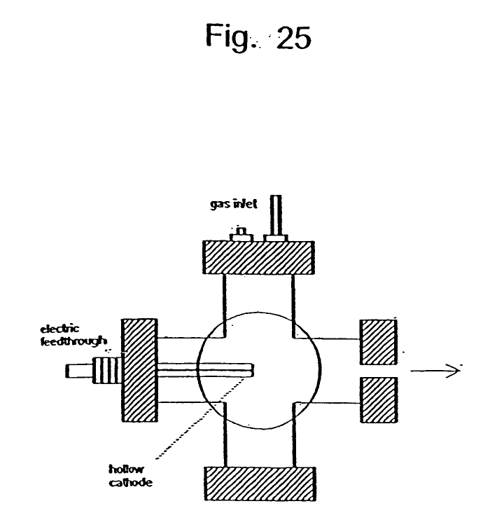

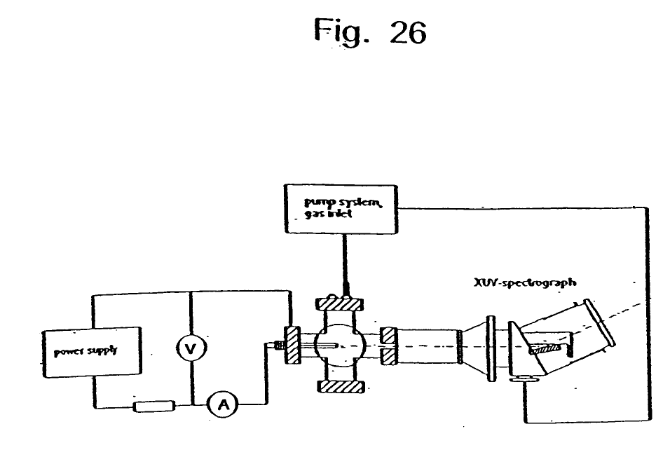

The extreme ultraviolet emission spectrum was obtained on an argon-hydrogen mixture (97/3%) glow discharge plasma. A diagram of the discharge plasma source is given in FIG. 25. The experimental setup for the discharge measurements is illustrated in FIG. 26. The cell comprised a five-way stainless steel cross that served as the anode with a hollow stainless steel cathode. The hollow cathode was constructed of a stainless steel rod inserted into a steel tube, and this assembly was inserted into an Alumina tube. The gas mixture was flowed through the five-way cross. An AC power supply (U=0−1 kV, I=0−100 mA) was connected to the hollow cathode to generate a discharge at the hollow cathode inside the discharge cell. The AC voltage and current at the time the EUV spectrum was recorded were 200 V and 40 mA, respectively. A Swagelok adapter at the very end of the steel cross provided a gas inlet and a connection with the pumping system, and the cell was pumped with a mechanical pump. Valves were between the cell and the mechanical pump, the cell and the monochromator, and the monochromator and its turbo pump. A flange opposite the end of the hollow cathode connected the spectrometer with the cell. It had a small hole that permitted radiation to pass to the spectrometer. The hollow cathode and EUV spectrograph were aligned on a common optical axis using a laser. The light emission was introduced into a normal incidence EUV spectrometer. (See EUV-Spectroscopy section).

5.3.2.3 Microwave Emission Spectra

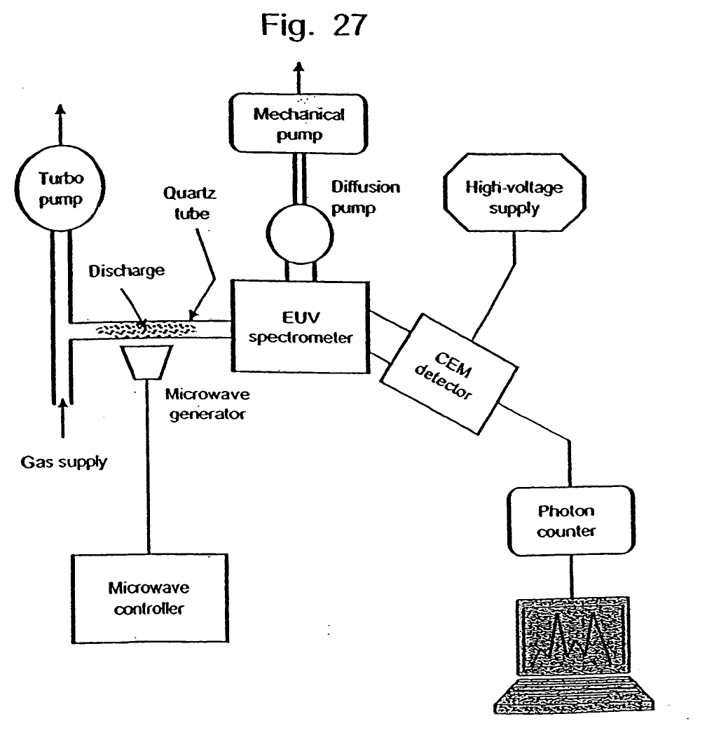

The extreme ultraviolet emission spectrum was obtained on an argon-hydrogen mixture (97/3%) microwave discharge plasma. The experimental set up comprising a microwave discharge gas cell light source and an EUV spectrometer which was differentially pumped is shown in FIG. 27. The gas mixture was flowed through a half inch diameter quartz tube fitted with an Opthos coaxial microwave cavity (Evenson cavity). The microwave generator was a Opthos model MPG-4M generator (Frequency: 2450 MHz). The input power to the plasma was set at 40 watts. The light emission was introduced into a normal incidence EUV spectrometer. (See EUV-Spectroscopy section).

5.3.3.4 Balmer Line Broadening Recorded on Glow Discharge Plasmas

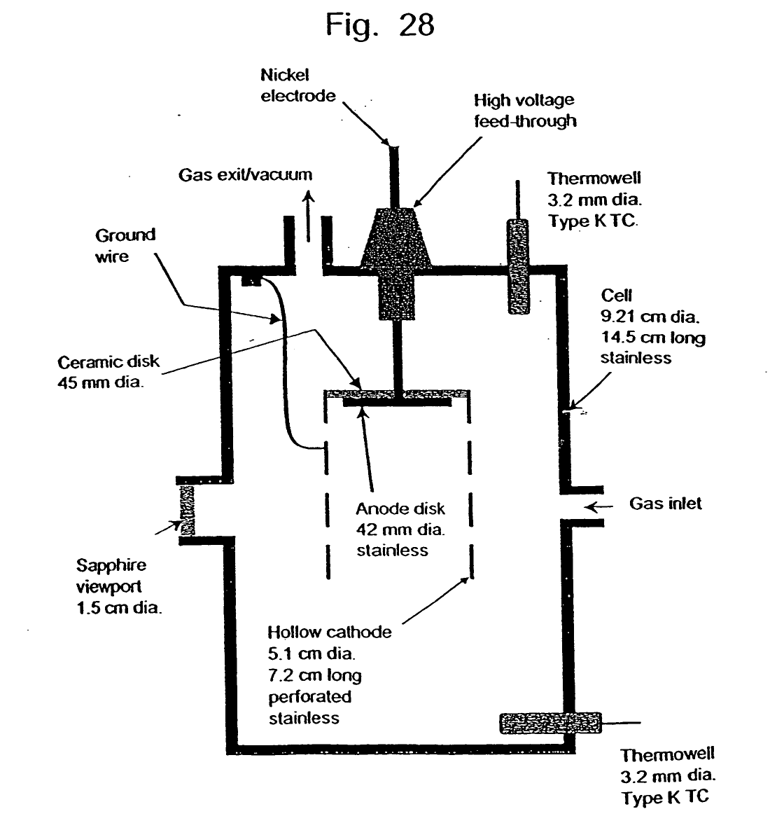

The width of the 656.5 nm Balmer α line emitted from gas discharge plasmas having atomized hydrogen from pure hydrogen alone, strontium or magnesium with hydrogen, and a mixture of 10% hydrogen and helium, argon, neon, krypton, or xenon was measured with a high resolution visible spectrometer with a resolution of ±0.025 nm over the spectral range 190-860 nm. The plasmas were maintained in the cylindrical stainless steel gas cell shown in FIG. 28.

The 304-stainless steel cell cylindrical cell was 9.21 cm in diameter and 14.5 cm in height. The base of the cell contained a welded-in stainless steel thermocouple well (1 cm OD) which housed a thermocouple probe in the cell interior approximately 2 cm from the discharge and 2 cm from the cell axis. The top end of the cell was welded to a high vacuum 11.75 cm diameter conflat flange. A silver plated copper gasket was placed between a mating flange and the cell flange. The two flanges were clamped together with 10 circumferential bolts. The mating flange contained three penetrations comprising 1.) a stainless steel thermocouple well (1 cm OD) also housing a thermocouple probe in the cell interior approximately 2 cm from the discharge and 2 cm from the cell axis, 2.) a centered high voltage feedthrough which transmitted the power, supplied through a power connector, to a hollow cathode inside the cell, and 3.) a stainless steel tube (0.95 cm diameter and 100 cm in length) welded flush with the bottom surface of the top flange that served as a vacuum line from the cell and the line to supply the test gas.

The axial hollow cathode glow discharge electrode assembly comprised a stainless steel plate (42 mm diameter, 0.9 mm thick) anode and a circumferential stainless steel cylindrical frame (5.08 cm OD, 7.2 cm long) perforated with evenly spaced 1 cm diameter holes. The cathode was attached to the cell body by a stainless steel wire, and the cell body was grounded.

A 1.6 mm thick UV-grade sapphire window with 1.5 cm view diameter provided a visible light path from inside the cell. The viewing direction was normal to the cell axis.

The cell was sealed in the glove box, removed, and then evacuated with a turbo vacuum pump to a pressure of 4 mTorr. The gas was ultrahigh purity hydrogen or noble gas-hydrogen mixture (90/10%) at 2 Torr total pressure. The pressure of each test gas comprising a mixture with 10% hydrogen was determined by adding the pure noble gas to a given pressure and increasing the pressure with hydrogen gas to a final pressure. The partial pressure of the hydrogen gas was given by the incremental increase in total gas pressure monitored by a 0-10 Torr absolute pressure gauge. The discharge was carried out under static gas conditions. The discharge was started and maintained by a DC electric field supplied by a constant voltage DC power supply at 275 V which produced a current of about 0.2 A. In the case of strontium-hydrogen, helium-hydrogen, and argon-hydrogen plasmas, the voltage was increased at 50 V increments from 275 V to 475 V, and the high resolution visible spectra were recorded to observe the effect of voltage on the Balmer α line broadening.

The plasma emission from the glow discharges of pure hydrogen, strontium or magnesium with hydrogen, and noble gas-hydrogen mixtures was fiber-optically coupled to the spectrometer through a 220 F matching fiber adapter. The entrance and exit slits were set to 20 μm. The spectrometer was scanned between 656-657 nm using a 0.01 nm step size. The signal was recorded by a PMT with a stand alone high voltage power supply (950 V) and an acquisition controller. The data was obtained in a single accumulation with a 1 second integration time.

5.3.2.5 Balmer Line Broadening Recorded on Microwave Discharge Plasmas

The width of the 656.2 nm Balmer α line emitted from microwave discharges of pure hydrogen alone, strontium or magnesium with hydrogen, and a mixture of 10% hydrogen and helium, argon, neon, krypton, or xenon was measured with a high resolution visible spectrometer. Each pure test gas or mixture was flowed through a half inch diameter quartz tube at 0.3 Torr maintained with a noble gas flow rate of 9.3 sccm or an noble gas flow rate of 8.3 sccm and a hydrogen flow rate of 1 sccm. Each gas flow was controlled by a 0-20 sccm range mass flow controller (MKS 1179A21CS1BB) with a readout (MKS type 246). The cell pressure was monitored by a 0-10 Torr MKS Baratron absolute pressure gauge. Magnesium or strontium was added to the plasma by transferring 50 mg of solid metal into the quartz tube with flowing argon. The plasma discharge partially vaporized the metal during the experiment. The tube was fitted with an Opthos coaxial microwave cavity (Evenson cavity). The microwave generator shown in FIG. 27 was a Opthos model MPG-4M generator (Frequency: 2450 MHz). The input power to the plasma was set at 40 watts with forced air cooling of the cell.

The plasma emission was fiber-optically coupled through a 220 F matching fiber adapter positioned 2 cm from the cell wall to a high resolution visible spectrometer with a resolution of ±0.006 nm over the spectral range 190-860 nm. The spectrometer was a Jobin Yvon Horiba 1250 M with 2400 groves/mm ion-etched holographic diffraction grating. The entrance and exit slits were set to 20 μm. The spectrometer was scanned between 655.5-657 nm using a 0.005 nm step size. The signal was recorded by a PMT with a stand alone high voltage power supply (950 V) and an acquisition controller. The data was obtained in a single accumulation with a 1 second integration time.

5.3.2.6 T_{c} Measurements of Microwave Discharge Plasmas

The experimental set up comprising a microwave discharge gas cell light source and an UV-VIS spectrometer which was differentially pumped is shown in FIG. 27. T_{c} was measured on microwave plasmas of helium alone and helium-hydrogen mixture (90/10%) from the ratio of the intensity of the He 501.6 nm (upper quantum level n=3) line to that of the He 492.2 nm (n=4) line as described by Griem [21]. T_{c} was measured on microwave plasmas of argon alone and argon-hydrogen mixture (90/10%) from the ratio of the intensity of the Ar 104.8 nm (upper quantum level n=3) line to that of the Ar 420.06 nm (n=4) line as described by Griem [21]. T_{c} was also measured by the same method on microwave plasmas of pure hydrogen alone, strontium or magnesium with hydrogen, and a mixture of 10% hydrogen and neon, krypton, or xenon using the ratio of the intensities of two noble gas or alkaline earth metal lines in two quantum states. In each case, the microwave plasma cell was run under the conditions given in section B. The spectrometer was a normal incidence McPherson 0.2 meter monochromator (Model 302, Seya-Namioka type) equipped with a 1200 lines/mm holographic grating with a platinum coating. The wavelength region covered by the monochromator was 2-560 nm. The visible spectra (400-560 nm) of the cell emission was recorded with a photomultiplier tube (PMT) and a sodium salicylate scintillator. The PMT (Model R1527P, Hamamatsu) used has a spectral response in the range of 185-680 nm with a peak efficiency at about 400 nm. The scan interval was 0.4 nm. The inlet and outlet slit were 300 μm with a corresponding wavelength resolution of 2 nm. The spectra were repeated five times per experiment and were found to be reproducible within less than 5%.

5.3.3 Results and Discussion

5.3.3.1 EUV Spectroscopy

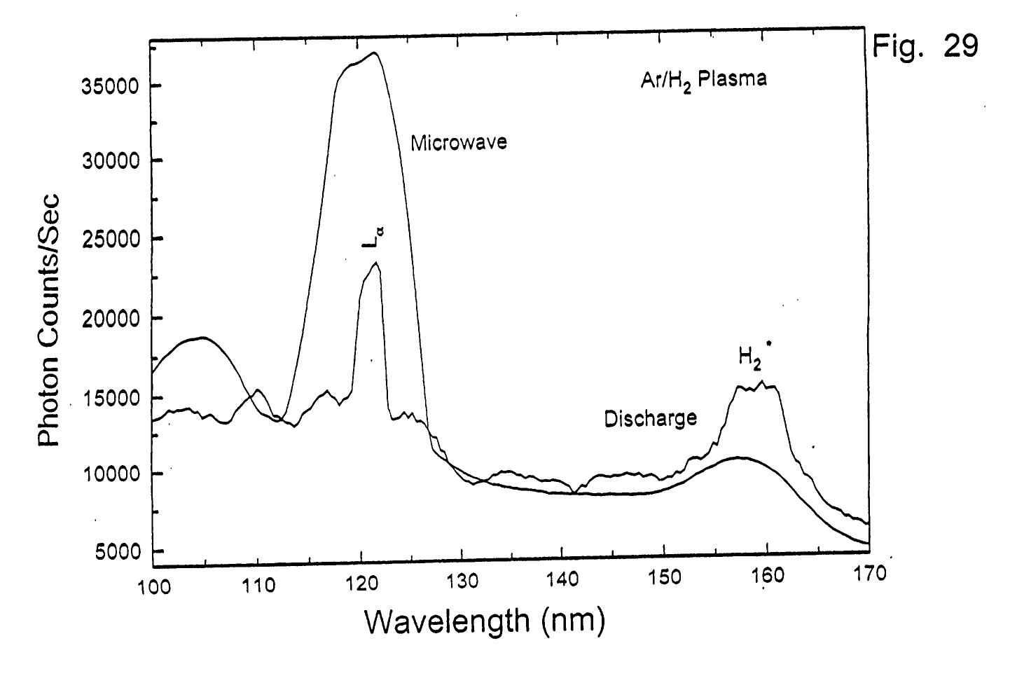

Extreme ultraviolet (EUV) spectroscopy was recorded on microwave and discharge cell light sources to compare Lyman α line widths from the two sources. The EUV spectra (100-170 nm) of emission from the discharge and microwave plasmas of argon-hydrogen mixture (97/3%) are shown in FIG. 29. The microwave plasma showed significant broadening relative to the discharge plasma. The width of the microwave plasma Lyman α line was 10 nm; whereas, the width of the glow discharge plasma Lyman α line was 2.6 nm. In addition, the intensity of the Lyman α emission compared to the molecular hydrogen emission was significantly higher in the case of the microwave plasma. The Lyman α line broadening and increased intensity indicate a much higher ion temperature in the microwave plasma which was confirmed by high resolution measurements of the Balmer α line width which gave quantitative ion temperature measurements reported sections B and C. No electric field was present in the microwave plasmas. Thus, the results can not be explained by Stark broadening or acceleration of charged species due to high fields of over 10 kV/cm as proposed by Videnovic et al. [8] to explain excessive broadening observed in glow discharges.

5.3.3.2 Balmer Line Broadening Recorded n Glow Discharge Plasmas

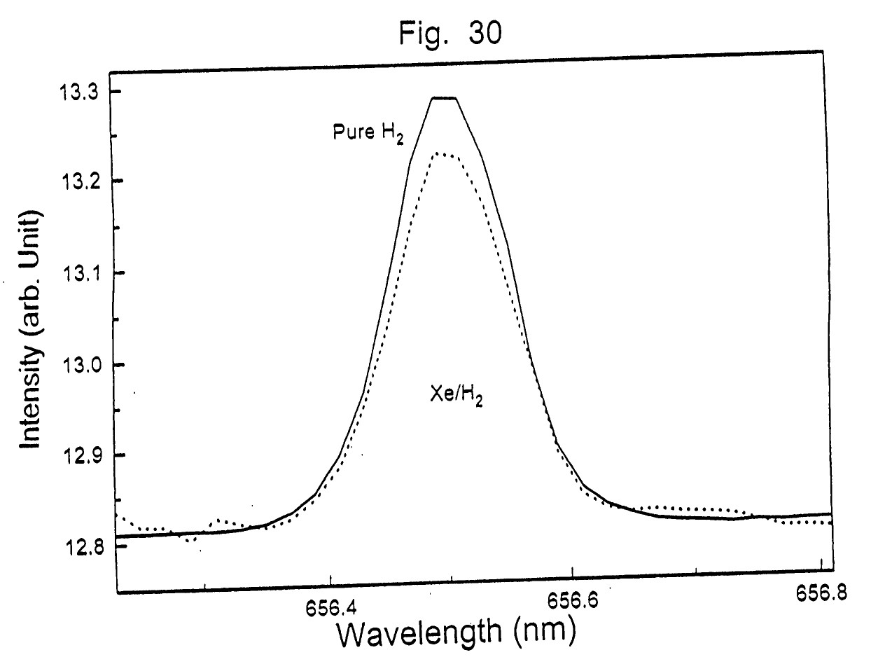

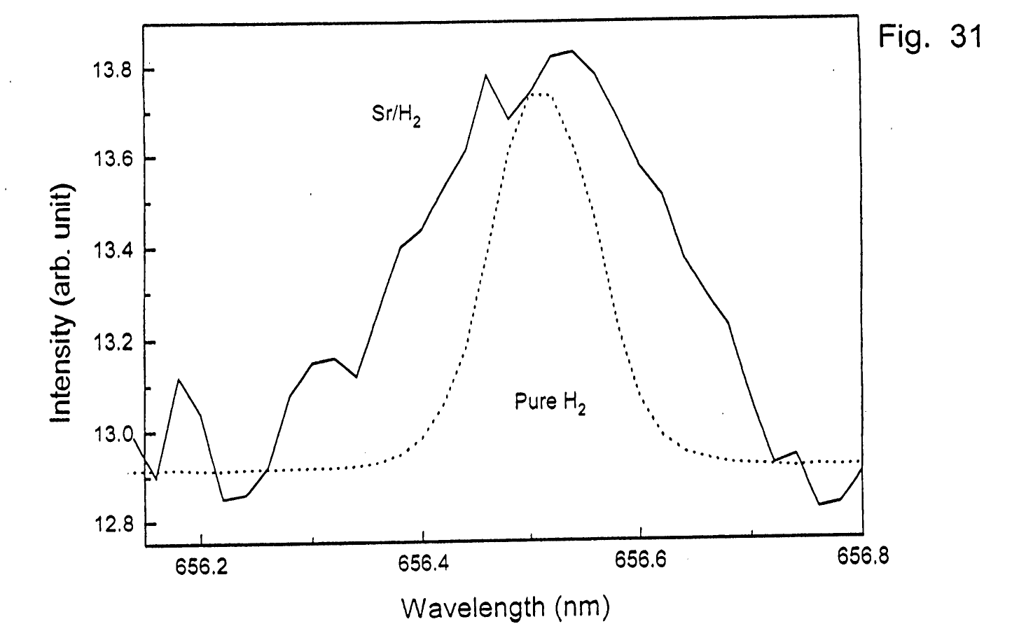

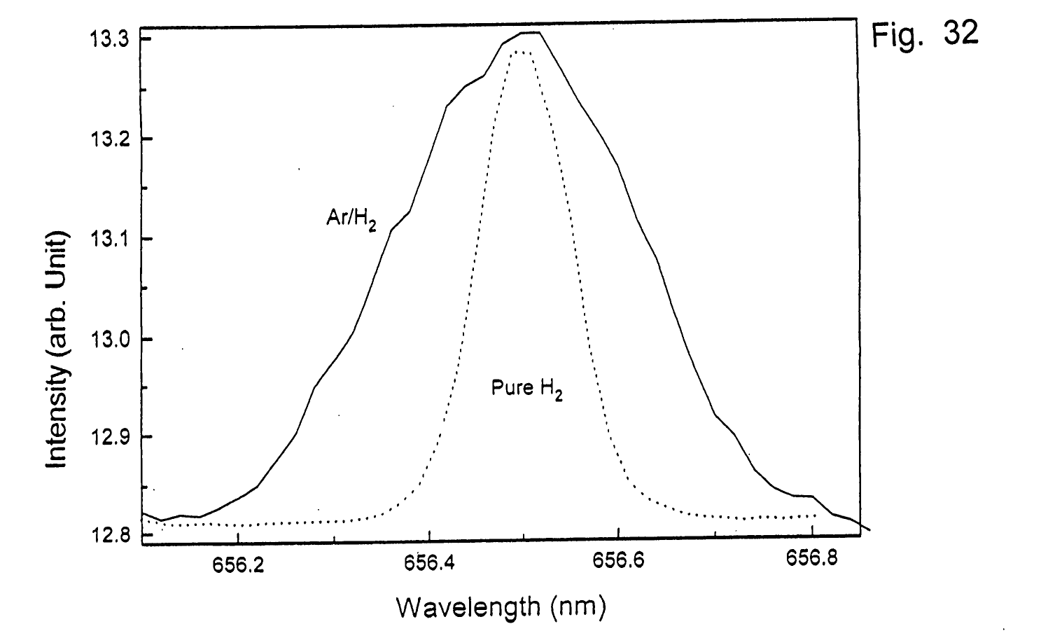

The 656 nm Balmer α line width recorded with a high resolution (±0.025 nm) visible spectrometer on glow discharge plasmas of hydrogen compared with each of xenon-hydrogen (90/10%), strontium-hydrogen and argon-hydrogen (90/10%) are shown in FIGS. 30-32, respectively. The energetic hydrogen atom densities and energies of the plasmas of hydrogen alone, strontium or magnesium with hydrogen, and hydrogen-noble gas mixtures were calculated using the method of Videnovic et al. [8] and are given in Table 1. It was found that strontium-hydrogen, helium-hydrogen, and argon-hydrogen showed significant broadening corresponding to an average hydrogen atom temperature of 23-38 eV; whereas, pure hydrogen, neon-hydrogen, krypton-hydrogen, and xenon-hydrogen showed no excessive broadening corresponding to an average hydrogen atom temperature of ≈4 eV. No voltage effect was observed with the strontium-hydrogen, helium-hydrogen, or argon-hydrogen plasmas.

TABLE 1
The energetic hydrogen atom densities and energies for catalyst
and noncatalyst glow discharge plasmas.

| | Hydrogen Atom | Hydrogen Atom |
|---|---|---|
| Plasma | Density^{a} | Energy^{b} |
| Gas | (10¹³ atoms/cm³) | (eV) |
| H₂ | 5 | 3-4 |
| Mg/H₂ | 6 | 4-5 |
| Sr/H₂ | 10 | 23-25 |
| Ne/H₂ | 2.1 | 5-6 |
| Kr/H₂ | 1 | 3-4 |
| Xe/H₂ | 1 | 3-4 |
| Ar/H₂ | 3 | 30-35 |
| He/H₂ | 3 | 33-38 |

^{a}Approximate Calculated [8]
^{b}Calculated [8]

5.3.3.3 Balmer line Broadening Recorded on Microwave Discharge Plasmas

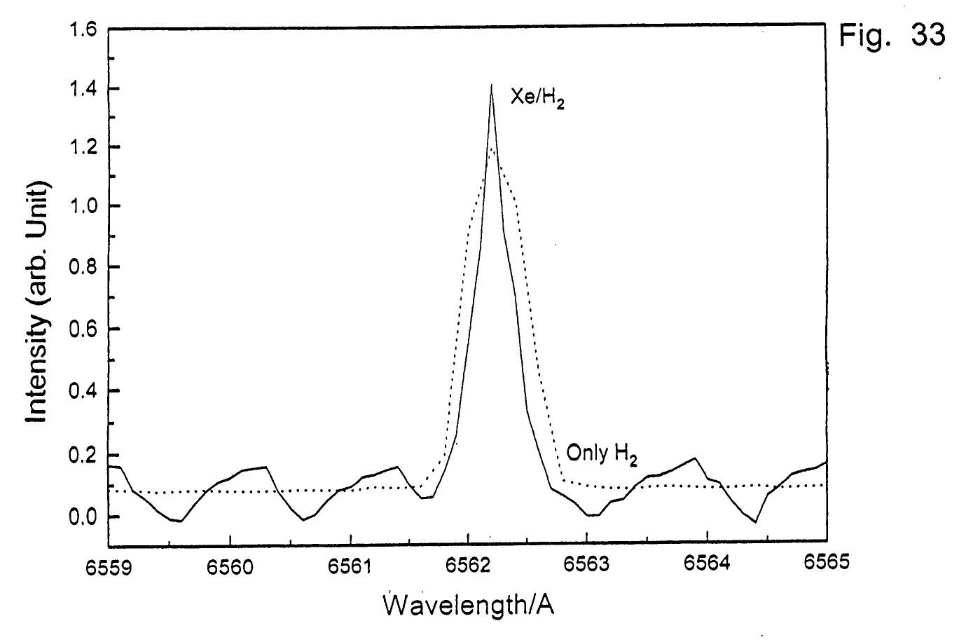

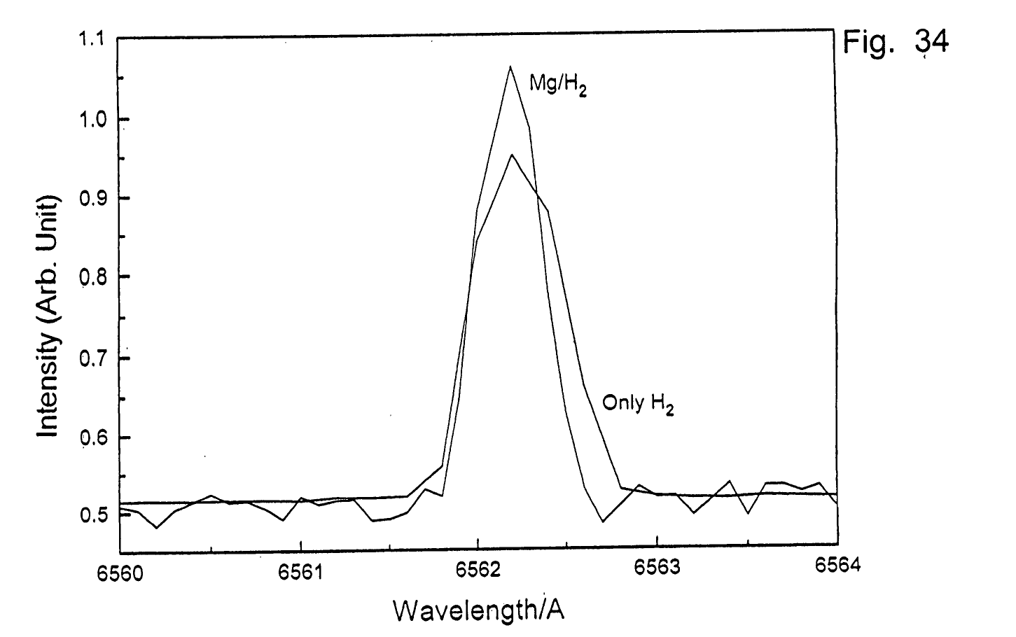

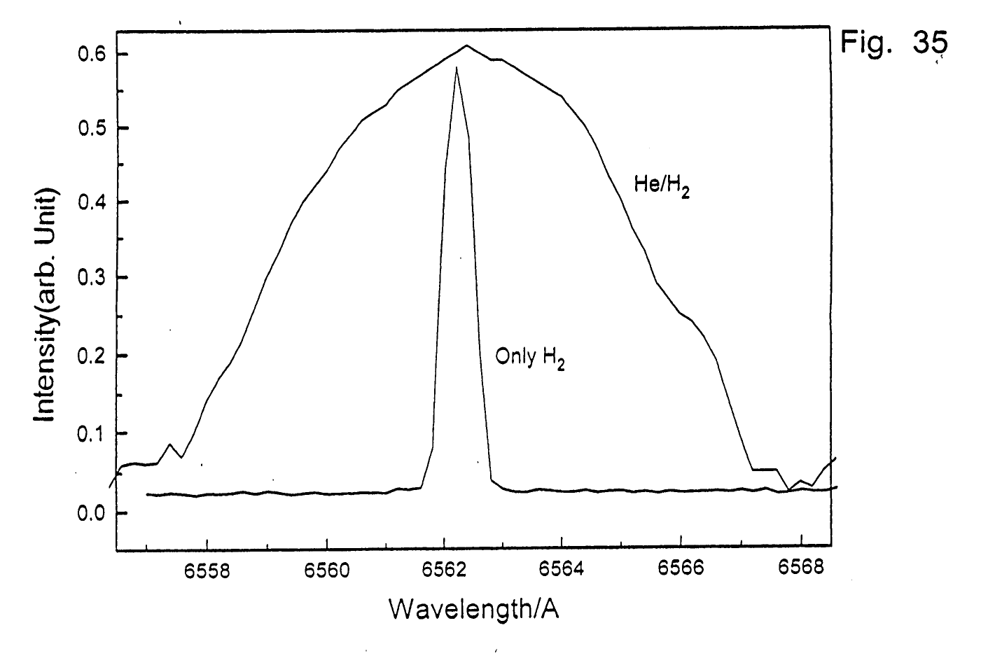

The 656 nm Balmer α line width recorded with a high resolution (±0.025 nm) visible spectrometer on microwave discharge plasmas of hydrogen compared with each of xenon-hydrogen (90/10%), magnesium-hydrogen, and helium-hydrogen (90/10%) are shown in FIGS. 33-35, respectively. The energetic hydrogen atom densities and energies of plasmas of hydrogen alone, strontium or magnesium with hydrogen, and noble gas-hydrogen mixtures were calculated using the method of Videnovic et al. [8] and are given in Table 2. It was found that the strontium-hydrogen microwave plasma showed a broadening similar to that observed in the glow discharge cell of 27-33 eV; whereas, in both sources, no broadening was observed for magnesium-hydrogen. Furthermore, the microwave helium-hydrogen, and argon-hydrogen plasmas showed extraordinary broadening corresponding to an average hydrogen atom temperature of 110-130 eV and 180-210 eV, respectively, and an atom density of 3.5×10¹⁴ atoms/cm³ and 4.8×10¹⁴ atoms/cm³, respectively. Whereas, pure hydrogen, neon-hydrogen, krypton-hydrogen, and xenon-hydrogen showed no excessive broadening corresponding to an average hydrogen atom temperature of ≈4 eV and an atom density of only 7×10¹³ atoms/cm³ even though 10 times more hydrogen was present. These studies demonstrate excessive line broadening in the absence of an observable effect attributable to an electric field since the hydrogen emission shows no broadening. Excessive line broadening was only observed in the cases where an ion was present which could provide a net enthalpy of reaction of an integer multiple of the potential energy of atomic hydrogen (Sr, Ar⁺, or He⁺). Whereas plasmas of chemically similar controls that do not provide gaseous atoms or ions that have electron ionization energies which are a multiple of 27.2 eV. These support the rt-plasma mechanism.

Rt-plasmas formed with hydrogen-potassium mixtures have been reported previously [17-18] wherein the plasma decayed with a two second half-life when the electric field was set to zero. This was the thermal decay time of the filament which dissociated molecular hydrogen to atomic hydrogen. This experiment showed that hydrogen line emission was occurring even though the voltage between the heater wires was set to and measured to be zero and indicated that the emission was due to a reaction of potassium atoms with atomic hydrogen. Potassium atoms ionize at an integer multiple of the potential energy of atomic hydrogen, m·27.2 eV. The enthalpy of ionization of K to K³⁺ has a net enthalpy of reaction of 81.7426 eV, which is equivalent to m=3.

A rt-plasma of hydrogen and certain alkali ions formed at low temperatures (e.g. ≈10³ K) as recorded via EUV spectroscopy, and an excessive afterglow duration was observed by hydrogen Balmer and alkali line emissions in the visible range [18]. The observed plasma formed from atomic hydrogen generated at a tungsten filament that heated a titanium dissociator and one of potassium, rubidium, cesium, and their carbonates and nitrates. These atoms and ions ionize to provide a net enthalpy of reaction of an integer multiple of the potential energy of atomic hydrogen (m·27.2 eV, m=integer) to within 0.17 eV and comprise only a single ionization in the case of a potassium or rubidium ion. Whereas, the chemically similar atoms of sodium and sodium and lithium carbonates and nitrates which do not ionize with these constraints caused no emission. To test the electric dependence of the emission, the weak electric field of about 1 V/cm was set and measured to be zero in <0.5×10⁻⁶ sec. An afterglow duration of about one to two seconds was recorded in the case of potassium, rubidium, cesium, K₂CO₃, RbNO₃, and CsNO₃. Hydrogen line or alkali line emission was occurring even though the voltage between the heater wires was set to and measured to be zero. These atoms and ions ionize to provide a net enthalpy of reaction of an integer multiple of the potential energy of atomic hydrogen to within less than the thermal energies at ≈10³ K and comprise only a single ionization in the case of a potassium or rubidium ion. Since the thermal decay time of the filament for dissociation of molecular hydrogen to atomic hydrogen was similar to the rt-plasma afterglow duration, the emission was determined to be due to a reaction of atomic hydrogen with each of the atoms or ions that did not require the presence of an electric field to be functional.

TABLE 2
The energetic hydrogen atom densities and energies and the electron
temperature for catalyst and noncatalyst microwave discharge plasmas.

| | Hydrogen Atom | Hydrogen Atom | Electron |
|---|---|---|---|
| Plasma | Density^{a} | Energy^{b} | Temperature T_{c}^{c} |
| Gas | (10¹³ atoms/cm³) | (eV) | (K) |
| H₂ | 7 | 3-4 | 5500 |
| Mg/H₂ | 11.1 | 4-5 | 5800 |
| Sr/H₂ | 18.5 | 27-33 | 10,280 |
| Ne/H₂ | 9 | 5-6 | 7800 |
| Kr/H₂ | 4 | 3-4 | 6700 |
| Xe/H₂ | 3 | 3-4 | 6500 |
| Ar/H₂ | 35 | 110-130 | 11,600 |
| He/H₂ | 48 | 180-210 | 28,000 |

^{a}Approximate Calculated [8]
^{b}Calculated [8]
^{c}Calculated [21]

5.3.3.4 T_{c} Measurements of Microwave Discharge Plasmas

The results of the T_{c} measurements on microwave plasmas of pure hydrogen alone, strontium or magnesium with hydrogen, and a mixture of 10% hydrogen and helium, neon, argon, krypton, or xenon are given in Table 2. Similarly to the ion measurement, the average electron temperature for helium-hydrogen plasma was 28,000 K; whereas, the corresponding temperature of helium alone was only 6800 K. The average electron temperature for argon-hydrogen plasma was 11,600 K; whereas, the corresponding temperature of argon alone was only 4800 K.

5.3.4 Summary and Conclusions

The argon-hydrogen microwave plasma showed significant broadening of the width of the Lyman α line of 10 nm; whereas, the width of the Lyman α line emitted from the glow discharge plasma was 2.6 nm. In addition, the intensity of the Lyman α emission compared to the molecular hydrogen emission was significantly higher in the case of the microwave plasma. The results indicate a much greater ion temperature in the microwave plasma.

Line broadening of the hydrogen Balmer lines provides a sensitive measure of the number and energy of excited hydrogen atoms in a glow discharge plasma. The width of the 656.5 nm Balmer α line emitted from glow discharge plasmas having atomized hydrogen from pure hydrogen alone, strontium or magnesium with hydrogen, and a mixture of 10% hydrogen and helium, argon, neon, krypton, or xenon was measured with a high resolution (±0.025 nm) visible spectrometer. The energetic hydrogen atom density and energies were determined from the broadening, and it was found that strontium-hydrogen, helium-hydrogen, and argon-hydrogen showed significant broadening corresponding to an average hydrogen atom temperature of 23-38 eV; whereas, pure hydrogen, neon-hydrogen, krypton-hydrogen, and xenon-hydrogen showed no excessive broadening corresponding to an average hydrogen atom temperature of ≈4 eV. Thus, line broadening was only observed for the ions which provided a net enthalpy of reaction of a multiple of the potential energy of the hydrogen atom.

Kuraica and Konjevic [7] and Videnovic et al. [8] studied 97% argon and 3% hydrogen mixtures in Grimm-type discharges with a hollow anode. In our studies with argon-hydrogen plasmas, the voltage was increased at 50 V increments from 275 V to 475 V, and the high resolution visible spectra were recorded to observe the effect of voltage on the Balmer α line broadening. In contrast to an increase in broadening with voltage predicted by Kuraica and Konjevic [7], no voltage effect was observed. Also, no voltage effect was also observed with the strontium-hydrogen plasma which supports the rt-plasma mechanism of the low voltage strontium-hydrogen and strontium-argon-hydrogen plasmas reported by Mills and Nansteel [14-15, 19]. Similarly, no voltage effect was observed in the case of the helium-hydrogen plasma which supports the rt-plasma mechanism as the source of the excessive broadening.

The 656.5 nm Balmer α line width measurements were repeated with microwave discharge plasmas rather than the glow discharge plasmas, and significant differences were observed between the plasma source while the same trend was observed for the particular plasma gas. It was found that the strontium-hydrogen microwave plasma showed a broadening similar to that observed in the glow discharge cell of 27-33 eV; whereas, in both sources, no broadening was observed for magnesium-hydrogen. Furthermore, the microwave helium-hydrogen, and argon-hydrogen plasmas showed extraordinarily higher broadening corresponding to an average hydrogen atom temperature of 110-130 eV and 180-210 eV, respectively, and an atom density of 3.5×10¹⁴ atoms/cm³ and 4.8×10¹⁴ atoms/cm³, respectively. Whereas, similarly to the glow discharge case, pure hydrogen, neon-hydrogen, krypton-hydrogen, and xenon-hydrogen showed no excessive broadening corresponding to an average hydrogen atom temperature of ≈4 eV and an atom density of only 7×10¹³ atoms/cm³ even though 10 times more hydrogen was present. Similarly, the average electron temperature for helium-hydrogen plasma was 28,000 K; whereas, the corresponding temperature of helium alone was only 6800 K. And, the average electron temperature for argon-hydrogen plasma was 11,600 K; whereas, the corresponding temperature of helium alone was only 4800 K.

Thus, excessive line broadening and an elevated electron temperature were only observed for the ions which provided a net enthalpy of reaction of a multiple of the potential energy of the hydrogen atom. No electric field was present in the microwave plasmas. Thus, the results can not be explained by Stark broadening or acceleration of charged species due to high fields of over 10 kV/cm as proposed by Videnovic et al. [8] to explain excessive broadening observed in glow discharges. The results are consistent with an energetic reaction caused by a resonance energy transfer between hydrogen atoms and strontium atoms, Ar⁺, or He⁺ as the source of the excessive line broadening. The reaction rate is higher under the conditions of a microwave compared to a glow discharge plasma even at a lower input power.

5.3.5 References

1. P. W. J. M. Boumans, Spectrochim. Acta Part B, 46 (1991) 711.

2. J. A. C. Broekaert, Appi. Spectrosc., 49, (1995) 12A.

3. P. W. J. M. Boumans, J. A. C. Broekaert, and R. K. Marcus, Eds., Spectrochim. Acta Part B, 46(1991)457.

4. M. Dogan, K. Laqua, and H. Massmann, “Spektrochemische Analysen mit einer Glimmentladungslampe als Lichtquelle—I,” Spectrochim. Acta, Volume 26B, (1971) 631-649.

5. M. Dogan, K. Laqua, and H. Massmann, “Spektrochemische Analysen mit einer Glimmentladungslampe als Lichtquelle—II,” Spectrochim. Acta, Volume 27B, (1972) 65-88.

6. J. A. C. Broekaert, J. Anal. At. Spectrom., 2 (1987) 537.

7. M. Kuraica, N. Konjevic, “Line shapes of atomic hydrogen in a plane-cathode abnormal glow discharge”, Physical Review A, Volume 46, No. 7, October (1992), pp. 4429-4432.

8. I. R. Videnovic, N. Konjevic, M. M. Kuraica, “Spectroscopic investigations of a cathode fall region of the Grimm-type glow discharge”, Spectrochimica Acta, Part B, Vol. 51, (1996), pp. 1707-1731.

9. P. Kurunczi, H. Shah, and K. Becker, “Hydrogen Lyman-α and Lyman-β emissions from high-pressure microhollow cathode discharges in Ne—H₂ mixtures”, J. Phys. B: At. Mol. Opt. Phys., Vol. 32, (1999), L651-L658.

10. M. Parker and R. K. Marcus, Appl. Spectrosc., 48, (1994) 623.

11. J. A. R. Sampson, Techniques of Vacuum Ultraviolet Spectroscopy, Pied Publications, (1980), pp. 94-179.

12. R. Mills, P. Ray, “Spectroscopic Identification of a Novel Catalytic Reaction of Potassium and Atomic Hydrogen and the Hydride Ion Product”, Int. J. Hydrogen Energy, in press.

13. R. Mills, “Spectroscopic Identification of a Novel Catalytic Reaction of Atomic Hydrogen and the Hydride Ion Product”, Int. J. Hydrogen Energy, Vol. 26, No. 10, (2001), pp. 1041-1058.

14. R. Mills and M. Nansteel, “Argon-Hydrogen-Strontium Plasma Light Source”, IEEE Transactions on Plasma Science, submitted.

15. R. Mills, M. Nansteel, and Y. Lu, “Excessively Bright Hydrogen-Strontium Plasma Light Source Due to Energy Resonance of Strontium with Hydrogen”, European Journal of Physics D, submitted.

16. R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943.

17. R. Mills, “Temporal Behavior of Light-Emission in the Visible Spectral Range from a Ti-K2CO3-H-Cell”, Int. J. Hydrogen Energy, Vol. 26, No. 4, (2001), pp. 327-332.

18. R. Mills, T. Onuma, and Y. Lu, “Formation of a Hydrogen Plasma from an Incandescently Heated Hydrogen-Catalyst Gas Mixture with an Anomalous Afterglow Duration”, Int. J. Hydrogen Energy, Vol. 26, No. 7, July, (2001), pp. 749-762.

19. R. Mills, M. Nansteel, and Y. Lu, “Observation of Extreme Ultraviolet Hydrogen Emission from Incandescently Heated Hydrogen Gas with Strontium that Produced an Anomalous Optically Measured Power Balance”, Int. J. Hydrogen Energy, Vol. 26, No. 4, (2001), pp. 309-326.

20. R. Mills, P. Ray, “Spectral Emission of Fractional Quantum Energy Levels of Atomic Hydrogen from a Helium-Hydrogen Plasma and the Implications for Dark Matter”, Int. J. Hydrogen Energy, in press.

21. Griem, Principle of Plasma Spectroscopy, Cambridge University Press, (1987).

1. A cell comprising:
a reaction vessel;
a source of hydrogen atoms in communication with the vessel;
a source of catalyst for catalyzing a reaction of hydrogen atoms to lower-energy states in communication with the vessel, for releasing energy from the hydrogen atoms and producing a plasma; and
a source of microwave power which is constructed and arranged to provide sufficient microwave power to the vessel to initiate the plasma.

2. A cell according to claim 1, wherein the source of microwave power is constructed and arranged to ionize the source of catalyst to provide a catalyst.

3. A cell according to claim 1, wherein the source of microwave power comprises an antenna, waveguide or cavity.

4. A cell according to claim 1, wherein the source of catalyst comprises helium gas, which produces He+ catalyst when ionized by microwave power.

5. A cell according to claim 1, wherein the source of catalyst comprises argon gas, which produces Ar+ catalyst when ionized by microwave power.

6. A cell according to claim 1, wherein the source of catalyst is selected such that a catalyst formed by ionizing the source of catalyst using microwave power has a higher temperature than that at thermal equilibrium.

7. A cell according to claim 1, wherein the cell is further constructed and arranged such that, in operation, excited or ionized states of the source of catalyst predominate over excited or ionized states of hydrogen compared to a thermal plasma where excited or ionized states of hydrogen predominate.

8. A cell according to claim 1, wherein the source of microwave power is constructed and arranged to provide microwave power to the cell in the form of dissipated energetic electrons within about the electron mean free path.

9. A cell according to claim 8, wherein the source of microwave power is further constructed and arranged to provide microwave power to the cell in the form of dissipated energetic electrons within about the electron mean free path of about 0.1 cm to 1 cm when the cell is operated at a pressure of about 0.5 to about 5 Torr.

10. A cell according to claim 9, wherein the cell is further constructed to be greater than the electron mean free path.

11. A cell according to any one of claims 1, wherein the cell comprises a microwave resonator cavity and is further constructed and arranged to provide sufficient microwave power to ionize the source of catalyst to provide a catalyst.

12. A cell according to claim 11, wherein the cavity is an Evenson cavity.

13. A cell according to claim 1, further comprising a plurality of microwave power sources.

14. A cell according to claim 13, further comprising a plurality of Evenson cavities constructed and arranged so that they operate in parallel.

15. A cell according to claim 1, wherein the cell comprises a quartz cell having a plurality of Evenson cavities spaced along a longitudinal axis.

16. A cell comprising:
a reaction vessel;
a source of atomic hydrogen in communication with the vessel;
a source of catalyst for catalyzing a reaction of hydrogen atoms to lower-energy states in communication with the vessel, for releasing energy from the hydrogen atoms and producing a plasma; and
a source of radio frequency (RF) power which is constructed and arranged to provide sufficient microwave power to the vessel to initiate the plasma.

17. A cell according to claim 16, wherein the RF power is capacitively or inductively coupled to the cell of the hydride reactor.

18. A cell according to claim 16, further comprising two electrodes.

19. A cell according to claim 18, further comprising a coaxial cable connected to a powered electrode by a coaxial center conductor.

20. A cell according to claim 16, further comprising a coaxial center conductor connected to an external source coil which is wrapped around the cell.

21. A cell according to claim 20, wherein the coaxial center conductor connected to an external source coil which is wrapped around the cell terminates without a connection to ground.

22. A cell according to claim 20, wherein the coaxial center conductor connected to an external source coil which is wrapped around the cell is connected to ground.

23. A cell according to claim 16, further comprising two electrodes wherein the electrodes are parallel plates.

24. A cell according to claim 23, wherein one of the parallel plate electrodes is powered and the other is connected to ground.

25. A cell according to claim 16, wherein the cell comprises a Gaseous Electronics Conference (GEC) Reference Cell or modification.

26. A cell according to claim 16, wherein the RF power is at 13.56 MHz.

27. A cell according to claim 20, wherein at least one wall of the cell wrapped with the external coil is at least partially transparent to the RF excitation.

28. A cell according to claim 16, wherein the RF frequency is in the range of about 100 Hz to about 100 GHz.

29. A cell according to claim 16, wherein the RF frequency is in the range of about 1 kHz to about 100 MHz.

30. A cell according to claim 16, wherein the RF frequency is in the range of about 13.56 MHz±50 MHz or about 2.4 GHz±1 GHz.

31. A cell according to claim 16, further comprising at least one coil.

32. A cell according to claim 16, wherein the cell comprises an Astron system.

33. A cell according to claim 16, wherein the cell is an inductively coupled toroidal plasma cell comprising a primary of a transformer circuit.

34. A cell according to claim 33, further comprising a primary of a transformer circuit driven by a radio frequency power supply.

35. A cell according to claim 34, further comprising a primary of a transformer circuit wherein the plasma is a closed loop which acts at as a secondary of the transformer circuit.

36. A cell according to claim 33, wherein the RF frequency is in the range of about 100 Hz to about 100 GHz.

37. A cell according to claim 33, wherein the RF frequency is in the range of about 1 kHz to about 100 MHz.

38. A cell according to claim 33, wherein the RF frequency is in the range of about 13.56 MHz±50 MHz or about 2.4 GHz±1 GHz.

39. A cell comprising:
a reaction vessel;
a source of hydrogen atoms in communication with the vessel;
a source of catalyst for catalyzing a reaction of hydrogen atoms to lower-energy states in communication with the vessel, for releasing energy from the hydrogen atoms and producing a plasma;
a hollow cathode in the vessel;
an anode in the vessel; and
a power supply connected to the cathode and anode to produce a glow discharge plasma.

40. A cell according to claim 39, wherein the hollow cathode comprises a compound electrode having multiple electrodes in series or parallel that may occupy a substantial portion of the volume of the cell.

41. A cell according to claim 39, further comprising multiple hollow cathodes in parallel so that a desired electric field can be produced in a large volume to generate a substantial power level.

42. A cell according to claim 39, further comprising an anode and multiple concentric hollow cathodes each electrically isolated from a common anode.

43. A cell according to claim 39, further comprising an anode and multiple parallel plate electrodes connected in series.

44. A cell according to claim 39, wherein electrodes are connected and arranged to operate at 1 to 100,000 volts.

45. A cell according to claim 39, wherein electrodes are connected and arranged to operate at 50 to 10,000 volts.

46. A cell according to claim 39, wherein electrodes are connected and arranged to operate at 50 to 5,000 volts.

47. A cell according to claim 39, wherein electrodes are connected and arranged to operate at 50 to 500 volts.

48. A cell according to claim 39,wherein the hollow cathode comprises at least one refractory material.

49. A cell according to claim 48, wherein the refractory material comprises at least one of molybdenum or tungsten.

50. A cell according to claim 39, comprising neon as the source of catalyst.

51. A cell according to claim 39, comprising neon as the source of catalyst with hydrogen wherein neon is in the range of about 90 to about 99.99 atom % and hydrogen is in the range of about 0.01 to about 10 atom %.

52. A cell according to claim 39, comprising neon as the source of catalyst with hydrogen wherein neon is in the range of about 99 to about 99.9 atom % and hydrogen is in the range of about 0.1 to about 1 atom %.

53. A cell comprising:
a reaction vessel;
a source of hydrogen atoms in communication with the vessel;
a source of catalyst for catalyzing a reaction of hydrogen atoms to lower-energy states in communication with the vessel, for releasing energy from the hydrogen atoms and producing a plasma; and
a magnetohydrodynamic power converter constructed and arranged to convert plasma energy into electricity.

54. A cell comprising:
a reaction vessel;
a source of hydrogen atoms in communication with the vessel;
a source of catalyst for catalyzing a reaction of hydrogen atoms to lower-energy states in communication with the vessel, for releasing energy from the hydrogen atoms and producing a plasma; and
a plasmadynamic power converter constructed and arranged to convert plasma energy into electricity.

55. A cell according to any one of claims 1, 16, 39, 53 and 54 wherein the source of catalyst can provide a catalyst having a net enthalpy of about m·27.2±0.5 eV, where m is an integer, when the catalyst is excited.

56. A cell according to any one of claims 1, 16, 39, 53 and 54 wherein the source of catalyst can provide a catalyst having a net enthalpy of about m/2·27.2±0.5 eV where m is an integer greater than one, when the catalyst is excited.

57. A cell according to any one of claims 1, 16, 39, 53 and 54 wherein the source of catalyst can provide a catalyst comprising He⁺ which absorbs 40.8 eV during the transition from the n=1 energy level to the n=2 energy level which corresponds to 3/2·27.2 eV (m=3) that serves as a catalyst for the transition of atomic hydrogen from the n=1 (p=1) state to the n=1/2 (p=2) state.

58. A cell according to any one of claims 1, 16, 39, 53 and 54 wherein the source of catalyst can provide a catalyst comprising Ar²⁺ which absorbs 40.8 eV and is ionized to Ar³⁺ which corresponds to 3/2·27.2 eV (m=3) during the transition of atomic hydrogen from the n=1 (p=1) energy level to the n=1/2 (p=2) energy level.

59. A cell according to any one of claims 1, 16, 39, 53 and 54 wherein the source of catalyst comprises a mixture of a first catalyst and a source of a second catalyst.

60. A cell according to claim 59, wherein the first catalyst produces a second catalyst from the source of the second catalyst when the cell is operated.

61. A cell according to claim 60, wherein energy released by the catalysis of hydrogen by the first catalyst produces the plasma.

62. A cell according to claim 61, wherein the first and second catalysts are selected such that the energy released by the catalysis of hydrogen by the first catalyst ionizes the source of the second catalyst to produce the second catalyst.

63. A cell according to claim 61, wherein one or more ions are produced in the absence of a strong electric field when the cell is in operation.

64. A cell according to claim 61, further comprising a source of an electric field for increasing the rate of catalysis of the second catalyst such that the enthalpy of reaction of the catalyst matches about m/2 27.2±0.5 eV where m is an integer to cause hydrogen catalysis.

65. A cell according to claim 59, wherein the first catalyst is selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Fe³⁺, Mo²⁺, Mo⁴⁺, Ne⁺ and In³⁺.

66. A cell according to claim 59, wherein the source of second catalyst comprises at least one selected from the group of helium and argon.

67. A cell according to claim 66, wherein a second catalyst produced from the source of second catalyst comprises at least one selected from the group of He⁺ and Ar⁺ and wherein a second catalyst ion is generated from the corresponding atom by the plasma.

68. A cell according to claim 59, wherein the second catalyst comprises Ar⁺.

69. A cell according to claim 68, wherein the source of second catalyst is argon and wherein the catalysis of hydrogen with the first catalyst ionizes the argon and produces a second catalyst comprising Ar⁺.

70. A cell according to claim 59, wherein the source of catalyst comprises a mixture of strontium and argon wherein the catalysis of hydrogen by strontium produces a second catalyst of Ar⁺.

71. A cell according to claim 59, wherein the source of catalyst comprises a mixture of potassium and argon wherein the catalysis of hydrogen by potassium produces a second catalyst of Ar⁺.

72. A cell according to any one of claims 1, 16, 39, 53 and 54 wherein the source of catalyst comprises a mixture of a first catalyst and helium gas which produces He⁺ as a second catalyst.

73. A cell according to claim 59, wherein the source of second catalyst comprises helium, wherein the catalysis of hydrogen by the first catalyst produces He⁺ which functions as a second catalyst.

74. A cell according to claim 59, wherein the source of second catalyst comprises helium, wherein the catalysis of hydrogen by strontium produces He⁺ which functions as a second catalyst.

75. A cell according to claim 59, wherein the source of second catalyst comprises helium, wherein the catalysis of hydrogen by potassium produces He⁺ which functions as a second catalyst.

76. A cell according to any one of claims 1, 16, 39, 53 and 54 further comprising a source of a magnetic field, and at least two electrodes constructed and arranged to receive power from the plasma when the cell is operated.

77. A cell according to any one of claims 1, 16, 39, 53 and 54 further comprising a means to cause a directional flow of ions, and a power converter for converting the kinetic energy of the flowing ions into electrical power when the cell is operated.

78. A cell according to claim 77, wherein the component of plasma ion motion perpendicular to the direction of the z-axis v_{⊥} is at least partially converted into parallel motion v_{∥} due to the adiabatic invariant
$$\frac{{v}_{⊥}^{2}}{B} = constant$$
to form the directional flow of ions when the cell is operated.

79. A cell according to claim 77, further comprising at least one magnetic mirror which is constructed and arranged to at least partially convert the component of plasma ion motion perpendicular to the direction of the z-axis v_{⊥} into parallel motion v_{∥} due to the adiabatic invariant
$$\frac{{v}_{⊥}^{2}}{B} = constant$$
to form the directional flow of ions when the cell is operated.

80. A cell according to claim 77, further comprising a magnetohydrodynamic power converter constructed and arranged such that when the cell is operated ions have a preferential velocity along a z-axis and propagate into the magnetohydrodynamic power converter, wherein the magnetohydrodynamic power converter comprises electrodes and a magnetic field crossed with a direction of the flowing ions wherein the ions are Lorentzian deflected by the magnetic field and the deflected ions form a voltage at the electrodes crossed with the corresponding transverse deflecting field.

81. A cell according to claim 80, wherein the electrode voltage may drive a current through an electrical load.

82. A cell according to claim 80, wherein the magnetohydrodynamic power converter comprises a segmented Faraday generator type magnetohydrodynamic power converter which is constructed and arranged such that when the cell is operated the ions have a preferential velocity along the z-axis and propagate into the converter and the converter comprises a magnetic field crossed with the direction of the flowing ions, and wherein the ions are Lorentzian deflected by the magnetic field and the deflected ions form a voltage at electrodes crossed with the corresponding transverse deflecting field.

83. A cell according to claim 77, further comprising a magnetohydrodynamic power converter constructed and arranged such that when the cell is operated ions have a preferential velocity along the z-axis and propagate into the magnetohydrodynamic power converter, the converter comprising a magnetic field crossed with the direction of the flowing ions and at least two electrodes, wherein the ions are Lorentzian deflected by the magnetic field to form a transverse current and the transverse current is deflected by the crossed magnetic field to form a Hall voltage between at least two electrodes which are transverse to and separated along the z-axis.

84. A cell according to claim 73, wherein the electrode voltage may drive a current through an electrical load.

85. A cell according to claim 77, further comprising a Hall generator type magnetohydrodynamic power converter constructed and arranged such that when the cell is operated ions have a preferential velocity along the z-axis and propagate into the Hall generator type magnetohydrodynamic power converter, the converter comprising a magnetic field crossed with the direction of the flowing ions and at least two electrodes, wherein the ions are Lorentzian deflected by the magnetic field to form a transverse current and the transverse current is deflected by the crossed magnetic field to form a Hall voltage between at least two electrodes which are transverse to and separated along the z-axis.

86. A cell according to claim 77, further comprising a diagonal generator having a window frame construction type magnetohydrodynamic power converter constructed and arranged such that when the cell is operated ions have a preferential velocity along the z-axis and propagate into the converter, the converter comprising a magnetic field crossed with the direction of the flowing ions and at least two ions, wherein the ions are Lorentzian deflected by the magnetic field to form a transverse current and the transverse current is deflected by the crossed magnetic field to form a Hall voltage between at least two electrodes which are transverse to and separated along the z-axis.

87. A cell according to claim 77, further comprising confining structure to confine the hydrogen catalysis generated plasma to a desired region.

88. A cell according to claim 87, wherein the confining structure comprises at least two electrodes.

89. A cell according to claim 87, wherein the confining structure comprises at least one microwave antenna.

90. A cell according to claim 87, wherein the confining structure comprises a microwave cavity.

91. A cell according to claim 87, wherein the microwave cavity comprises an Evenson cavity.

92. A cell according to claim 77, further comprising a magnetic bottle comprising a plurality of magnetic mirrors, wherein the magnetic bottle is constructed and arranged such that when the cell is operated ions penetrate at least one of the magnetic mirrors to form the source of ions having a preferential velocity along the z-axis and propagate into a power converter for converting the kinetic energy of the flowing ions into electrical power.

93. A cell according to claim 77, further comprising a magnetohydrodynamic power converter constructed and arranged such that when the cell is operated the source of ions having a preferential velocity along the z-axis propagate into the magnetohydrodynamic power converter, wherein Lorentzian deflected ions form a voltage at electrodes crossed with the corresponding transverse deflecting field.

94. A cell according to any one of claims 1, 16, 39, 53 and 54 wherein the cell comprises a discharge cell.

95. A cell according to claim 94, further comprising structure for providing intermittent or pulsed discharge current.

96. A cell according to claim 94, further comprising structure to provide an offset voltage of from about 0.5 to about 500 V.

97. A cell according to claim 94, further comprising structure to provide an offset voltage which provides a field of about 1 V/cm to about 10 V/cm.

98. A cell according to claim 94, further comprising structure to provide a pulse frequency of from about 0.1 Hz to about 100 MHz and a duty cycle of about 0.1% to about 95%.

99. A cell according to any one of claims 1, 16, 39, 53 and 54 further comprising a hydrogen catalyst of atomic hydrogen capable of providing a net enthalpy of m·27.2±0.5 eV where m is an integer or m/2·27.2±0.5 eV where m is an integer greater than one and capable of forming a hydrogen atom having a binding energy of about
$$\frac{13.6 eV}{{( \frac{1}{p} )}^{2}}$$
where p is an integer wherein the net enthalpy is provided by the breaking of a molecular bond of the catalyst and the ionization of t electrons from an atom of the broken molecule each to a continuum energy level such that the sum of the bond energy and the ionization energies of the t electrons is approximately m·27.2±0.5 eV where m is an integer or m/2·27.2±0.5 eV where m is an integer greater than one.

100. A cell according to claim 99, wherein the hydrogen catalyst further comprising at least one of C₂, N₂, O₂, CO₂, NO₂, and NO₃.

101. A cell according to claim 99, further comprising a molecule in combination with the hydrogen catalyst.

102. A cell according to any one of claims 1, 16, 39, 53 and 54 wherein the source of catalyst comprises at least one molecule selected from the group of C₂, N₂, O₂, CO₂, NO₂, and NO₃ in combination with at least one atom or ion selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, He⁺, Na⁺, Rb⁺, Fe³⁺, Mo²⁺, Mo⁴⁺, In³⁺, He⁺, Ar⁺, Xe⁺, Ar²⁺, Ne⁺ and H⁺, and Ne⁺ and H⁺.

103. A cell according to any one of claims 1, 16, 39, 53 and 54 wherein the cell is constructed an arranged such that when operated a catalytic disproportionation reaction of atomic hydrogen occurs wherein lower-energy hydrogen (hydrino) atoms act as catalysts because each of the metastable excitation, resonance excitation, and ionization energy of a hydrino atom is m×27.2 eV.

104. A cell according to claim 103, wherein a first hydrino atom is reacted to a lower energy state affected by a second hydrino atom which involves a resonant coupling between the hydrino atoms of m degenerate multipoles each having 27.21 eV of potential energy.

105. A cell according to claim 104, wherein the energy transfer of m×27.2 eV from the first hydrino atom to the second hydrino atom causes the central field of the first atom to increase by m and its electron to drop m levels lower from a radius of
$$\frac{{a}_{H}}{p}$$
to a radius of
$$\frac{{a}_{H}}{p + m} .$$

106. A cell according to claim 104, wherein the cell is constructed and arranged such that the second interacting hydrino atom is either excited to a metastable state, excited to a resonance state, or ionized by the resonant energy transfer.

107. A cell according to claim 104, wherein the resonant transfer may occur in multiple stages.

108. A cell according to claim 104, wherein a nonradiative transfer by multipole coupling can occur wherein the central field of the first increases by m, then the electron of the first drops m levels lower from a radius of
$$\frac{{a}_{H}}{p}$$
to a radius of
$$\frac{{a}_{H}}{p + m}$$
with further resonant energy transfer.

109. A cell according to claim 104, wherein the energy transferred by multipole coupling may occur by a mechanism that is analogous to photon absorption involving an excitation to a virtual level.

110. A cell according to claim 104, wherein the energy transferred by multipole coupling during the electron transition of the first hydrino atom may occur by a mechanism that is analogous to two photon absorption involving a first excitation to a virtual level and a second excitation to a resonant or continuum level.

111. A cell according to claim 104, wherein the catalytic reaction with hydrino catalysts for the transition of
$$H [ \frac{{a}_{H}}{p} ] to H [ \frac{{a}_{H}}{p + m} ]$$
induced by a multipole resonance transfer of m·27.21 eV and a transfer of [(p′)²−(p′−m′)²]×13.6 eV−m·27.2 eV with a resonance state of
$$H [ \frac{{a}_{H}}{{p}^{′} - {m}^{′}} ]$$
excited in
$$H [ \frac{{a}_{H}}{{p}^{′}} ]$$
is represented by
$$\begin{matrix}H ⌊ \frac{{a}_{H}}{{p}^{′}} ⌋ + H ⌊ \frac{{a}_{H}}{p} ⌋ \to \\ H [ \frac{{a}_{H}}{{p}^{′} - {m}^{′}} ] + H [ \frac{{a}_{H}}{p + m} ] + [ ( {( p + m )}^{2} - {p}^{2} ) - ( {p}^{′2} - {( {p}^{′} - {m}^{′} )}^{2} ) ] X 13.6 eV\end{matrix}$$
where p, p′, m, and m′ are integers.

112. A cell according to any one of claims 1, 16, 39, 53 and 54 wherein a lower-energy hydrogen (hydrino) atom which has the initial lower-energy state quantum number p and radius
$$\frac{{a}_{H}}{p}$$
may undergo a transition to the state with lower-energy state quantum number (p+m) and radius
$$\frac{{a}_{H}}{( p + m )}$$
by reaction with a hydrino atom with the initial lower-energy state quantum number m′, initial radius
$$\frac{{a}_{H}}{{m}^{′}} ,$$
and final radius a_{H} that provides a net enthalpy of m·27.2±0.5 eV where m is an integer or m/2·27.2±0.5 eV where m is an integer greater than one.

113. A cell according to claim 112, wherein the hydrino atom,
$$H [ \frac{{a}_{H}}{p} ] ,$$
with the hydrino atom,
$$H [ \frac{{a}_{H}}{{m}^{′}} ] ,$$
is ionized by the resonant energy transfer to cause a transition reaction is represented by
$$\begin{matrix}m X27 .21 eV + H [ \frac{{a}_{H}}{{m}^{′}} ] + H ⌊ \frac{{a}_{H}}{p} ⌋ \to \\ {H}^{+} + {e}^{-} + H [ \frac{{a}_{H}}{( p + m )} ] + [ {( p + m )}^{2} - {p}^{2} - ( {m}^{′2} - 2 m ) ] X 13.6 eV \\ {H}^{+} + {e}^{-} \to H [ \frac{{a}_{H}}{1} ] + 13.6 eV\end{matrix}$$
And, the overall reaction is
$$\begin{matrix}H [ \frac{{a}_{H}}{{m}^{′}} ] + H ⌊ \frac{{a}_{H}}{p} ⌋ \to \\ H [ \frac{{a}_{H}}{1} ] + H [ \frac{{a}_{H}}{( p + m )} ] + [ 2 p m + {m}^{2} - {m}^{′2} ] X13 .6 eV + 13.6 eV .\end{matrix}$$

114. A cell according to any one of claims 1, 16, 39, 53 and 54 further comprising a power converter which is constructed and arranged to separate ions and electrons to produce a voltage across at least two separated electrodes.

115. A cell according to claim 114, wherein the power converter comprises a source of a magnetic field.

116. A cell according to claim 115, wherein the power converter can selectively confine electrons during operation.

117. A cell according to claim 115, wherein the source of magnetic field comprises at least one of a minimum B field source or a magnetic bottle.

118. A cell according to claim 114, wherein an electrode is constructed and arranged such that when the cell is operated the electrode is in contact with the confined plasma which collects electrons and a counter electrode which collects positive ions in a region outside of the confined plasma.

119. A cell according to any one of claims 1, 16, 39, 53 and 54 further comprising plasma confining structure constructed and arranged such that when the cell is operated the confining structure confines most of the hydrogen catalysis generated plasma to a desired region in the cell.

120. A cell according to claim 119, further comprising a power converter to convert separated ions into a voltage.

121. A cell according to claim 120, wherein the power converter comprises two separated electrodes located in regions where separated charges will occur when the cell is operated.

122. A cell according to claim 120, wherein the converter comprises a magnetic bottle.

123. A cell according to claim 120, wherein the converter comprises a source of solenoidal field.

124. A cell according to claim 120, wherein the converter comprises at least one electrode that is magnetized during operation of the cell and at least one counter electrode.

125. A cell according to claim 124, wherein the electrode provides a uniform magnetic field that is parallel to the electrode.

126. A cell according to claim 124, wherein the electrode comprises solenoidal magnets or permanent magnets to provide a uniform magnetic field.

127. A cell according to claim 124, wherein the magnetized electrode is constructed and arranged such that when in operation electrons are magnetically trapped on field lines at the magnetized electrode which collects positive ions, and the unmagnetized counter electrode collects electrons to produce a voltage between the electrodes.

128. A cell according to claim 127, wherein the magnetic field is adjustable to maximize the positive ion collection at the magnetized electrode.

129. A cell according to claim 119, further comprising localization means to selectively maintain the plasma in a desired region.

130. A cell according to claim 129, further comprising a plasma confining structure.

131. A cell according to claim 130, wherein the confining structure comprises a minimum B field.

132. A cell according to claim 130, wherein the confining structure comprises a magnetic bottle.

133. A cell according to claim 129, further comprising a means of spatial selective plasma generation and maintenance.

134. A cell according to claim 133, wherein the means of spatial selective plasma generation and maintenance comprises at least one selected from the group consisting of electrodes to provide an electric field, microwave antenna, microwave waveguide, and microwave cavity.

135. A cell according to any one of claims 1, 16, 39, 53 and 54 further comprising at least one electrode which is magnetized during operation to receive positive ions, at least one separated unmagnetized counter electrode to receive electrons, and an electrical load between the separated electrodes.

136. A cell according to any one of claims 1, 16, 39, 53 and 54, wherein the source of catalyst is in excess compared to the source of hydrogen atoms such that the formation of a nonthermal plasma is favored.

137. A cell according to any one of claims 1, 16, 39, 53 and 54, further comprising a cavity comprising at least one selected from the group consisting of Evenson, Beenakker, McCarrol, and cylindrical cavity.

138. A cell according to any one of claims 1, 16, 39, 53 and 54, wherein the catalyst comprises neon excimer, Ne₂ *, which absorbs 27.21 eV and is ionized to 2Ne⁺, to catalyze the transition of atomic hydrogen from the (p) energy level to the (p+1) energy level given by
$$\begin{matrix}27.21 eV + {Ne}_{2}^{*} + H [ \frac{{a}_{H}}{p} ] \to 2 {Ne}^{+} + H [ \frac{{a}_{H}}{( p + 1 )} ] + [ {( p + 1 )}^{2} - {p}^{2} ] X13 .6 eV \\ 2 {Ne}^{+} \to {Ne}_{2}^{*} + 27.21 eV\end{matrix}$$
and, the overall reaction is
$$H [ \frac{{a}_{H}}{p} ] \to H [ \frac{{a}_{H}}{( p + 1 )} ] + [ {( p + 1 )}^{2} - {p}^{2} ] X13 .6 eV .$$

139. A cell according to any one of claims 1, 16, 39, 53 and 54, wherein the catalyst comprises helium excimer, He₂ *, which absorbs 27.21 eV and is ionized to 2He⁺, to catalyze the transition of atomic hydrogen from the (p) energy level to the (p+1 ) energy level given by
$$\begin{matrix}27.21 eV + {He}_{2}^{*} + H [ \frac{{a}_{H}}{p} ] \to 2 {He}^{+} + H [ \frac{{a}_{H}}{( p + 1 )} ] + [ {( p + 1 )}^{2} - {p}^{2} ] X 13.6 eV \\ 2 {He}^{+} \to {He}_{2}^{*} + 27.21 eV\end{matrix}$$
and, the overall reaction is
$$H [ \frac{{a}_{H}}{p} ] \to H [ \frac{{a}_{H}}{( p + 1 )} ] + [ {( p + 1 )}^{2} - {p}^{2} ] X 13.6 eV .$$

140. A cell according to any one of claims 1, 16, 39, 53 and 54, wherein the catalyst comprises two hydrogen atoms which absorbs 27.21 eV and is ionized to 2H⁺, to catalyze the transition of atomic hydrogen from the (p) energy level to the (p+1) energy level given by
$$\begin{matrix}27.21 eV + 2 H [ \frac{{a}_{H}}{1} ] + H [ \frac{{a}_{H}}{p} ] \to 2 {H}^{+} + 2 {e}^{-} + H [ \frac{{a}_{H}}{( p + 1 )} ] + [ {( p + 1 )}^{2} - {p}^{2} ] X 13.6 eV \\ 2 {He}^{+} + 2 {e}^{-} \to 2 H [ \frac{{a}_{H}}{1} ] + 27.21 eV\end{matrix}$$
and, the overall reaction is
$$H [ \frac{{a}_{H}}{p} ] \to H [ \frac{{a}_{H}}{( p + 1 )} ] + [ {( p + 1 )}^{2} - p ] X 13.6 eV .$$

141. A cell according to any one of claims 1, 16, 39, 53 and 54, wherein the catalyst is atomic hydrogen.

142. A cell according to any one of claims 1, 16, 39, 53 and 54, further comprising a source of a weak electric field.

143. A cell according to claim 142, wherein the source of a weak electric field is constructed to produce a field in the range of about 0.1 to about 100 V/cm.

144. A cell according to claim 142 wherein the source of weak electric field is constructed and arranged to increase the rate of catalysis of the second catalyst such that the enthalpy of reaction of the catalyst matches approximately m·27.2±0.5 eV where m is an integer or m/2·27.2±0.5 eV where m is an integer greater than one to cause hydrogen catalysis when the cell is operated.

145. A cell according to claim 142, wherein the weak electric field is constructed and arranged to localize a plasma to a desired region of the cell during operation.

146. A cell according to any one of claims 1, 16, 39, 53 and 54 wherein the cell is further constructed and arranged to produce a compound comprising:
(a) at least one neutral, positive, or negative increased binding energy hydrogen species having a binding energy
(i) greater than the binding energy of the corresponding ordinary hydrogen species, or
(ii) greater than the binding energy of any hydrogen species for which the corresponding ordinary hydrogen species is unstable or is not observed because the ordinary hydrogen species' binding energy is less than thermal energies at ambient conditions, or is negative; and
(b) at least one other element.

147. A cell according to claim 146, wherein the increased binding energy hydrogen species is selected from the group consisting of Hₙ, Hₙ⁻, and Hₙ⁺, where n is a positive integer, with the proviso that n is greater than 1 when H has a positive charge.

148. A cell according to claim 146, wherein the increased binding energy hydrogen species is selected from the group consisting of (a) hydride ion having a binding energy that is greater than the binding of ordinary hydride ion (about 0.8 eV) for p=2 up to 23 in which the binding energy is represented by
$$Binding Energy = \frac{{ℏ}^{2} \sqrt{s ( s + 1 )}}{8 {μ}_{c} {{a}_{0}^{2} [ \frac{1 + \sqrt{s ( s + 1 )}}{p} ]}^{2}} - \frac{π {μ}_{0} {e}^{2} {ℏ}^{2}}{{m}_{c}^{2} {a}_{0}^{3}} ( 1 + \frac{{2}^{2}}{{[ \frac{1 + \sqrt{s ( s + 1 )}}{p} ]}^{3}} )$$
where p is an integer greater than one, s=1/2, π is pi, \overline{h} is Planck's constant bar, μ₀ is the permeability of vacuum, mₑ is the mass of the electron, μₑ is the reduced electron mass, a₀ is the Bohr radius, and e is the elementary charge; (b) hydrogen atom having a binding energy greater than about 13.6 eV; (c) hydrogen molecule having a first binding energy greater than about 15.5 eV; and (d) molecular hydrogen ion having a binding energy greater than about 16.4 eV.

149. A cell according to claim 146, wherein the increased binding energy hydrogen species is a hydride ion having a binding energy of about 3.0, 6.6, 11.2, 16.7, 22.8, 29.3, 36.1, 42.8, 49.4, 55.5, 61.0, 65.6, 69.2, 71.5, 72.4, 71.5, 68.8, 64.0, 56.8, 47.1, 34.6, 19.2, or 0.65 eV.

150. A cell according to claim 146, wherein the increased binding energy hydrogen species is a hydride ion having the binding energy:
$$Binding Energy = \frac{{ℏ}^{2} \sqrt{s ( s + 1 )}}{8 {μ}_{c} {{a}_{0}^{2} [ \frac{1 + \sqrt{s ( s + 1 )}}{p} ]}^{2}} - \frac{π {μ}_{0} {e}^{2} {ℏ}^{2}}{{m}_{c}^{2} {a}_{0}^{3}} ( 1 + \frac{{2}^{2}}{{[ \frac{1 + \sqrt{s ( s + 1 )}}{p} ]}^{3}} )$$
where p is an integer greater than one, s=1/2, π is pi, \overline{h} is Planck's constant bar, μ₀ is the permeability of vacuum, mₑ is the mass of the electron, μₑ is the reduced electron mass, a₀ is the Bohr radius, and e is the elementary charge.

151. A cell according to any one of claims 1, 16, 39, 53 and 54, wherein the cell is constructed and arranged to provide an increased binding energy hydrogen species selected from the group consisting of
(a) a hydrogen atom having a binding energy of about
$$\frac{13.6 eV}{{( \frac{1}{p} )}^{2}}$$
where p is an integer,
(b) an increased binding energy hydride ion (H⁻) having a binding energy of about
$$\frac{{ℏ}^{2} \sqrt{s ( s + 1 )}}{8 {μ}_{c} {{a}_{0}^{2} [ \frac{1 + \sqrt{s ( s + 1 )}}{p} ]}^{2}} - \frac{π {μ}_{0} {e}^{2} {ℏ}^{2}}{{m}_{c}^{2} {a}_{0}^{3}} ( 1 + \frac{{2}^{2}}{{[ \frac{1 + \sqrt{s ( s + 1 )}}{p} ]}^{3}} )$$
where s=1/2, π is pi, \overline{h} is Planck's constant bar, μ₀ is the permeability of vacuum, mₑ is the mass of the electron, μₑ is the reduced electron mass, a₀ is the Bohr radius, and e is the elementary charge;
(c) an increased binding energy hydrogen species H₄⁺ (1/p);
(d) an increased binding energy hydrogen species trihydrino molecular ion, H₃⁺(1/p), having a binding energy of about
$$\frac{22.6}{{( \frac{1}{p} )}^{2}} eV$$
where p is an integer,
(e) an increased binding energy hydrogen molecule having a binding energy of about
$$\frac{15.5}{{( \frac{1}{p} )}^{2}} eV ;$$
and
(f) an increased binding energy hydrogen molecular ion with a binding energy of about
$$\frac{16.4}{{( \frac{1}{p} )}^{2}} eV .$$

152. A cell according to claim 1, wherein the cell is further constructed and arranged such that during operation the catalysis reaction provides power to form and maintain a plasma initiated by the source of microwave power.

153. A cell according to claim 1, wherein the cell is further constructed and arranged such that during operation the catalysis reaction provides power to at least partially form and maintain a plasma.

154. A cell according to claim 1, further comprising a means to convert at least some of the power from hydrogen catalysis to microwave power to maintain a microwave driven plasma.

155. A cell according to claim 154, wherein the means to convert at least some of the power from hydrogen catalysis to microwave power comprises phase bunched or nonbunched electrons or ions in a magnetic field during operation of the cell.

156. A cell according to claim 1, wherein the cell comprises a vessel having a chamber capable of containing a vacuum or pressures greater than atmospheric, a source of microwave power to form a plasma, and the source of catalyst provides a catalyst having a net enthalpy of m·27.2±0.5 eV where m is an integer or m/2·27.2±0.5 eV where m is an integer greater than one.

157. A cell according to any one of claims 1, 16, 39, 53 and 54, further comprising a hydrogen supply tube and a hydrogen supply passage to supply hydrogen gas to the vessel.

158. A cell according to claim 157, further comprising a hydrogen flow controller and valve to control the flow of hydrogen to the chamber.

159. A cell according to any one of claims 1, 16, 39, 53 and 54, further comprising an anode and a hydrogen permeable hollow cathode of an electrolysis cell as the source of hydrogen communicating with the chamber that delivers hydrogen to the chamber through a hydrogen supply passage.

160. A cell according to claim 159, wherein the cell is constructed and arranged such that during operation electrolysis of water produces hydrogen that permeates through the hollow cathode.

161. A cell according to claim 160, wherein the hydrogen permeable hollow cathode comprises at least one of a transition metal, nickel, iron, titanium, noble metal, palladium, platinum, tantalum, palladium coated tantalum, and palladium coated niobium.

162. A cell according to claim 161, wherein the electrolyte is basic.

163. A cell according to claim 161, wherein the anode comprises nickel.

164. A cell according to claim 161, wherein the electrolyte comprises aqueous K₂CO₃.

165. A cell according to claim 161, wherein the anode comprises platinum.

166. A cell according to claim 161, wherein the anode is dimensionally stable.

167. A cell according to claim 161, further comprising an electrolysis current controller to control the flow of hydrogen into the cell.

168. A cell according to claim 161, further comprising an electrolysis power controller to control the flow of hydrogen into the cell.

169. A cell according to claim 161, further comprising a plasma gas, a plasma gas supply, and a plasma gas passage.

170. A cell according to any one of claims 1, 16, 39, 53 and 54, wherein a plasma gas flows from a plasma gas supply via the plasma gas passage into the vessel.

171. A cell according to claim 170, further comprising plasma gas flow controller and control valve.

172. A cell according to claim 171, wherein the plasma gas flow controller and control valve control the flow of plasma gas into the vessel.

173. A cell according to any one of claims 1, 16, 39, 53 and 54, further comprising a hydrogen-plasma-gas mixer and mixture flow regulator.

174. A cell according to any one of claims 1, 16, 39, 53 and 54, further comprising a hydrogen-plasma-gas mixture, a hydrogen-plasma-gas mixer, and a mixture flow regulator which control the composition of the mixture and the flow of the mixture into the vessel.

175. A cell according to any one of claims 1, 16, 39, 53 and 54, further comprising a passage for the flow of the hydrogen-plasma-gas mixture into the vessel.

176. A cell according to claim 170, wherein the plasma gas comprises at least one of helium or argon.

177. A cell according to claim 176, wherein the helium or argon comprise a source of catalyst which provides a catalyst comprising at least one of He⁺ or Ar⁺.

178. A cell according to claim 170, wherein the plasma gas comprises a source of catalyst and when the hydrogen-plasma-gas mixture flows into a plasma during operation it becomes a catalyst and atomic hydrogen in the vessel.

179. A cell according to claim 1, wherein the source of microwave power comprises a microwave generator, a tunable microwave cavity, waveguide, and a RF transparent window.

180. A cell according to claim 1, wherein the source of microwave power comprises a microwave generator, a tunable microwave cavity, waveguide, and an antenna.

181. A cell according to claim 1, wherein the source of microwave power is constructed and arranged such that microwaves are tuned by a tunable microwave cavity, carried by waveguide, and are delivered to the vessel though the RF transparent window.

182. A cell according to claim 1, wherein the source of microwave power is constructed and arranged such that microwaves are tuned by a tunable microwave cavity, carried by waveguide, and are delivered to the vessel though the antenna.

183. A cell according to claim 182, wherein the waveguide is inside of the cell.

184. A cell according to claim 182, wherein the waveguide is outside of the cell.

185. A cell according to claim 183, wherein the antenna is inside of the cell.

186. A cell according to claim 183, wherein the antenna is outside of the cell.

187. A cell according to claim 183, wherein the source of microwave power comprises at least one selected from the group consisting of traveling wave tubes, klystrons, magnetrons, cyclotron resonance masers, gyrotrons, and free electron lasers.

188. A cell according to claim 182, wherein the window comprises an Alumina or quartz window.

189. A cell according to claim 1, wherein the vessel comprises a microwave resonator cavity.

190. A cell according to claim 1, wherein the vessel comprises a cavity that is an Evenson microwave cavity and the source of microwave power excites a plasma in the Evenson cavity.

191. A cell according to claim 1, further comprising a magnet.

192. A cell according to claim 191, wherein the magnet comprises a solenoidal magnet to provide an axial magnetic field.

193. A cell according to claim 192, wherein the magnet is constructed and arranged to produce microwaves from the kinetic energy of the magnetized ions of the plasma during operation.

194. A cell according to claim 191, wherein the magnet is constructed and arranged to magnetize ions formed during the hydrogen catalysis reaction and produce microwaves to maintain a microwave discharge plasma.

195. A cell according to claim 1, wherein the source of microwave power is constructed and arranged such that a microwave frequency can be selected to efficiently form atomic hydrogen from molecular hydrogen.

196. A cell according to claim 1, wherein the source of microwave power is constructed and arranged such that a microwave frequency can be selected to efficiently form ions that serve as catalysts from a source of catalyst.

197. A cell according to claim 196, wherein the source of catalyst comprises at least one of helium or argon, which form at least one of He⁺ or Ar⁺ that acts as a catalyst during operation of the cell.

198. A cell according to claim 1, wherein the source of microwave power is constructed and arranged to provide a microwave frequency in the range of about 1 MHz to about 100 GHz.

199. A cell according to claim 1, wherein the source of microwave power is constructed and arranged to provide a microwave frequency in the range of about 50 MHz to about 10 GHz.

200. A cell according to claim 1, wherein the source of microwave power is constructed and arranged to provide a microwave frequency in the range of 75 MHz±about 50 MHz.

201. A cell according to claim 1, wherein the source of microwave power is constructed and arranged to provide a microwave frequency in the range of 2.4 GHz±about 1 GHz.

202. A cell according to any one of claims 1, 16, 39, 53 and 54, further comprising a source of a magnetic field which during operation provides magnetic confinement of the plasma.

203. A cell according to claim 202, wherein the source of magnetic field is constructed and arranged to provide a magnetic confinement which increases the electron energy to be converted into power.

204. A cell according to any one of claims 1, 16, 39, 53 and 54, further comprising a vacuum pump and vacuum lines connected to the cell.

205. A cell according to claim 204, wherein the vacuum pump is constructed and arranged to evacuate the vessel through the vacuum lines.

206. A cell according to any one of claims 1, 16, 39, 53 and 54, further comprising gas flow means constructed and arranged to supply hydrogen and catalyst continuously from the catalyst source and the hydrogen source.

207. A cell according to any one of claims 1, 16, 39, 53 and 54, further comprising a catalyst reservoir and a catalyst supply passage for the passage of catalyst from the reservoir to the vessel.

208. A cell according to claim 207, further comprising a catalyst reservoir heater and a power supply to heat the catalyst in the catalyst reservoir to provide the gaseous catalyst.

209. A cell according to claim 208, further comprising a temperature control means wherein the vapor pressure of the catalyst can be controlled by controlling the temperature of the catalyst reservoir.

210. A cell according to claim 209, wherein the catalyst comprises at least one selected from the group consisting of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Fe³⁺, Mo²⁺, Mo⁴⁺, Ne⁺, and In³⁺.

211. A cell according to any one of claims 1, 16, 39, 53 and 54, further comprising a chemically resistant open container located inside the vessel which contains the source of catalyst.

212. A cell according to claim 211, wherein the chemically resistant open container comprises a ceramic boat.

213. A cell according to claim 212, further comprising a heater for obtaining or maintaining an elevated cell temperature such that the source of catalyst in the boat is sublimed, boiled, or volatilized into the gas phase.

214. A cell according to claim 212, further comprising a boat heater, and a power supply for heating the source of catalyst in the boat to provide gaseous catalyst to the vessel.

215. A cell according to claim 214, further comprising a temperature control means wherein the vapor pressure of the catalyst can be controlled by controlling the temperature of the boat.

216. A cell according to claim 215, wherein the catalyst comprises at least one selected from the group consisting of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Ee³⁺, Mo²⁺, Mo⁴⁺, Ne⁺, and In³⁺.

217. A cell according to claim 211, further comprising a lower-energy hydrogen species and lower-energy hydrogen compound trap.

218. A cell according to claim 217, further comprising a vacuum pump in communication with the trap for causing a pressure gradient from the vessel to the trap for causing gas flow and transport of a lower-energy hydrogen species or lower-energy hydrogen compound.

219. A cell according to claim 218, further comprising a passage from the vessel to the trap and a vacuum line from the trap to the pump, and further comprising valves to and from the trap.

220. A cell according to any one of claims 1, 16, 39, 53 and 54, wherein the cell comprises at least one material selected from group consisting of stainless steel, molybdenum, tungsten, glass, quartz, and ceramic.

221. A cell according to any one of claims 1, 16, 39, 53 and 54, further comprising at least one selected from the group consisting of an aspirator, atomizer, or nebulizer, for forming an aerosol of the source of catalyst.

222. A cell according to claim 221, wherein the aspirator, atomizer, or nebulizer are constructed and arranged for injecting the source of catalyst or catalyst directly into the plasma during operation.

223. A cell according to any one of claims 1, 16, 39, 53 and 54, wherein the cell is constructed and arranged such that during operation a catalyst or source of catalyst is agitated from a source of catalyst and supplied to the vessel through a flowing gas stream.

224. A cell according to claim 223, wherein the flowing gas stream comprises hydrogen gas or plasma gas which may be an additional source of catalyst.

225. A cell according to claim 224, wherein the additional source of catalyst comprises helium or argon gas.

226. A cell according to any one of claims 1, 16, 39, 53 and 54, wherein the source of catalyst is dissolved or suspended in a liquid medium.

227. A cell according to claim 226, wherein the cell is further constructed and arranged such that the source of catalyst is dissolved or suspended in a liquid medium and aerosolized during operation of the cell.

228. A cell according to claim 227, wherein the liquid medium is contained in a catalyst reservoir.

229. A cell according to claim 227, further comprising a carrier gas for transporting the catalyst to the vessel during operation of the cell.

230. A cell according to claim 229, wherein the carrier gas comprises at least one of hydrogen, helium, or argon.

231. A cell according to claim 229, wherein the carrier gas comprises at least one of helium and argon which also serves as a source of catalyst and, during operation of the cell, is ionized by the plasma to form at least one catalyst He⁺ or Ar⁺.

232. A cell according to any one of claims 1, 16, 39, 53 and 54, wherein the cell is constructed and arranged to produce a nonthermal plasma having a temperature in the range of about 5,000 to about 5,000,000° C.

233. A cell according to any one of claims 1, 16, 39, 53 and 54, further comprising a catalyst reservoir and a heater constructed and arranged to provide a cell temperature above that of the catalyst reservoir to serve as a controllable source of catalyst.

234. A cell according to claim 233, wherein the heater is constructed and arranged to provide a cell temperature above that of the catalyst boat to serve as a controllable source of catalyst.

235. A cell according to any one of claims 1, 16, 39, 53 and 54, wherein the cell comprises stainless steel alloy which can be maintained in temperature range of about 0 to about 1200° C. during operation.

236. A cell according to any one of claims 1, 16, 39, 53 and 54, wherein the cell comprises molybdenum which can be maintained in temperature range of about 0 to about 1800° C. during operation.

237. A cell according to any one of claims 1, 16, 39, 53 and 54, wherein the cell comprises tungsten which can be maintained in temperature range of about 0 to about 3000° C.

238. A cell according to any one of claims 1, 16, 39, 53 and 54, wherein the cell comprises glass, quartz, or ceramic which can be maintained in a temperature range of about 0 about 1800° C.

239. A cell according to any one of claims 1, 16, 39, 53 and 54, wherein the cell is constructed and arranged to provide molecular and atomic hydrogen partial pressures in a range of about 1 mtorr to about 100 atm.

240. A cell according to any one of claims 1, 16, 39, 53 and 54, wherein the cell is constructed and arranged to provide molecular and atomic hydrogen partial pressures in a range of about 100 mtorr to about 20 torr.

241. A cell according to any one of claims 1, 16, 39, 53 and 54, wherein the cell is constructed and arranged to provide catalytic partial pressure in a range of about I mtorr to 100 atm.

242. A cell according to any one of claims 1, 16, 39, 53 and 54, wherein the cell is constructed and arranged to provide catalytic partial pressure in a range of about 100 mtorr to 20 torr.

243. A cell according to any one of claims 1, 16, 39, 53 and 54, further comprising a mixture flow regulator constructed and arranged to provide a flow rate of the plasma gas in the range of about 0 to about 1 standard liters per minute per cm³ of cell volume.

244. A cell according to claim 243, wherein the mixture flow regulator is constructed and arranged to provide a flow rate of the plasma gas in the range of about 0.001 to about 100 sccm per cm³ of cell volume.

245. A cell according to claim 243, wherein the mixture flow regulator is constructed and arranged to provide a flow rate of the hydrogen gas in the range of about 0 to about 1 standard liters per minute per cm³ of cell volume.

246. A cell according to claim 243, wherein the mixture flow regulator is constructed and arranged to provide a flow rate of the hydrogen gas in the range of about 0.001 to about 100 sccm per cm³ of cell volume.

247. A cell according to claim 243, wherein the hydrogen-plasma-gas mixture comprises at least one of helium or argon and being present in the amount of about 99 to about 1% by volume compared to the amount of hydrogen.

248. A cell according to claim 243, wherein the hydrogen-plasma-gas mixture comprises at least one of helium or argon and being present in the amount of about 99 to about 95% by volume compared to the amount of hydrogen.

249. A cell according to claim 243, wherein the mixture flow regulator is constructed and arranged to provide a flow rate of the hydrogen-plasma-gas mixture in the range of about 0 to about 1 standard liters per minute per cm³ of cell volume.

250. A cell according to claim 243, wherein the mixture flow regulator is constructed and arranged to provide a flow rate of the hydrogen-plasma- gas mixture in the range of about 0.001 to about 100 sccm per cm³ of cell volume.

251. A cell according to any one of claims 1, 16, 39, 53 and 54, wherein the cell is constructed and arranged to provide a power density of plasma power in the range of about 0.01 W to about 100 W/cm³ cell volume.

252. A cell according to any one of claims 1, 16, 39, 53 and 54, further comprising a power converter for converting plasma to electricity.

253. A cell according to claim 252, wherein the power converter comprises a heat engine.

254. A cell according to claim 252, wherein the direct plasma to electric power converter comprises at least one selected from the group consisting of magnetic mirror magnetohydrodynamic power converter, plasmadynamic power converter, gyrotron, photon bunching microwave power converter, photoelectric, and charge drift power converter.

255. A cell according to claim 252, wherein the heat engine power converter comprises at least one selected from the group consisting of steam, gas turbine system, sterling engine, thermionic, and thermoelectric.

256. A cell according to any one of claims 1, 16, 39, 53 and 54, further comprising a selective valve for removal of lower-energy hydrogen products.

257. A cell according to claim 256, wherein the selectively removed lower-energy hydrogen products comprise dihydrino molecules.

258. A cell according to any one of claims 1, 16, 39, 53 and 54, further comprising a cold wall to which increased binding energy hydrogen compounds can be cryopumped.

259. A cell according to claim 53, wherein the power converter comprises a magnetohydrodynamic power converter contained in a vacuum vessel.

260. A cell according to claim 53, wherein the cell is constructed and arranged such that the plasma is generated in a desired region and a plasma temperature is much greater than the temperature of the magnetohydrodynamic power converter vacuum vessel.

261. A cell according to claim 53, wherein the cell is constructed and arranged such that high energy ions and electrons of the plasma flow from the hot desired plasma region of the cell to the colder magnetohydrodynamic power converter by virtue of the second law of thermodynamics during operation of the cell.

262. A cell according to claim 53, wherein the magnetohydrodynamic power converter is constructed and arranged such that the thermodynamically produced ion flow is converted into electricity by the magnetohydrodynamic power converter which receives the flow.

263. A cell according to claim 53, wherein the magnetohydrodynamic power converter vacuum vessel further comprises a pump to maintain a lower pressure than the pressure in the cell where the plasma is formed.

264. A cell according to claim 53, wherein the cell is constructed and arranged such that energetic ions flow thermodynamically into the magnetohydrodynamic power converter and neutral particles formed from the energetic ions following conversion of their energy to electricity flow in the opposite direction.

265. A cell according to claim 53, wherein the cell is constructed and arranged such that protons and electron have a large mean free path and energetic protons and electrons flow from the cell into the magnetohydrodynamic power converter, and hydrogen flows convectively in substantially the opposite direction.

266. A cell according to any one of claims 1, 16, 39, 53 and 54, wherein the cell comprises a microwave cell.

267. A cell according to claim 266, further comprising at least one microwave antenna constructed and arranged to confine the plasma in a desired region of the cell during operation.

268. A cell according to claim 266, further comprising at least one microwave cavity constructed and arranged to confine the plasma in a desired region of the cell during operation.

269. A cell according to claim 268, wherein the microwave cavity comprises an Evenson cavity.

270. A cell according to claim 39, wherein hydrogen catalysis generated plasma is confined to a desired region during operation by at least two electrodes.

271. A cell according to any one of claims 1, 16, 39, 53 and 54 further comprising a vessel, a cathode, an anode, an electrolyte, a high voltage electrolysis power supply, and a source of catalyst capable of providing a net enthalpy of m·27.2±0.5 eV where m is an integer or m/2·27.2±0.5 eV where m is an integer greater than one.

272. A cell according to claim 271, wherein the power supply is constructed and arranged to provide a voltage in the range of about 10 to about 50 kV and a current density in the range of about 1 to about 100 A/cm².

273. A cell according to claim 271, wherein the anode comprises tungsten.

274. A cell according to claim 271, wherein the anode comprises platinum.

275. A cell according to claim 271, wherein the source of catalyst provides a catalyst comprising at least one selected from the group consisting of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Fe³⁺, Mo²⁺, Mo⁴⁺, Ne⁺, and In³⁺ during operation of the cell.

276. A cell according to any one of claims 1, 16, 39, 53 and 54, wherein the source of catalyst provides a catalyst comprising at least one selected from the group consisting of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Fe³⁺, Mo²⁺, Mo⁴⁺, In³⁺, Ne⁺ and K⁺/K⁺ during operation ofthe cell.

277. A cell according to claim 271, wherein the source of catalyst provides K⁺ that is reduced to a catalyst comprising potassium atom during operation of the cell.

278. A cell according to any one of claims 1, 16, 39, 53 and 54, further comprising an axial magnetic field constructed and arranged to cause energetic protons in the plasma during operation of the cell to undergo cyclotron motion, a means to cause the protons to gyrobunch to emit radio frequency radiation, and a receiver of the radio frequency power.

279. A cell according to claim 278, wherein the cell comprises a resonate cavity and an antenna to excite the cavity at a cyclotron resonance frequency of the protons during operation of the cell, and a second antenna to excite a proton spin resonance frequency to cause spin bunching wherein spin bunching causes gyrobunching during operation of the cell.

280. A cell according to claim 278, wherein the cell is constructed and arranged such that during operation gyro bunching can be achieved by spin bunching with the application of resonant RF at the proton spin resonance frequency.

281. A cell according to claim 278, wherein the antenna is constructed and arranged such that electromagnetic radiation emitted from the protons during operation of the cell excites the mode of the cavity and is received by the resonant receiving antenna.

282. A cell according to claim 278, further comprising a rectifier for rectifying a radiowave into DC electricity with a rectifier.

283. A cell according to claim 278, further comprising an inverter and power conditioner to invert and transform the DC electricity into a desired voltage and frequency.

284. A cell according to claim 16, further comprising at least on electrode and at least one cathode.

285. A cell according to claim 284, wherein at least one of the cathode and the anode is shielded by a dielectric barrier.

286. A cell according to claim 285, wherein the dielectric barrier comprises at least one selected from the group consisting of glass, quartz, Alumina, and ceramic.

287. A cell according to claim 16, wherein the cell is constructed and arranged such that the RF power can be capacitively coupled to the cell.

288. A cell according to claim 284, wherein the electrodes are external to the cell.

289. A cell according to claim 284, wherein at least one of the cathode and electrode is shielded by a dielectric barrier and the dielectric barrier separates the electrode and anode from a cell wall.

290. A cell according to claim 284, wherein the cell is constructed and arranged to provide a high driving voltage and high frequency.

291. A cell according to claim 290, wherein the cell is constructed and arranged to provide an AC power.

292. A cell according to claim 16, wherein the RF source of power comprises a driving circuit comprising a high voltage power source which is constructed and arranged to provide RF and an impedance matching circuit.

293. A cell according to claim 16, wherein the source of RF power is constructed and arranged to provide a frequency in the range of about 5 to about 10 kHz.

294. A cell according to claim 292, wherein the high voltage power source is constructed and arranged to provide a voltage in the range of about 100 V to about 1 MV.

295. A cell according to claim 292, wherein the high voltage power source is constructed and arranged to provide a voltage in the range of about 1 kV to about 100 kV.

296. A cell according to claim 292, wherein the high voltage power source is constructed and arranged to provide a voltage in the range of about 5 to about 10 kV.

297. A cell according to any one of claims 1, 16,39, 53 and 54, wherein the source of catalyst comprises one or more molecules wherein the energy to break the molecular bond and the ionization of t electrons from an atom from the dissociated molecule to a continuum energy level is such that the sum of the ionization energies of the t electrons is approximately m·27.2±0.5 eV where m is an integer or m/2.27.2±0.5 eV where m is an integer greater than one and t is an integer.

298. A cell according to claim 297, wherein the molecule comprises at least one selected from the group of C₂, N₂, O₂, CO₂, NO₂, and NO₃.

299. A cell according to any one of claims 1, 16, 39, 53 and 54, wherein the source of catalyst comprises a catalytic system provided by the ionization of t electrons from a participating species such as an atom, an ion, a molecule, and an ionic or molecular compound to a continuum energy level such that the sum of the ionization energies of the t electrons is approximately m·27.2±0.5 eV where m is an integer or m/2·27.2±0.5 eV where m is an integer greater than one and t is an integer.

300. A cell according to claim 299, wherein the catalytic system includes at least one selected from the group consisting of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt. He⁺, Na⁺, R⁺, Fe³⁺, Mo²⁺, Mo⁴⁺, Ne⁺, and In³⁺.

301. A cell according to any one of claims 1, 16, 39, 53 and 54, wherein a catalyst is provided by the transfer of t electrons between participating ions and the transfer of t electrons from one ion to another ion provides a net enthalpy of reaction whereby the sum of the ionization energy of the electron donating ion minus the ionization energy of the electron accepting ion equals approximately m·27.2±0.5 eV where m is an integer or m/2·27.2±0.5 eV where m is an integer greater than one and t is an integer.

302. A cell according to any one of claims 1, 16, 39, 53 and 54, wherein the source of catalyst comprises a molecule, and a catalyst of atomic hydrogen capable of providing a net enthalpy of reaction of m·27.2±0.5 eV where m is an integer or m/2·27.2±0.5 eV where m is an integer greater than one and capable of forming a hydrogen atom having a binding energy of about
$$\frac{13.6 eV}{{( \frac{1}{p} )}^{2}}$$
where p is an integer wherein the net enthalpy is provided by the breaking of a molecular bond of the source of catalyst and the ionization of t electrons from an atom of the broken molecule each to a continuum energy level such that the sum of the bond energy and the ionization energies of the t electrons is approximately m/2·27.2±0.5 eV where m is an integer greater than one and t is an integer.

303. A cell according to claim 302, wherein the molecule comprises at least one of C₂, N₂, O₂, CO₂, NO₂, and NO₃.

304. A cell according to claim 302, wherein the source of catalyst comprises the molecule in combination with an ion or atom catalyst.

305. A cell according to claim 302, wherein the molecule comprises at least one selected from the group of C₂, N₂, O₂, CO₂, NO₂, and NO₃ in combination with at least one atom or ion selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, He⁺, Na⁺, Rb⁺, Fe³⁺, Mo²⁺, Mo⁴⁺In³⁺, He⁺, Ar⁺, Xe⁺, Ar²⁺, Ne⁺, and H⁺, and Ne⁺ and H⁺.

306. A cell according to any one of claims 1, 16, 39, 53 and 54, wherein the cell is constructed and arranged to produce extreme ultraviolet light.

307. A cell according to claim 306, further comprising light propagation structure that propagates extreme ultraviolet light.

308. A cell according to claim 307, wherein the light propagation structure comprises quartz.

309. A cell according to any one of claims 1, 16, 39, 53 and 54, wherein the cell is constructed and arranged to produce ultraviolet light.

310. A cell according to claim 309, further comprising light propagation structure that propagates ultraviolet light.

311. A cell according to claim 310, wherein the light propagation structure comprises quartz.

312. A cell according to any one of claims 1, 16, 39, 53 and 54, wherein the cell is constructed and arranged to produce visible light.

313. A cell according to claim 312, further comprising light propagation structure that propagates visible light.

314. A cell according to claim 313, wherein the light propagation structure comprises glass.

315. A cell according to any one of claims 1, 16, 39, 53 and 54, wherein the cell is constructed and arranged to produce extreme infrared light.

316. A cell according to claim 315, further comprising light propagation structure that propagates infrared light.

317. A cell according to claim 316, wherein the light propagation structure comprises glass.

318. A cell according to any one of claims 1, 16, 39, 53 and 54, wherein the cell is constructed and arranged to produce microwaves.

319. A cell according to claim 318, further comprising light propagation structure that propagates microwaves.

320. A cell according to claim 319, wherein the light propagation structure comprises glass, quartz or ceramic.

321. A cell according to any one of claims 1, 16, 39, 53 and 54, wherein the cell is constructed and arranged to produce radiowaves.

322. A cell according to claim 321, further comprising light propagation structure that propagates radiowaves.

323. A cell according to claim 322, wherein the light propagation structure comprises glass, quartz or ceramic.

324. A cell according to any one of claims 1, 16, 39, 53 and 54, further comprising light propagation structure that propagates a wavelength of light produced during operation of the cell.

325. A cell according to any one of claims 1, 16, 39, 53 and 54, wherein the cell is constructed and arranged to provide short wavelength light and comprises a light propagation structure that propagates short wavelength light which is suitable for photolithography.

326. A cell according to any one of claims 1, 16, 39, 53 and 54, further comprising light propagation structure that comprises at least part of a cell wall and propagates a desired wavelength or wavelength range.

327. A cell according to claim 326, wherein the cell wall is insulated such that an elevated temperature may be maintained in the cell.

328. A cell according to claim 326, wherein the cell wall comprises a double wall with a separating vacuum space.

329. A cell according to any one of claims 1, 16, 39, 53 and 54, further comprising a light propagation structure coated with a phosphor that converts one or more short wavelengths to longer wavelength light.

330. A cell according to claim 329, wherein the phosphor converts at least one of ultraviolet and extreme ultraviolet light to visible light.

331. A cell according to any one of claims 1, 16, 39, 53 and 54 further comprising a hydrogen dissociator.

332. A cell according to claim 331, wherein the hydrogen dissociator comprises a filament.

333. A cell according to claim 332, wherein the filament comprises a tungsten filament.

334. A cell of according to 331, wherein the hydrogen dissociator further comprises a heater to heat the source of catalyst to form a gaseous catalyst.

335. A cell according to claim 334, wherein the source of catalyst comprises at least one selected from the group consisting of potassium, rubidium, cesium and strontium metal.

336. A cell according to any one of claims 1, 16, 39, 53 and 54, wherein the source of hydrogen comprises a hydride that decomposes over time to maintain a desired hydrogen partial pressure.

337. A cell according to claim 336, further comprising a means to control the temperature of the cell to maintain a desired decomposition rate of the hydride to provide a desired hydrogen partial pressure.

338. A cell according to claim 337, wherein the means to control the temperature comprises a heater and a heater power controller.

339. A cell according to claim 338, wherein the heater and controller comprise a filament and a filament power controller.

340. A cell according to claim 54, which is based on magnetic space charge separation.

341. A cell according to claim 54, which comprises a at least one of a hydrino hydride reactor or other power source such as a microwave plasma cell, at least one electrode magnetized with a source of magnetic field which provides a uniform parallel magnetic field, at least one magnetized electrode, and at least one counter electrode.

342. A cell according to claim 341, wherein the source of magnetic field comprises at least of solenoidal magnets and permanent magnets.

343. A cell according to claim 54, further comprising a means to localized the plasma in a desired region.

344. A cell according to claim 343, wherein the means to localized the plasma in a desired region comprises at least one of a magnetic confinement structure or spatially selective generation means.

345. A cell according to claim 344, wherein the cell is a microwave cell and the spatially selective generation means comprises one or more spatially selective antennas, waveguides, or cavities.

346. A cell according to claim 54, wherein electrons are magnetically trapped on field lines of the magnetic field while positive ions drift.

347. A cell according to claim 346, wherein the floating potential is increased at the magnetized electrode relative to the unmagnetized counter electrode to produce a voltage between the electrodes.

348. A cell according to claim 54, further comprising electrodes and power is supplied to a load through the connected electrodes.

349. A cell according to claim 54, further comprising a plurality of magnetized electrodes.

350. A cell according to claim 349, wherein the source of uniform magnetic field parallel to each electrode comprises Helmholtz coils.

351. A cell according to claim 350, wherein the strength of the magnetic field is adjusted to produce an optimal positive ion versus electron radius of gyration to maximize the power at the electrodes.

352. A cell according to claim 54, wherein plasma is confined to the region of at least one magnetized electrode, and the counter electrode is in a region outside of the energetic plasma.

353. A cell according to claim 54, wherein the energetic plasma is confined to a region of one unmagnetized electrode and a counter magnetized electrode is outside of the plasma region.

354. A cell according to claim 349, wherein both electrodes are magnetized, and the field strength at one electrode is greater than that at the other electrode.

355. A cell according to claim 349, wherein further comprises a heater that heats the magnetized electrode to boil off electrons which are much more mobile than the ions.

356. A cell according to claim 355, wherein the electrons are trapped by the magnetic field lines or recombine with ions to give rise to a greater positive voltage at the magnetized electron compared to the unmagnetized electrode.

357. A cell according to claim 54, wherein energy is extracted from energetic positive ions and electrons.

358. A cell according to claim 349, wherein a magnetized electrode comprises a magnetized pin wherein the field lines are substantially parallel to the pin.

359. A cell according to claim 358, wherein any flux that would intercept the pin ends on an electrical insulator.

360. A cell according to claim 359, comprising an array of the pins used to increase the power converted.

361. A cell according to claim 360, wherein at least one counter unmagnetized electrode is electrically connected to the one or more magnetized pins through an electrical load.

362. A cell comprising:
a reaction vessel;
a source of hydrogen; and
a source of microwave power constructed and arranged to provide sufficient microwave power to the hydrogen to dissociate the hydrogen into separate hydrogen atoms under conditions such that that two hydrogen atoms act like a catalyst and ionize to absorb a total of 27.2 eV from a third hydrogen atom to thereby cause the third hydrogen atom to relax to a lower energy state.

363. A cell comprising:
a reaction vessel;
a source of hydrogen; and
a source of microwave power constructed and arranged to provide sufficient microwave power to the hydrogen to dissociate the hydrogen and form a plasma.

364. A cell according to one of claims 362 and 363, further comprising a power converter for converting power from a plasma to electricity.

365. A cell according to claim 364, wherein the converter comprises a magnetohydrodynamic power converter.

366. A cell according to claim 364, wherein the converter comprises a plasmadynamic power converter.

367. A method of operating a cell for producing a plasma comprising the steps of:
providing a source of hydrogen atoms and a source of catalyst for catalyzing a reaction of hydrogen atoms to lower-energy states; and
applying microwaves to the source of hydrogen atoms and catalyst to initiate a reaction between hydrogen atoms and catalyst to form lower-energy hydrogen and produce a plasma.

368. A method according to claim 367, wherein the cell operates to provide a non-thermal plasma.

369. A method according to claim 367, wherein sufficient microwave power is provided to ionize the source of catalyst to provide a catalyst.

370. A method according to claim 369, wherein the source of microwave power is provided through the use of an antenna, waveguide, or cavity.

371. A method according to claim 367, wherein the source of catalyst is provided through the use of helium gas for producing He+ catalyst when ionized by microwave power.

372. A method according to claim 367, wherein the source of catalyst is provided through the use of argon gas for producing Ar+ catalyst when ionized by microwave power.

373. A method according to claim 367, wherein the source of catalyst is provided such that a catalyst formed by ionizing the source of catalyst using microwave power has a higher temperature than that at thermal equilibrium.

374. A method according to claim 367, further comprising the step of providing the source of catalyst such that excited or ionized states thereof predominate over excited or ionized states of hydrogen compared to a thermal plasma where excited or ionized states of hydrogen predominate.

375. A method according to claim 367, further comprising the step of using the source of microwave power to provide microwave power to the cell in the form of dissipated energetic electrons within about the electron mean free path.

376. A method according to claim 375, further comprising the step of using the source of microwave power to provide microwave power to the cell in the form of dissipated energetic electrons within about the electron mean free path of about 0.1 cm to 1 cm when the cell is operated at a pressure of about 0.5 to about 5 Torr.

377. A method according to claim 376, further comprising the step of constructing the cell to be greater than the electron mean free path.

378. A method according to claim 376, further comprising the steps of providing a microwave resonator cavity and providing sufficient microwave power to ionize the source of catalyst to provide a catalyst.

379. A method according to claim 378, wherein the cavity provided is an Evenson cavity.

380. A method according to claim 376, further comprising the step of providing a plurality of microwave power sources.

381. A method according to claim 376, further comprising the step of providing a plurality of Evenson cavities operating in parallel.

382. A method according to claim 381, further comprising the step of providing a quartz cell having a plurality of Evenson cavities spaced along a longitudinal axis.

383. A method according to claim 376, wherein the microwaves produce free hydrogen atoms from the source of hydrogen atoms.

384. A method of operating a cell for producing a plasma comprising the steps of:
providing a source of hydrogen atoms and a source of catalyst for catalyzing a reaction of hydrogen atoms to lower-energy states; and
applying radio waves (RF) to the source of hydrogen atoms and catalyst to initiate a reaction between the hydrogen and the catalyst to form lower-energy hydrogen and produce a plasma.

385. A method according to claim 384, wherein the RF power is capacitively or inductively coupled to the cell of the hydride reactor.

386. A method according to claim 384, further comprising two electrodes.

387. A method according to claim 386, further comprising a coaxial cable connected to a powered electrode by a coaxial center conductor.

388. A method according to claim 387, further comprising a coaxial center conductor connected to an external source coil which is wrapped around the cell.

389. A method according to claim 388, wherein the coaxial center conductor connected to an external source coil which is wrapped around the cell terminates without a connection to ground.

390. A method according to claim 388, wherein the coaxial center conductor connected to an external source coil which is wrapped around the cell is connected to ground.

391. A method according to claim 384, further comprising two electrodes wherein the electrodes are parallel plates.

392. A method according to claim 391, wherein the one of the parallel plate electrodes is powered and the other is connected to ground.

393. A method according to claim 384, wherein the cell comprises a Gaseous Electronics Conference (GEC) Reference Cell or modification.

394. A method according to claim 384, wherein the RF power is at 13.56 MHz.

395. A method according to claim 388, wherein at least one wall of the cell wrapped with the external coil is at least partially transparent to the RF excitation.

396. A method according to claim 384, wherein the RF frequency is in the range of about 100 Hz to about 100 GHz.

397. A method according to claim 384, wherein the RF frequency is in the range of about 1 kHz to about 100 MHz.

398. A method according to claim 384, wherein the RF frequency is in the range of about 13.56 MHz±50 MHz or about 2.4 GHz±1 GHz.

399. A method according to claim 384, further comprising at least one coil.

400. A method according to claim 384, wherein the cell comprises an Astron system.

401. A method according to claim 384, wherein the cell is an inductively coupled toroidal plasma cell comprising a primary of a transformer circuit.

402. A method according to claim 401, further comprising a primary of a transformer circuit driven by a radio frequency power supply.

403. A method according to claim 402, further comprising a primary of a transformer circuit wherein the plasma is a closed loop which acts at as a secondary of the transformer circuit.

404. A method according to claim 402, wherein the RF frequency is in the range of about 100 Hz to about 100 GHz.

405. A method according to claim 402, wherein the RF frequency is in the range of about 1 kHz to about 100 MHz.

406. A method according to claim 402, wherein the RF frequency is in the range of about 13.56 MHz±50 MHz or about 2.4 GHz±1 GHz.

407. A method of operating a cell comprising:
providing a source of hydrogen atoms, a source of catalyst for catalyzing a reaction of hydrogen atoms to lower-energy states, a hollow cathode, an anode and a power supply connected to the cathode and anode; and
supplying power to the cathode and anode and produce a glow discharge and react hydrogen atoms with the catalyst to form lower energy hydrogen and produce a plasma.

408. A method according to claim 407, wherein the hollow cathode comprises a compound electrode having multiple electrodes in series or parallel that may occupy a substantial portion of the volume of the cell.

409. A method according to claim 407, further comprising multiple hollow cathodes in parallel and producing a desired electric field in a large volume to generate a substantial power level.

410. A method according to claim 409, further comprising an anode and multiple concentric hollow cathodes each electrically isolated from a common anode.

411. A method according to claim 409, further comprising an anode and multiple parallel plate electrodes connected in series.

412. A method according to claim 409, wherein electrodes are operated at 1 to 100,000 volts.

413. A method according to claim 409, wherein electrodes are operated at 50 to 10,000 volts.

414. A method according to claim 409, wherein electrodes are operated at 50 to 5,000 volts.

415. A method according to claim 409, wherein the electrodes are operated at 50 to 500 volts.

416. A method according to claim 409, wherein the hollow cathode comprises at least one refractory material.

417. A method according to claim 416, wherein the refractory material comprises at least one of molybdenum or tungsten.

418. A method according to claim 409, comprising neon as the source of catalyst.

419. A method according to claim 409, comprising neon as the source of catalyst with hydrogen wherein neon is in the range of about 90 to about 99.99 atom % and hydrogen is in the range of about 0.01 to about 10 atom %.

420. A method according to claim 409, comprising neon as the source of catalyst with hydrogen wherein neon is in the range of about 99 to about 99.9 atom % and hydrogen is in the range of about 0.1 to 1 atom %.

421. A method of operating a cell for producing electricity comprising the steps of:
providing a source of hydrogen atoms and a source of catalyst for catalyzing a reaction of hydrogen atoms to lower-energy states;
reacting hydrogen atoms with the catalyst to form lower-energy hydrogen and produce a plasma; and
using a magnetohydrodynamic power converter to convert plasma energy into electricity.

422. A method of operating a cell for producing electricity comprising the steps of:
providing a source of hydrogen atoms and a source of catalyst for catalyzing a reaction of hydrogen atoms to lower-energy states;
reacting hydrogen atoms with the catalyst to form lower-energy hydrogen and produce a plasma; and
using a plasmadynamic power converter to convert plasma energy into electricity.

423. A method according to any one of claims 367, 384, 407, 421 and 422, wherein a cell wall temperature is elevated.

424. A method according to any one of claims 367, 384, 407, 421 and 422, wherein a cell wall temperature is from about 50 to about 2000° C.

425. A method according to any one of claims 367, 384, 407, 421 and 422, wherein a cell wall temperature is above 200° C.

426. A method according to any one of claims 367, 384, 407, 421 and 422, further comprising the step of using the source of catalyst to provide a catalyst having a net enthalpy of about m·27.2±0.5 eV, where m is an integer, when the catalyst is excited.

427. A method according to any one of claims 367, 384, 407, 421 and 422, further comprising the step of using the source of catalyst to provide a catalyst having a net enthalpy of about m/2·27.2+0.5 eV where m is an integer greater than one, when the catalyst is excited.

428. A method according to any one of claims 367, 384, 407, 421 and 422, further comprising the step of using the source of catalyst to provide a catalyst comprising He⁺ which absorbs 40.8 eV during the transition from the n=1 energy level to the n=2 energy level which corresponds to 3/2·27.2 eV (m=3) that serves as a catalyst for the transition of atomic hydrogen from the n=1 (p=1) state to the n=1/2 (p=2) state.

429. A method according to any one of claims 367, 384, 407, 421 and 422, further comprising the step of using the source of catalyst to provide a catalyst comprising Ar²⁺ which absorbs 40.8 eV and is ionized to Ar³⁺ which corresponds to 3/2·27.2 eV (m=3) during the transition of atomic hydrogen from the n=1 (p=1) energy level to the n=1/2 (p=2) energy level.

430. A method according to any one of claims 367, 384, 407, 421 and 422, wherein the source of catalyst is provided using a mixture of a first catalyst and a source of a second catalyst.

431. A method according to claim 430, further comprising the step of using the first catalyst to produce a second catalyst from the source of the second catalyst.

432. A method according to claim 431, wherein a plasma is produced upon the release of energy by the catalysis of hydrogen by the first catalyst.

433. A method according to claim 431, further comprising the step of selecting the first and second catalysts such that the energy released by the catalysis of hydrogen by the first catalyst ionizes the source of the second catalyst to produce the second catalyst.

434. A method according to claim 433, further comprising the step of producing one or more ions in the absence of a strong electric field.

435. A method according to claim 433, further comprising the step of providing a source of an electric field for increasing the rate of catalysis of the second catalyst such that the enthalpy of reaction of the catalyst matches about m/2·27.2±0.5 eV where m is an integer to cause hydrogen catalysis.

436. A method according to claim 430, further comprising the step of selecting the first catalyst from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, He⁺, Na⁺, Rb⁺, Fe³⁺, Mo²⁺, Mo⁴⁺, Ne⁺ and In³⁺.

437. A method according to claim 430, further comprising the step of selecting the source of second catalyst from the group of helium and argon.

438. A method according to claim 437, further comprising the step of producing a second catalyst, selected from the group of He⁺ and Ar⁺, from the source of second catalyst thereby generating a second catalyst ion from the corresponding atom by the plasma.

439. A method according to claim 430, further comprising the step of providing Ar⁺ as the second catalyst.

440. A method according to claim 430, further comprising the steps of providing argon as the source of second catalyst and using the catalysis of hydrogen with the first catalyst to ionize the argon thereby producing a second catalyst comprising Ar⁺.

441. A method according to claim 430, wherein the source of catalyst is provided using a mixture of strontium and argon whereby the catalysis of hydrogen by strontium produces a second catalyst of Ar⁺.

442. A method according to claim 430, wherein the source of catalyst is provided using a mixture of potassium and argon whereby the catalysis of hydrogen by potassium produces a second catalyst of Ar⁺.

443. A method according to any one of claims 367, 384, 407, 421 and 422, wherein the source of catalyst is provided using a mixture of a first catalyst and helium gas whereby He⁺ is produced as a second catalyst.

444. A method according to any one of claims 367, 384, 407, 421 and 422, wherein the source of catalyst is provided using a mixture of a first catalyst and helium whereby the catalysis of hydrogen by the first catalyst produces He⁺ which functions as a second catalyst.

445. A method according to any one of claims 367, 384, 407, 421 and 422, wherein the source of catalyst is provided using a mixture of strontium and helium whereby the catalysis of hydrogen by strontium produces He⁺ which functions as a second catalyst.

446. A method according to any one of claims 367, 384, 407, 421 and 422, wherein the source of catalyst is provided using a mixture of potassium and helium whereby the catalysis of hydrogen by potassium produces He⁺ which functions as a second catalyst.

447. A method according to any one of claims 367, 384, 407, 421 and 422, further comprising the steps of providing a source of a magnetic field and providing at least two electrodes for receiving power from the plasma.

448. A method according to any one of claims 367, 384, 407, 421 and 422, further comprising the steps of providing a means for causing a directional flow of ions, and providing a power converter for converting the kinetic energy of the flowing ions into electrical power.

449. A method according to claim 448, further comprising the step of at least partially converting the component of plasma ion motion perpendicular to the direction of the z-axis v_{⊥} into parallel motion v_{∥} due to the adiabatic invariant
$$\frac{{v}_{⊥}^{2}}{B} = constant$$
to form the directional flow of ions.

450. A method according to claim 448, further comprising the step of providing at least one magnetic mirror for at least partially converting the component of plasma ion motion perpendicular to the direction of the z-axis v_{⊥} into parallel motion v_{∥} due to the adiabatic invariant
$$\frac{{v}_{⊥}^{2}}{B} = constant$$
to form the directional flow of ions.

451. A method according to claim 421, further comprising the steps of providing a magnetohydrodynamic power converter such that ions have a preferential velocity along a z-axis and propagate into the magnetohydrodynamic power converter, and providing the magnetohydrodynanic power converter with electrodes and a magnetic field crossed with a direction of the flowing ions whereby the ions are Lorentzian deflected by the magnetic field and the deflected ions form a voltage at the electrodes crossed with the corresponding transverse deflecting field.

452. A method according to claim 451, further comprising the step of using the electrode voltage to drive a current through an electrical load.

453. A method according to claim 421, further comprising the step of providing the magnetohydrodynamic power converter using a segmented Faraday generator type magnetohydrodynamic power converter such that the ions have a preferential velocity along the z-axis and propagate into the converter and further using a magnetic field crossed with the direction of the flowing ions, whereby the ions are Lorentzian deflected by the magnetic field and the deflected ions form a voltage at electrodes crossed with the corresponding transverse deflecting field.

454. A method according to claim 421, further comprising the step of providing a magnetohydrodynamic power converter such that ions have a preferential velocity along the z-axis and propagate into the magnetohydrodynamic power converter, which uses a magnetic field crossed with the direction of the flowing ions and at least two electrodes, whereby the ions are Lorentzian deflected by the magnetic field to form a transverse current and the transverse current is deflected by the crossed magnetic field to form a Hall voltage between at least two electrodes which are transverse to and separated along the z-axis.

455. A method according to claim 454, further comprising the step of using the electrode voltage to drive a current through an electrical load.

456. A method according to claim 421, further comprising the step of providing a Hall generator type magnetohydrodynamic power converter such that ions have a preferential velocity along the z-axis and propagate into the Hall generator type magnetohydrodynamic power converter, which uses a magnetic field crossed with the direction of the flowing ions and at least two electrodes, wherein the ions are Lorentzian deflected by the magnetic field to form a transverse current and the transverse current is deflected by the crossed magnetic field to form a Hall voltage between at least two electrodes which are transverse to and separated along the z-axis.

457. A method according to claim 421, further comprising the step of providing a diagonal generator having a window frame construction type magnetohydrodynamic power converter such that ions have a preferential velocity along the z-axis and propagate into the converter, which uses a magnetic field crossed with the direction of the flowing ions and at least two ions, wherein the ions are Lorentzian deflected by the magnetic field to form a transverse current and the transverse current is deflected by the crossed magnetic field to form a Hall voltage between at least two electrodes which are transverse to and separated along the z-axis.

458. A method according to any one of claims 367, 384, 407, 421 and 422, further comprising the step of confining the hydrogen catalysis generated plasma to a desired region.

459. A method according to any one of claims 367, 384, 407, 421 and 422, further comprising the step of providing at least two electrodes for confining the hydrogen catalysis generated plasma to the desired region.

460. A method according to claim 459, further comprising the step of providing at least one microwave antenna for confining the hydrogen catalysis generated plasma to the desired region.

461. A method according to claim 459, further comprising the step of providing a microwave cavity for confining the hydrogen catalysis generated plasma to the desired region.

462. A method according to claim 461, wherein the microwave cavity provided is an Evenson cavity.

463. A method according to any one of claims 367, 384, 407, 421 and 422, further comprising the step of providing a magnetic bottle having a plurality of magnetic mirrors, whereby ions penetrate at least one of the magnetic mirrors to form the source of ions having a preferential velocity along the z-axis and propagate into a power converter for converting the kinetic energy of the flowing ions into electrical power.

464. A method according to claim 421, further comprising the step of providing a magnetohydrodynamic power converter such that the source of ions having a preferential velocity along the z-axis propagate into the magnetohydrodynamic power converter, whereby Lorcntzian deflected ions form a voltage at electrodes crossed with the corresponding transverse deflecting field.

465. A method according to any one of claims 367, 384, 407, 421 and 422, wherein the cell comprises a discharge cell.

466. A method according to claim 466, further comprising the step of providing structure for producing intermittent or pulsed discharge current.

467. A method according to claim 466, further comprising the step of providing structure for producing an offset voltage of from about 0.5 to about 500 V.

468. A method according to claim 466, further comprising the step of providing structure for producing an offset voltage which provides a field of about 1 V/cm to about 10 V/cm.

469. A method according to claim 466, further comprising the step of providing structure for producing a pulse frequency of from about 0.1 Hz to about 100 MHz and a duty cycle of about 0.1% to about 95%.

470. A method according to any one of claims 367, 384, 407, 421 and 422, further comprising the step of providing a hydrogen catalyst of atomic hydrogen capable of providing a net enthalpy of m·27.2±0.5 eV where m is an integer or m/2·27.2±0.5 eV where m is an integer greater than one and capable of forming a hydrogen atom having a binding energy of about
$$\frac{13.6 eV}{{( \frac{1}{p} )}^{2}}$$
where p is an integer whereby the net enthalpy is provided by the breaking of a molecular bond of the catalyst and the ionization of t electrons from an atom of the broken molecule each to a continuum energy level such that the sum of the bond energy and the ionization energies of the t electrons is approximately m·27.2±0.5 eV where m is an integer or m/2·27.2±0.5 eV where m is an integer greater than one.

471. A method according to claim 471, wherein the hydrogen catalyst is provided using at least one of C₂, N₂, O₂, CO₂, NO₂, and NO₃.

472. A method according to claim 471, further comprising the step of providing a molecule in combination with the hydrogen catalyst.

473. A method according to any one of claims 367, 384, 407, 421 and 422, wherein the source of catalyst is provided using at least one molecule selected from the group of C₂, N₂, O₂, CO₂, NO₂, and NO₃ in combination with at least one atom or ion selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, He⁺, Na⁺, Rb⁺, Fe³⁺, Mo²⁺, Mo⁴⁺, In³⁺, He⁺, Ar⁺, Xe⁺, Ar²⁺, Ne⁺, and H⁺, and Ne⁺and H⁺.

474. A method according to any one of claims 367, 3°4, 407, 421 and 422, wherein catalytic disproportionation reaction of atomic hydrogen occurs wherein lower-energy hydrogen atoms (hydrinos) act as catalysts because each of the metastable excitation, resonance excitation, and ionization energy of a hydrino atom is m×27.2 eV.

475. A method according to claim 474, wherein a first hydrino atom is reacted to a lower energy state affected by a second hydrino atom which involves a resonant coupling between the hydrino atoms of m degenerate multipoles each having 27.21 eV of potential energy.

476. A method according to claim 474, wherein the energy transfer of m×27.2 eV from the first hydrino atom to the second hydrino atom causes the central field of the first atom to increase by m and its electron to drop m levels lower from a radius of
$$\frac{{a}_{H}}{p}$$
to a radius of
$$\frac{{a}_{H}}{p + m} .$$

477. A method according to claim 474, wherein the second interacting hydrino atom is either excited to a metastable state, excited to a resonance state, or ionized by the resonant energy transfer.

478. A method according to claim 474, wherein the resonant transfer may occur in multiple stages.

479. A method according to claim 474, wherein a nonradiative transfer by multipole coupling can occur wherein the central field of the first increases by m, then the electron of the first drops m levels lower from a radius of
$$\frac{{a}_{H}}{p}$$
to a radius of
$$\frac{{a}_{H}}{p + m}$$
with further resonant energy transfer.

480. A method according to claim 474, wherein the energy transferred by multipole coupling may occur by a mechanism that is analogous to photon absorption involving an excitation to a virtual level.

481. A method according to claim 474, wherein the energy transferred by multipole coupling during the electron transition of the first hydrino atom may occur by a mechanism that is analogous to two photon absorption involving a first excitation to a virtual level and a second excitation to a resonant or continuum level.

482. A method according to claim 474, wherein the catalytic reaction with hydrino catalysts for the transition of
$$H [ \frac{{a}_{H}}{p} ] to H [ \frac{{a}_{H}}{p + m} ]$$
induced by a multipole resonance transfer of m·27.21 eV and a transfer of [(p′)²−(p′−m′)²]×13.6 eV−m·27.2 eV with a resonance state of
$$H [ \frac{{a}_{H}}{{p}^{′} - {m}^{′}} ]$$
excited in
$$H [ \frac{{a}_{H}}{{p}^{′}} ]$$
is represented by
$$H ⌊ \frac{{a}_{H}}{{p}^{′}} ⌋ + H ⌊ \frac{{a}_{H}}{p} ⌋ -> H [ \frac{{a}_{H}}{{p}^{′} - {m}^{′}} ] + \\ H [ \frac{{a}_{H}}{p + m} ] + [ ( {( p + m )}^{2} - {p}^{2} ) - ( {p}^{′2} - {( {p}^{′} - {m}^{′} )}^{2} ) ] \times 13.6 eV$$
where p, p′, m, and m′ are integers.

483. A method according to any one of claims 367, 384, 407, 421 and 422, wherein the lower-energy hydrogen atoms (hydrino atoms), which have the initial lower-energy state quantum number p and radius
$$\frac{{a}_{H}}{p} ,$$
may undergo a transition to the state with lower-energy state quantum number (p+m) and radius
$$\frac{{a}_{H}}{( p + m )}$$
by reaction with a hydrino atom with the initial lower-energy state quantum number m′, initial radius
$$\frac{{a}_{H}}{{m}^{′}} ,$$
and final radius a_{H} that provides a net enthalpy of m·27.2±0.5 eV where m is an integer or m/2·27.2±0.5 eV where m is an integer greater than one.

484. A method according to claim 485, wherein the hydrino atom,
$$H [ \frac{{a}_{H}}{p} ] ,$$
with hydrino atom,
$$H [ \frac{{a}_{H}}{p} ] ,$$
is ionized by the resonant energy transfer to cause a transition reaction is represented by
$$m \times 27.21 eV + H [ \frac{{a}_{H}}{{m}^{′}} ] + H [ \frac{{a}_{H}}{p} ] -> \\ {H}^{+} + {e}^{-} + H [ \frac{{a}_{H}}{( p + m )} ] + [ {( p + m )}^{2} - {p}^{2} - ( {m}^{′2} - 2 m ) ] \times 13.6 eV$$
$${H}^{+} + {e}^{-} -> H [ \frac{{a}_{H}}{p} ] + 13.6 eV$$
And, the overall reaction is
$$H [ \frac{{a}_{H}}{{m}^{′}} ] + H [ \frac{{a}_{H}}{p} ] -> H [ \frac{{a}_{H}}{1} ] + \\ H [ \frac{{a}_{H}}{( p + m )} ] + [ 2 p m + {m}^{2} - {m}^{′2} ] \times 13.6 eV + 13.6 eV .$$

485. A method according to any one of claims 367, 384, 407, 421 and 422, further comprising the step of providing a power converter for separating ions and electrons to produce a voltage across at least two separated electrodes.

486. A method according to claim 485, wherein the power converter provided uses a source of a magnetic field.

487. A method according to claim 485, wherein the power converter provided selectively confines electrons.

488. A method according to claim 485, wherein the source of magnetic field comprises at least one of a minimum B field source or a magnetic bottle.

489. A method according to claim 485, further comprising the steps of providing an electrode in contact with the confined plasma for collecting electrons and providing a counter electrode for collecting positive ions in a region outside of the confined plasma.

490. A method according to any one of claims 367, 384, 407, 421 and 422, further comprising the step of providing structure for confining most of the hydrogen catalysis generated plasma to a desired region in the cell.

491. A method according to claim 490, further comprising the step of providing a power converter for converting separated ions into a voltage.

492. A method according to claim 491, wherein the power converter provided uses two separated electrodes located in regions where separated charges occur.

493. A method according to claim 491, wherein the converter provided comprises a magnetic bottle.

494. A method according to claim 491, wherein the converter provided comprises a source of solenoidal field.

495. A method according to claim 491, wherein the converter provided comprises at least one electrode that is magnetized during operation of the cell and at least one counter electrode.

496. A method according to claim 495, wherein the electrode provides a uniform magnetic field that is parallel to the electrode.

497. A method according to claim 495, wherein the electrode comprises solenoidal magnets or permanent magnets to provide a uniform magnetic field.

498. A method according to claim 495, wherein the magnetized electrode magnetically traps electrons on field lines at the magnetized electrode which collects positive ions, and the unmagnetized counter electrode collects electrons to produce a voltage between the electrodes.

499. A method according to claim 498, further comprising the step of adjusting the magnetic field to maximize the positive ion collection at the magnetized electrode.

500. A method according to claim 485, further comprising the step of providing localization means for selectively maintaining the plasma in a desired region.

501. A method according to claim 500, further comprising the step of providing structure for confining the plasma.

502. A method according to claim 501, wherein the confining structure comprises a minimum B field.

503. A method according to claim 502, wherein the confining structure comprises a magnetic bottle.

504. A method according to claim 500, further comprising the step of providing a means of spatial selective plasma generation and maintenance.

505. A method according to claim 504, wherein the means of spatial selective plasma generation and maintenance is provided using at least one selected from the group consisting of electrodes to provide an electric field, microwave antenna, microwave waveguide, and microwave cavity.

506. A method according to any one of claims 367, 384, 407, 421 and 422, further comprising the step of providing at least one electrode which is magnetized to receive positive ions, at least one separated unmagnetized counter electrode to receive electrons, and an electrical load between the separated electrodes.

507. A method according to claim 407, wherein the hollow cathode is provided with a compound electrode having multiple electrodes in series or parallel that may occupy a substantial portion of the volume of the cell.

508. A method according to claim 407, further comprising the step of providing multiple hollow cathodes in parallel for producing a desired electric field in a large volume to generate a substantial power level.

509. A method according to claim 407, further comprising the step of providing an anode and multiple concentric hollow cathodes each electrically isolated from the common anode.

510. A method according to claim 407, further comprising the step of providing an anode and multiple parallel plate electrodes connected in series.

511. A method according to any one of claims 367, 384, 407, 421 and 422, wherein the cell produces a compound comprising:
(a) at least one neutral, positive, or negative increased binding energy hydrogen species having a binding energy
(i) greater than the binding energy of the corresponding ordinary hydrogen species, or
(ii) greater than the binding energy of any hydrogen species for which the corresponding ordinary hydrogen species is unstable or is not observed because the ordinary hydrogen species' binding energy is less than thermal energies at ambient conditions, or is negative; and
(b) at least one other element.

512. A method according to claim 511, further comprising the step of using an increased binding energy hydrogen species from the group consisting of Hₙ, Hₙ⁻, and Hₙ⁺ where n is a positive integer, with the proviso that n is greater than 1 when H has a positive charge.

513. A method according to claim 511, further comprising the step of using an increased binding energy hydrogen species from the group consisting of (a) hydride ion having a binding energy that is greater than the binding of ordinary hydride ion (about 0.8 eV) for p=2 up to 23 in which the binding energy is represented by
$$Binding Energy = \frac{{ℏ}^{2} \sqrt{s ( s + 1 )}}{8 {μ}_{c} {{a}_{0}^{2} [ \frac{1 + \sqrt{s ( s + 1 )}}{p} ]}^{2}} - \frac{{πμ}_{0} {ⅇ}^{2} {ℏ}^{2}}{{m}_{c}^{2} {a}_{0}^{3}} ( 1 + \frac{{2}^{2}}{{[ \frac{1 + \sqrt{s ( s + 1 )}}{p} ]}^{3}} )$$
where p is an integer greater than one, s=1/2, π is pi, \overline{h} is Planck's constant bar, μ₀ is the permeability of vacuum, mₑ is the mass of the electron, μₑ is the reduced electron mass, a₀ is the Bohr radius, and e is the elementary charge; (b) hydrogen atom having a binding energy greater than about 13.6 eV; (c) hydrogen molecule having a first binding energy greater than about 15.5 eV; and (d) molecular hydrogen ion having a binding energy greater than about 16.4 eV.

514. A method according to claim 511, wherein the increased binding energy hydrogen species is a hydride ion having a binding energy of about 3.0, 6.6, 11.2, 16.7, 22.8, 29.3, 36.1, 42.8, 49.4, 55.5, 61.0, 65.6, 69.2, 71.5, 72.4, 71.5, 68.8, 64.0, 56.8, 47.1, 34.6, 19.2, or 0.65 eV.

515. A method according to claim 511, wherein the increased binding energy hydrogen species is a hydride ion having the binding energy:
$$Binding Energy = \frac{{ℏ}^{2} \sqrt{s ( s + 1 )}}{8 {μ}_{c} {{a}_{0}^{2} [ \frac{1 + \sqrt{s ( s + 1 )}}{p} ]}^{2}} - \frac{{πμ}_{0} {ⅇ}^{2} {ℏ}^{2}}{{m}_{c}^{2} {a}_{0}^{3}} ( 1 + \frac{{2}^{2}}{{[ \frac{1 + \sqrt{s ( s + 1 )}}{p} ]}^{3}} )$$
where p is an integer greater than one, s=1/2, π is pi, \overline{h} is Planck's constant bar, μ₀ is the permeability of vacuum, mₑ is the mass of the electron, μₑ is the reduced electron mass, a₀ is the Bohr radius, and e is the elementary charge.

516. A method according to any one of claims 367, 384, 407, 421 and 422, further comprising the step of providing a source of a weak electric field.

517. A method according to claim 516, wherein the source of a weak electric field produces a field in the range of about 0.1 to about 100 V/cm.

518. A method according to claim 516, wherein the source of weak electric field increases the rate of catalysis of a second catalyst such that the enthalpy of reaction of the catalyst matches approximately m·27.2±0.5 eV where m is an integer or m/2·27.2±0.5 eV where m is an integer greater than one to cause hydrogen catalysis when the cell is operated.

519. A method according to claim 516, wherein the weak electric field localizes the plasma to a desired region of the cell.

520. A method according to claim 367, wherein the source of microwave energy provides a microwave discharge to form a catalyst from the source of catalyst.

521. A method according to claim 367, wherein the catalysis reaction provides power for forming and maintaining a plasma initiated by the source of microwave power.

522. A method according to claim 521, wherein the catalysis reaction provides power for at least partially forming and maintaining a plasma.

523. A method according to claim 521, further comprising the step of providing a means for converting at least some of the power from hydrogen catalysis to microwave power for maintaining a microwave driven plasma.

524. A method according to claim 523, wherein the means for converting at least some of the power from hydrogen catalysis to microwave power comprises phase bunched or nonbunched electrons or ions in a magnetic field.

525. A method according to claim 523, further comprising the step of providing a source of microwave power for forming a plasma, wherein the cell comprises a vessel having a chamber capable of containing a vacuum or pressures greater than atmospheric and the source of catalyst provides a catalyst having a net enthalpy of m·27.2±0.5 eV where m is an integer or m/2·27.2±0.5 eV where m is an integer greater than one.

526. A method according to any one of claims 367, 384, 407, 421 and 422, further comprising the step of providing a hydrogen supply tube and a hydrogen supply passage for supplying hydrogen gas to the vessel.

527. A method according to claim 526, further comprising the step of providing a hydrogen flow controller and valve to control the flow of hydrogen to the chamber.

528. A method according to claim 407, further comprising the step of using an anode and a hydrogen permeable hollow cathode of an electrolysis cell as the source of hydrogen communicating with the chamber that delivers hydrogen to the chamber through a hydrogen supply passage and an anode.

529. A method according to claim 528, wherein electrolysis of water is used to produce hydrogen that permeates through the hollow cathode.

530. A method according to claim 529, wherein the hydrogen permeable hollow cathode comprises at least one of a transition metal, nickel, iron, titanium, noble metal, palladium, platinum, tantalum, palladium coated tantalum, and palladium coated niobium.

531. A method according to claim 528, wherein the electrolyte is basic.

532. A method according to claim 528, wherein the anode comprises nickel.

533. A method according to claim 528, wherein the electrolyte comprises aqueous K₂CO₃.

534. A method according to claim 528, wherein the anode comprises platinum.

535. A method according to claim 528, wherein the anode is dimensionally stable.

536. A method according to claim 528, further comprising the step of providing an electrolysis current controller for controlling the flow of hydrogen into the cell.

537. A method according to claim 528, further comprising the step of providing an electrolysis power controller to control the flow of hydrogen into the cell.

538. A method according to any one of claims 367, 384, 407, 421 and 422, further comprising the step of providing a plasma gas, a plasma gas supply, and a plasma gas passage into the vessel.

539. A method according to claim 538, further comprising the step of allowing the plasma gas to flow from the plasma gas supply via the plasma gas passage into the vessel.

540. A method according to claim 538, further comprising the step of providing a plasma gas flow controller and control valve.

541. A method according to claim 540, further comprising the step of using the plasma gas flow controller and control valve to control the flow of plasma gas into the vessel.

542. A method according to claim 538, further comprising the step of providing a hydrogen-plasma-gas mixer and mixture flow regulator.

543. A method according to claim 538, further comprising the step of providing a hydrogen-plasma-gas mixture, a hydrogen-plasma-gas mixer, and a mixture flow regulator for controlling the composition of the mixture and the flow of the mixture into the vessel.

544. A method according to claim 538, wherein the plasma gas comprises at least one of helium or argon.

545. A method according to claim 544, wherein the helium or argon comprise a source of catalyst which provides a catalyst comprising at least one of He⁺ or Ar⁺.

546. A method according to claim 538, wherein the plasma gas comprises a source of catalyst and when the hydrogen-plasma-gas mixture flows into a plasma it becomes a catalyst and atomic hydrogen in the vessel.

547. A method according to claim 367, wherein the source of microwave power comprises a microwave generator, a tunable microwave cavity, waveguide, and a RF transparent window.

548. A method according to claim 367, wherein the source of microwave power comprises a microwave generator, a tunable microwave cavity, waveguide, and an antenna.

549. A method according to claim 367, wherein the source of microwave power provides microwaves that are tuned by a tunable microwave cavity, carried by waveguide, and are delivered to the vessel though the RF transparent window.

550. A method according to claim 367, wherein the source of microwave power provides microwaves that are tuned by a tunable microwave cavity, carried by waveguide, and are delivered to the vessel though the antenna.

551. A method according to claim 550, wherein the waveguide is inside of the cell.

552. A method according to claim 550, wherein the waveguide is outside of the cell.

553. A method according to claim 550, wherein the antenna is inside of the cell.

554. A method according to claim 550, wherein the antenna is outside of the cell.

555. A method according to claim 367, wherein the source of microwave power comprises at least one selected from the group consisting of traveling wave tubes, klystrons, magnetrons, cyclotron resonance masers, gyrotrons, and free electron lasers.

556. A method according to claim 549, wherein the window comprises an Alumina or quartz window.

557. A method according to claim 367, wherein the vessel comprises a microwave resonator cavity.

558. A method according to claim 367, wherein the vessel comprises a cavity that is an Evenson microwave cavity and the source of microwave power excites a plasma in the Evenson cavity.

559. A method according to claim 367, further comprising the step of providing a magnet.

560. A method according to claim 559, wherein the magnet comprises a solenoidal magnet for providing an axial magnetic field.

561. A method according to claim 559, wherein the magnet produces microwaves from the kinetic energy of the magnetized ions of the plasma.

562. A method according to claim 559, wherein the magnetic magnetizes ions formed during the hydrogen catalysis reaction and produces microwaves for maintaining a microwave discharge plasma.

563. A method according to claim 367, wherein the source of microwave power allows a microwave frequency to be selected to efficiently form atomic hydrogen from molecular hydrogen.

564. A method according to claim 367, wherein the source of microwave power allows a microwave frequency to be selected to efficiently form ions that serve as catalysts from a source of catalyst.

565. A method according to claim 367, wherein the source of microwave power provides a microwave frequency in the range of about 1 MHz to about 100 GHz.

566. A method according to claim 367, wherein the source of microwave power provides a microwave frequency in the range of about 50 MHz to about 10 GHz.

567. A method according to claim 367, wherein the source of microwave power provides a microwave frequency in the range of 75 MHz±about 50 MHz.

568. A method according to claim 367, wherein the source of microwave power provides a microwave frequency in the range of 2.4 GHz±about 1 GHz.

569. A method according to any one of claims 367, 384, 407, 421 and 422, further comprising the step of providing a source of a magnetic field for magnetically confining the plasma.

570. A method according to claim 569, wherein the source of magnetic field provides a magnetic confinement which increases the electron energy to be converted into power.

571. A method according to any one of claims 367, 384, 407, 421 and 422, further comprising the step of providing a vacuum pump and vacuum lines connected to the cell.

572. A method according to any one of claims 367, 384, 407, 421 and 422, wherein the vacuum pump evacuates the vessel through the vacuum lines.

573. A method according to any one of claims 367, 384, 407, 421 and 422, further comprising the step of providing gas flow means for supplying hydrogen and catalyst continuously from the catalyst source and the hydrogen source.

574. A method according to any one of claims 367, 384, 407, 421 and 422, further comprising the step of providing a catalyst reservoir and a catalyst supply passage for the passage of catalyst from the reservoir to the vessel.

575. A method according to any one of claims 367, 384, 407, 421 and 422, further comprising the step of providing a catalyst reservoir heater and a power supply for heating the catalyst in the catalyst reservoir to provide the gaseous catalyst.

576. A method according to claim 575, further comprising the step of providing a temperature control means for controlling the temperature of the catalyst reservoir, thereby controlling the vapor pressure of the catalyst.

577. A method according to any one of claims 367, 384, 407, 421 and 422, further comprising the step of providing a chemically resistant open container located inside the vessel for containing the source of catalyst.

578. A method according to claim 577, wherein the chemically resistant open container comprises a ceramic boat.

579. A method according to claim 578, further comprising the step of providing a heater for obtaining or maintaining an elevated cell temperature such that the source of catalyst in the boat is sublimed, boiled, or volatilized into the gas phase.

580. A method according to claim 578, further comprising the step of providing a boat heater, and a power supply for heating the source of catalyst in the boat to provide gaseous catalyst to the vessel.

581. A method according to claim 578, further comprising the step of providing a temperature control means for controlling the temperature of the boat whereby the vapor pressure of the catalyst can be controlled.

582. A method according to any one of claims 367, 384, 407, 421 and 422, further comprising the step of providing a lower-energy hydrogen species and lower-energy hydrogen compound trap.

583. A method according to claim 582, further comprising the step of providing a vacuum pump in communication with the trap for causing a pressure gradient from the vessel to the trap for causing gas flow and transport of a lower-energy hydrogen species or lower-energy hydrogen compound.

584. A method according to claim 583, further comprising the steps of providing a passage from the vessel to the trap and a vacuum line from the trap to the pump, and providing valves to and from the trap.

585. A method according to any one of claims 367, 384, 407, 421 and 422, wherein the cell comprises at least one material selected from group consisting of stainless steel, molybdenum, tungsten, glass, quartz, and ceramic.

586. A method according to any one of claims 367, 384, 407, 421 and 422, further comprising the step of providing at least one selected from the group consisting of an aspirator, atomizer, or nebulizer, for forming an aerosol of the source of catalyst.

587. A method according to claim 586, further comprising the step of injecting the source of catalyst or catalyst directly into the plasma using the aspirator, atomizer, or nebulizer.

588. A method according to any one of claims 367, 384, 407, 421 and 422, further comprising the steps of agitating the catalyst or source of catalyst from a source of catalyst and supplying it to the vessel through a flowing gas stream.

589. A method according to claim 588, wherein the flowing gas stream comprises hydrogen gas or plasma gas which may be an additional source of catalyst.

590. A method according to claim 589, wherein the additional source of catalyst comprises helium or argon gas.

591. A method according to any one of claims 367, 384, 407, 421 and 422, further comprising the step of dissolving or suspending the source of catalyst in a liquid medium.

592. A method according to claim 591, further comprising the step of dissolving or suspending the source of catalyst in a liquid medium and aerosolizing the source of catalyst.

593. A method according to any one of claims 367, 384, 407, 421 and 422, further comprising the step of providing a carrier gas for transporting the catalyst to the vessel.

594. A method according to claim 593, wherein the carrier gas comprises at least one of hydrogen, helium, or argon.

595. A method according to claim 594, wherein the carrier gas comprises at least one of helium and argon which also serves as a source of catalyst and is ionized by the plasma to form at least one catalyst He⁺ or Ar⁺.

596. A method according to any one of claims 367, 384, 407, 421 and 422, wherein the cell produces a nonthermal plasma having a temperature in the range of about 5,000 to about 5,000,000° C.

597. A method according to any one of claims 367, 384, 407, 421 and 422, wherein heater provides a cell temperature above that of catalyst reservoir to serve as a controllable source of catalyst.

598. A method according to any one of claims 367, 384, 407, 421 and 422, wherein heater provides a cell temperature above that of catalyst boat to serve as a controllable source of catalyst.

599. A method according to any one of claims 367, 384, 407, 421 and 422, wherein the cell comprises stainless steel alloy which can be maintained in temperature range of 0 to about 1200° C.

600. A method according to any one of claims 367, 384, 407, 421 and 422, wherein the cell comprises molybdenum which can be maintained in temperature range of 0 to about 1800° C.

601. A method according to any one of claims 367, 384, 407, 421 and 422, wherein the cell comprises tungsten which can be maintained in temperature range of 0 to about 3000° C.

602. A method according to any one of claims 367, 384, 407, 421 and 422, wherein the cell comprises glass, quartz, or ceramic which can be maintained in a temperature range of 0 about 1800° C.

603. A method according to any one of claims 367, 384, 407, 421 and 422, wherein the cell provides molecular and atomic hydrogen partial pressures in a range of about 1 mtorr to about 100 atm.

604. A method according to any one of claims 367, 384, 407, 421 and 422, wherein the cell provides molecular and atomic hydrogen partial pressures in a range of about 100 mtorr to about 20 torr.

605. A method according to any one of claims 367, 384, 407, 421 and 422, wherein the cell provides catalytic partial pressure in a range of about 1 mtorr to 100 atm.

606. A method according to any one of claims 367, 384, 407, 421 and 422, wherein the cell provides catalytic partial pressure in a range of about 100 mtorr to 20 torr.

607. A method according to any one of claims 367, 384, 407, 421 and 422, wherein a mixture flow regulator provides a flow rate of the plasma gas in the range of about 0 to about 1 standard liters per minute per cm³ of cell volume.

608. A method according to claim 607, wherein the mixture flow regulator provides a flow rate of the plasma gas in the range of about 0.001 to about 100 sccm per cm³ of cell volume.

609. A method according to claim 607, wherein the mixture flow regulator provides a flow rate of the hydrogen gas in the range of about 0 to about 1 standard liters per minute per cm³ of cell volume.

610. A method according to claim 607, wherein the mixture flow regulator provides a flow rate of the hydrogen gas in the range of about 0.001 to about 100 sccm per cm³ of cell volume.

611. A method according to any one of claims 367, 384, 407, 421 and 422, wherein a hydrogen-plasma-gas mixture comprises at least one of helium or argon and being present in the amount of about 99 to about 1% by volume compared to the amount of hydrogen.

612. A method according to claim 611, wherein the hydrogen-plasma-gas mixture comprises at least one of helium or argon and being present in the amount of about 99 to about 95% by volume compared to the amount of hydrogen.

613. A method according to any one of claims 367, 384, 407, 421 and 422, wherein a mixture flow regulator provides a flow rate of hydrogen-plasma-gas mixture in the range of about 0 to about 1 standard liters per minute per cm³ of cell volume.

614. A method according to any one of claims 367, 384, 407, 421 and 422, wherein a mixture flow regulator provides a flow rate of a hydrogen-plasma- gas mixture in the range of about 0.001 to about 100 sccm per cm³ of cell volume.

615. A method according to any one of claims 367, 384, 407, 421 and 422, wherein the cell provides a power density of plasma power in the range of about 0.01 W to about 100 W/cm³ cell volume.

616. A method according to any one of claims 367, 384, 407, 421 and 422, further comprising the step of providing a power converter for converting the energy of ions in the plasma to electricity.

617. A method according to any one of claims 367, 384, 407, 421 and 422, further comprising a power converter that directly converts plasma to electricity.

618. A method according to claim 617, wherein the power converter comprises a heat engine.

619. A method according to claim 617, wherein the direct plasma to electric power converter comprises at least one selected from the group consisting of magnetic mirror magnetohydrodynamic power converter, plasmadynamic power converter, gyrotron, photon bunching microwave power converter, photoelectric, and charge drift power converter.

620. A method according to claim 617, wherein the heat engine power converter comprises at least one selected from the group consisting of steam, gas turbine system, sterling engine, thermionic, and thermoelectric.

621. A method according to any one of claims 367, 384, 407, 421 and 422, further comprising the step of providing a selective valve for removing lower-energy hydrogen products.

622. A method according to claim 621, wherein the selectively removed lower-energy hydrogen products comprise dihydrino molecules.

623. A method according to claim 621, further comprising the step of providing a cold wall to which increased binding energy hydrogen compounds can be cryopumped.

624. A method according to claim 421, wherein the power converter comprises a magnetohydrodynamic power converter contained in a vacuum vessel.

625. A method according to claim 624, further comprising the step of generating the plasma in a desired region, wherein a plasma temperature is much greater than the temperature of the magnetohydrodynamic power converter vacuum vessel.

626. A method according to claim 624, wherein high energy ions and electrons of the plasma flow from the hot desired plasma region of the cell to the colder magnetohydrodynamic power converter by virtue of the second law of thermodynamics.

627. A method according to claim 421, wherein the magnetohydrodynamic power converter receives the flow and converts the thermodynamically produced ion flow into electricity.

628. A method according to claim 624, wherein the magnetohydrodynamic power converter vacuum vessel further comprises a pump for maintaining a lower pressure than the pressure in the cell where the plasma is formed.

629. A method according to claim 624, wherein energetic ions flow thermodynamically into the magnetohydrodynamic power converter and neutral particles formed from the energetic ions following conversion of their energy to electricity flow in the opposite direction.

630. A method according to claim 629, wherein protons and electron have a large mean free path and energetic protons and electrons flow from the cell into the magnetohydrodynamic power converter, and hydrogen flows convectively in substantially the opposite direction.

631. A method according to claim 407, wherein the power supply provides a voltage in the range of about 10 to about 50 kV and a current density in the range of about 1 to about 100 A/cm².

632. A method according to claim 407, wherein the anode comprises tungsten.

633. A method according to claim 407, wherein the anode comprises platinum.

634. A method according to any one of claims 367, 384, 407, 421 and 422, further comprising the step of providing an axial magnetic field constructed and arranged to cause energetic protons in the plasma to undergo cyclotron motion, a means to cause the protons to gyrobunch to emit radio frequency radiation, and a receiver of the radio frequency power.

635. A method according to claim 634, further comprising the step of providing the cell with a resonate cavity and an antenna for exciting the cavity at a cyclotron resonance frequency of the protons, and a second antenna for exciting a proton spin resonance frequency to cause spin bunching wherein spin bunching causes gyrobunching.

636. A method according to claim 635, wherein gyrobunching is achieved by spin bunching with the application of resonant RF at the proton spin resonance frequency.

637. A method according to claim 635, wherein the antenna allows electromagnetic radiation emitted from the protons to excite the mode of the cavity and be received by the resonant receiving antenna.

638. A method according to claim 635, further comprising the step of providing a rectifier for rectifying a radiowave into DC electricity with a rectifier.

639. A method according to claim 638, further comprising the step of providing an inverter and power conditioner for inverting and transforming the DC electricity into a desired voltage and frequency.

640. A method according to claim 407, further comprising the step of shielding at least one of the cathode and the anode by a dielectric barrier.

641. A method according to claim 640, wherein the dielectric barrier comprises at least one selected from the group consisting of glass, quartz, Alumina, and ceramic.

642. A method according to claim 407, wherein the RF power is capacitively coupled to the cell.

643. A method according to claim 407, wherein the electrodes are external to the cell.

644. A method according to claim 407, further comprising the step of shielding at least one of the cathode and electrode by a dielectric barrier, wherein the dielectric barrier separates the electrode and anode from a cell wall.

645. A method according to claim 407, wherein the cell provides a high driving voltage and high frequency.

646. A method according to claim 407, wherein the cell provides an AC power.

647. A method according to claim 407, wherein the RF source of power comprises a driving circuit comprising a high voltage power source for providing RF and an impedance matching circuit.

648. A method according to claim 647, wherein the high voltage power source provides a voltage in the range of about 100 V to about 1 MV.

649. A method according to claim 647, wherein the high voltage power source provides a voltage in the range of about 1 kV to about 100 kV.

650. A method according to claim 647, wherein the high voltage power source provides a voltage in the range of about 5 to about 10 kV.

651. A method according to any one of claims 367, 384, 407, 421 and 422, wherein the source of catalyst comprises one or more molecules wherein the energy to break the molecular bond and the ionization of t electrons from an atom from the dissociated molecule to a continuum energy level is such that the sum of the ionization energies of the t electrons is approximately m·27.2±0.5 eV where m is an integer or m/2·27.2±0.5 eV where m is an integer greater than one and t is an integer.

652. A method according to any one of claims 367, 384, 407, 421 and 422, wherein the source of catalyst provides a catalytic system comprising the ionization of t electrons from a participating species comprising atoms, ions, molecules, and ionic or molecular compounds, to a continuum energy level such that the sum of the ionization energies of the t electrons is approximately m·27.2±0.5 eV where m is an integer or m/2·27.2±0.5 eV where m is an integer greater than one and t is an integer.

653. A method according to any one of claims 367, 384, 407, 421 and 422, wherein the source of catalyst provides a catalyst comprising the transfer of t electrons between participating ions and the transfer of t electrons from one ion to another ion provides a net enthalpy of reaction whereby the sum of the ionization energy of the electron donating ion minus the ionization energy of the electron accepting ion equals approximately m·27.2±0.5 eV where m is an integer or m/2·27.2±0.5 eV where m is an integer greater than one and t is an integer.

654. A method according to any one of claims 367, 384, 407, 421 and 422, wherein the source of catalyst comprises a molecule, and a catalyst of atomic hydrogen capable of providing a net enthalpy of reaction of m·27.2±0.5 eV where m is an integer or m/2·27.2±0.5 eV where m is an integer greater than one and capable of forming a hydrogen atom having a binding energy of about
$$\frac{13.6 eV}{{( \frac{1}{p} )}^{2}}$$
where p is an integer wherein the net enthalpy is provided by the breaking of a molecular bond of the source of catalyst and the ionization of t electrons from an atom of the broken molecule each to a continuum energy level such that the sum of the bond energy and the ionization energies of the t electrons is approximately m/2·27.2±0.5 eV where m is an integer greater than one and t is an integer.

655. A method according to any one of claims 367, 384, 407, 421 and 4223, wherein the cell produces extreme ultraviolet light.

656. A method according to claim 655, wherein the cell comprises light propagation structure comprises a material that propagates extreme ultraviolet light.

657. A method according to claim 656, wherein the light propagation structure comprises quartz.

658. A method according to any one of claims 367, 384, 407, 421 and 422, wherein the cell produces ultraviolet light.

659. A method according to claim 658, wherein the cell comprises light propagation structure comprises a material that propagates ultraviolet light.

660. A method according to claim 659, wherein the light propagation structure comprises quartz.

661. A method according to any one of claims 367, 384, 407, 421 and 422, wherein the cell produces visible light.

662. A method according to claim 661, wherein the cell comprises light propagation structure comprises a material that propagates visible light.

663. A method according to claim 662, wherein the light propagation structure comprises glass.

664. A method according to any one of claims 367, 384, 407, 421 and 4223, wherein the cell produces extreme infrared light.

665. A method according to claim 664, wherein the cell comprises light propagation structure comprises a material that propagates infrared light.

666. A method according to claim 665, wherein the light propagation structure comprises glass.

667. A method according to any one of claims 367, 384, 407, 421 and 422, wherein the cell produces microwaves.

668. A method according to claim 667, wherein the cell comprises light propagation structure comprises a material that propagates microwaves.

669. A method according to claim 668, wherein the light propagation structure comprises glass, quartz or ceramic.

670. A method according to any one of claims 367, 384, 407, 421 and 4223, wherein the cell produces radiowaves.

671. A method according to claim 670, wherein the cell comprises light propagation structure comprises a material that propagates radiowaves.

672. A method according to claim 671, wherein the light propagation structure comprises glass, quartz or ceramic.

673. A method according to any one of claims 367, 384,407, 421 and 422, wherein the cell comprises light propagation structure that propagates a wavelength of light produced.

674. A method according to any one of claims 367, 384, 407, 421 and 422, wherein the cell provides short wavelength light and comprises light propagation structure that propagates short wavelength light which is suitable for photolithography.

675. A method according to any one of claims 367, 384, 407, 421 and 422, further comprising light propagation structure that comprises at least part of a cell wall and propagates a desired wavelength or wavelength range.

676. A method according to claim 675, further comprising the step of insulating the cell wall for maintaining an elevated temperature in the cell.

677. A method according to claim 676, wherein the cell wall comprises a double wall with a separating vacuum space.

678. A method according to any one of claims 367, 384, 407, 421 and 422, wherein the cell comprises light propagation structure coated with a phosphor that converts one or more short wavelengths to longer wavelength light.

679. A method according to claim 678, wherein the phosphor converts at least one of ultraviolet and extreme ultraviolet light to visible light.

680. A method according to any one of claims 367, 384, 407, 421 and 422, further comprising the step of providing a hydrogen dissociator.

681. A method according to claim 680, wherein the hydrogen dissociator comprises a filament.

682. A method according to claim 681, wherein the filament comprises a tungsten filament.

683. A cell of according to 680, wherein the hydrogen dissociator further comprises a heater to heat the source of catalyst to form a gaseous catalyst.

684. A method according to claim 680, wherein the source of catalyst comprises at least one selected from the group consisting of potassium, rubidium, cesium and strontium metal.

685. A method according to any one of claims 367, 384, 407, 421 and 422, wherein the source of hydrogen comprises a hydride that decomposes over time to maintain a desired hydrogen partial pressure.

686. A method according to claim 685, further comprising the step of providing a means for controlling the temperature of the cell to maintain a desired decomposition rate of the hydride to provide a desired hydrogen partial pressure.

687. A method according to claim 686, wherein the means to control the temperature comprises a heater and a heater power controller.

688. A method according to claim 687, wherein the heater and controller comprise a filament and a filament power controller.

689. A method according to claim 422, which is based on magnetic space charge separation.

690. A method according to claim 422, which comprises at least one of a hydrino hydride reactor or other power source such as a microwave plasma cell, at least one electrode magnetized with a source of magnetic field which provides a uniform parallel magnetic field, at least one magnetized electrode, and at least one counter electrode.

691. A method according to claim 690, wherein the source of magnetic field comprises at least of solenoidal magnets and permanent magnets.

692. A method according to claim 422, further comprising a means to localized the plasma in a desired region.

693. A method according to claim 692, wherein the means to localized the plasma in a desired region comprises at least one of a magnetic confinement structure or spatially selective generation means.

694. A method according to claim 693, wherein the cell is a microwave cell and the spatially selective generation means comprises one or more spatially selective antennas, waveguides, or cavities.

695. A method according to claim 422, wherein electrons are magnetically trapped on field lines of the magnetic field while positive ions drift.

696. A method according to claim 695, wherein the floating potential is increased at the magnetized electrode relative to the unmagnetized counter electrode to produce a voltage between the electrodes.

697. A method according to claim 696, further comprising electrodes and power is supplied to a load through the connected electrodes.

698. A method according to claim 422, further comprising a plurality of magnetized electrodes.

699. A method according to claim 698, wherein source of uniform magnetic field parallel to each electrode comprises Helmholtz coils.

700. A method according to claim 699, wherein the strength of the magnetic field is adjusted to produce an optimal positive ion versus electron radius of gyration to maximize the power at the electrodes.

701. A method according to claim 422, wherein plasma is confined to the region of at least one magnetized electrode, and the counter electrode is in a region outside of the energetic plasma.

702. A method according to claim 422, wherein plasma is confined to a region of one unmagnetized electrode and a counter magnetized electrode is outside of the plasma region.

703. A method according to claim 422, wherein the plasmadynamic converter comprises at least two electrodes and two electrodes are magnetized, and the field strength at one electrode is greater than that at the other electrode.

704. A method according to claim 703, wherein further comprises a heater that heats the magnetized electrode to boil off electrons which are much more mobile than the ions.

705. A method according to claim 704, wherein the electrons are trapped by the magnetic field lines or recombine with ions to give rise to a greater positive voltage at the magnetized electron compared to the unmagnetized electrode.

706. A method according to claim 422, wherein energy is extracted from energetic positive ions and electrons.

707. A method according to claim 422, further comprising a magnetized electrode having a magnetized pin wherein field lines are substantially parallel to the pin.

708. A method according to claim 707, wherein any flux that would intercept the pin ends on an electrical insulator.

709. A method according to claim 708, comprising an array of the pins used to increase the power converted.

710. A method according to claim 708, wherein at least one counter unmagnetized electrode is electrically connected to the one or more magnetized pins through an electrical load.

711. A method of operating a cell for producing a plasma comprising the steps of:
providing a source of hydrogen atoms; and
applying microwaves to the source of hydrogen atoms sufficient to dissociate the hydrogen into separate hydrogen atoms under conditions such that that two hydrogen atoms act like a catalyst and ionize to absorb a total of 27.2 eV from a third hydrogen atom to thereby cause the third hydrogen atom to relax to a lower energy state and form lower-energy hydrogen and produce a plasma.

712. A method of operating a cell for producing a plasma comprising the steps of:
providing a source of hydrogen atoms; and
applying microwaves to the source of hydrogen atoms sufficient to dissociate the hydrogen into separate hydrogen atoms and produce a plasma.

713. A method according to one of claims 711 and 712, further comprising converting power from a plasma to electricity using a converter.

714. A method according to claim 713, wherein the converter comprises a magnetohydrodynamic power converter.

715. A method according to claim 713, wherein the converter comprises a plasmadynamic power converter.

716. A method according to claim 511, wherein the increased binding energy hydrogen species is selected from the group consisting of
(a) a hydrogen atom having a binding energy of about
$$\frac{13.6 eV}{{( \frac{1}{p} )}^{2}}$$
where p is an integer,
(b) an increased binding energy hydride ion (H⁻) having a binding energy of about
$$\frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{π {μ}_{0} {e}^{2} {ℏ}^{2}}{{m}_{e}^{2} {a}_{0}^{3}} ( 1 + \frac{{2}^{2}}{{[ \frac{1 + \sqrt{s ( s + 1 )}}{p} ]}^{3}} )$$
where s=1/2, π is pi, \overline{h} is Planck's constant bar, μ₀ is the permeability of vacuum, mₑ is the mass of the electron, μₑ is the reduced electron mass, a₀ is the Bohr radius, and e is the elementary charge;
(c) an increased binding energy hydrogen species H₄⁺(1/p);
(d) an increased binding energy hydrogen species trihydrino molecular ion, H₃⁺(1/p), having a binding energy of about
$$\frac{22.6}{{( \frac{1}{p} )}^{2}} eV$$
where p is an integer,
(e) an increased binding energy hydrogen molecule having a binding energy of about
$$\frac{15.5}{{( \frac{1}{p} )}^{2}} eV ;$$
and
(f) an increased binding energy hydrogen molecular ion with a binding energy of about
$$\frac{16.4}{{( \frac{1}{p} )}^{2}} eV .$$
